(19) United States
(12) Patent Application Publication
(10) Pub. No.: US 2026/0215152 A1
(43) Pub. Date: Jul. 23, 2026

(54) HETEROCYCLIC COMPOUND AND ORGANIC ELECTROLUMINESCENT DEVICE

(71) Applicant: GUANGDONG AGLAIA OPTOELECTRONIC MATERIALS CO., LTD, Guangdong (CN)

(72) Inventors: Shaofu CHEN, Guangdong (CN); Jiahui TAN, Guangdong (CN); Keyan BAI, Guangdong (CN); Lei DAI, Guangdong (CN); Lifei CAI, Guangdong (CN)

(73) Assignee: GUANGDONG AGLAIA OPTOELECTRONIC MATERIALS CO., LTD, Guangdong (CN)

(21) Appl. No.: 19/455,344

(22) Filed: Jan. 21, 2026

(30) Foreign Application Priority Data
Jan. 23, 2025 (CN) 202510110555X

(51) Int. Cl. H10K 85/60; C07B 59/00; C07F 9/6558; C07F 9/6561; H10K 50/11

(52) U.S. Cl. CPC H10K 85/654; C07B 59/004; C07F 9/65583; C07F 9/65586; C07F 9/6561; H10K 85/615; H10K 85/626; H10K 85/6572; H10K 85/6574; C07B 2200/05; H10K 50/11

(57) ABSTRACT

The present disclosure relates a heterocyclic compound and an organic electroluminescent device. The compound has the structure of formula (1), wherein X₁, X₂, and X₃ are each independently selected from N or CR₅, and at least one of X₁ to X₃ is N. The compound can be used to prepare N-type charge generation layer of OLED, which can effectively reduce device power consumption, improve luminous efficiency, and extend device lifetime, and has the potential to be applied in the AMOLED industry.

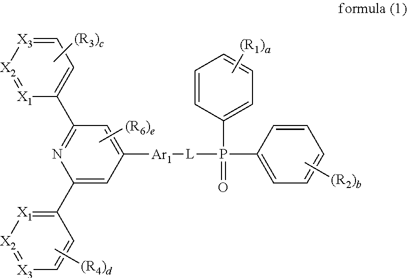

### CROSS-REFERENCE TO RELATED APPLICATION

This application claims priority to Chinese Patent Application No. 202510110555.X, filed Jan. 23, 2025, the disclosure of which is hereby incorporated by reference in its entirety.

### TECHNICAL FIELD

The present disclosure belongs to the technical field of organic electroluminescence, and in particular relates to a heterocyclic compound and an organic electroluminescent device.

### BACKGROUND

Currently, organic electroluminescent devices (OLEDs), as a next-generation display technology, have received widespread attention in the fields of display and lighting, showing broad application prospects. With the continuous development of OLED technology in the fields of display and lighting, higher requirements have been put forward for the performance of OLED devices, especially in terms of low power consumption, high efficiency and long lifetime. Therefore, the development of higher-performance functional materials and the optimization of device structures have become hot topics in current research.

The most common OLED device structures typically include the following functional materials: hole injection materials, hole transport materials, electron transport materials, and luminescent materials (including host materials and guest materials), etc. Electron transport materials, as an important functional material, have a direct impact on electron mobility and ultimately affect the luminous efficiency of OLEDs. Therefore, improving the mobility of electron transport materials and reducing device power consumption have become important directions for improving the performance of OLED devices. By forming a tandem OLED structure, stacking multiple light-emitting layers, and sandwiching charge generation layers therebetween, the mobility can be further improved. The charge generation layers typically include an N-type charge generation layer and a P-type charge generation layer. The N-type charge generation layer, as an electron transport material, plays an important role in improving mobility and reducing power consumption. However, the performance improvement of related materials is still limited, and the device efficiency or lifetime still needs further improvement.

Therefore, it is necessary to develop a charge generation layer material with higher mobility.

### SUMMARY

The present disclosure aims to solve at least one of the technical problems existing in the prior art. To this end, the present disclosure provides a heterocyclic compound, which can be used to prepare an N-type charge generation layer of organic electroluminescent devices (OLEDs). The compound has high electron mobility, which can effectively reduce device power consumption, improve luminous efficiency, and extend device lifetime.

Specifically, in a first aspect, an embodiment of the present disclosure relates to a heterocyclic compound having a structure of formula (1):

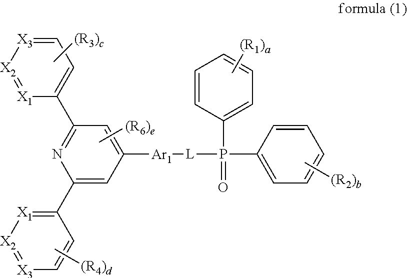

wherein X₁, X₂, and X₃ are each independently selected from N or CR₅; and at least one of X₁ to X₃ is N;
wherein R₁ to R₅, each time appearing, are each independently selected from the group consisting of hydrogen, deuterium, halogen, cyano, nitro, C1-C40 alkyl, C1-C40 heteroalkyl, C2-C40 alkenyl, C2-C40 alkynyl, C3-C40 cycloalkyl, C3-C40 heterocycloalkyl, C6-C60 aryl, C5-C60 heteroaryl, C1-C40 alkoxy, C6-C60 aryloxy, C3-C40 alkylsilyl, C6-C60 arylsilyl, C1-C40 alkylboryl, C6-C60 arylboryl, C6-C60 arylphosphino, and C6-C60 arylamino;
wherein R₆ is hydrogen, deuterium, or halogen;
wherein Ar₁ is substituted or unsubstituted C6-C30 arylene, or substituted or unsubstituted C3-C60 heteroarylene;
wherein a and b are each independently selected from an integer of 0 to 5; and c, d, and e are each independently selected from an integer of 0 to 2;
wherein L is single bond, substituted or unsubstituted C6-C30 arylene, or substituted or unsubstituted C2-C30 heteroarylene;
wherein a heteroatom in the heteroaryl, heteroarylene, heteroalkyl, or heterocycloalkyl is at least one selected from the group consisting of O, S, N, Se, Si, and Ge; and
wherein each of substitutions in L and Ar₁ refers to being independently substituted with at least one selected from the group consisting of deuterium, halogen, cyano, isocyano, nitro, C1-C20 alkyl, C1-C20 heteroalkyl, C2-C20 alkenyl, C2-C20 alkynyl, C3-C20 cycloalkyl, C3-C20 heterocycloalkyl, C1-C6 alkyl-substituted amino, C1-C8 hydrocarbyl-substituted or unsubstituted C6-C30 aryl, C1-C8 hydrocarbyl-substituted or unsubstituted C4-C30 heteroaryl, C1-C20 alkoxy, C6-C30 aryloxy, C3-C20 alkylsilyl, C6-C30 arylsilyl, C1-C20 alkylboryl, C6-C30 arylboryl, C6-C30 arylphosphino, and C6-C30 arylamino, wherein the number of substitutions ranges from monosubstitution to the maximum number of substitutions; and
the heterocyclic compound satisfies the following conditions:
(1) Ar₁ is not C1-C20 alkyl-substituted or unsubstituted anthrylene;
(2) Ar₁ is not selected from

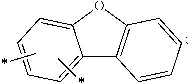

(3) when —Ar₁-L- is one of the structures shown in formula (C-1) to formula (C-3), L is not phenylene or six-membered heteroarylene:

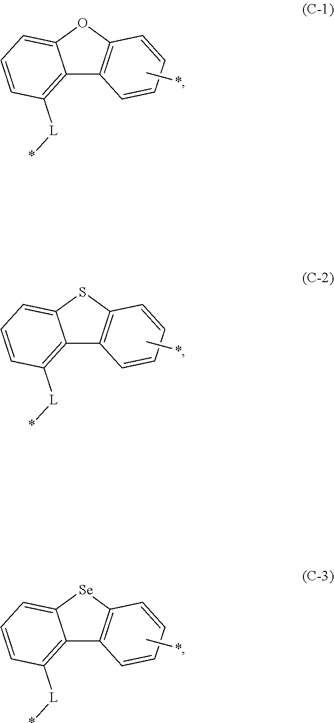

and
(4) neither L nor Ar₁ contains a benzonaphthofuran ring.

The beneficial effects of the present disclosure are as follows:

The heterocyclic compound of the present disclosure has a nitrogen-containing heterocyclic and phosphinyl structure, exhibits high mobility, and can serve as a charge generation layer material for OLEDs. In particular, the compound can coordinate with a dopant (such as an alkali metal, an alkaline earth metal, and a lanthanide metal) to reduce the energy level difference between the N-type charge generation layer and the P-type charge generation layer, thereby promoting electron injection into the N-type charge generation layer and maximizing electron transfer from the N-type charge generation layer to the adjacent electron transport layer, further improving device performance.

When applied to OLED devices, the compound can effectively reduce driving voltage, improve luminous efficiency, and extend device lifetime, showing potential for application in the AMOLED industry.

### BRIEF DESCRIPTION OF DRAWINGS

FIG. 1 shows a ¹H NMR spectrum of compound A59 according to an embodiment of the present disclosure; and

FIG. 2 is a schematic diagram of the structure of an organic electroluminescent device according to an embodiment of the present disclosure.

### DETAILED DESCRIPTION

To enable those skilled in the art to better understand the technical solutions described in the present disclosure, the following embodiments are provided for illustration. It should be noted that the following embodiments do not constitute a limitation on the scope of protection claimed by the present disclosure.

In a first aspect, an embodiment of the present disclosure provides a heterocyclic compound having a structure of formula (1):

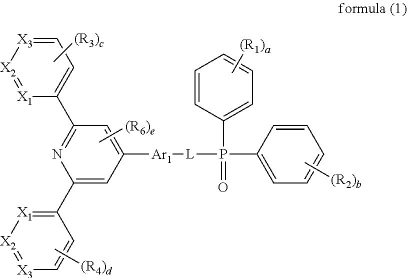

wherein X₁, X₂, and X₃ are each independently selected from N or CR₅; and at least one of X₁ to X₃ is N;
wherein R₁ to R₅, each time appearing, are each independently selected from the group consisting of hydrogen, deuterium, halogen, cyano, nitro, C1-C40 alkyl, C1-C40 heteroalkyl, C2-C40 alkenyl, C2-C40 alkynyl, C3-C40 cycloalkyl, C3-C40 heterocycloalkyl, C6-C60 aryl, C5-C60 heteroaryl, C1-C40 alkoxy, C6-C60 aryloxy, C3-C40 alkylsilyl, C6-C60 arylsilyl, C1-C40 alkylboryl, C6-C60 arylboryl, C6-C60 arylphosphino, and C6-C60 arylamino;
wherein R₆ is hydrogen, deuterium, or halogen;
wherein Ar₁ is substituted or unsubstituted C6-C30 arylene, or substituted or unsubstituted C3-C60 heteroarylene;
wherein a and b are each independently selected from an integer of 0 to 5; and c, d, and e are each independently selected from an integer of 0 to 2;
wherein L is single bond, substituted or unsubstituted C6-C30 arylene, or substituted or unsubstituted C2-C30 heteroarylene;
wherein a heteroatom in the heteroaryl, heteroarylene, heteroalkyl, or heterocycloalkyl is at least one selected from the group consisting of O, S, N, Se, Si, and Ge; and
wherein each of substitutions in L and Ar₁ refers to being independently substituted with at least one selected from the group consisting of deuterium, halogen, cyano, isocyano, nitro, C1-C20 alkyl, C1-C20 heteroalkyl, C2-C20 alkenyl, C2-C20 alkynyl, C3-C20 cycloalkyl, C3-C20 heterocycloalkyl, C1-C6 alkyl-substituted amino, C1-C8 hydrocarbyl-substituted or unsubstituted C6-C30 aryl, C1-C8 hydrocarbyl-substituted or unsubstituted C4-C30 heteroaryl, C1-C20 alkoxy, C6-C30 aryloxy, C3-C20 alkylsilyl, C6-C30 arylsilyl, C1-C20 alkylboryl, C6-C30 arylboryl, C6-C30 arylphosphino, and C6-C30 arylamino, wherein the number of substitutions ranges from monosubstitution to the maximum number of substitutions; and
the heterocyclic compound satisfies the following conditions:
(1) Ar₁ is not C1-C20 alkyl-substituted or unsubstituted anthrylene;
(2) Ar₁ is not

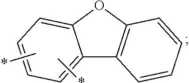

(3) when —Ar₁-L- is one of the structures shown in formula (C-1) to formula (C-3), L is not a phenylene group or a six-membered heteroarylene group:

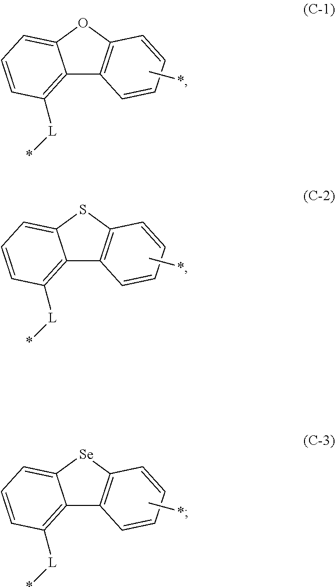

and
(4) neither L nor Ar₁ contains a benzonaphthofuran ring.

It should be understood that a, b, c, d, and e represent the number of substituents or atoms R₁, R₂, R₃, R₄, and R₆, respectively. When any one of a, b, c, d, or e is greater than or equal to 2, the multiple substituents or atoms (R₁, R₂, R₃, R₄, or R₆) on the same substituted ring can be the same or different. For example, when a is an integer of 2 to 5, each R₁ can be the same or different.

The term “six-membered heteroarylene” refers to a heterocyclic structure containing six ring atoms formed when at least one carbon atom in a phenyl group is replaced by a heteroatom as defined above. There are usually 1 to 3 heteroatoms, such as pyridinyl, pyrimidinyl, triazine, and the like.

Unless otherwise specified, “*” in the structural formula indicates a connection site, which usually means that the corresponding structure is connected to other atoms or groups through the site indicated by “*”. For example, —Ar₁-L- is

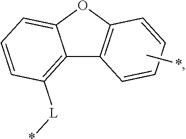

indicating that Ar₁-L is connected to the P atom and pyridine ring in formula (1) through the sites marked with “*” at both ends of the structural formula (i.e., any substituted sites of L and the benzene ring on the right).

The heterocyclic compound satisfies conditions (1) to (4), and specifically excludes the following structures, for example:

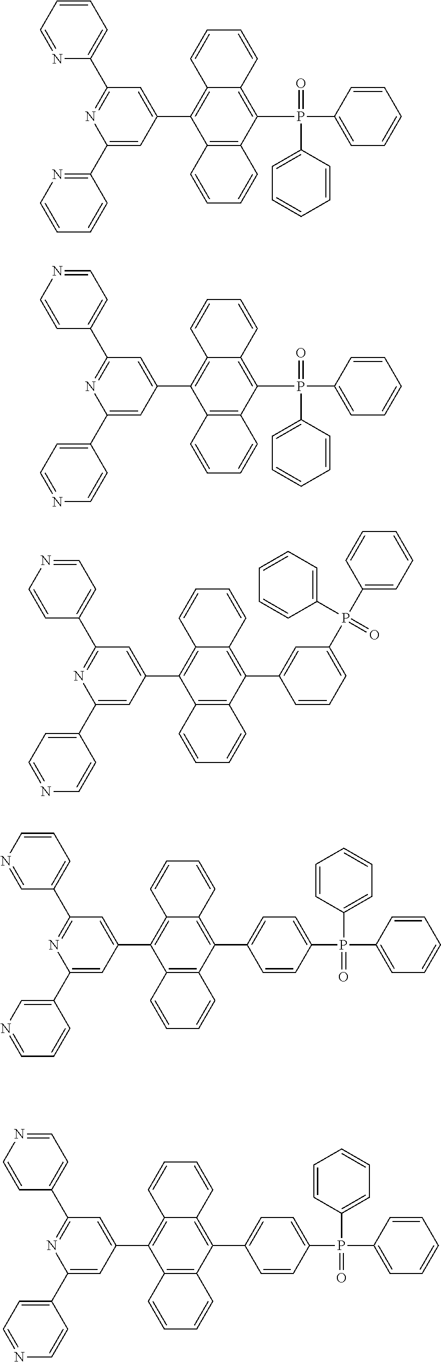

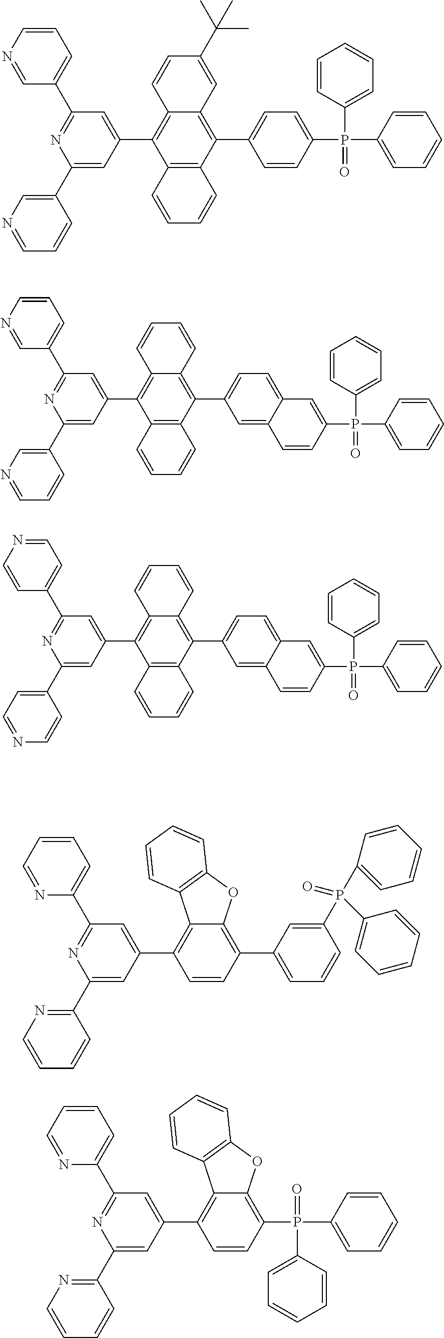

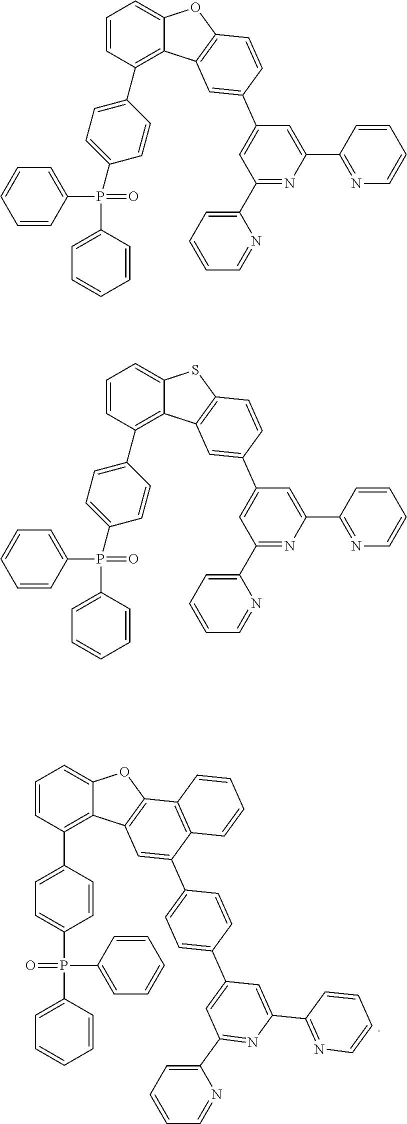 [SMILES: O=P(c1ccccc1)(c1ccccc1)c1ccc(-c2cccc3oc4ccc(-c5cc(-c6ccccn6)nc(-c6ccccn6)c5)cc4c23)cc1 ; O=P(c1ccccc1)(c1ccccc1)c1ccc(-c2cccc3sc4ccc(-c5cc(-c6ccccn6)nc(-c6ccccn6)c5)cc4c23)cc1 ; O=P(c1ccccc1)(c1ccccc1)c1ccc(-c2cccc3oc4c5ccccc5c(-c5ccc(-c6cc(-c7ccccn7)nc(-c7ccccn7)c6)cc5)cc4c23)cc1]

In some embodiments, only one of X₁ to X₃ is N.

In some embodiments, X₁ or X₂ is N, and the rest of X₁ to X₃ are each selected from CR₅.

In some embodiments, the above-mentioned heterocyclic compound is selected from one of the structures shown in formula (A-1) to formula (A-3):

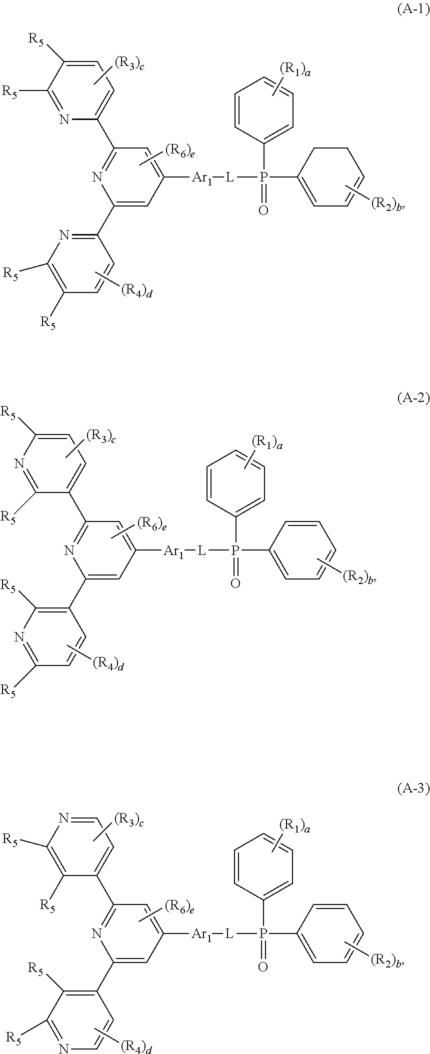

wherein R₅ is independently selected from the group consisting of hydrogen, deuterium, halogen, cyano, C1-C6 alkyl, C1-C6 heteroalkyl, C3-C6 cycloalkyl, C3-C6 heterocycloalkyl, C6-C12 aryl, and C5-C12 heteroaryl; and
L, Ar₁, R₁-R₄, R₆, a, d, e are as defined above.

In some embodiments, Are is selected from one of the structures shown in formula (B-1) to formula (B-22) or a combination of at least two thereof:

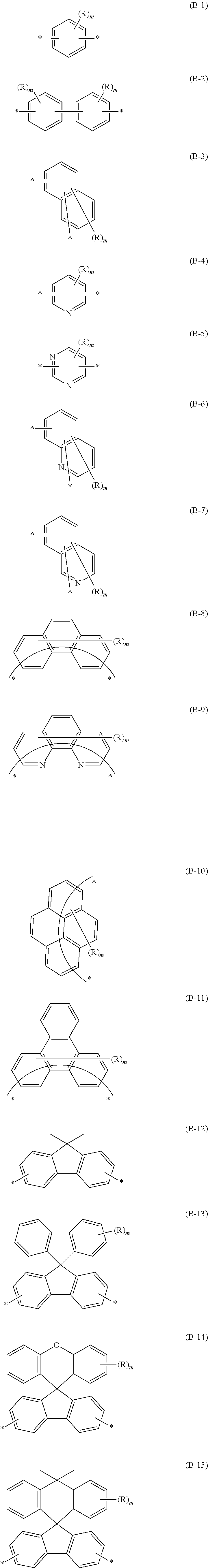

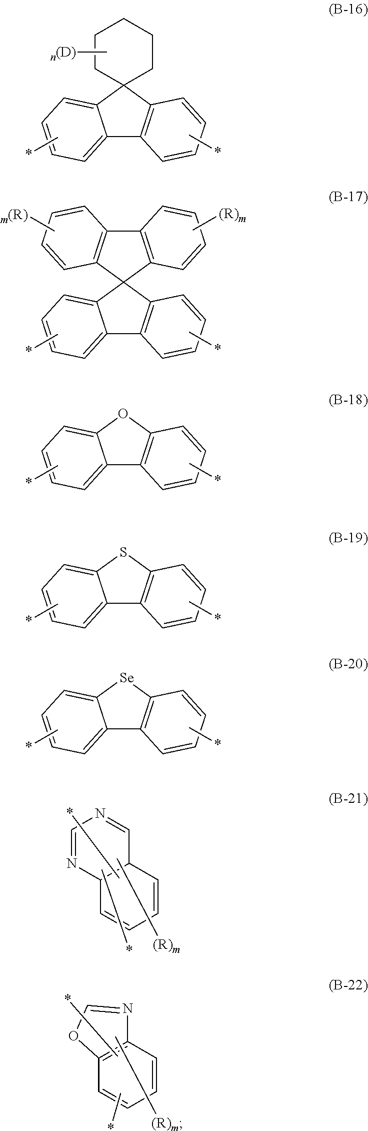

wherein R is independently selected from the group consisting of hydrogen, deuterium, halogen, cyano, isocyano, nitro, C1-C20 alkyl, C1-C20 heteroalkyl, C2-C20 alkenyl, C2-C20 alkynyl, C3-C20 cycloalkyl, C3-C20 heterocycloalkyl, C1-C6 alkyl-substituted amino, C1-C8 hydrocarbyl-substituted or unsubstituted C6-C30 aryl, C1-C8 hydrocarbyl-substituted or unsubstituted C4-C30 heteroaryl, C1-C20 alkoxy, C6-C30 aryloxy, C3-C20 alkylsilyl, C6-C30 arylsilyl, C1-C20 alkylboryl, C6-C30 arylboryl, C6-C30 arylphosphino, and C6-C30 arylamino;
m is selected from an integer of 0 to 8; D represents a deuterium atom; and n is selected from an integer of 0 to 10; and
when —Ar₁-L- is selected from one of the structures shown in formula (C-1) to formula (C-3), L is not selected from phenylene group or six-membered heteroarylene.

It should be understood that the range of values for m above covers the maximum number of substitutions for R in formula (B-1) to formula (B-22). Therefore, the value of m is simultaneously subject to the restriction of the maximum number of substitutions for the corresponding structure. For example, when the maximum number of substitutions is 4, the value of m should be selected from integer of 0 to 4.

The term “a combination of at least two thereof” means that at least two structures as defined above (one of formulas (B-1) to (B-22), also referred to as substructures) are combined to form Ar₁ (also referred to as a combined structure). In the combined structure, either two sites indicated by “*” in any substructure, or one site indicated by “*” in each of any two substructures, serve as the connection site for Ar₁. Substructures are connected to each other through other sites indicated by “*” or through sites indicated by R. If any substructure is connected to the site indicated by “*” (or the site indicated by R) of another substructure through the site indicated by R (i.e., the maximum number of R that can be substituted in the substructure will be reduced by one), one (or two) additional connection sites indicated by “*” will be present in the combined structure. In this case, except for the connection site indicated by “*” that serves as Ar₁ linker, all other connection sites indicated by “*” in the combined structure can be substituted with R, and thus the total number of Rs in the combined structure is the same as the total number of Rs in all substructures.

For example, the structures that can be formed by the combination of

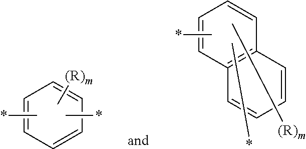

include, but are not limited to, the following structures:

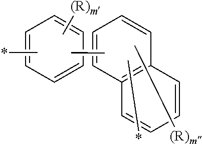

(m′ is selected from an integer of 0 to 4, and m″ is selected from an integer of 0 to 6) or

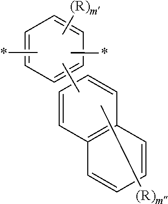

(m′ is selected from an integer of 0 to 3 and m″ is selected from an integer of 0 to 7), etc.

It should be understood that the combination of groups is based on the premise of satisfying the carbon number range of Ar₁ as defined above.

In some embodiments, when Ar₁ includes the structure shown in formula (B-18), formula (B-19), or formula (B-20), —Ar₁-L- includes one of the following structures:

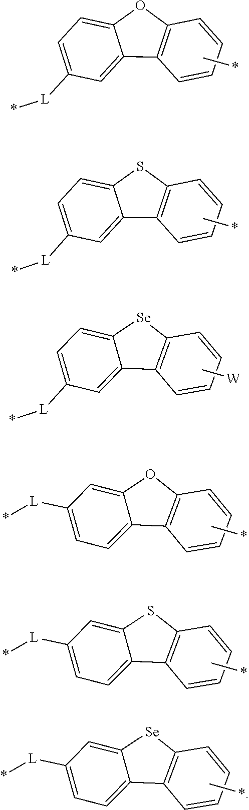

When L is connected to the para or meta position of the benzene ring in a benzofuran-based structure, the resulting heterocyclic compound, when used as an N-type charge generation layer material, can achieve lower driving voltage, higher luminous efficiency, and effectively extend the device lifetime.

In some embodiments, L is selected from one of the structures shown in formula (B-1) to formula (B-20) or a combination of at least two thereof, or a single bond; and when —Ar₁-L- is selected from one of the structures shown in formula (C-1) to formula (C-3), L is not selected from formula (B-1), formula (B-4) or formula (B-5).

In some embodiments, R₁ to R₅, each time appearing, are each independently selected from the group consisting of hydrogen, deuterium, halogen, cyano, nitro, C1-C20 alkyl, C1-C20 heteroalkyl, C2-C20 alkenyl, C2-C20 alkynyl, C3-C20 cycloalkyl, C3-C20 heterocycloalkyl, C6-C30 aryl, C5-C30 heteroaryl, C1-C20 alkoxy, C6-C30 aryloxy, C3-C20 alkylsilyl, C6-C30 arylsilyl, C1-C20 alkylboryl, C6-C30 arylboryl, C6-C30 arylphosphino, and C6-C30 arylamino.

In some embodiments, R₁ to R₅, each time appearing, are each independently selected from the group consisting of hydrogen, deuterium, halogen, cyano, nitro, C1-C12 alkyl, C1-C12 heteroalkyl, C3-C12 cycloalkyl, C3-C12 heterocycloalkyl, C6-C20 aryl, and C5-C20 heteroaryl.

In some embodiments, R₁ to R₅, each time appearing, are each independently selected from the group consisting of hydrogen, deuterium, halogen, cyano, C1-C6 alkyl, C1-C6 heteroalkyl, C3-C6 cycloalkyl, C3-C6 heterocycloalkyl, C6-C12 aryl, and C5-C12 heteroaryl. Specifically, for example, R₁ to R₅ are each independently selected from the group consisting of hydrogen, deuterium, F, Cl, Br, methyl, ethyl, propyl, butyl, phenyl, and benzoxazolyl, and the like. Each group includes various isomers, for example, butyl includes n-butyl, isobutyl, sec-butyl, or tert-butyl isomers.

In some embodiments, each of substitutions in L and Ar₁ refers to being independently substituted with at least one selected from the group consisting of deuterium, halogen, cyano, isocyano, nitro, C1-C10 alkyl, C1-C10 heteroalkyl, C2-C10 alkenyl, C2-C10 alkynyl, C3-C10 cycloalkyl, C3-C10 heterocycloalkyl, C1-C6 alkyl-substituted amino, C1-C8 hydrocarbyl-substituted or unsubstituted C6-C20 aryl, C1-C8 hydrocarbyl-substituted or unsubstituted C4-C20 heteroaryl, C1-C10 alkoxy, C6-C20 aryloxy, C3-C10 alkylsilyl, C6-C20 arylsilyl, C1-C10 alkylboryl, C6-C20 arylboryl, C6-C20 arylphosphino, and C6-C20 arylamino, wherein the number of substitutions ranges from monosubstitution to the maximum number of substitutions.

In some embodiments, each of substitutions in L and Ar₁ refers to being independently substituted with at least one selected from the group consisting of deuterium, halogen, cyano, isocyano, C1-C6 alkyl, C3-C6 cycloalkyl, C1-C6 alkyl-substituted amino, C1-C8 hydrocarbyl-substituted or unsubstituted C6-C16 aryl, C1-C8 hydrocarbyl-substituted or unsubstituted C4-C16 heteroaryl, and C6-C12 arylphosphino, wherein the number of substitutions ranges from monosubstitution to the maximum number of substitutions.

In some embodiments, the heterocyclic compound satisfies at least one of the following conditions:
(1) only one of X₁ to X₃ is N, and the rest of X₁ to X₃ are each independently selected from CR₅, and each of R₅ is independently selected from the group consisting of hydrogen, deuterium, methyl and phenyl;
(2) R₁ to R₄, each time appearing, are each independently selected from the group consisting of hydrogen, deuterium, methyl, phenyl and pyridyl;
(3) R₆ is hydrogen, deuterium, or fluorine; and
(4) Ar₁ is one of the structures shown in formula (B-1) to formula (B-22), or a combination of at least two thereof; L is one of the structures shown in formula (B-1) to formula (B-20) or a combination of at least two thereof, or a single bond; furthermore, when —Ar₁-L- is selected from one of the structures shown in formula (C-1) to formula (C-3), L is not selected from formula (B-1), formula (B-4), or formula (B-5);
wherein R is independently selected from the group consisting of hydrogen, deuterium, fluorine, cyano, methyl, isopropyl, tert-butyl, C1-C8 hydrocarbyl-substituted or unsubstituted phenyl, naphthyl, phenanthryl, pyridyl, pyrimidinyl, and benzoxazolyl.

In some embodiments, the heterocyclic compound is one of the following structural formulas, or one of the following structural formulas in which hydrogen is partially or completely substituted by deuterium or fluorine:

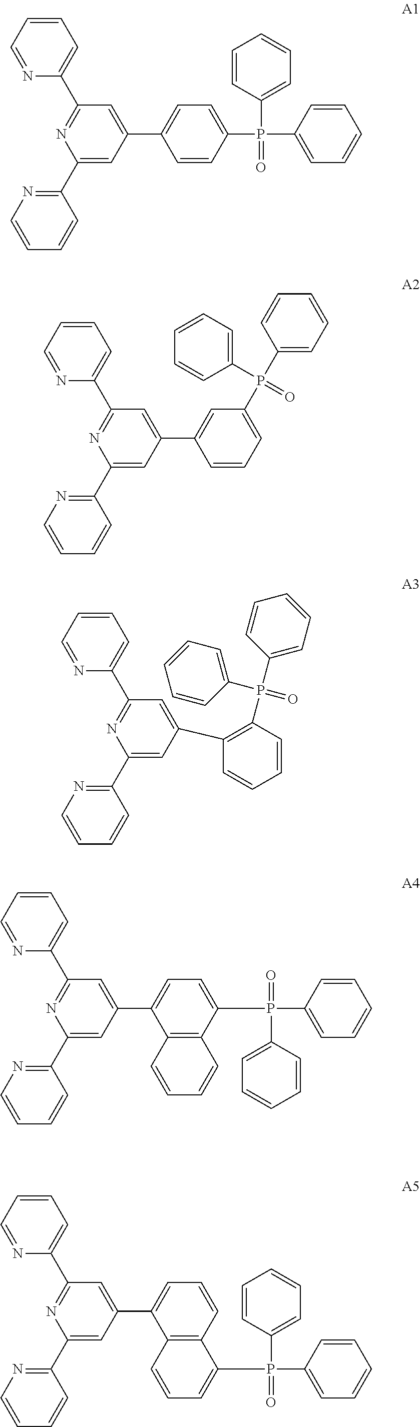 [SMILES: O=P(c1ccccc1)(c1ccccc1)c1ccc(-c2cc(-c3ccccn3)nc(-c3ccccn3)c2)cc1 ; O=P(c1ccccc1)(c1ccccc1)c1cccc(-c2cc(-c3ccccn3)nc(-c3ccccn3)c2)c1 ; O=P(c1ccccc1)(c1ccccc1)c1ccccc1-c1cc(-c2ccccn2)nc(-c2ccccn2)c1 ; O=P(c1ccccc1)(c1ccccc1)c1ccc(-c2cc(-c3ccccn3)nc(-c3ccccn3)c2)c2ccccc12 ; O=P(c1ccccc1)(c1ccccc1)c1cccc2c(-c3cc(-c4ccccn4)nc(-c4ccccn4)c3)cccc12]

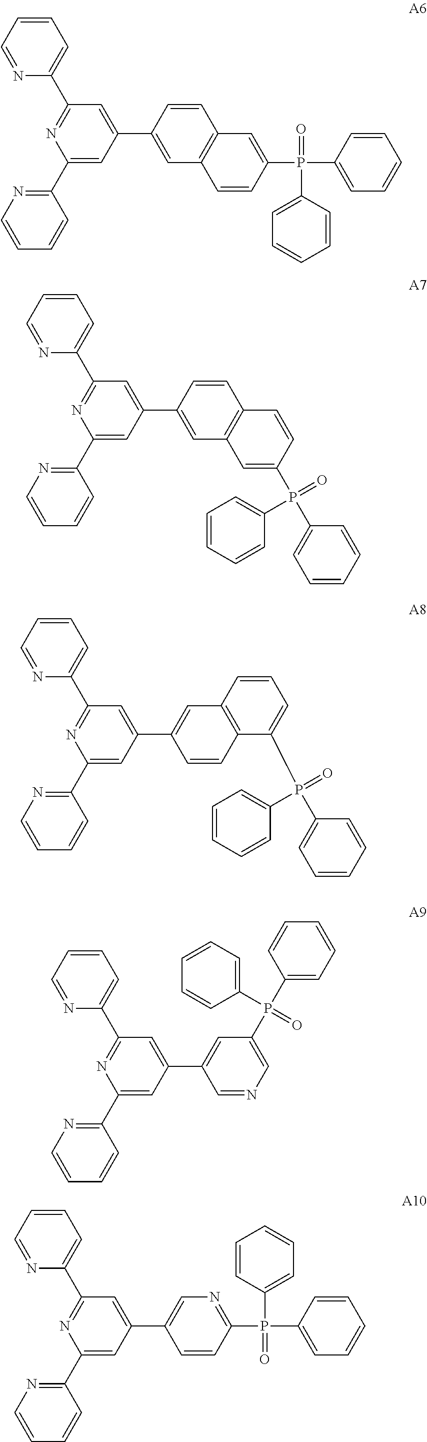

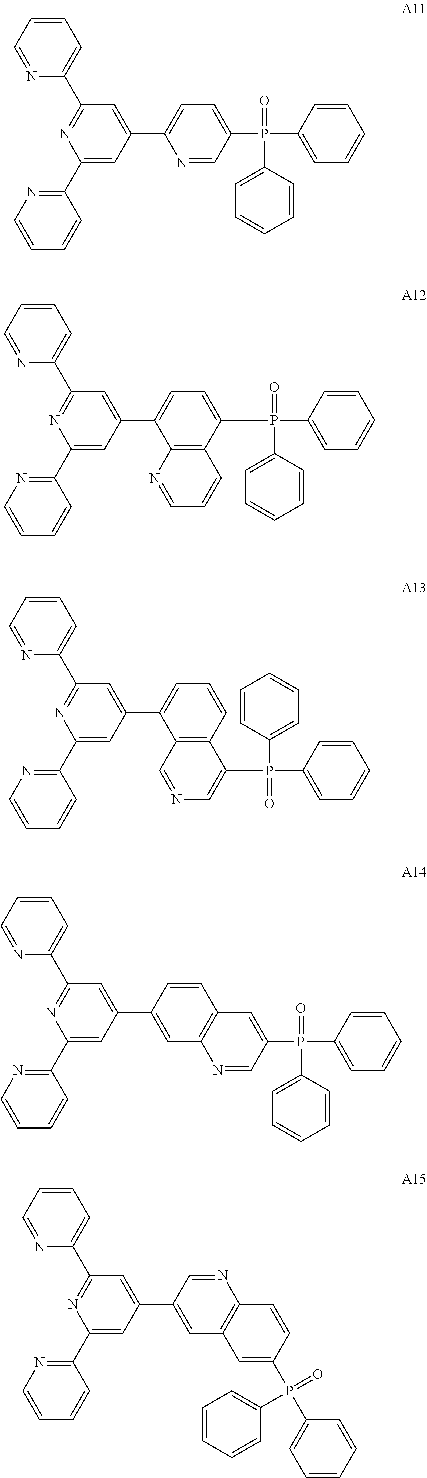 [SMILES: O=P(c1ccccc1)(c1ccccc1)c1ccc(-c2cc(-c3ccccn3)nc(-c3ccccn3)c2)nc1 ; O=P(c1ccccc1)(c1ccccc1)c1ccc(-c2cc(-c3ccccn3)nc(-c3ccccn3)c2)c2ncccc12 ; O=P(c1ccccc1)(c1ccccc1)c1cncc2c(-c3cc(-c4ccccn4)nc(-c4ccccn4)c3)cccc12 ; O=P(c1ccccc1)(c1ccccc1)c1cnc2cc(-c3cc(-c4ccccn4)nc(-c4ccccn4)c3)ccc2c1 ; O=P(c1ccccc1)(c1ccccc1)c1ccc2ncc(-c3cc(-c4ccccn4)nc(-c4ccccn4)c3)cc2c1]

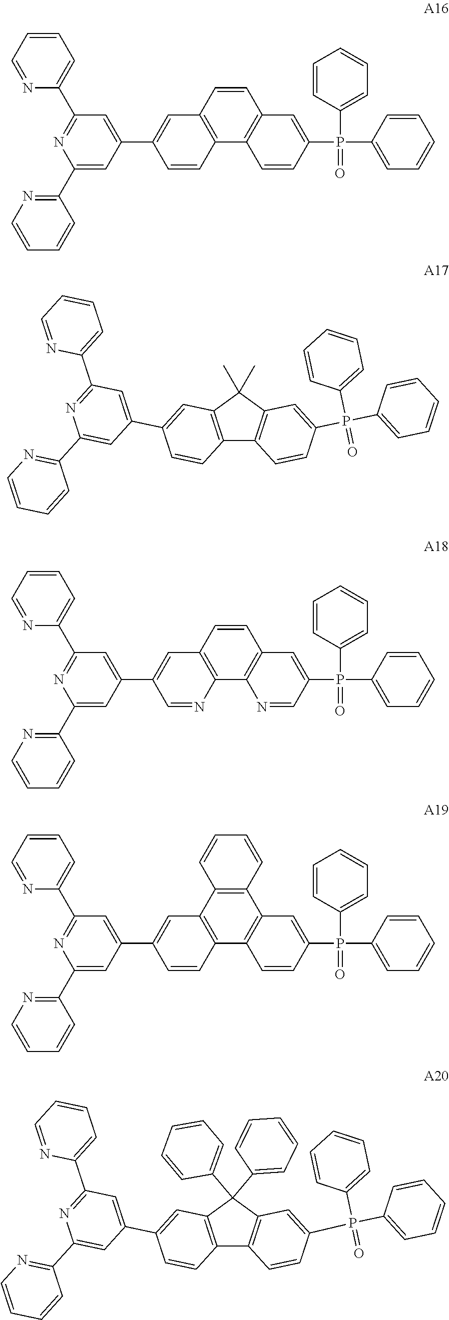 [SMILES: O=P(c1ccccc1)(c1ccccc1)c1ccc2c(ccc3cc(-c4cc(-c5ccccn5)nc(-c5ccccn5)c4)ccc32)c1 ; CC1(C)c2cc(-c3cc(-c4ccccn4)nc(-c4ccccn4)c3)ccc2-c2ccc(P(=O)(c3ccccc3)c3ccccc3)cc21 ; O=P(c1ccccc1)(c1ccccc1)c1cnc2c(ccc3cc(-c4cc(-c5ccccn5)nc(-c5ccccn5)c4)cnc32)c1 ; O=P(c1ccccc1)(c1ccccc1)c1ccc2c3ccc(-c4cc(-c5ccccn5)nc(-c5ccccn5)c4)cc3c3ccccc3c2c1 ; O=P(c1ccccc1)(c1ccccc1)c1ccc2c(c1)C(c1ccccc1)(c1ccccc1)c1cc(-c3cc(-c4ccccn4)nc(-c4ccccn4)c3)ccc1-2]

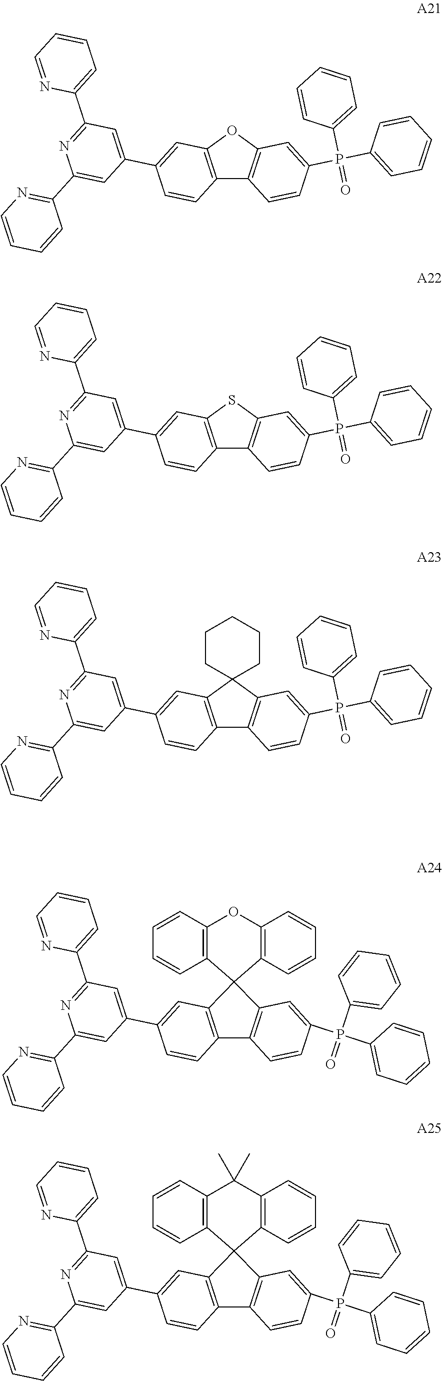 [SMILES: O=P(c1ccccc1)(c1ccccc1)c1ccc2c(c1)oc1cc(-c3cc(-c4ccccn4)nc(-c4ccccn4)c3)ccc12 ; O=P(c1ccccc1)(c1ccccc1)c1ccc2c(c1)sc1cc(-c3cc(-c4ccccn4)nc(-c4ccccn4)c3)ccc12 ; O=P(c1ccccc1)(c1ccccc1)c1ccc2c(c1)C1(CCCCC1)c1cc(-c3cc(-c4ccccn4)nc(-c4ccccn4)c3)ccc1-2 ; O=P(c1ccccc1)(c1ccccc1)c1ccc2c(c1)C1(c3ccccc3Oc3ccccc31)c1cc(-c3cc(-c4ccccn4)nc(-c4ccccn4)c3)ccc1-2 ; CC1(C)c2ccccc2C2(c3cc(-c4cc(-c5ccccn5)nc(-c5ccccn5)c4)ccc3-c3ccc(P(=O)(c4ccccc4)c4ccccc4)cc32)c2ccccc21]

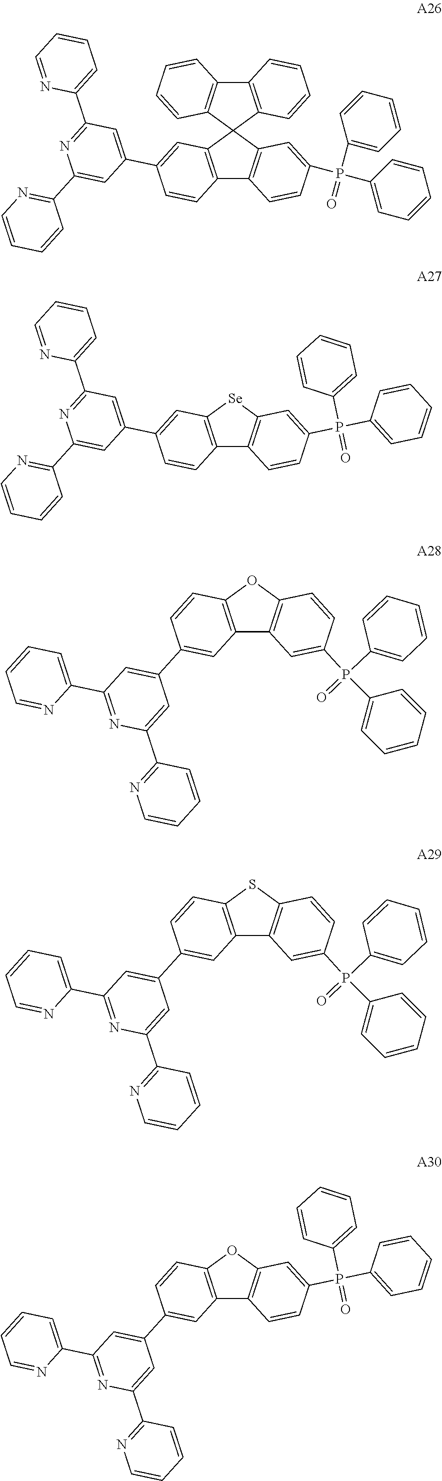 [SMILES: O=P(c1ccccc1)(c1ccccc1)c1ccc2c(c1)C1(c3ccccc3-c3ccccc31)c1cc(-c3cc(-c4ccccn4)nc(-c4ccccn4)c3)ccc1-2 ; O=P(c1ccccc1)(c1ccccc1)c1ccc2c(c1)[se]c1cc(-c3cc(-c4ccccn4)nc(-c4ccccn4)c3)ccc12 ; O=P(c1ccccc1)(c1ccccc1)c1ccc2oc3ccc(-c4cc(-c5ccccn5)nc(-c5ccccn5)c4)cc3c2c1 ; O=P(c1ccccc1)(c1ccccc1)c1ccc2sc3ccc(-c4cc(-c5ccccn5)nc(-c5ccccn5)c4)cc3c2c1 ; O=P(c1ccccc1)(c1ccccc1)c1ccc2c(c1)oc1ccc(-c3cc(-c4ccccn4)nc(-c4ccccn4)c3)cc12]

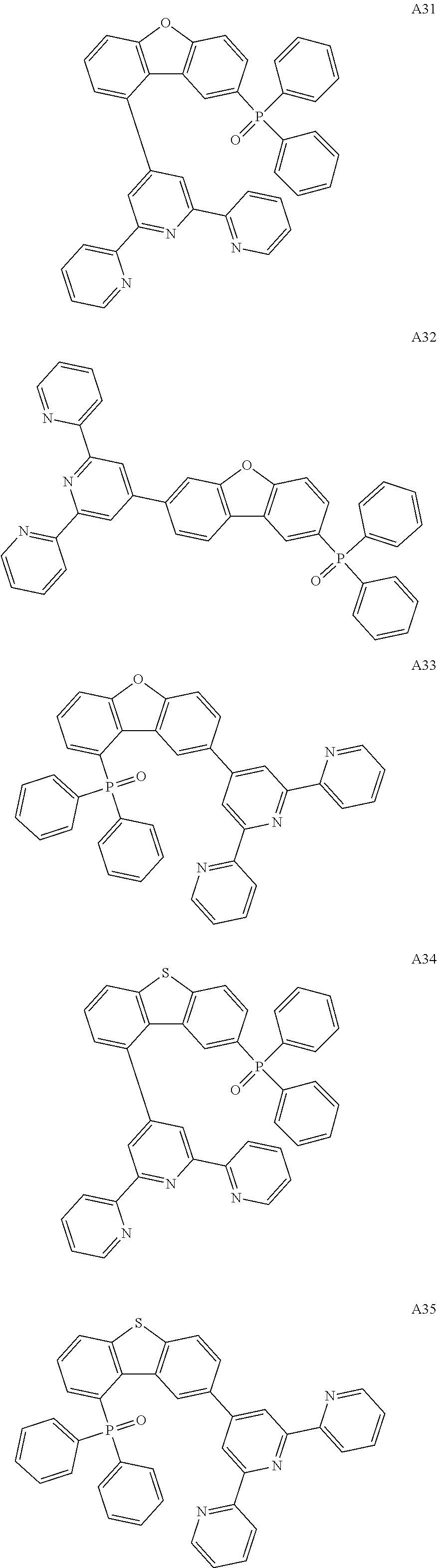 [SMILES: O=P(c1ccccc1)(c1ccccc1)c1ccc2oc3cccc(-c4cc(-c5ccccn5)nc(-c5ccccn5)c4)c3c2c1 ; O=P(c1ccccc1)(c1ccccc1)c1ccc2oc3cc(-c4cc(-c5ccccn5)nc(-c5ccccn5)c4)ccc3c2c1 ; O=P(c1ccccc1)(c1ccccc1)c1cccc2oc3ccc(-c4cc(-c5ccccn5)nc(-c5ccccn5)c4)cc3c12 ; O=P(c1ccccc1)(c1ccccc1)c1ccc2sc3cccc(-c4cc(-c5ccccn5)nc(-c5ccccn5)c4)c3c2c1 ; O=P(c1ccccc1)(c1ccccc1)c1cccc2sc3ccc(-c4cc(-c5ccccn5)nc(-c5ccccn5)c4)cc3c12]

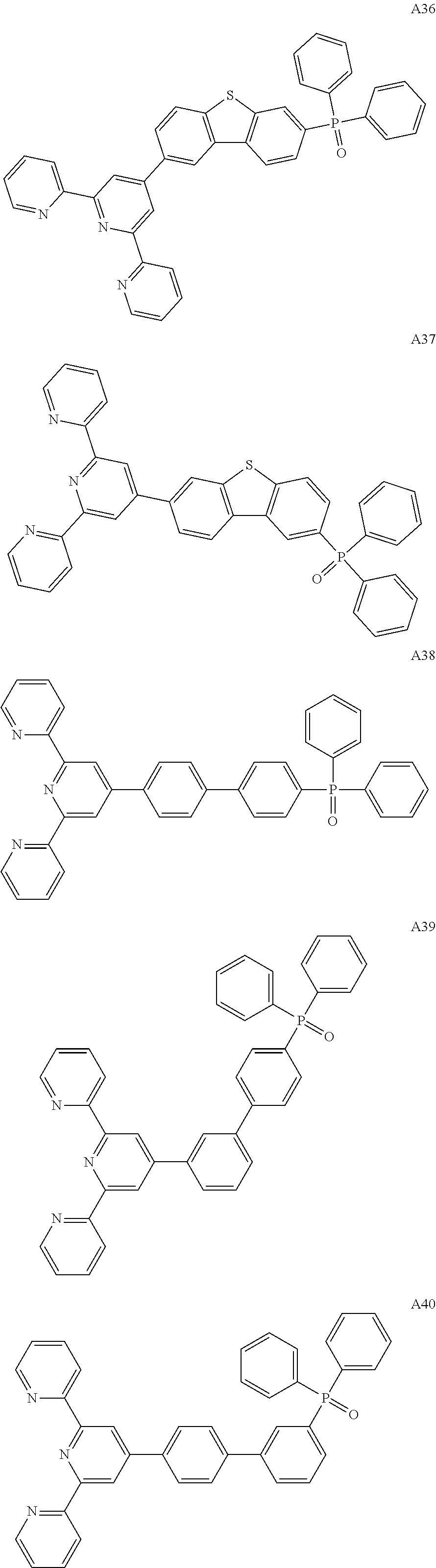 [SMILES: O=P(c1ccccc1)(c1ccccc1)c1ccc2c(c1)sc1ccc(-c3cc(-c4ccccn4)nc(-c4ccccn4)c3)cc12 ; O=P(c1ccccc1)(c1ccccc1)c1ccc2sc3cc(-c4cc(-c5ccccn5)nc(-c5ccccn5)c4)ccc3c2c1 ; O=P(c1ccccc1)(c1ccccc1)c1ccc(-c2ccc(-c3cc(-c4ccccn4)nc(-c4ccccn4)c3)cc2)cc1 ; O=P(c1ccccc1)(c1ccccc1)c1ccc(-c2cccc(-c3cc(-c4ccccn4)nc(-c4ccccn4)c3)c2)cc1 ; O=P(c1ccccc1)(c1ccccc1)c1cccc(-c2ccc(-c3cc(-c4ccccn4)nc(-c4ccccn4)c3)cc2)c1]

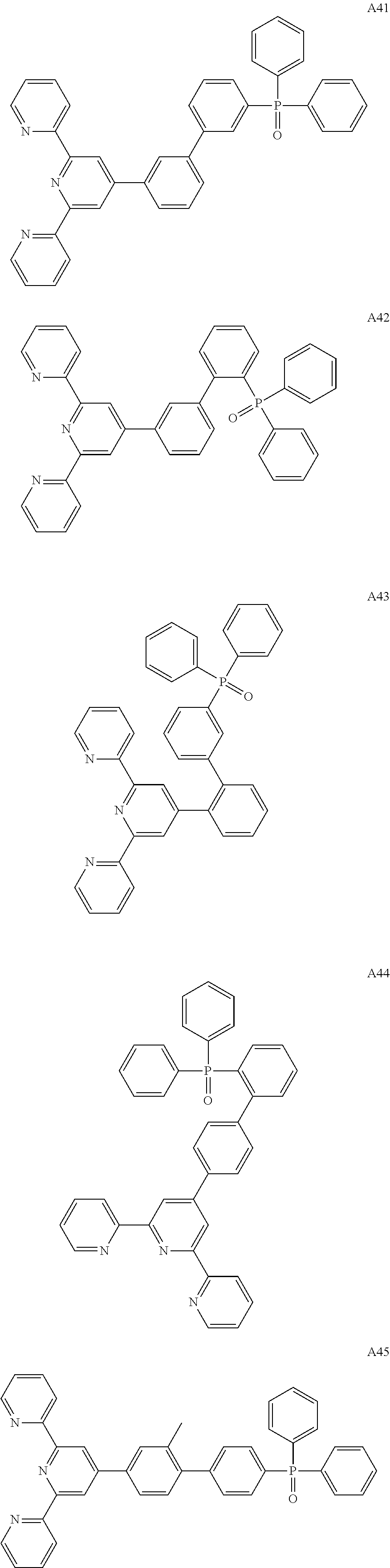 [SMILES: O=P(c1ccccc1)(c1ccccc1)c1cccc(-c2cccc(-c3cc(-c4ccccn4)nc(-c4ccccn4)c3)c2)c1 ; O=P(c1ccccc1)(c1ccccc1)c1ccccc1-c1cccc(-c2cc(-c3ccccn3)nc(-c3ccccn3)c2)c1 ; O=P(c1ccccc1)(c1ccccc1)c1cccc(-c2ccccc2-c2cc(-c3ccccn3)nc(-c3ccccn3)c2)c1 ; O=P(c1ccccc1)(c1ccccc1)c1ccccc1-c1ccc(-c2cc(-c3ccccn3)nc(-c3ccccn3)c2)cc1 ; Cc1cc(-c2cc(-c3ccccn3)nc(-c3ccccn3)c2)ccc1-c1ccc(P(=O)(c2ccccc2)c2ccccc2)cc1]

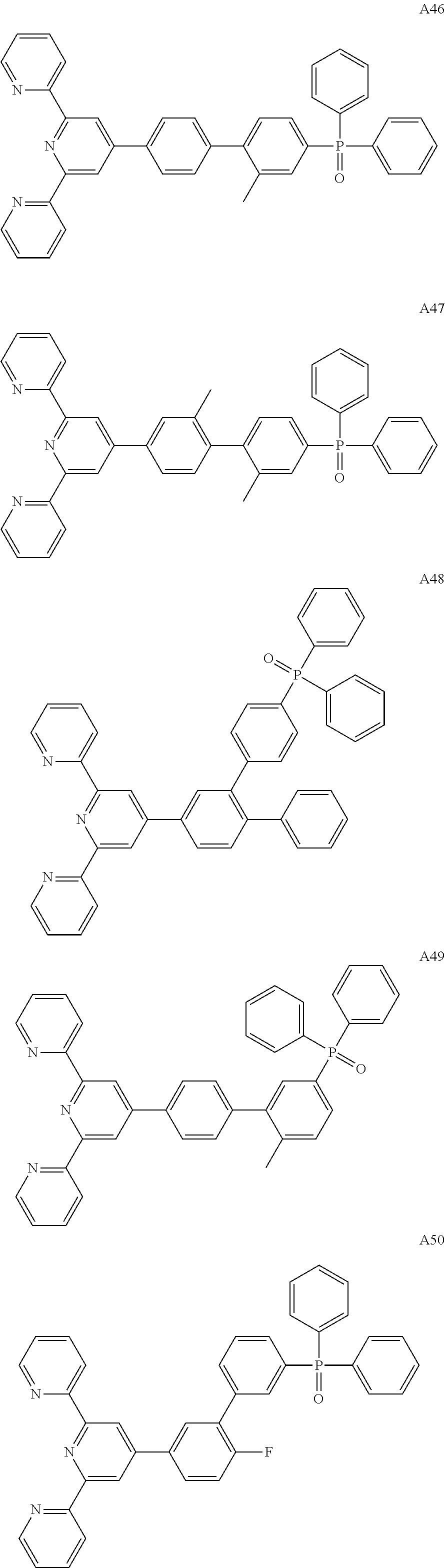 [SMILES: Cc1cc(P(=O)(c2ccccc2)c2ccccc2)ccc1-c1ccc(-c2cc(-c3ccccn3)nc(-c3ccccn3)c2)cc1 ; Cc1cc(-c2cc(-c3ccccn3)nc(-c3ccccn3)c2)ccc1-c1ccc(P(=O)(c2ccccc2)c2ccccc2)cc1C ; O=P(c1ccccc1)(c1ccccc1)c1ccc(-c2cc(-c3cc(-c4ccccn4)nc(-c4ccccn4)c3)ccc2-c2ccccc2)cc1 ; Cc1ccc(P(=O)(c2ccccc2)c2ccccc2)cc1-c1ccc(-c2cc(-c3ccccn3)nc(-c3ccccn3)c2)cc1 ; O=P(c1ccccc1)(c1ccccc1)c1cccc(-c2cc(-c3cc(-c4ccccn4)nc(-c4ccccn4)c3)ccc2F)c1]

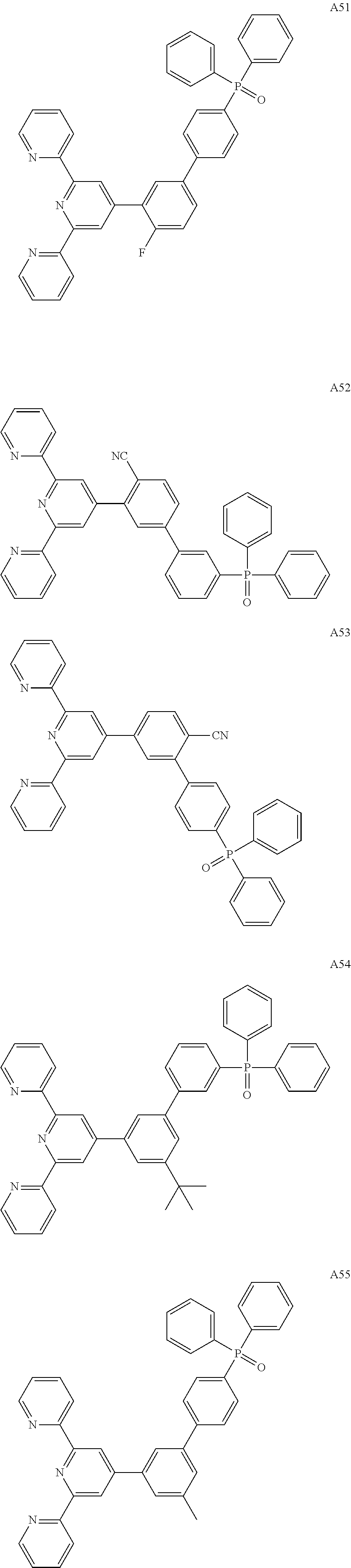 [SMILES: O=P(c1ccccc1)(c1ccccc1)c1ccc(-c2ccc(F)c(-c3cc(-c4ccccn4)nc(-c4ccccn4)c3)c2)cc1 ; N#Cc1ccc(-c2cccc(P(=O)(c3ccccc3)c3ccccc3)c2)cc1-c1cc(-c2ccccn2)nc(-c2ccccn2)c1 ; N#Cc1ccc(-c2cc(-c3ccccn3)nc(-c3ccccn3)c2)cc1-c1ccc(P(=O)(c2ccccc2)c2ccccc2)cc1 ; CC(C)(C)c1cc(-c2cccc(P(=O)(c3ccccc3)c3ccccc3)c2)cc(-c2cc(-c3ccccn3)nc(-c3ccccn3)c2)c1 ; Cc1cc(-c2ccc(P(=O)(c3ccccc3)c3ccccc3)cc2)cc(-c2cc(-c3ccccn3)nc(-c3ccccn3)c2)c1]

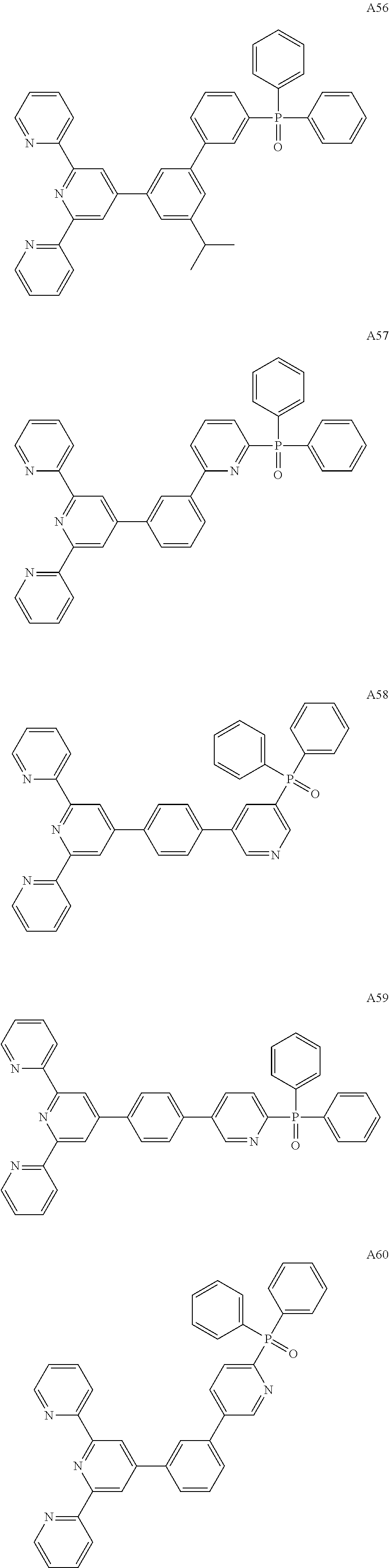 [SMILES: CC(C)c1cc(-c2cccc(P(=O)(c3ccccc3)c3ccccc3)c2)cc(-c2cc(-c3ccccn3)nc(-c3ccccn3)c2)c1 ; O=P(c1ccccc1)(c1ccccc1)c1cccc(-c2cccc(-c3cc(-c4ccccn4)nc(-c4ccccn4)c3)c2)n1 ; O=P(c1ccccc1)(c1ccccc1)c1cncc(-c2ccc(-c3cc(-c4ccccn4)nc(-c4ccccn4)c3)cc2)c1 ; O=P(c1ccccc1)(c1ccccc1)c1ccc(-c2ccc(-c3cc(-c4ccccn4)nc(-c4ccccn4)c3)cc2)cn1 ; O=P(c1ccccc1)(c1ccccc1)c1ccc(-c2cccc(-c3cc(-c4ccccn4)nc(-c4ccccn4)c3)c2)cn1]

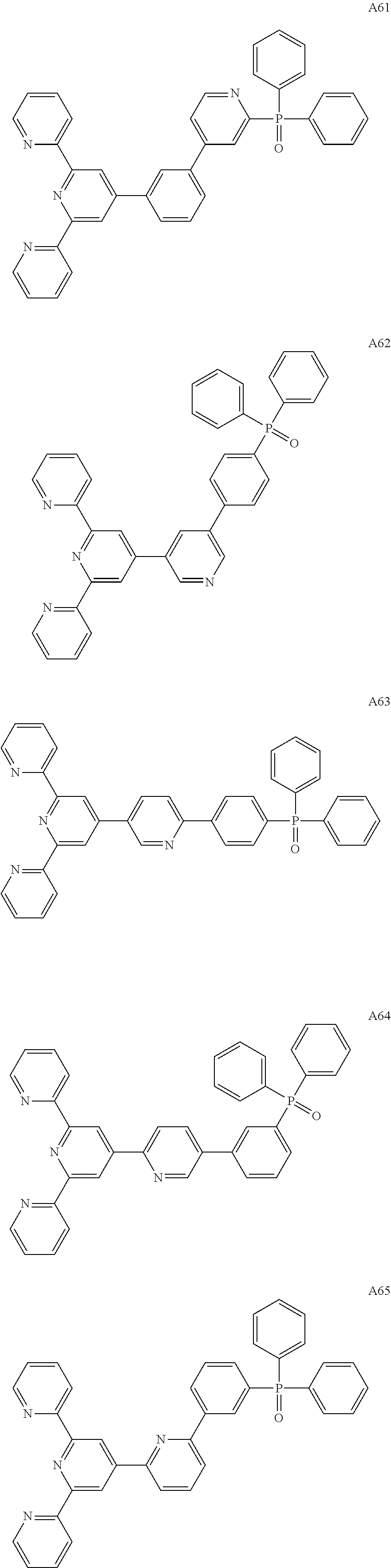 [SMILES: O=P(c1ccccc1)(c1ccccc1)c1cc(-c2cccc(-c3cc(-c4ccccn4)nc(-c4ccccn4)c3)c2)ccn1 ; O=P(c1ccccc1)(c1ccccc1)c1ccc(-c2cncc(-c3cc(-c4ccccn4)nc(-c4ccccn4)c3)c2)cc1 ; O=P(c1ccccc1)(c1ccccc1)c1ccc(-c2ccc(-c3cc(-c4ccccn4)nc(-c4ccccn4)c3)cn2)cc1 ; O=P(c1ccccc1)(c1ccccc1)c1cccc(-c2ccc(-c3cc(-c4ccccn4)nc(-c4ccccn4)c3)nc2)c1 ; O=P(c1ccccc1)(c1ccccc1)c1cccc(-c2cccc(-c3cc(-c4ccccn4)nc(-c4ccccn4)c3)n2)c1]

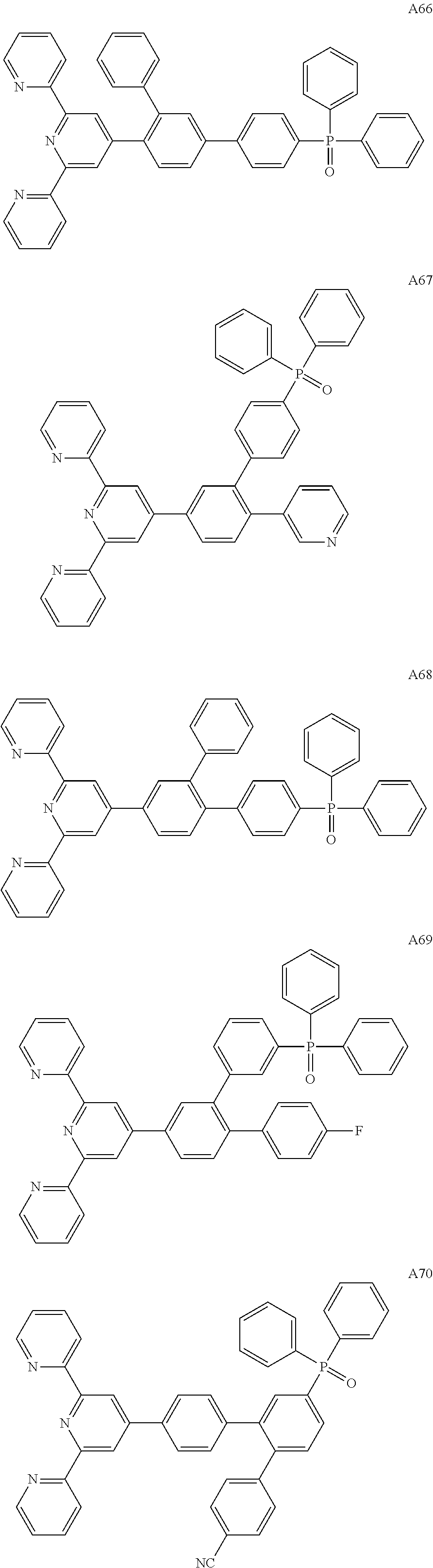 [SMILES: O=P(c1ccccc1)(c1ccccc1)c1ccc(-c2ccc(-c3cc(-c4ccccn4)nc(-c4ccccn4)c3)c(-c3ccccc3)c2)cc1 ; O=P(c1ccccc1)(c1ccccc1)c1ccc(-c2cc(-c3cc(-c4ccccn4)nc(-c4ccccn4)c3)ccc2-c2cccnc2)cc1 ; O=P(c1ccccc1)(c1ccccc1)c1ccc(-c2ccc(-c3cc(-c4ccccn4)nc(-c4ccccn4)c3)cc2-c2ccccc2)cc1 ; O=P(c1ccccc1)(c1ccccc1)c1cccc(-c2cc(-c3cc(-c4ccccn4)nc(-c4ccccn4)c3)ccc2-c2ccc(F)cc2)c1 ; N#Cc1ccc(-c2ccc(P(=O)(c3ccccc3)c3ccccc3)cc2-c2ccc(-c3cc(-c4ccccn4)nc(-c4ccccn4)c3)cc2)cc1]

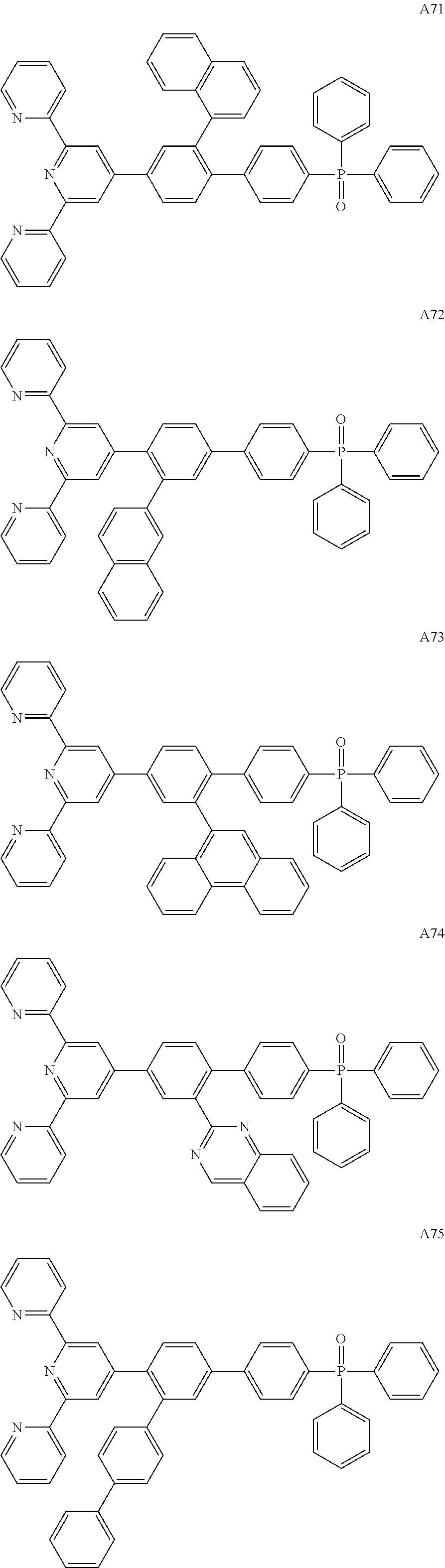 [SMILES: O=P(c1ccccc1)(c1ccccc1)c1ccc(-c2ccc(-c3cc(-c4ccccn4)nc(-c4ccccn4)c3)cc2-c2cccc3ccccc23)cc1 ; O=P(c1ccccc1)(c1ccccc1)c1ccc(-c2ccc(-c3cc(-c4ccccn4)nc(-c4ccccn4)c3)c(-c3ccc4ccccc4c3)c2)cc1 ; O=P(c1ccccc1)(c1ccccc1)c1ccc(-c2ccc(-c3cc(-c4ccccn4)nc(-c4ccccn4)c3)cc2-c2cc3ccccc3c3ccccc23)cc1 ; O=P(c1ccccc1)(c1ccccc1)c1ccc(-c2ccc(-c3cc(-c4ccccn4)nc(-c4ccccn4)c3)cc2-c2ncc3ccccc3n2)cc1 ; O=P(c1ccccc1)(c1ccccc1)c1ccc(-c2ccc(-c3cc(-c4ccccn4)nc(-c4ccccn4)c3)c(-c3ccc(-c4ccccc4)cc3)c2)cc1]

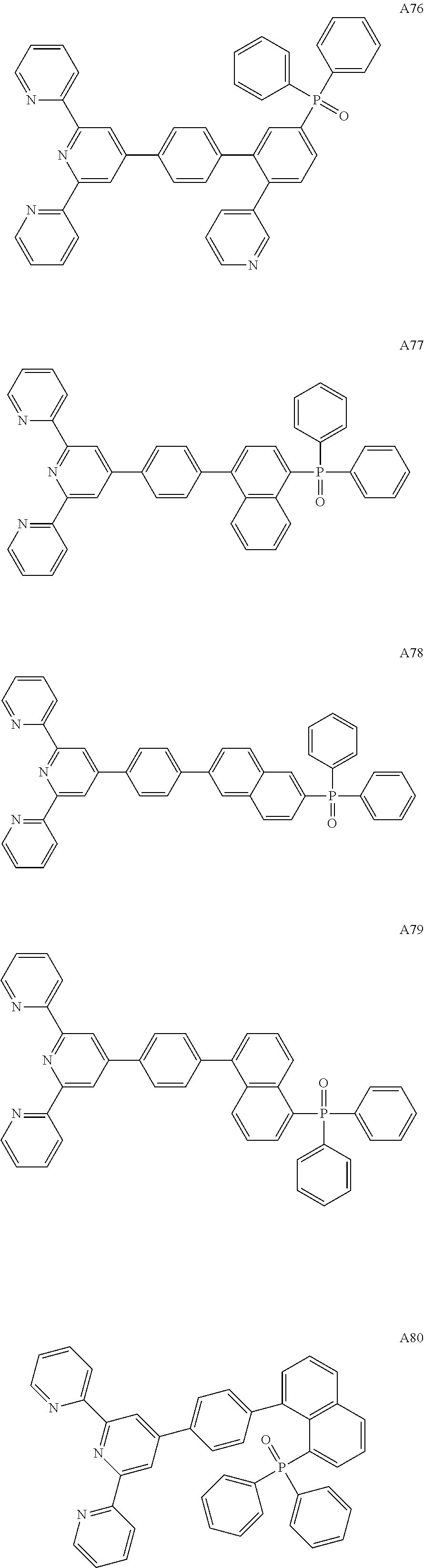 [SMILES: O=P(c1ccccc1)(c1ccccc1)c1ccc(-c2cccnc2)c(-c2ccc(-c3cc(-c4ccccn4)nc(-c4ccccn4)c3)cc2)c1 ; O=P(c1ccccc1)(c1ccccc1)c1ccc(-c2ccc(-c3cc(-c4ccccn4)nc(-c4ccccn4)c3)cc2)c2ccccc12 ; O=P(c1ccccc1)(c1ccccc1)c1ccc2cc(-c3ccc(-c4cc(-c5ccccn5)nc(-c5ccccn5)c4)cc3)ccc2c1 ; O=P(c1ccccc1)(c1ccccc1)c1cccc2c(-c3ccc(-c4cc(-c5ccccn5)nc(-c5ccccn5)c4)cc3)cccc12 ; O=P(c1ccccc1)(c1ccccc1)c1cccc2cccc(-c3ccc(-c4cc(-c5ccccn5)nc(-c5ccccn5)c4)cc3)c12]

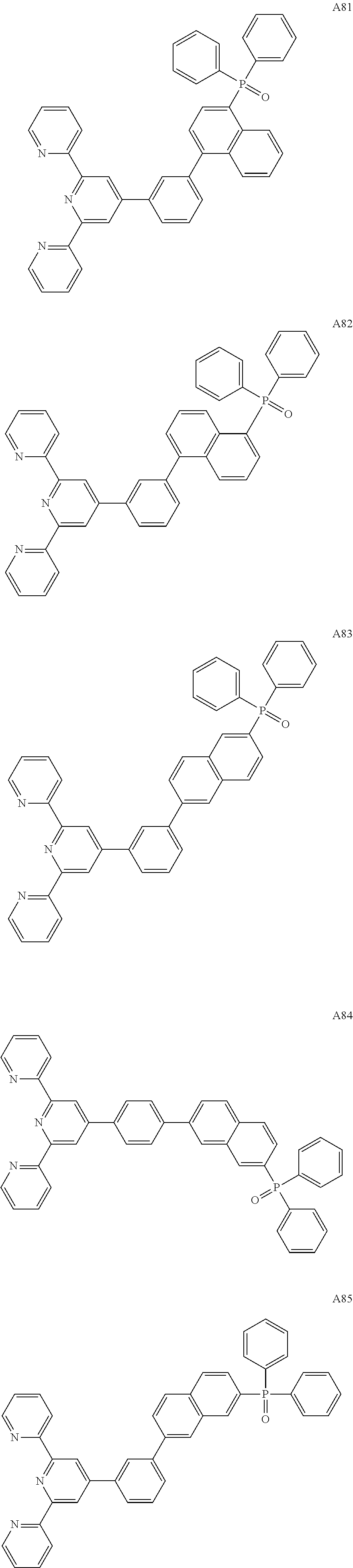 [SMILES: O=P(c1ccccc1)(c1ccccc1)c1ccc(-c2cccc(-c3cc(-c4ccccn4)nc(-c4ccccn4)c3)c2)c2ccccc12 ; O=P(c1ccccc1)(c1ccccc1)c1cccc2c(-c3cccc(-c4cc(-c5ccccn5)nc(-c5ccccn5)c4)c3)cccc12 ; O=P(c1ccccc1)(c1ccccc1)c1ccc2cc(-c3cccc(-c4cc(-c5ccccn5)nc(-c5ccccn5)c4)c3)ccc2c1 ; O=P(c1ccccc1)(c1ccccc1)c1ccc2ccc(-c3ccc(-c4cc(-c5ccccn5)nc(-c5ccccn5)c4)cc3)cc2c1 ; O=P(c1ccccc1)(c1ccccc1)c1ccc2ccc(-c3cccc(-c4cc(-c5ccccn5)nc(-c5ccccn5)c4)c3)cc2c1]

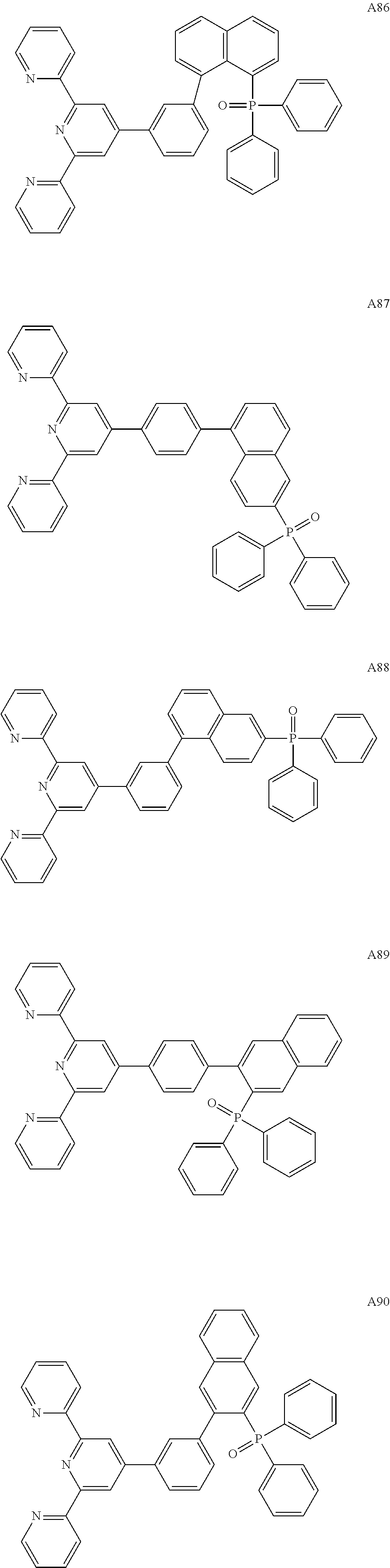 [SMILES: O=P(c1ccccc1)(c1ccccc1)c1cccc2cccc(-c3cccc(-c4cc(-c5ccccn5)nc(-c5ccccn5)c4)c3)c12 ; O=P(c1ccccc1)(c1ccccc1)c1ccc2c(-c3ccc(-c4cc(-c5ccccn5)nc(-c5ccccn5)c4)cc3)cccc2c1 ; O=P(c1ccccc1)(c1ccccc1)c1ccc2c(-c3cccc(-c4cc(-c5ccccn5)nc(-c5ccccn5)c4)c3)cccc2c1 ; O=P(c1ccccc1)(c1ccccc1)c1cc2ccccc2cc1-c1ccc(-c2cc(-c3ccccn3)nc(-c3ccccn3)c2)cc1 ; O=P(c1ccccc1)(c1ccccc1)c1cc2ccccc2cc1-c1cccc(-c2cc(-c3ccccn3)nc(-c3ccccn3)c2)c1]

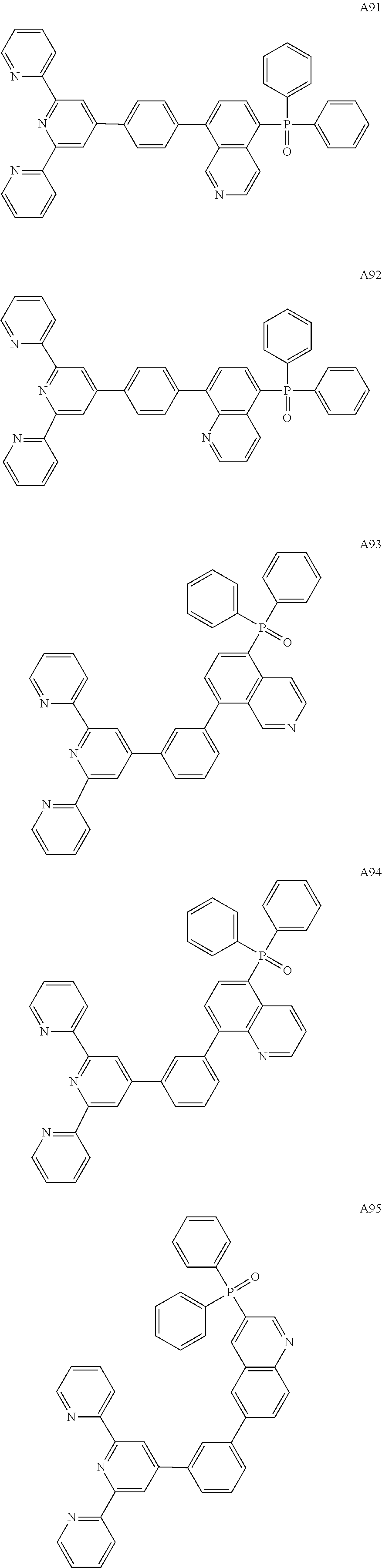 [SMILES: O=P(c1ccccc1)(c1ccccc1)c1ccc(-c2ccc(-c3cc(-c4ccccn4)nc(-c4ccccn4)c3)cc2)c2cnccc12 ; O=P(c1ccccc1)(c1ccccc1)c1ccc(-c2ccc(-c3cc(-c4ccccn4)nc(-c4ccccn4)c3)cc2)c2ncccc12 ; O=P(c1ccccc1)(c1ccccc1)c1ccc(-c2cccc(-c3cc(-c4ccccn4)nc(-c4ccccn4)c3)c2)c2cnccc12 ; O=P(c1ccccc1)(c1ccccc1)c1ccc(-c2cccc(-c3cc(-c4ccccn4)nc(-c4ccccn4)c3)c2)c2ncccc12 ; O=P(c1ccccc1)(c1ccccc1)c1cnc2ccc(-c3cccc(-c4cc(-c5ccccn5)nc(-c5ccccn5)c4)c3)cc2c1]

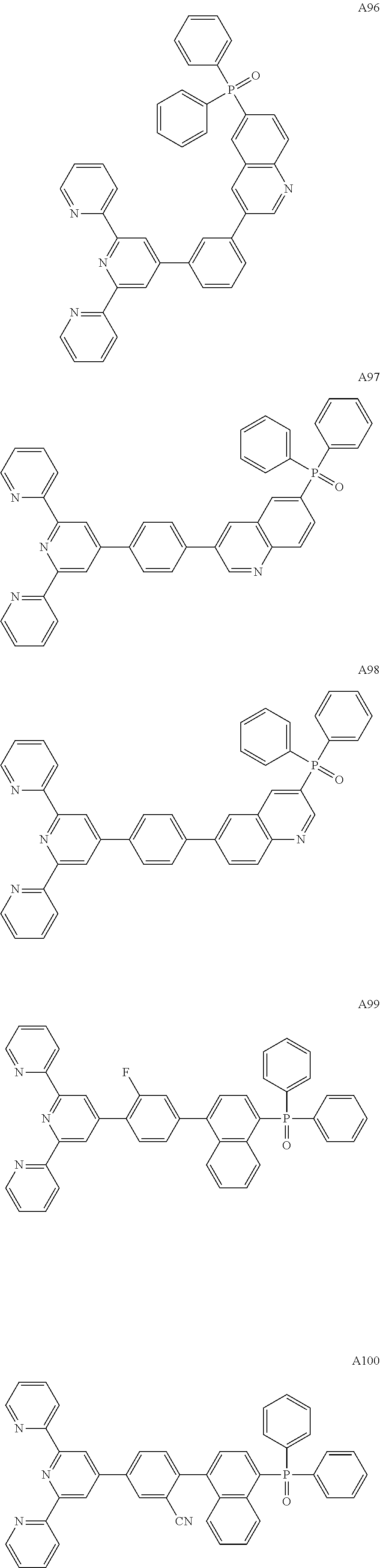 [SMILES: O=P(c1ccccc1)(c1ccccc1)c1ccc2ncc(-c3cccc(-c4cc(-c5ccccn5)nc(-c5ccccn5)c4)c3)cc2c1 ; O=P(c1ccccc1)(c1ccccc1)c1ccc2ncc(-c3ccc(-c4cc(-c5ccccn5)nc(-c5ccccn5)c4)cc3)cc2c1 ; O=P(c1ccccc1)(c1ccccc1)c1cnc2ccc(-c3ccc(-c4cc(-c5ccccn5)nc(-c5ccccn5)c4)cc3)cc2c1 ; O=P(c1ccccc1)(c1ccccc1)c1ccc(-c2ccc(-c3cc(-c4ccccn4)nc(-c4ccccn4)c3)c(F)c2)c2ccccc12 ; N#Cc1cc(-c2cc(-c3ccccn3)nc(-c3ccccn3)c2)ccc1-c1ccc(P(=O)(c2ccccc2)c2ccccc2)c2ccccc12]

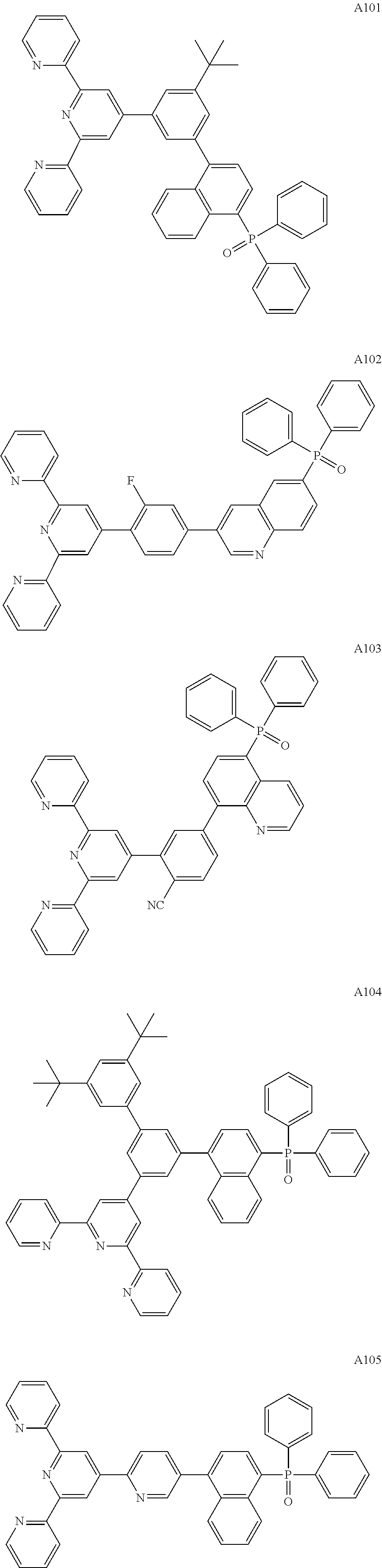 [SMILES: CC(C)(C)c1cc(-c2cc(-c3ccccn3)nc(-c3ccccn3)c2)cc(-c2ccc(P(=O)(c3ccccc3)c3ccccc3)c3ccccc23)c1 ; O=P(c1ccccc1)(c1ccccc1)c1ccc2ncc(-c3ccc(-c4cc(-c5ccccn5)nc(-c5ccccn5)c4)c(F)c3)cc2c1 ; N#Cc1ccc(-c2ccc(P(=O)(c3ccccc3)c3ccccc3)c3cccnc23)cc1-c1cc(-c2ccccn2)nc(-c2ccccn2)c1 ; CC(C)(C)c1cc(-c2cc(-c3cc(-c4ccccn4)nc(-c4ccccn4)c3)cc(-c3ccc(P(=O)(c4ccccc4)c4ccccc4)c4ccccc34)c2)cc(C(C)(C)C)c1 ; O=P(c1ccccc1)(c1ccccc1)c1ccc(-c2ccc(-c3cc(-c4ccccn4)nc(-c4ccccn4)c3)nc2)c2ccccc12]

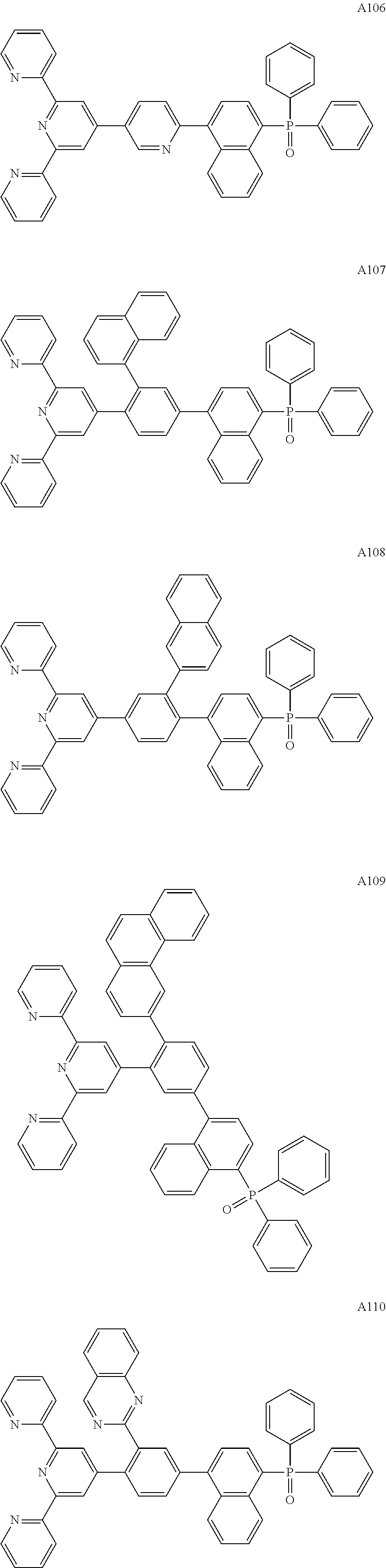 [SMILES: O=P(c1ccccc1)(c1ccccc1)c1ccc(-c2ccc(-c3cc(-c4ccccn4)nc(-c4ccccn4)c3)cn2)c2ccccc12 ; O=P(c1ccccc1)(c1ccccc1)c1ccc(-c2ccc(-c3cc(-c4ccccn4)nc(-c4ccccn4)c3)c(-c3cccc4ccccc34)c2)c2ccccc12 ; O=P(c1ccccc1)(c1ccccc1)c1ccc(-c2ccc(-c3cc(-c4ccccn4)nc(-c4ccccn4)c3)cc2-c2ccc3ccccc3c2)c2ccccc12 ; O=P(c1ccccc1)(c1ccccc1)c1ccc(-c2ccc(-c3ccc4ccc5ccccc5c4c3)c(-c3cc(-c4ccccn4)nc(-c4ccccn4)c3)c2)c2ccccc12 ; O=P(c1ccccc1)(c1ccccc1)c1ccc(-c2ccc(-c3cc(-c4ccccn4)nc(-c4ccccn4)c3)c(-c3ncc4ccccc4n3)c2)c2ccccc12]

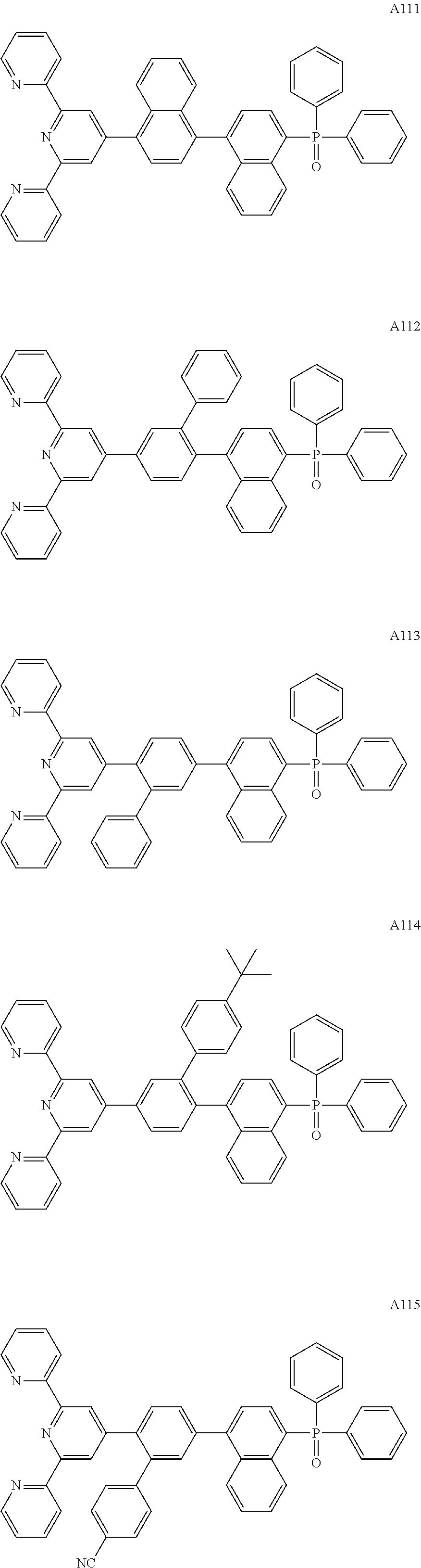 [SMILES: O=P(c1ccccc1)(c1ccccc1)c1ccc(-c2ccc(-c3cc(-c4ccccn4)nc(-c4ccccn4)c3)c3ccccc23)c2ccccc12 ; O=P(c1ccccc1)(c1ccccc1)c1ccc(-c2ccc(-c3cc(-c4ccccn4)nc(-c4ccccn4)c3)cc2-c2ccccc2)c2ccccc12 ; O=P(c1ccccc1)(c1ccccc1)c1ccc(-c2ccc(-c3cc(-c4ccccn4)nc(-c4ccccn4)c3)c(-c3ccccc3)c2)c2ccccc12 ; CC(C)(C)c1ccc(-c2cc(-c3cc(-c4ccccn4)nc(-c4ccccn4)c3)ccc2-c2ccc(P(=O)(c3ccccc3)c3ccccc3)c3ccccc23)cc1 ; N#Cc1ccc(-c2cc(-c3ccc(P(=O)(c4ccccc4)c4ccccc4)c4ccccc34)ccc2-c2cc(-c3ccccn3)nc(-c3ccccn3)c2)cc1]

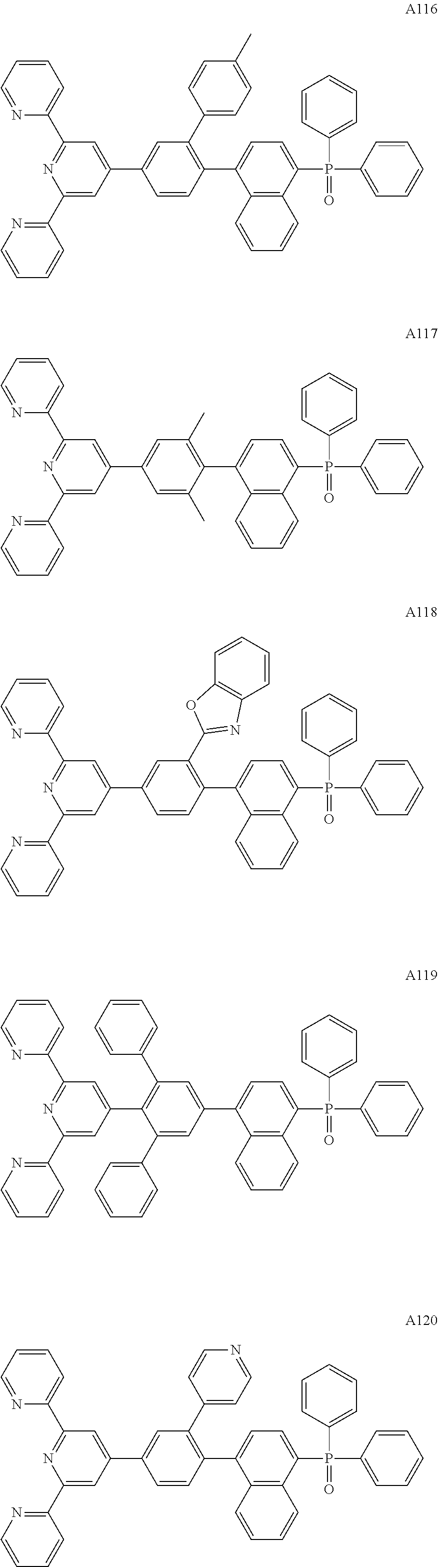 [SMILES: Cc1ccc(-c2cc(-c3cc(-c4ccccn4)nc(-c4ccccn4)c3)ccc2-c2ccc(P(=O)(c3ccccc3)c3ccccc3)c3ccccc23)cc1 ; Cc1cc(-c2cc(-c3ccccn3)nc(-c3ccccn3)c2)cc(C)c1-c1ccc(P(=O)(c2ccccc2)c2ccccc2)c2ccccc12 ; O=P(c1ccccc1)(c1ccccc1)c1ccc(-c2ccc(-c3cc(-c4ccccn4)nc(-c4ccccn4)c3)cc2-c2nc3ccccc3o2)c2ccccc12 ; O=P(c1ccccc1)(c1ccccc1)c1ccc(-c2cc(-c3ccccc3)c(-c3cc(-c4ccccn4)nc(-c4ccccn4)c3)c(-c3ccccc3)c2)c2ccccc12 ; O=P(c1ccccc1)(c1ccccc1)c1ccc(-c2ccc(-c3cc(-c4ccccn4)nc(-c4ccccn4)c3)cc2-c2ccncc2)c2ccccc12]

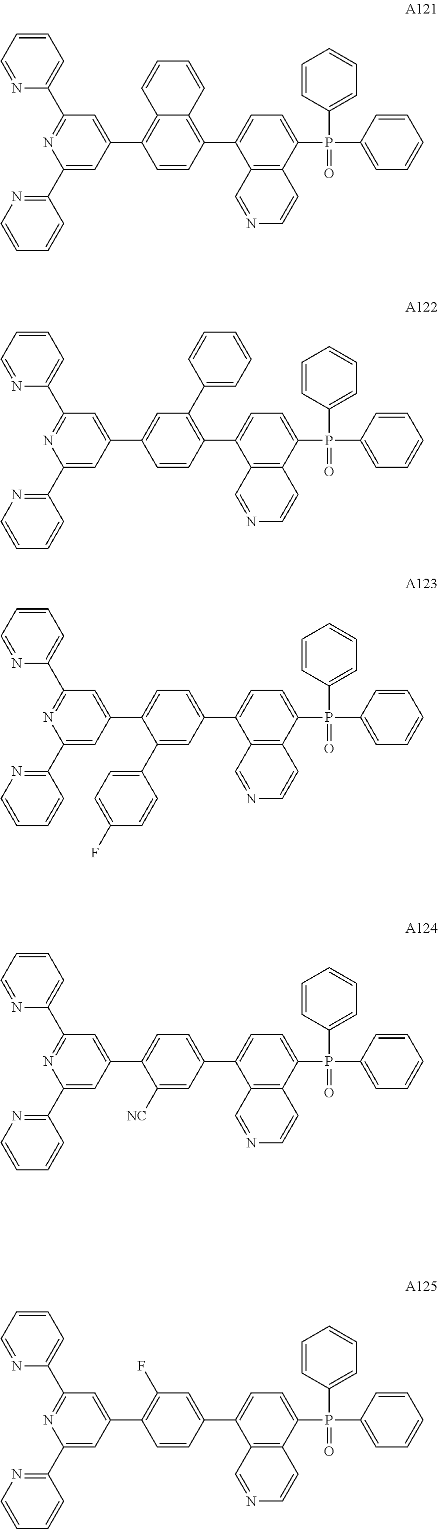 [SMILES: O=P(c1ccccc1)(c1ccccc1)c1ccc(-c2ccc(-c3cc(-c4ccccn4)nc(-c4ccccn4)c3)c3ccccc23)c2cnccc12 ; O=P(c1ccccc1)(c1ccccc1)c1ccc(-c2ccc(-c3cc(-c4ccccn4)nc(-c4ccccn4)c3)cc2-c2ccccc2)c2cnccc12 ; O=P(c1ccccc1)(c1ccccc1)c1ccc(-c2ccc(-c3cc(-c4ccccn4)nc(-c4ccccn4)c3)c(-c3ccc(F)cc3)c2)c2cnccc12 ; N#Cc1cc(-c2ccc(P(=O)(c3ccccc3)c3ccccc3)c3ccncc23)ccc1-c1cc(-c2ccccn2)nc(-c2ccccn2)c1 ; O=P(c1ccccc1)(c1ccccc1)c1ccc(-c2ccc(-c3cc(-c4ccccn4)nc(-c4ccccn4)c3)c(F)c2)c2cnccc12]

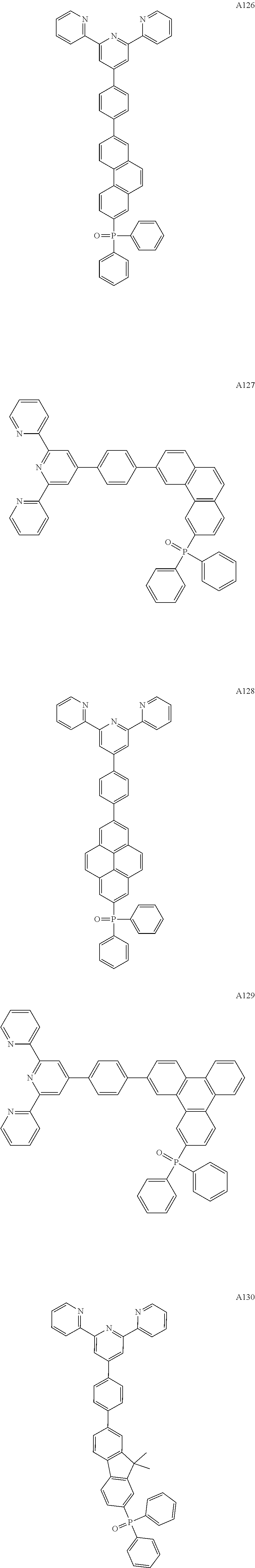 [SMILES: O=P(c1ccccc1)(c1ccccc1)c1ccc2c(ccc3cc(-c4ccc(-c5cc(-c6ccccn6)nc(-c6ccccn6)c5)cc4)ccc32)c1 ; O=P(c1ccccc1)(c1ccccc1)c1ccc2ccc3ccc(-c4ccc(-c5cc(-c6ccccn6)nc(-c6ccccn6)c5)cc4)cc3c2c1 ; O=P(c1ccccc1)(c1ccccc1)c1cc2ccc3cc(-c4ccc(-c5cc(-c6ccccn6)nc(-c6ccccn6)c5)cc4)cc4ccc(c1)c2c34 ; O=P(c1ccccc1)(c1ccccc1)c1ccc2c3ccccc3c3ccc(-c4ccc(-c5cc(-c6ccccn6)nc(-c6ccccn6)c5)cc4)cc3c2c1 ; CC1(C)c2cc(-c3ccc(-c4cc(-c5ccccn5)nc(-c5ccccn5)c4)cc3)ccc2-c2ccc(P(=O)(c3ccccc3)c3ccccc3)cc21]

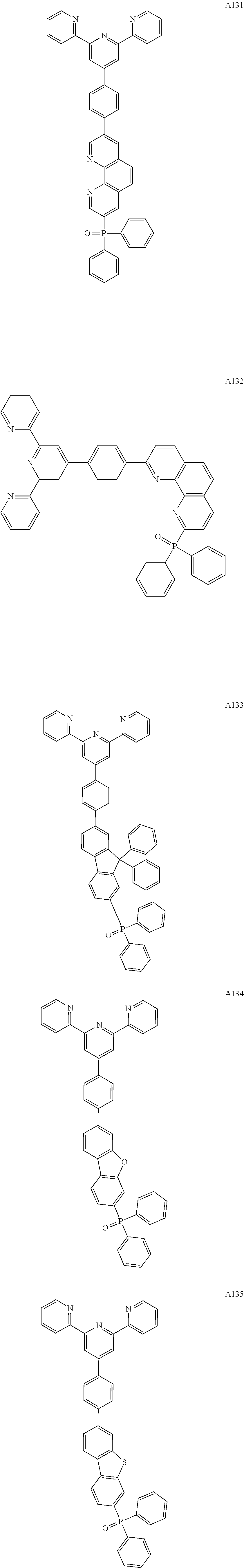 [SMILES: O=P(c1ccccc1)(c1ccccc1)c1cnc2c(ccc3cc(-c4ccc(-c5cc(-c6ccccn6)nc(-c6ccccn6)c5)cc4)cnc32)c1 ; O=P(c1ccccc1)(c1ccccc1)c1ccc2ccc3ccc(-c4ccc(-c5cc(-c6ccccn6)nc(-c6ccccn6)c5)cc4)nc3c2n1 ; O=P(c1ccccc1)(c1ccccc1)c1ccc2c(c1)C(c1ccccc1)(c1ccccc1)c1cc(-c3ccc(-c4cc(-c5ccccn5)nc(-c5ccccn5)c4)cc3)ccc1-2 ; O=P(c1ccccc1)(c1ccccc1)c1ccc2c(c1)oc1cc(-c3ccc(-c4cc(-c5ccccn5)nc(-c5ccccn5)c4)cc3)ccc12 ; O=P(c1ccccc1)(c1ccccc1)c1ccc2c(c1)sc1cc(-c3ccc(-c4cc(-c5ccccn5)nc(-c5ccccn5)c4)cc3)ccc12]

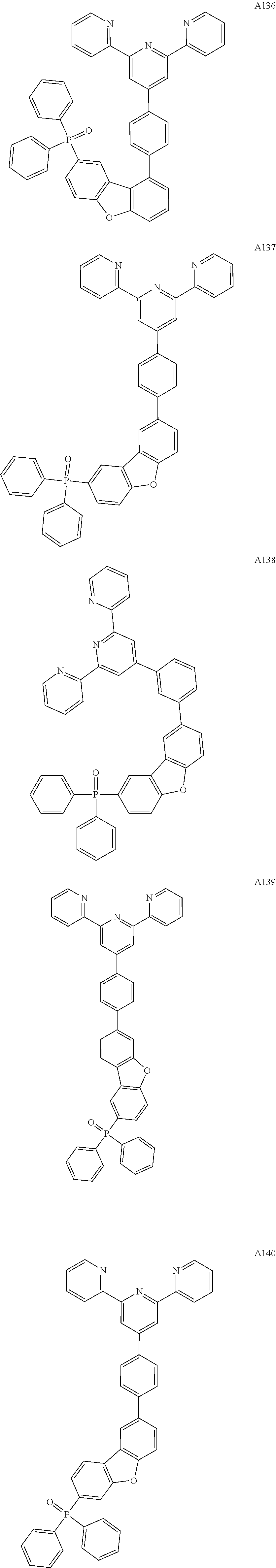 [SMILES: O=P(c1ccccc1)(c1ccccc1)c1ccc2oc3cccc(-c4ccc(-c5cc(-c6ccccn6)nc(-c6ccccn6)c5)cc4)c3c2c1 ; O=P(c1ccccc1)(c1ccccc1)c1ccc2oc3ccc(-c4ccc(-c5cc(-c6ccccn6)nc(-c6ccccn6)c5)cc4)cc3c2c1 ; O=P(c1ccccc1)(c1ccccc1)c1ccc2oc3ccc(-c4cccc(-c5cc(-c6ccccn6)nc(-c6ccccn6)c5)c4)cc3c2c1 ; O=P(c1ccccc1)(c1ccccc1)c1ccc2oc3cc(-c4ccc(-c5cc(-c6ccccn6)nc(-c6ccccn6)c5)cc4)ccc3c2c1 ; O=P(c1ccccc1)(c1ccccc1)c1ccc2c(c1)oc1ccc(-c3ccc(-c4cc(-c5ccccn5)nc(-c5ccccn5)c4)cc3)cc12]

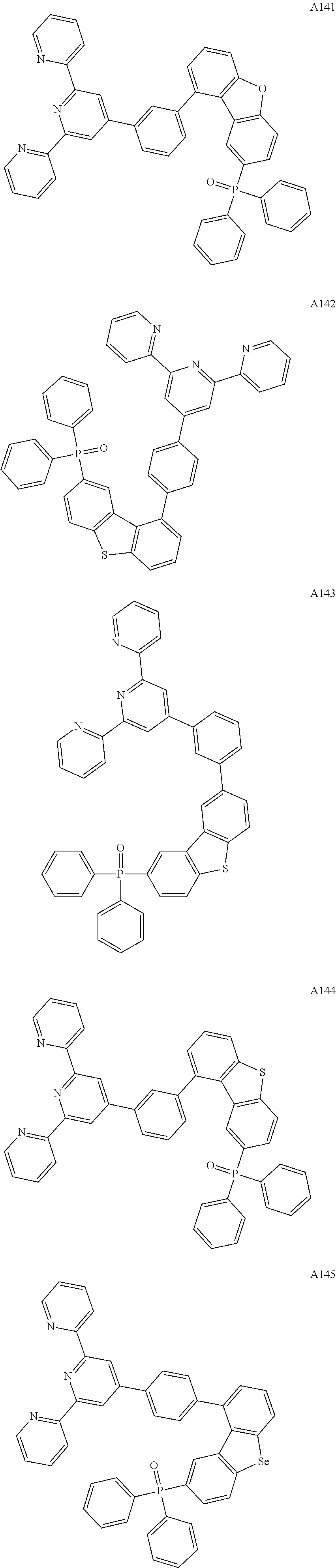

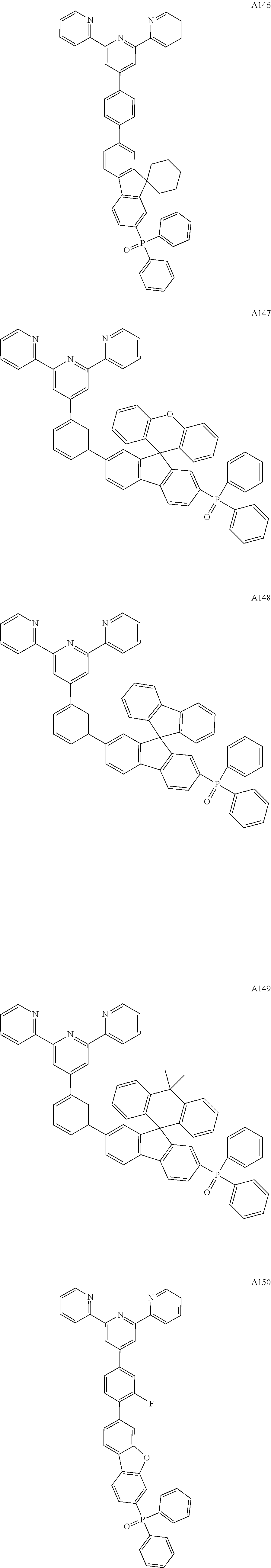

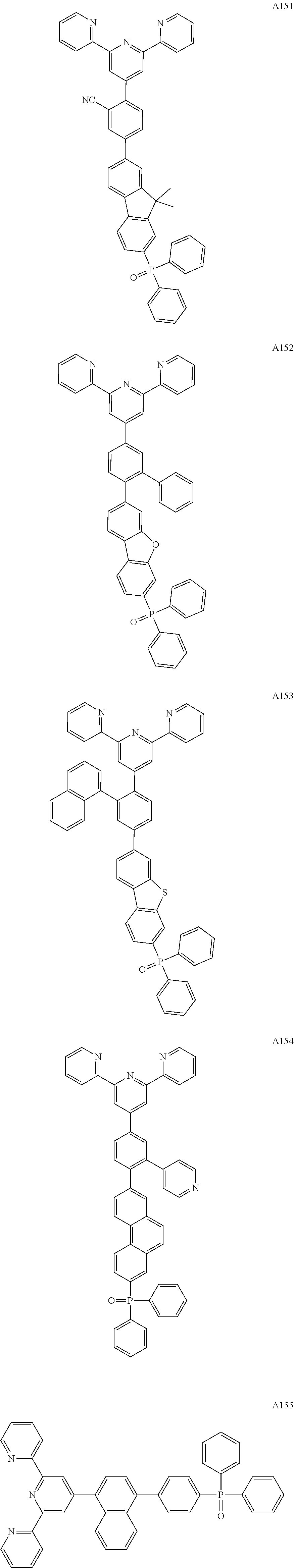 [SMILES: CC1(C)c2cc(-c3ccc(-c4cc(-c5ccccn5)nc(-c5ccccn5)c4)c(C#N)c3)ccc2-c2ccc(P(=O)(c3ccccc3)c3ccccc3)cc21 ; O=P(c1ccccc1)(c1ccccc1)c1ccc2c(c1)oc1cc(-c3ccc(-c4cc(-c5ccccn5)nc(-c5ccccn5)c4)cc3-c3ccccc3)ccc12 ; O=P(c1ccccc1)(c1ccccc1)c1ccc2c(c1)sc1cc(-c3ccc(-c4cc(-c5ccccn5)nc(-c5ccccn5)c4)c(-c4cccc5ccccc45)c3)ccc12 ; O=P(c1ccccc1)(c1ccccc1)c1ccc2c(ccc3cc(-c4ccc(-c5cc(-c6ccccn6)nc(-c6ccccn6)c5)cc4-c4ccncc4)ccc32)c1 ; O=P(c1ccccc1)(c1ccccc1)c1ccc(-c2ccc(-c3cc(-c4ccccn4)nc(-c4ccccn4)c3)c3ccccc23)cc1]

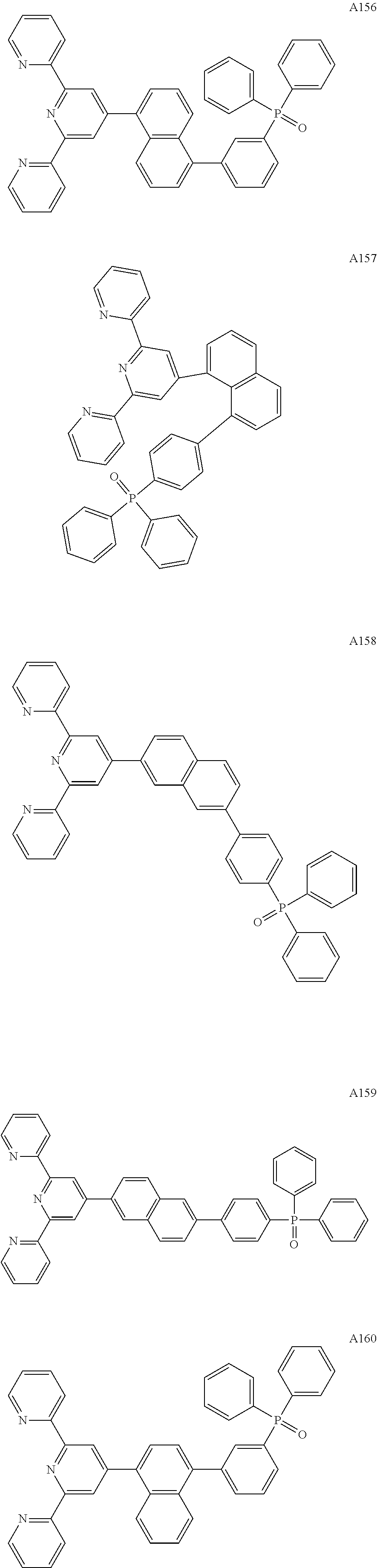 [SMILES: O=P(c1ccccc1)(c1ccccc1)c1cccc(-c2cccc3c(-c4cc(-c5ccccn5)nc(-c5ccccn5)c4)cccc23)c1 ; O=P(c1ccccc1)(c1ccccc1)c1ccc(-c2cccc3cccc(-c4cc(-c5ccccn5)nc(-c5ccccn5)c4)c23)cc1 ; O=P(c1ccccc1)(c1ccccc1)c1ccc(-c2ccc3ccc(-c4cc(-c5ccccn5)nc(-c5ccccn5)c4)cc3c2)cc1 ; O=P(c1ccccc1)(c1ccccc1)c1ccc(-c2ccc3cc(-c4cc(-c5ccccn5)nc(-c5ccccn5)c4)ccc3c2)cc1 ; O=P(c1ccccc1)(c1ccccc1)c1cccc(-c2ccc(-c3cc(-c4ccccn4)nc(-c4ccccn4)c3)c3ccccc23)c1]

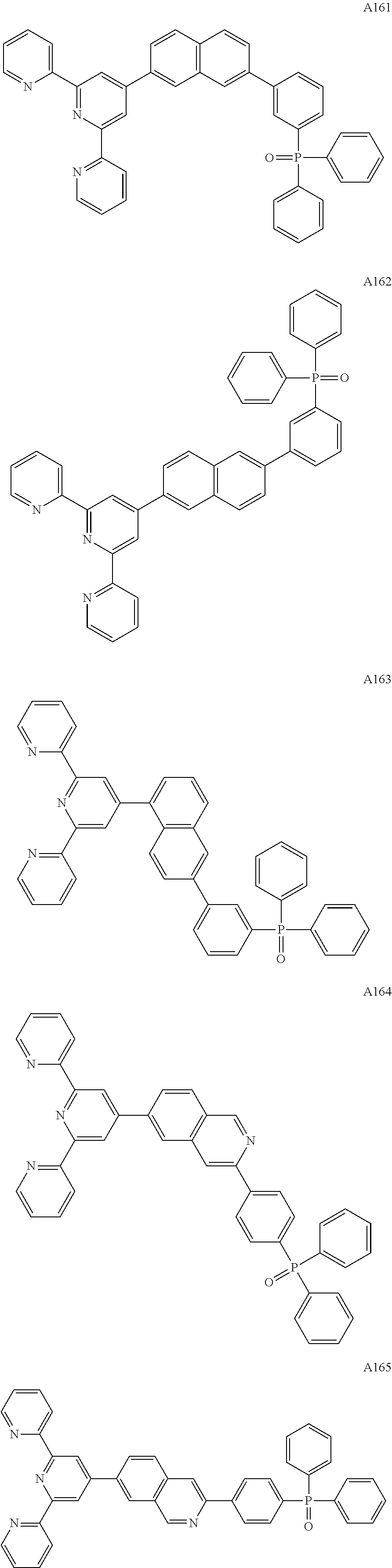 [SMILES: O=P(c1ccccc1)(c1ccccc1)c1cccc(-c2ccc3ccc(-c4cc(-c5ccccn5)nc(-c5ccccn5)c4)cc3c2)c1 ; O=P(c1ccccc1)(c1ccccc1)c1cccc(-c2ccc3cc(-c4cc(-c5ccccn5)nc(-c5ccccn5)c4)ccc3c2)c1 ; O=P(c1ccccc1)(c1ccccc1)c1cccc(-c2ccc3c(-c4cc(-c5ccccn5)nc(-c5ccccn5)c4)cccc3c2)c1 ; O=P(c1ccccc1)(c1ccccc1)c1ccc(-c2cc3cc(-c4cc(-c5ccccn5)nc(-c5ccccn5)c4)ccc3cn2)cc1 ; O=P(c1ccccc1)(c1ccccc1)c1ccc(-c2cc3ccc(-c4cc(-c5ccccn5)nc(-c5ccccn5)c4)cc3cn2)cc1]

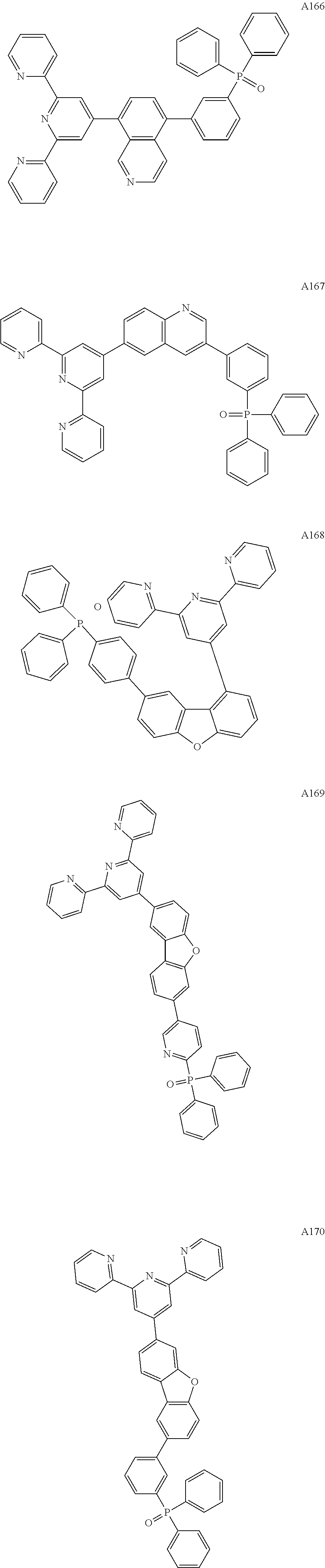

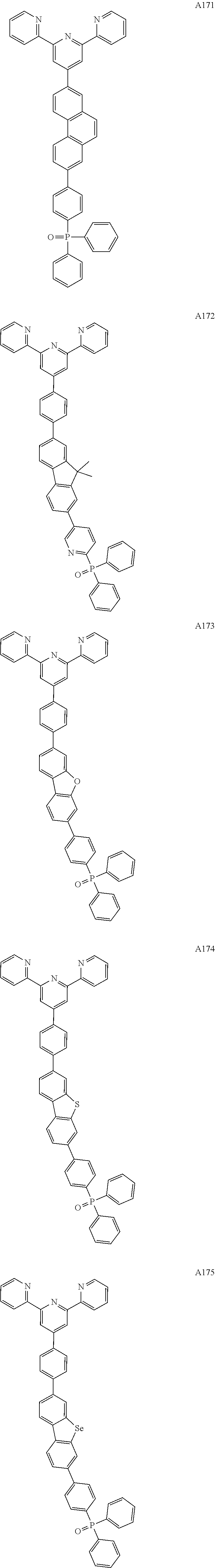

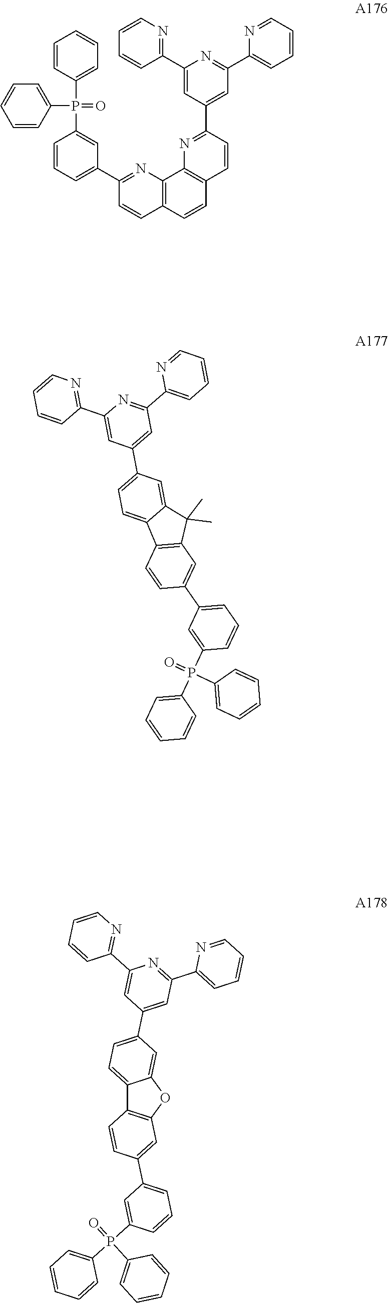 [SMILES: O=P(c1ccccc1)(c1ccccc1)c1cccc(-c2ccc3ccc4ccc(-c5cc(-c6ccccn6)nc(-c6ccccn6)c5)nc4c3n2)c1 ; CC1(C)c2cc(-c3cccc(P(=O)(c4ccccc4)c4ccccc4)c3)ccc2-c2ccc(-c3cc(-c4ccccn4)nc(-c4ccccn4)c3)cc21 ; O=P(c1ccccc1)(c1ccccc1)c1cccc(-c2ccc3c(c2)oc2cc(-c4cc(-c5ccccn5)nc(-c5ccccn5)c4)ccc23)c1]

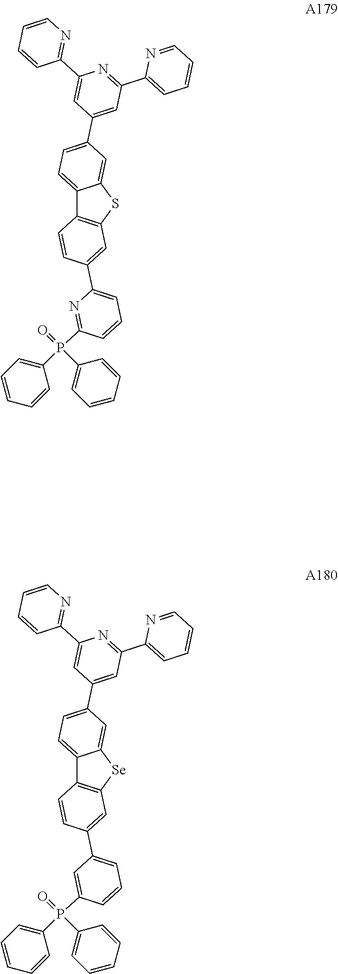 [SMILES: O=P(c1ccccc1)(c1ccccc1)c1cccc(-c2ccc3c(c2)sc2cc(-c4cc(-c5ccccn5)nc(-c5ccccn5)c4)ccc23)n1 ; O=P(c1ccccc1)(c1ccccc1)c1cccc(-c2ccc3c(c2)[se]c2cc(-c4cc(-c5ccccn5)nc(-c5ccccn5)c4)ccc23)c1]

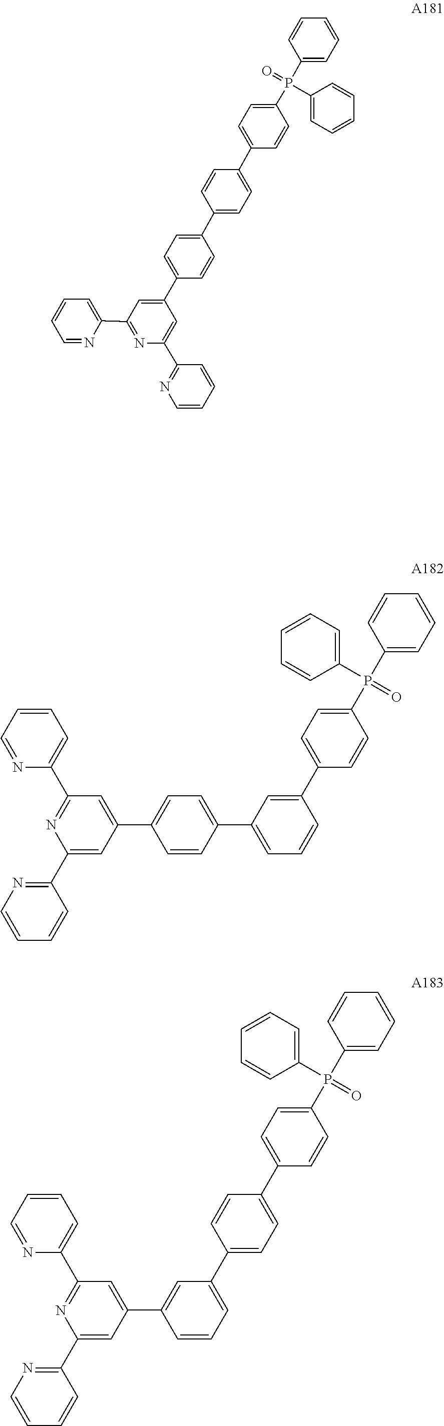 [SMILES: O=P(c1ccccc1)(c1ccccc1)c1ccc(-c2ccc(-c3ccc(-c4cc(-c5ccccn5)nc(-c5ccccn5)c4)cc3)cc2)cc1 ; O=P(c1ccccc1)(c1ccccc1)c1ccc(-c2cccc(-c3ccc(-c4cc(-c5ccccn5)nc(-c5ccccn5)c4)cc3)c2)cc1 ; O=P(c1ccccc1)(c1ccccc1)c1ccc(-c2ccc(-c3cccc(-c4cc(-c5ccccn5)nc(-c5ccccn5)c4)c3)cc2)cc1]

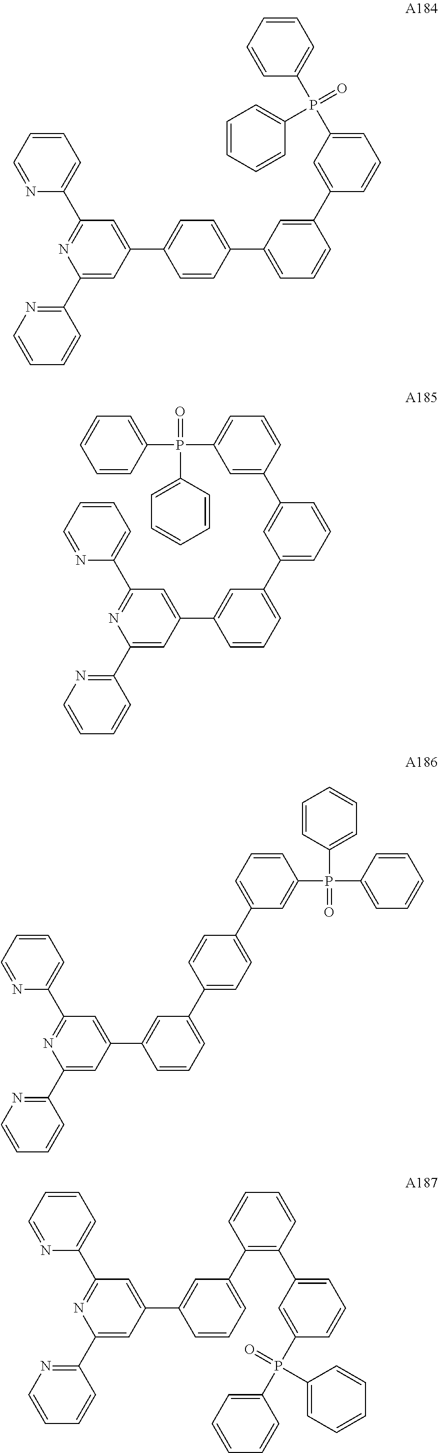

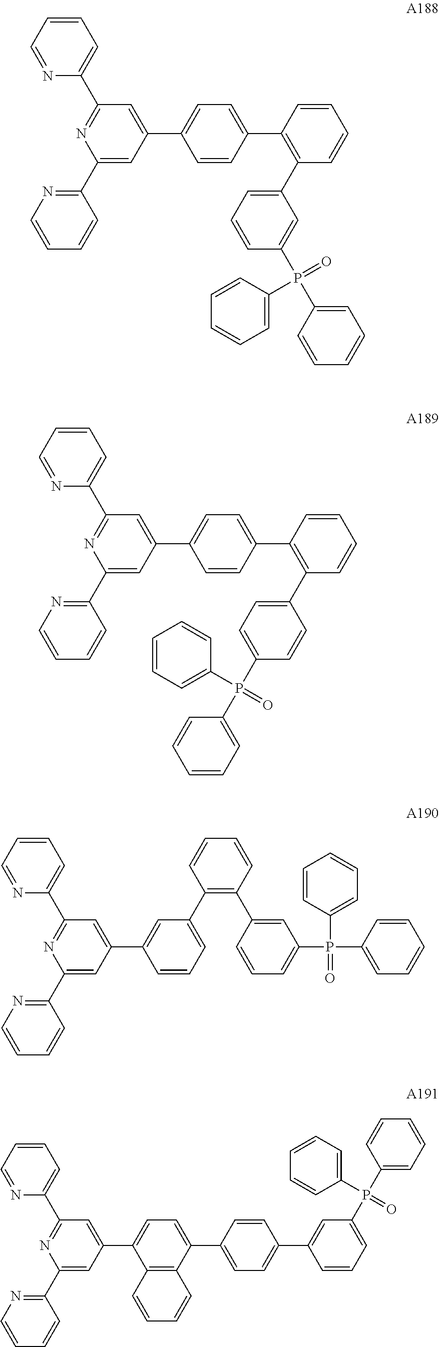 [SMILES: O=P(c1ccccc1)(c1ccccc1)c1cccc(-c2ccccc2-c2ccc(-c3cc(-c4ccccn4)nc(-c4ccccn4)c3)cc2)c1 ; O=P(c1ccccc1)(c1ccccc1)c1ccc(-c2ccccc2-c2ccc(-c3cc(-c4ccccn4)nc(-c4ccccn4)c3)cc2)cc1 ; O=P(c1ccccc1)(c1ccccc1)c1cccc(-c2ccccc2-c2cccc(-c3cc(-c4ccccn4)nc(-c4ccccn4)c3)c2)c1 ; O=P(c1ccccc1)(c1ccccc1)c1cccc(-c2ccc(-c3ccc(-c4cc(-c5ccccn5)nc(-c5ccccn5)c4)c4ccccc34)cc2)c1]

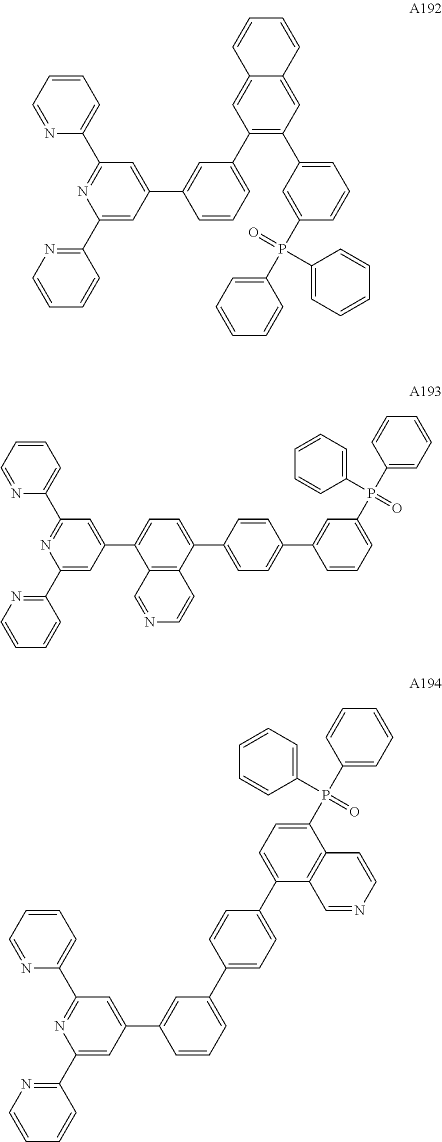 [SMILES: O=P(c1ccccc1)(c1ccccc1)c1cccc(-c2cc3ccccc3cc2-c2cccc(-c3cc(-c4ccccn4)nc(-c4ccccn4)c3)c2)c1 ; O=P(c1ccccc1)(c1ccccc1)c1cccc(-c2ccc(-c3ccc(-c4cc(-c5ccccn5)nc(-c5ccccn5)c4)c4cnccc34)cc2)c1 ; O=P(c1ccccc1)(c1ccccc1)c1ccc(-c2ccc(-c3cccc(-c4cc(-c5ccccn5)nc(-c5ccccn5)c4)c3)cc2)c2cnccc12]

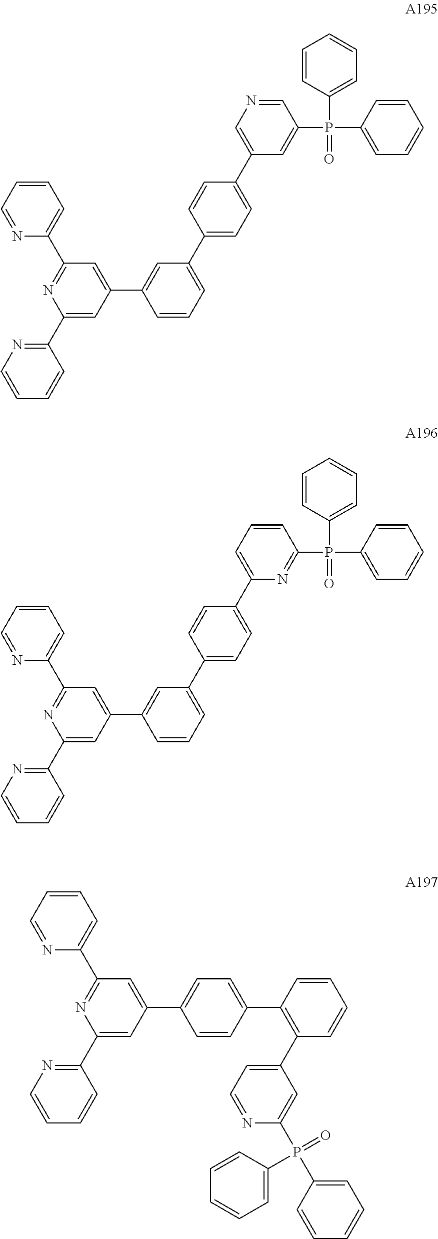 [SMILES: O=P(c1ccccc1)(c1ccccc1)c1cncc(-c2ccc(-c3cccc(-c4cc(-c5ccccn5)nc(-c5ccccn5)c4)c3)cc2)c1 ; O=P(c1ccccc1)(c1ccccc1)c1cccc(-c2ccc(-c3cccc(-c4cc(-c5ccccn5)nc(-c5ccccn5)c4)c3)cc2)n1 ; O=P(c1ccccc1)(c1ccccc1)c1cc(-c2ccccc2-c2ccc(-c3cc(-c4ccccn4)nc(-c4ccccn4)c3)cc2)ccn1]

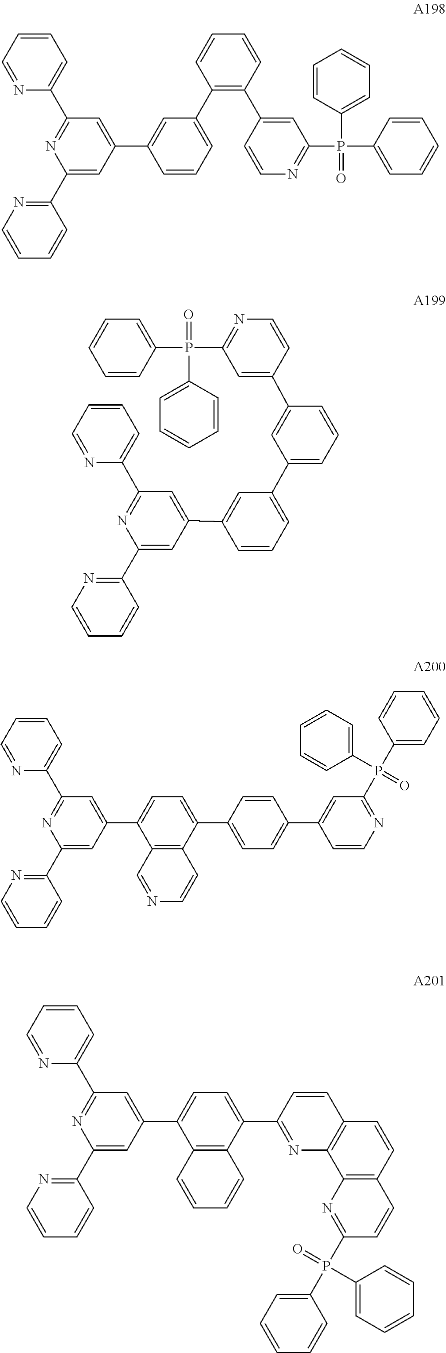 [SMILES: O=P(c1ccccc1)(c1ccccc1)c1cc(-c2ccccc2-c2cccc(-c3cc(-c4ccccn4)nc(-c4ccccn4)c3)c2)ccn1 ; O=P(c1ccccc1)(c1ccccc1)c1cc(-c2cccc(-c3cccc(-c4cc(-c5ccccn5)nc(-c5ccccn5)c4)c3)c2)ccn1 ; O=P(c1ccccc1)(c1ccccc1)c1cc(-c2ccc(-c3ccc(-c4cc(-c5ccccn5)nc(-c5ccccn5)c4)c4cnccc34)cc2)ccn1 ; O=P(c1ccccc1)(c1ccccc1)c1ccc2ccc3ccc(-c4ccc(-c5cc(-c6ccccn6)nc(-c6ccccn6)c5)c5ccccc45)nc3c2n1]

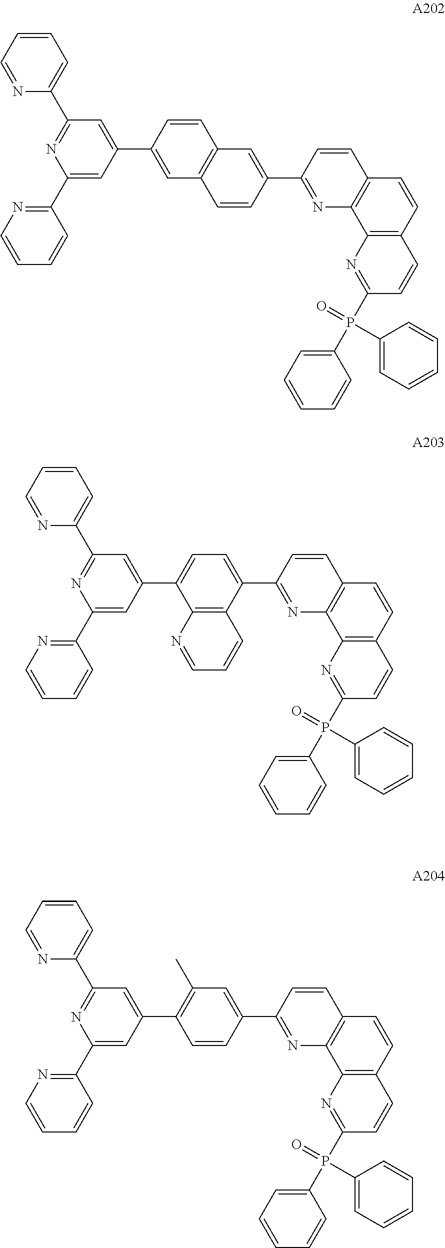 [SMILES: O=P(c1ccccc1)(c1ccccc1)c1ccc2ccc3ccc(-c4ccc5cc(-c6cc(-c7ccccn7)nc(-c7ccccn7)c6)ccc5c4)nc3c2n1 ; O=P(c1ccccc1)(c1ccccc1)c1ccc2ccc3ccc(-c4ccc(-c5cc(-c6ccccn6)nc(-c6ccccn6)c5)c5ncccc45)nc3c2n1 ; Cc1cc(-c2ccc3ccc4ccc(P(=O)(c5ccccc5)c5ccccc5)nc4c3n2)ccc1-c1cc(-c2ccccn2)nc(-c2ccccn2)c1]

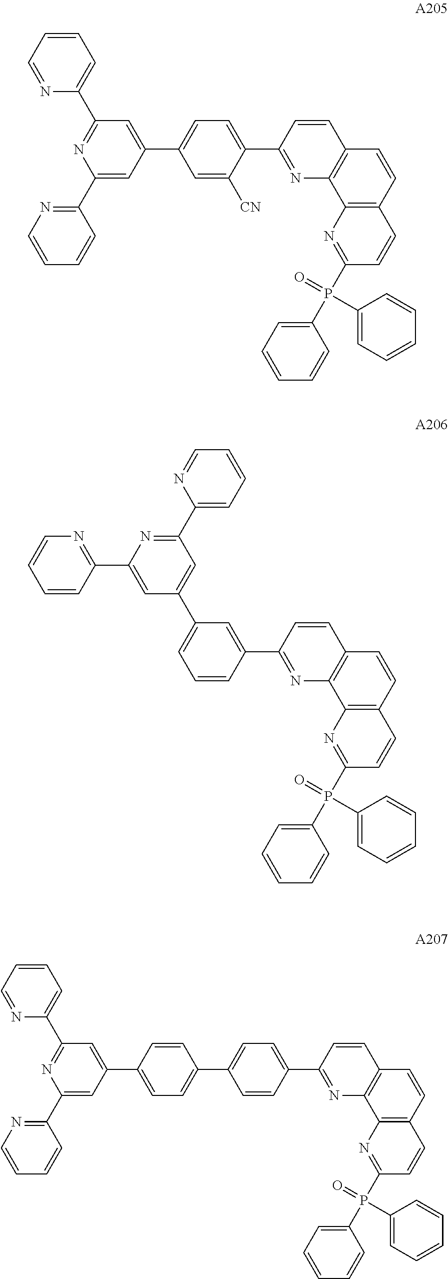 [SMILES: N#Cc1cc(-c2cc(-c3ccccn3)nc(-c3ccccn3)c2)ccc1-c1ccc2ccc3ccc(P(=O)(c4ccccc4)c4ccccc4)nc3c2n1 ; O=P(c1ccccc1)(c1ccccc1)c1ccc2ccc3ccc(-c4cccc(-c5cc(-c6ccccn6)nc(-c6ccccn6)c5)c4)nc3c2n1 ; O=P(c1ccccc1)(c1ccccc1)c1ccc2ccc3ccc(-c4ccc(-c5ccc(-c6cc(-c7ccccn7)nc(-c7ccccn7)c6)cc5)cc4)nc3c2n1]

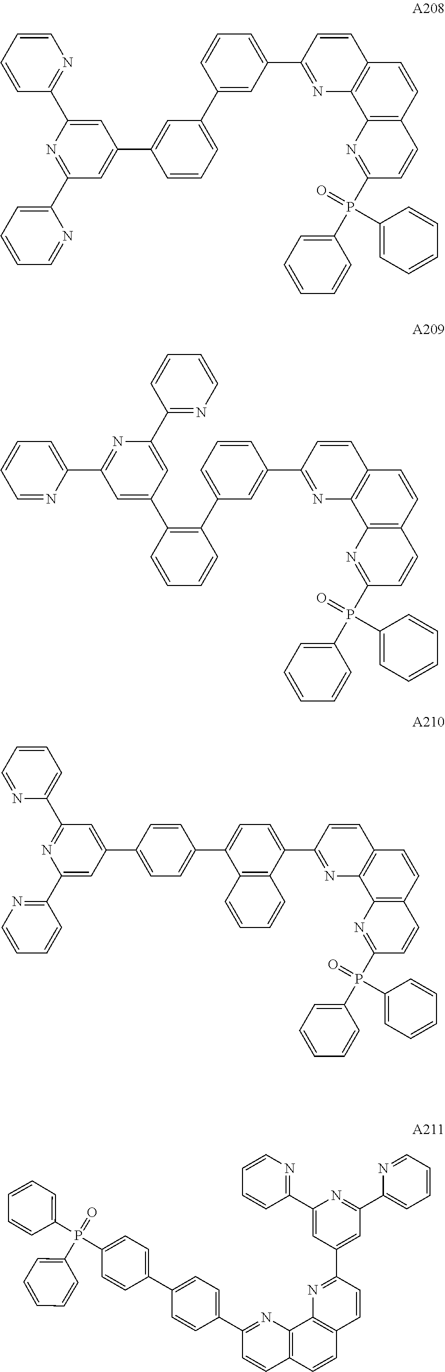 [SMILES: O=P(c1ccccc1)(c1ccccc1)c1ccc2ccc3ccc(-c4cccc(-c5cccc(-c6cc(-c7ccccn7)nc(-c7ccccn7)c6)c5)c4)nc3c2n1 ; O=P(c1ccccc1)(c1ccccc1)c1ccc2ccc3ccc(-c4cccc(-c5ccccc5-c5cc(-c6ccccn6)nc(-c6ccccn6)c5)c4)nc3c2n1 ; O=P(c1ccccc1)(c1ccccc1)c1ccc2ccc3ccc(-c4ccc(-c5ccc(-c6cc(-c7ccccn7)nc(-c7ccccn7)c6)cc5)c5ccccc45)nc3c2n1 ; O=P(c1ccccc1)(c1ccccc1)c1ccc(-c2ccc(-c3ccc4ccc5ccc(-c6cc(-c7ccccn7)nc(-c7ccccn7)c6)nc5c4n3)cc2)cc1]

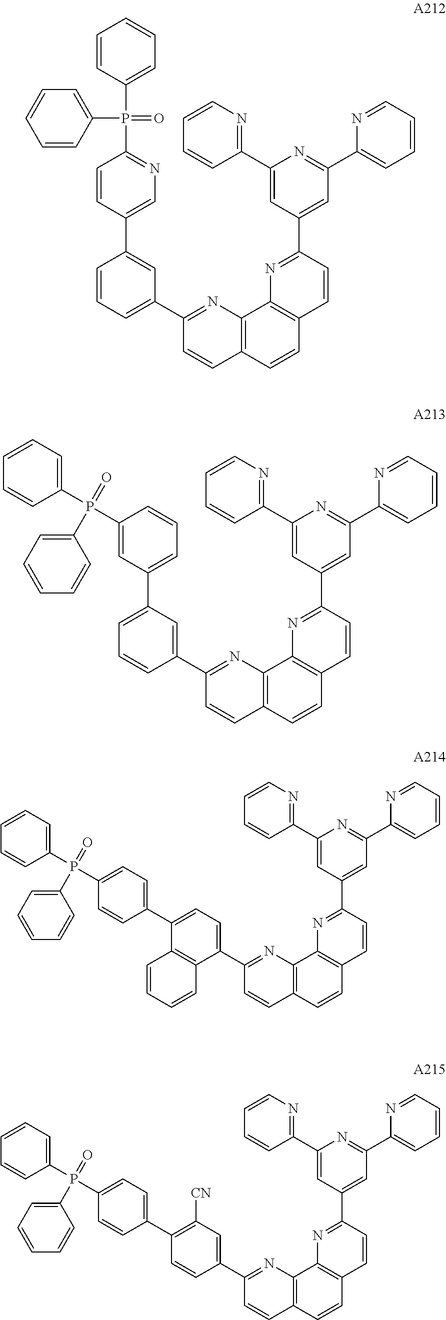 [SMILES: O=P(c1ccccc1)(c1ccccc1)c1ccc(-c2cccc(-c3ccc4ccc5ccc(-c6cc(-c7ccccn7)nc(-c7ccccn7)c6)nc5c4n3)c2)cn1 ; O=P(c1ccccc1)(c1ccccc1)c1cccc(-c2cccc(-c3ccc4ccc5ccc(-c6cc(-c7ccccn7)nc(-c7ccccn7)c6)nc5c4n3)c2)c1 ; O=P(c1ccccc1)(c1ccccc1)c1ccc(-c2ccc(-c3ccc4ccc5ccc(-c6cc(-c7ccccn7)nc(-c7ccccn7)c6)nc5c4n3)c3ccccc23)cc1 ; N#Cc1cc(-c2ccc3ccc4ccc(-c5cc(-c6ccccn6)nc(-c6ccccn6)c5)nc4c3n2)ccc1-c1ccc(P(=O)(c2ccccc2)c2ccccc2)cc1]

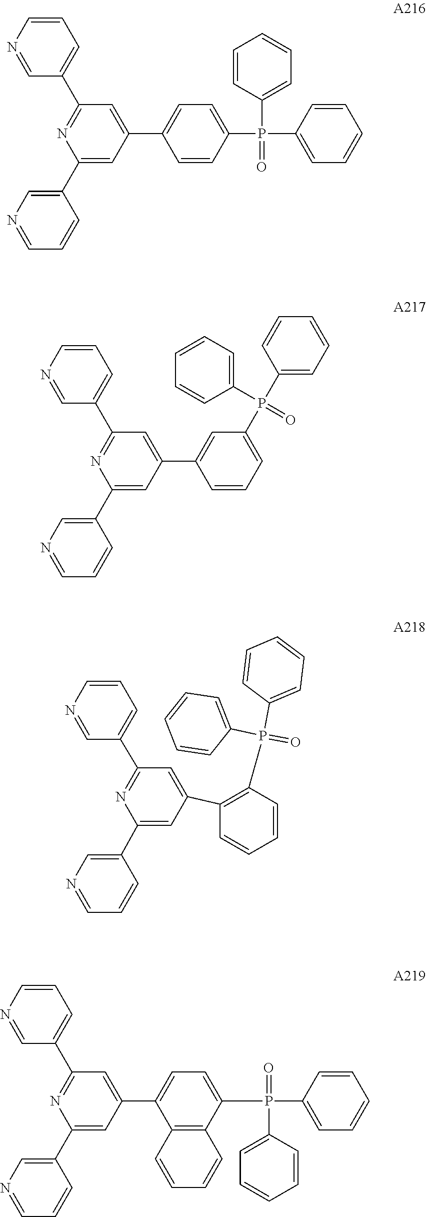 [SMILES: O=P(c1ccccc1)(c1ccccc1)c1ccc(-c2cc(-c3cccnc3)nc(-c3cccnc3)c2)cc1 ; O=P(c1ccccc1)(c1ccccc1)c1cccc(-c2cc(-c3cccnc3)nc(-c3cccnc3)c2)c1 ; O=P(c1ccccc1)(c1ccccc1)c1ccccc1-c1cc(-c2cccnc2)nc(-c2cccnc2)c1 ; O=P(c1ccccc1)(c1ccccc1)c1ccc(-c2cc(-c3cccnc3)nc(-c3cccnc3)c2)c2ccccc12]

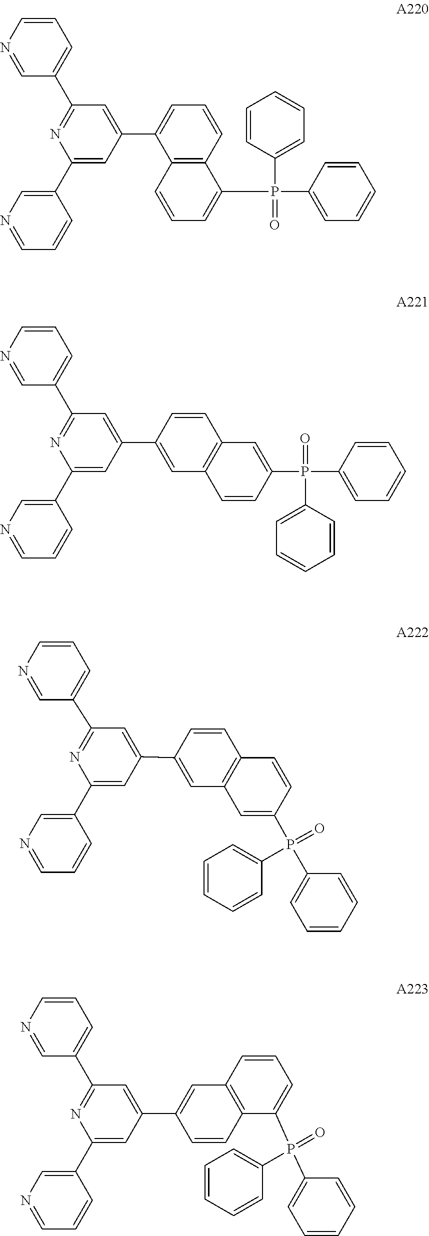 [SMILES: O=P(c1ccccc1)(c1ccccc1)c1cccc2c(-c3cc(-c4cccnc4)nc(-c4cccnc4)c3)cccc12 ; O=P(c1ccccc1)(c1ccccc1)c1ccc2cc(-c3cc(-c4cccnc4)nc(-c4cccnc4)c3)ccc2c1 ; O=P(c1ccccc1)(c1ccccc1)c1ccc2ccc(-c3cc(-c4cccnc4)nc(-c4cccnc4)c3)cc2c1 ; O=P(c1ccccc1)(c1ccccc1)c1cccc2cc(-c3cc(-c4cccnc4)nc(-c4cccnc4)c3)ccc12]

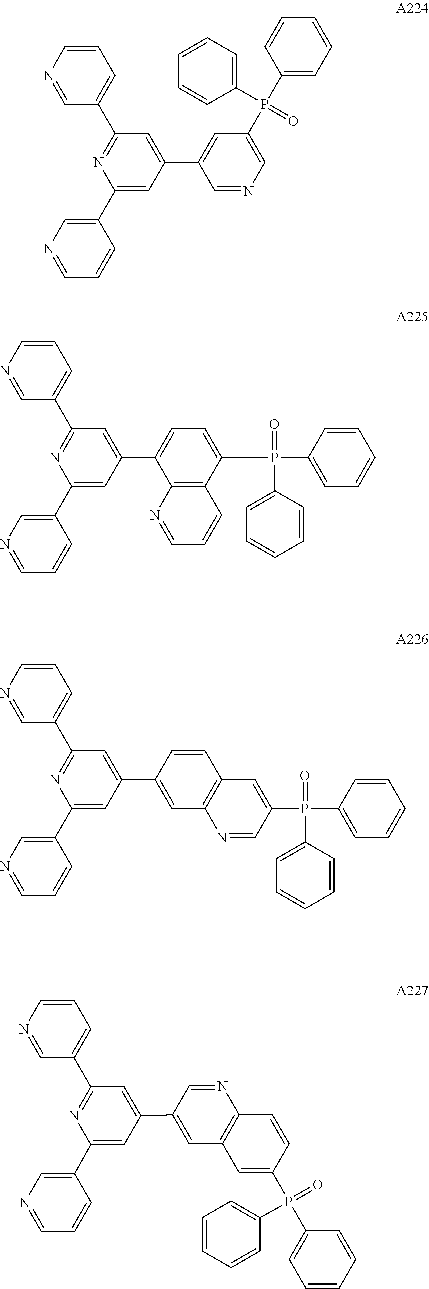 [SMILES: O=P(c1ccccc1)(c1ccccc1)c1cncc(-c2cc(-c3cccnc3)nc(-c3cccnc3)c2)c1 ; O=P(c1ccccc1)(c1ccccc1)c1ccc(-c2cc(-c3cccnc3)nc(-c3cccnc3)c2)c2ncccc12 ; O=P(c1ccccc1)(c1ccccc1)c1cnc2cc(-c3cc(-c4cccnc4)nc(-c4cccnc4)c3)ccc2c1 ; O=P(c1ccccc1)(c1ccccc1)c1ccc2ncc(-c3cc(-c4cccnc4)nc(-c4cccnc4)c3)cc2c1]

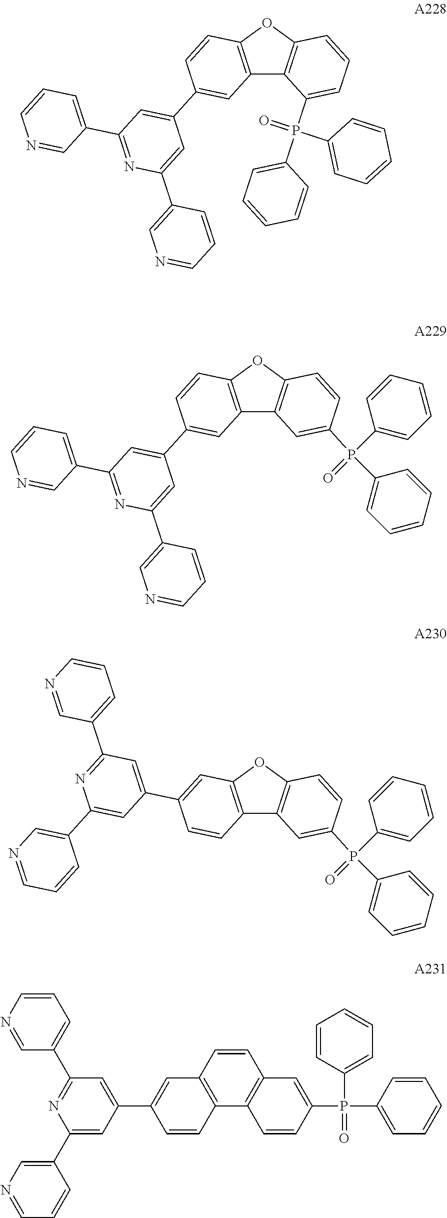 [SMILES: O=P(c1ccccc1)(c1ccccc1)c1cccc2oc3ccc(-c4cc(-c5cccnc5)nc(-c5cccnc5)c4)cc3c12 ; O=P(c1ccccc1)(c1ccccc1)c1ccc2oc3ccc(-c4cc(-c5cccnc5)nc(-c5cccnc5)c4)cc3c2c1 ; O=P(c1ccccc1)(c1ccccc1)c1ccc2oc3cc(-c4cc(-c5cccnc5)nc(-c5cccnc5)c4)ccc3c2c1 ; O=P(c1ccccc1)(c1ccccc1)c1ccc2c(ccc3cc(-c4cc(-c5cccnc5)nc(-c5cccnc5)c4)ccc32)c1]

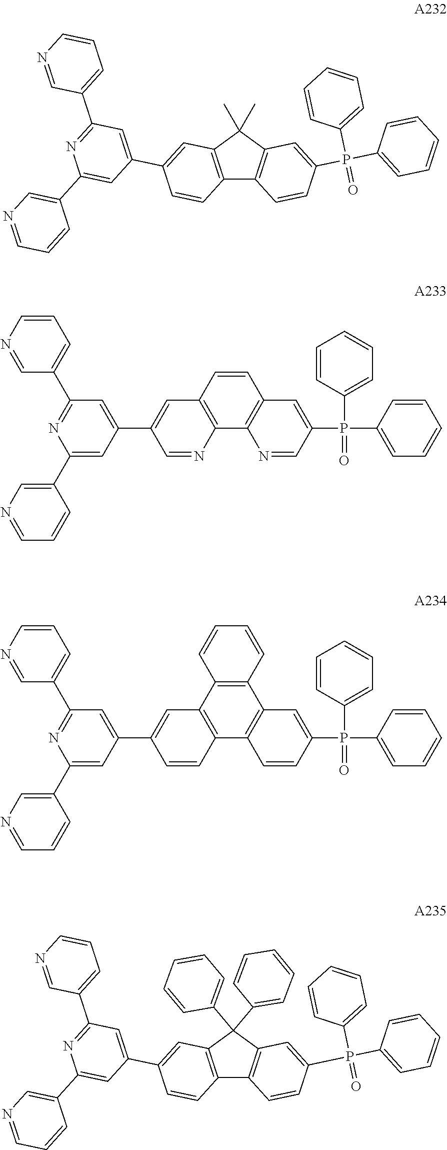 [SMILES: CC1(C)c2cc(-c3cc(-c4cccnc4)nc(-c4cccnc4)c3)ccc2-c2ccc(P(=O)(c3ccccc3)c3ccccc3)cc21 ; O=P(c1ccccc1)(c1ccccc1)c1cnc2c(ccc3cc(-c4cc(-c5cccnc5)nc(-c5cccnc5)c4)cnc32)c1 ; O=P(c1ccccc1)(c1ccccc1)c1ccc2c3ccc(-c4cc(-c5cccnc5)nc(-c5cccnc5)c4)cc3c3ccccc3c2c1 ; O=P(c1ccccc1)(c1ccccc1)c1ccc2c(c1)C(c1ccccc1)(c1ccccc1)c1cc(-c3cc(-c4cccnc4)nc(-c4cccnc4)c3)ccc1-2]

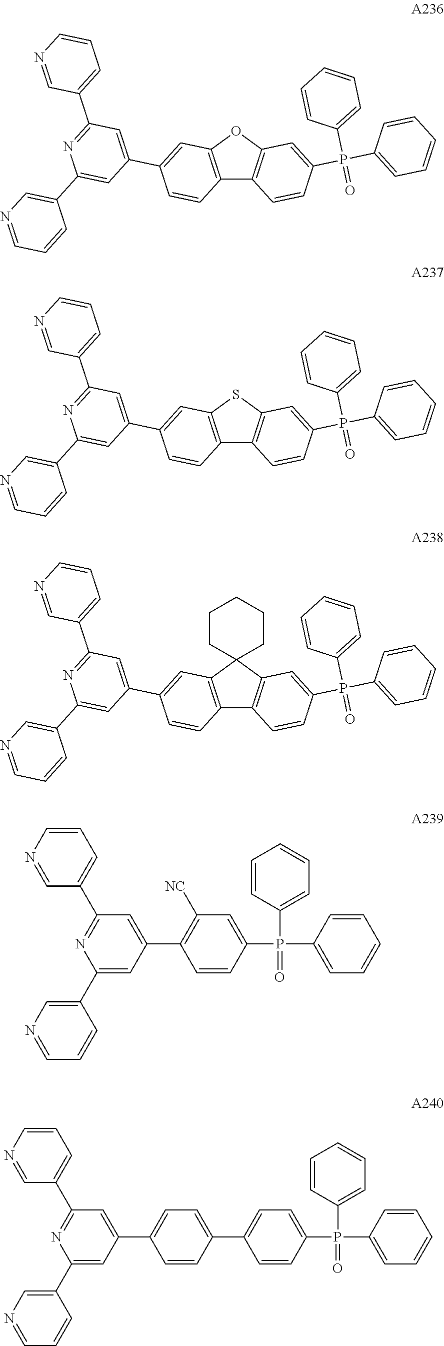 [SMILES: O=P(c1ccccc1)(c1ccccc1)c1ccc2c(c1)oc1cc(-c3cc(-c4cccnc4)nc(-c4cccnc4)c3)ccc12 ; O=P(c1ccccc1)(c1ccccc1)c1ccc2c(c1)sc1cc(-c3cc(-c4cccnc4)nc(-c4cccnc4)c3)ccc12 ; O=P(c1ccccc1)(c1ccccc1)c1ccc2c(c1)C1(CCCCC1)c1cc(-c3cc(-c4cccnc4)nc(-c4cccnc4)c3)ccc1-2 ; N#Cc1cc(P(=O)(c2ccccc2)c2ccccc2)ccc1-c1cc(-c2cccnc2)nc(-c2cccnc2)c1 ; O=P(c1ccccc1)(c1ccccc1)c1ccc(-c2ccc(-c3cc(-c4cccnc4)nc(-c4cccnc4)c3)cc2)cc1]

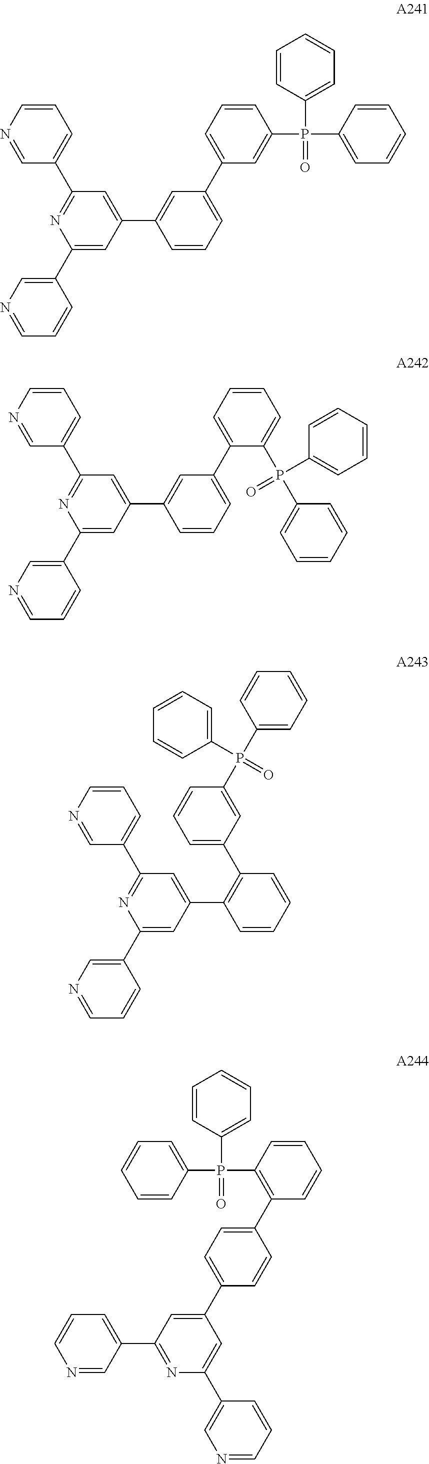 [SMILES: O=P(c1ccccc1)(c1ccccc1)c1cccc(-c2cccc(-c3cc(-c4cccnc4)nc(-c4cccnc4)c3)c2)c1 ; O=P(c1ccccc1)(c1ccccc1)c1ccccc1-c1cccc(-c2cc(-c3cccnc3)nc(-c3cccnc3)c2)c1 ; O=P(c1ccccc1)(c1ccccc1)c1cccc(-c2ccccc2-c2cc(-c3cccnc3)nc(-c3cccnc3)c2)c1 ; O=P(c1ccccc1)(c1ccccc1)c1ccccc1-c1ccc(-c2cc(-c3cccnc3)nc(-c3cccnc3)c2)cc1]

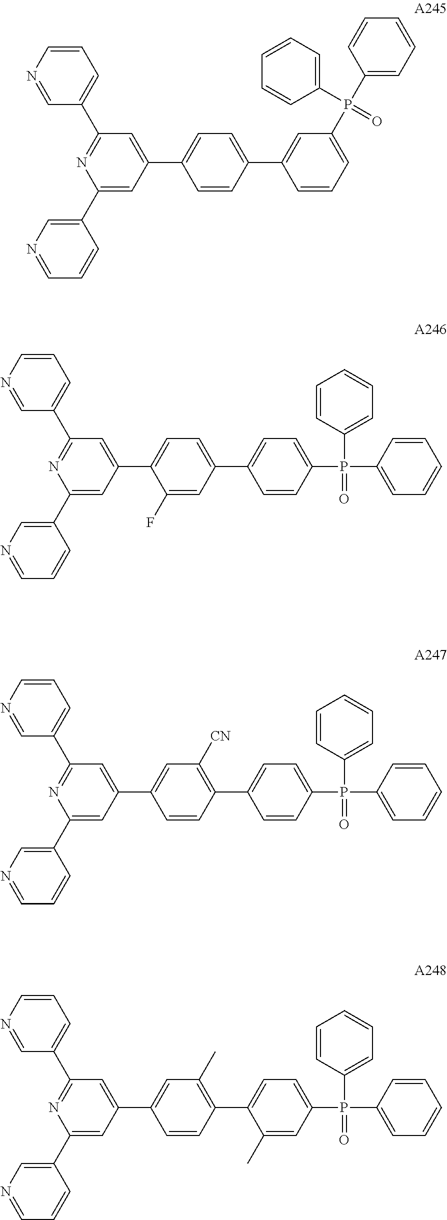 [SMILES: O=P(c1ccccc1)(c1ccccc1)c1cccc(-c2ccc(-c3cc(-c4cccnc4)nc(-c4cccnc4)c3)cc2)c1 ; O=P(c1ccccc1)(c1ccccc1)c1ccc(-c2ccc(-c3cc(-c4cccnc4)nc(-c4cccnc4)c3)c(F)c2)cc1 ; N#Cc1cc(-c2cc(-c3cccnc3)nc(-c3cccnc3)c2)ccc1-c1ccc(P(=O)(c2ccccc2)c2ccccc2)cc1 ; Cc1cc(-c2cc(-c3cccnc3)nc(-c3cccnc3)c2)ccc1-c1ccc(P(=O)(c2ccccc2)c2ccccc2)cc1C]

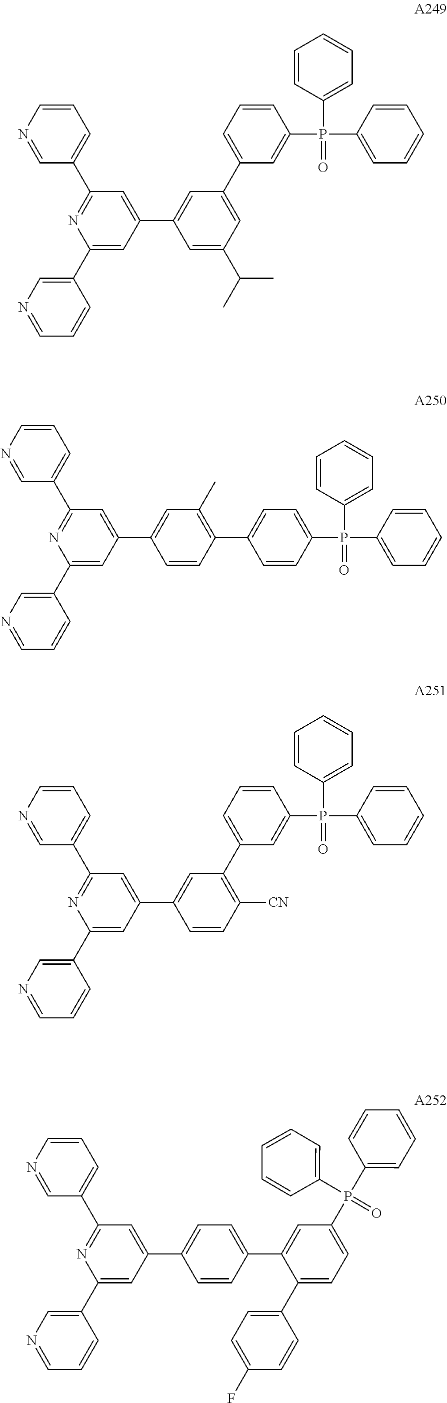 [SMILES: CC(C)c1cc(-c2cccc(P(=O)(c3ccccc3)c3ccccc3)c2)cc(-c2cc(-c3cccnc3)nc(-c3cccnc3)c2)c1 ; Cc1cc(-c2cc(-c3cccnc3)nc(-c3cccnc3)c2)ccc1-c1ccc(P(=O)(c2ccccc2)c2ccccc2)cc1 ; N#Cc1ccc(-c2cc(-c3cccnc3)nc(-c3cccnc3)c2)cc1-c1cccc(P(=O)(c2ccccc2)c2ccccc2)c1 ; O=P(c1ccccc1)(c1ccccc1)c1ccc(-c2ccc(F)cc2)c(-c2ccc(-c3cc(-c4cccnc4)nc(-c4cccnc4)c3)cc2)c1]

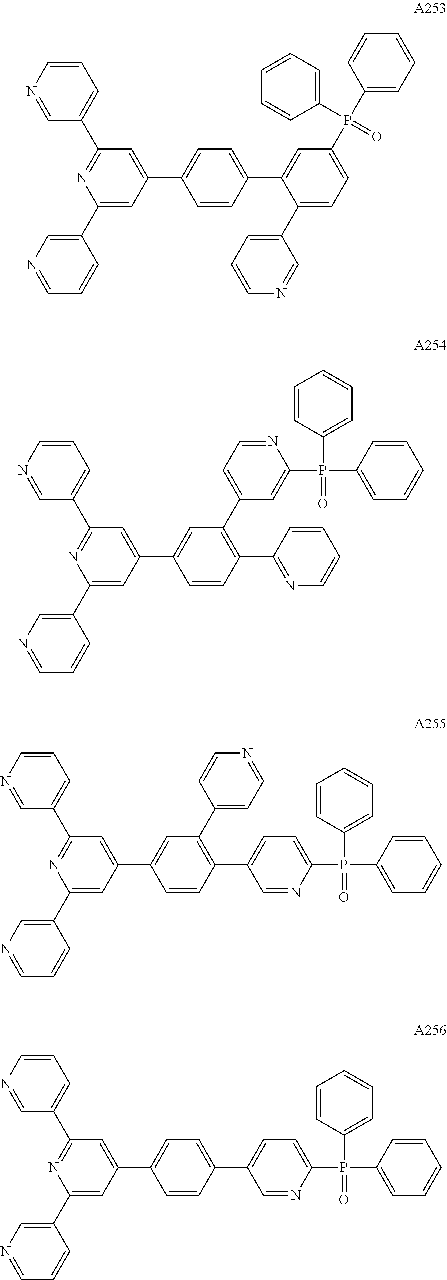 [SMILES: O=P(c1ccccc1)(c1ccccc1)c1ccc(-c2cccnc2)c(-c2ccc(-c3cc(-c4cccnc4)nc(-c4cccnc4)c3)cc2)c1 ; O=P(c1ccccc1)(c1ccccc1)c1cc(-c2cc(-c3cc(-c4cccnc4)nc(-c4cccnc4)c3)ccc2-c2ccccn2)ccn1 ; O=P(c1ccccc1)(c1ccccc1)c1ccc(-c2ccc(-c3cc(-c4cccnc4)nc(-c4cccnc4)c3)cc2-c2ccncc2)cn1 ; O=P(c1ccccc1)(c1ccccc1)c1ccc(-c2ccc(-c3cc(-c4cccnc4)nc(-c4cccnc4)c3)cc2)cn1]

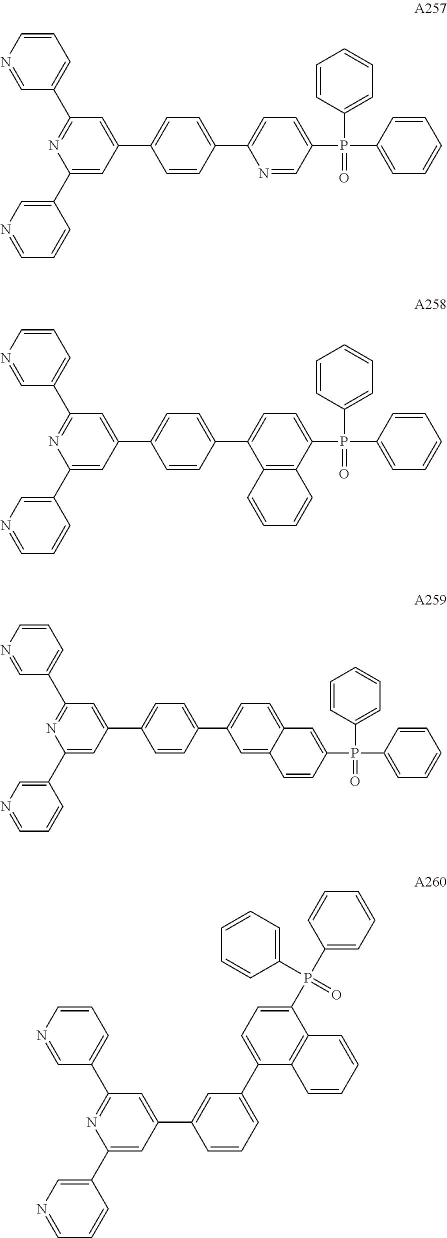 [SMILES: O=P(c1ccccc1)(c1ccccc1)c1ccc(-c2ccc(-c3cc(-c4cccnc4)nc(-c4cccnc4)c3)cc2)nc1 ; O=P(c1ccccc1)(c1ccccc1)c1ccc(-c2ccc(-c3cc(-c4cccnc4)nc(-c4cccnc4)c3)cc2)c2ccccc12 ; O=P(c1ccccc1)(c1ccccc1)c1ccc2cc(-c3ccc(-c4cc(-c5cccnc5)nc(-c5cccnc5)c4)cc3)ccc2c1 ; O=P(c1ccccc1)(c1ccccc1)c1ccc(-c2cccc(-c3cc(-c4cccnc4)nc(-c4cccnc4)c3)c2)c2ccccc12]

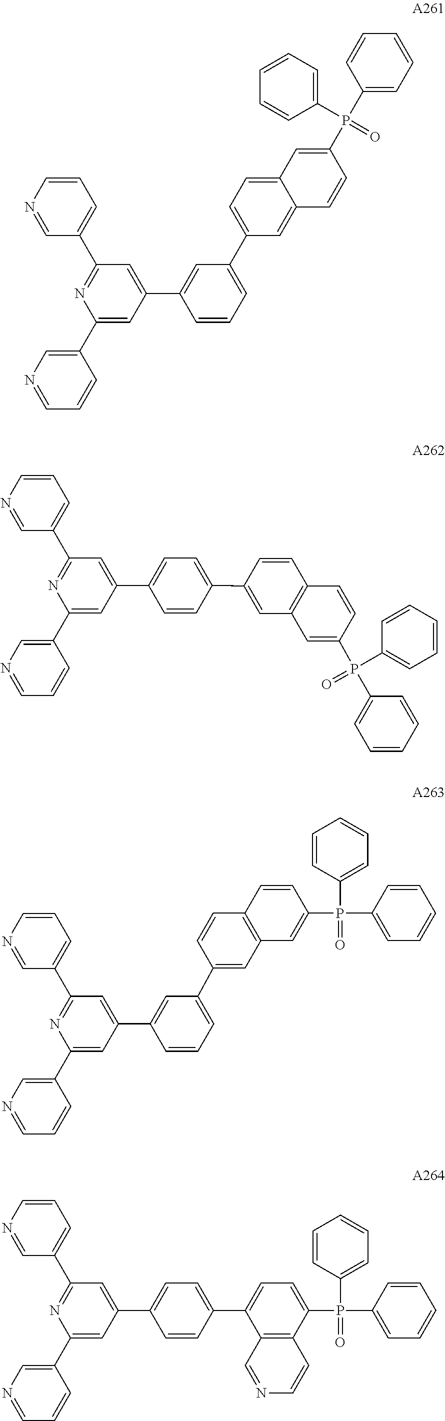 [SMILES: O=P(c1ccccc1)(c1ccccc1)c1ccc2cc(-c3cccc(-c4cc(-c5cccnc5)nc(-c5cccnc5)c4)c3)ccc2c1 ; O=P(c1ccccc1)(c1ccccc1)c1ccc2ccc(-c3ccc(-c4cc(-c5cccnc5)nc(-c5cccnc5)c4)cc3)cc2c1 ; O=P(c1ccccc1)(c1ccccc1)c1ccc2ccc(-c3cccc(-c4cc(-c5cccnc5)nc(-c5cccnc5)c4)c3)cc2c1 ; O=P(c1ccccc1)(c1ccccc1)c1ccc(-c2ccc(-c3cc(-c4cccnc4)nc(-c4cccnc4)c3)cc2)c2cnccc12]

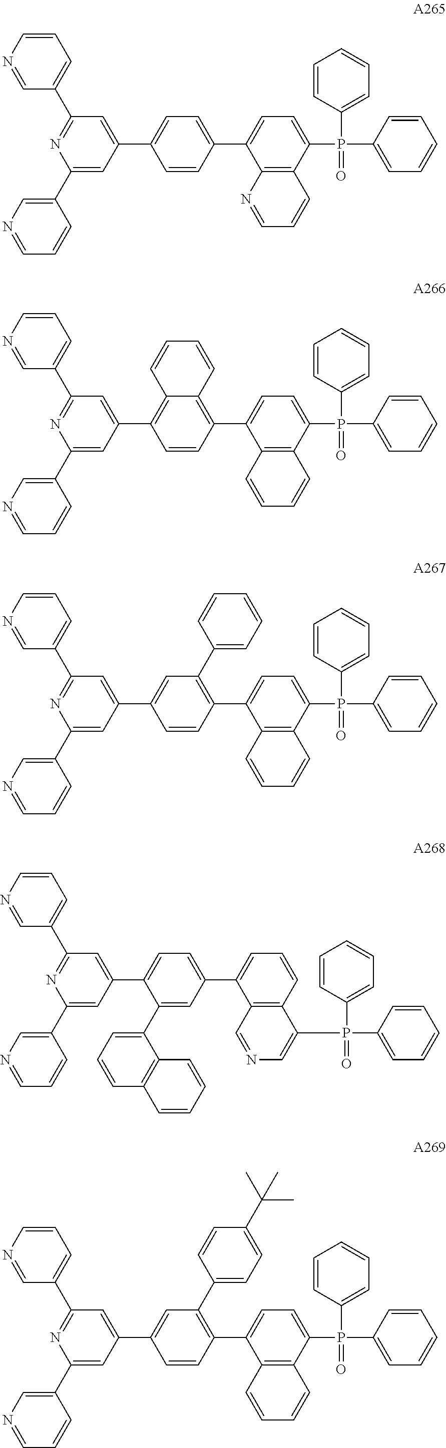 [SMILES: O=P(c1ccccc1)(c1ccccc1)c1ccc(-c2ccc(-c3cc(-c4cccnc4)nc(-c4cccnc4)c3)cc2)c2ncccc12 ; O=P(c1ccccc1)(c1ccccc1)c1ccc(-c2ccc(-c3cc(-c4cccnc4)nc(-c4cccnc4)c3)c3ccccc23)c2ccccc12 ; O=P(c1ccccc1)(c1ccccc1)c1ccc(-c2ccc(-c3cc(-c4cccnc4)nc(-c4cccnc4)c3)cc2-c2ccccc2)c2ccccc12 ; O=P(c1ccccc1)(c1ccccc1)c1cncc2c(-c3ccc(-c4cc(-c5cccnc5)nc(-c5cccnc5)c4)c(-c4cccc5ccccc45)c3)cccc12 ; CC(C)(C)c1ccc(-c2cc(-c3cc(-c4cccnc4)nc(-c4cccnc4)c3)ccc2-c2ccc(P(=O)(c3ccccc3)c3ccccc3)c3ccccc23)cc1]

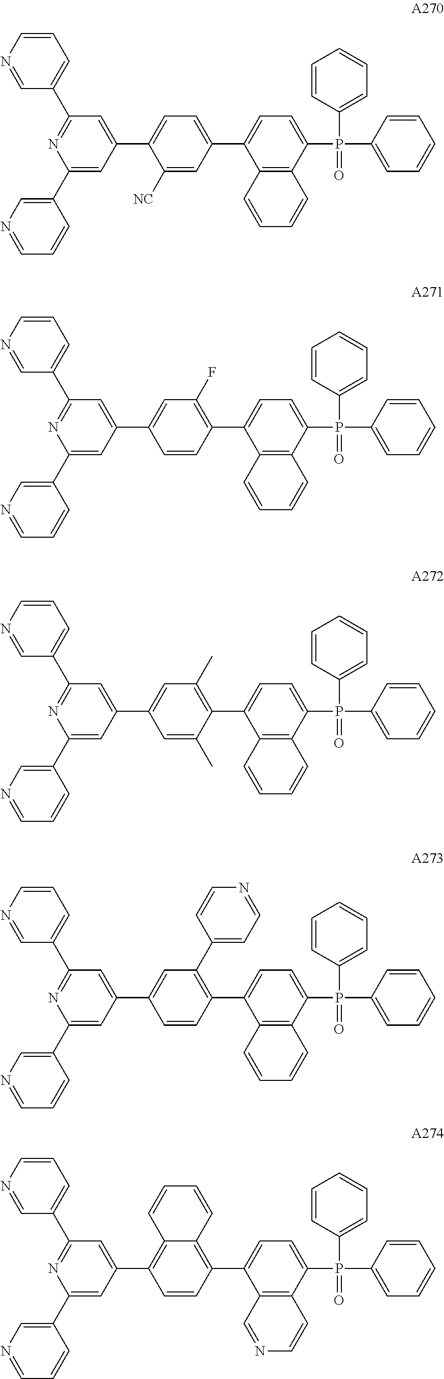 [SMILES: N#Cc1cc(-c2ccc(P(=O)(c3ccccc3)c3ccccc3)c3ccccc23)ccc1-c1cc(-c2cccnc2)nc(-c2cccnc2)c1 ; O=P(c1ccccc1)(c1ccccc1)c1ccc(-c2ccc(-c3cc(-c4cccnc4)nc(-c4cccnc4)c3)cc2F)c2ccccc12 ; Cc1cc(-c2cc(-c3cccnc3)nc(-c3cccnc3)c2)cc(C)c1-c1ccc(P(=O)(c2ccccc2)c2ccccc2)c2ccccc12 ; O=P(c1ccccc1)(c1ccccc1)c1ccc(-c2ccc(-c3cc(-c4cccnc4)nc(-c4cccnc4)c3)cc2-c2ccncc2)c2ccccc12 ; O=P(c1ccccc1)(c1ccccc1)c1ccc(-c2ccc(-c3cc(-c4cccnc4)nc(-c4cccnc4)c3)c3ccccc23)c2cnccc12]

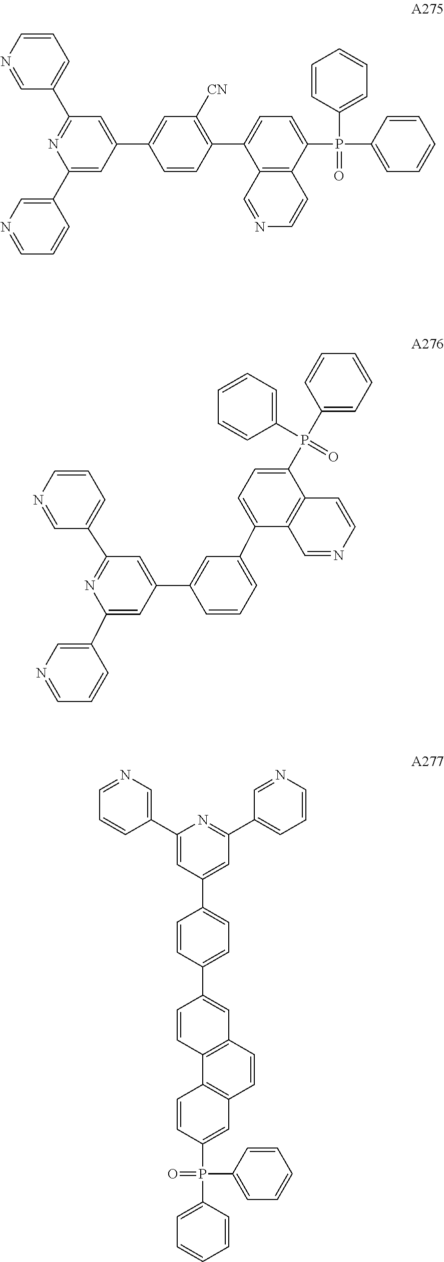 [SMILES: N#Cc1cc(-c2cc(-c3cccnc3)nc(-c3cccnc3)c2)ccc1-c1ccc(P(=O)(c2ccccc2)c2ccccc2)c2ccncc12 ; O=P(c1ccccc1)(c1ccccc1)c1ccc(-c2cccc(-c3cc(-c4cccnc4)nc(-c4cccnc4)c3)c2)c2cnccc12 ; O=P(c1ccccc1)(c1ccccc1)c1ccc2c(ccc3cc(-c4ccc(-c5cc(-c6cccnc6)nc(-c6cccnc6)c5)cc4)ccc32)c1]

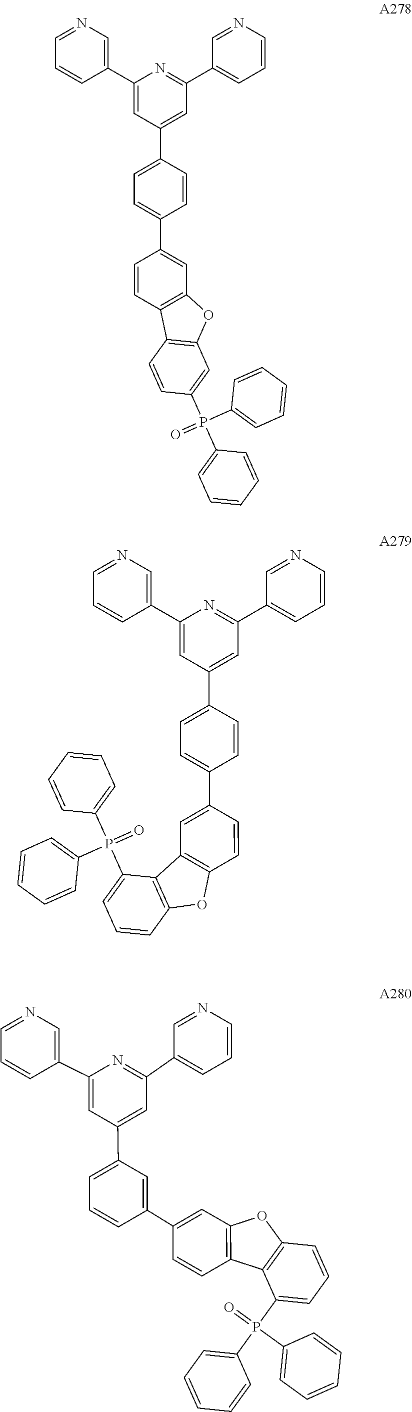 [SMILES: O=P(c1ccccc1)(c1ccccc1)c1ccc2c(c1)oc1cc(-c3ccc(-c4cc(-c5cccnc5)nc(-c5cccnc5)c4)cc3)ccc12 ; O=P(c1ccccc1)(c1ccccc1)c1cccc2oc3ccc(-c4ccc(-c5cc(-c6cccnc6)nc(-c6cccnc6)c5)cc4)cc3c12 ; O=P(c1ccccc1)(c1ccccc1)c1cccc2oc3cc(-c4cccc(-c5cc(-c6cccnc6)nc(-c6cccnc6)c5)c4)ccc3c12]

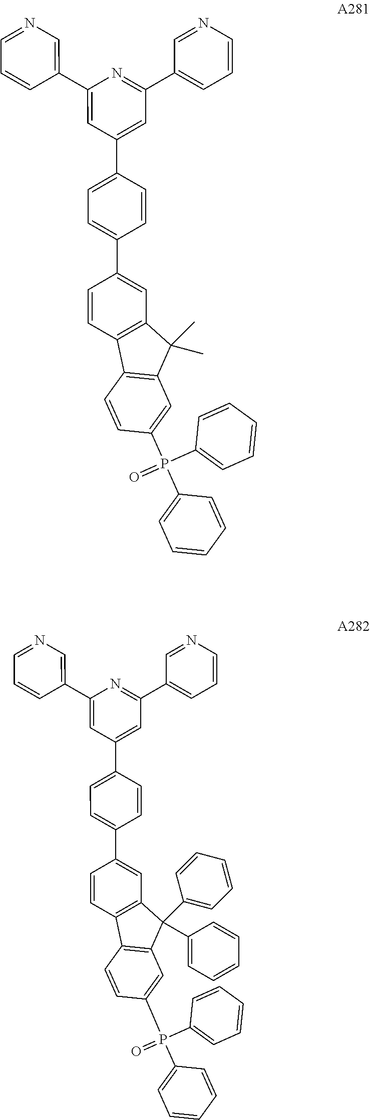 [SMILES: CC1(C)c2cc(-c3ccc(-c4cc(-c5cccnc5)nc(-c5cccnc5)c4)cc3)ccc2-c2ccc(P(=O)(c3ccccc3)c3ccccc3)cc21 ; O=P(c1ccccc1)(c1ccccc1)c1ccc2c(c1)C(c1ccccc1)(c1ccccc1)c1cc(-c3ccc(-c4cc(-c5cccnc5)nc(-c5cccnc5)c4)cc3)ccc1-2]

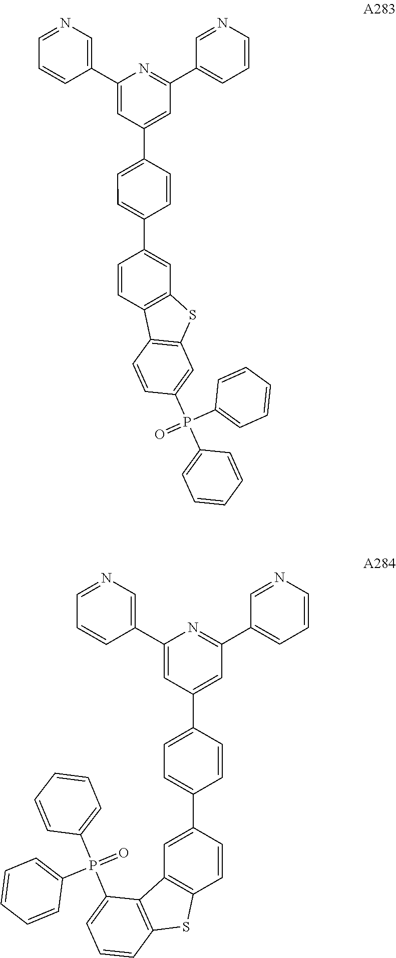 [SMILES: O=P(c1ccccc1)(c1ccccc1)c1ccc2c(c1)sc1cc(-c3ccc(-c4cc(-c5cccnc5)nc(-c5cccnc5)c4)cc3)ccc12 ; O=P(c1ccccc1)(c1ccccc1)c1cccc2sc3ccc(-c4ccc(-c5cc(-c6cccnc6)nc(-c6cccnc6)c5)cc4)cc3c12]

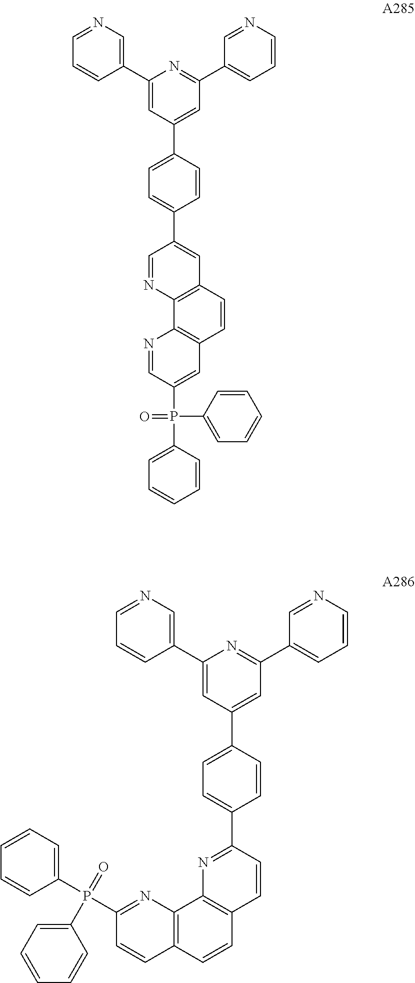 [SMILES: O=P(c1ccccc1)(c1ccccc1)c1cnc2c(ccc3cc(-c4ccc(-c5cc(-c6cccnc6)nc(-c6cccnc6)c5)cc4)cnc32)c1 ; O=P(c1ccccc1)(c1ccccc1)c1ccc2ccc3ccc(-c4ccc(-c5cc(-c6cccnc6)nc(-c6cccnc6)c5)cc4)nc3c2n1]

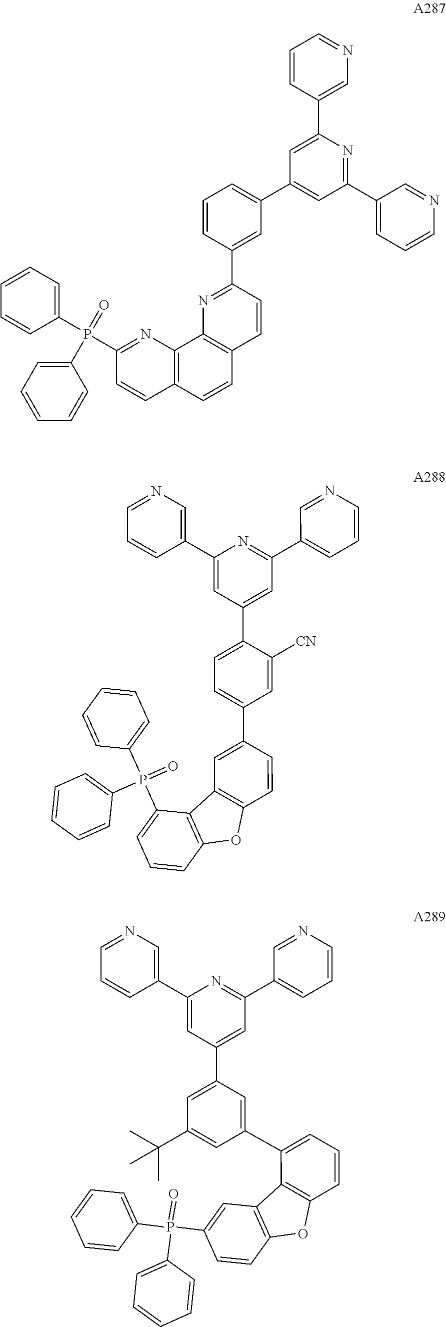 [SMILES: O=P(c1ccccc1)(c1ccccc1)c1ccc2ccc3ccc(-c4cccc(-c5cc(-c6cccnc6)nc(-c6cccnc6)c5)c4)nc3c2n1 ; N#Cc1cc(-c2ccc3oc4cccc(P(=O)(c5ccccc5)c5ccccc5)c4c3c2)ccc1-c1cc(-c2cccnc2)nc(-c2cccnc2)c1 ; CC(C)(C)c1cc(-c2cc(-c3cccnc3)nc(-c3cccnc3)c2)cc(-c2cccc3oc4ccc(P(=O)(c5ccccc5)c5ccccc5)cc4c23)c1]

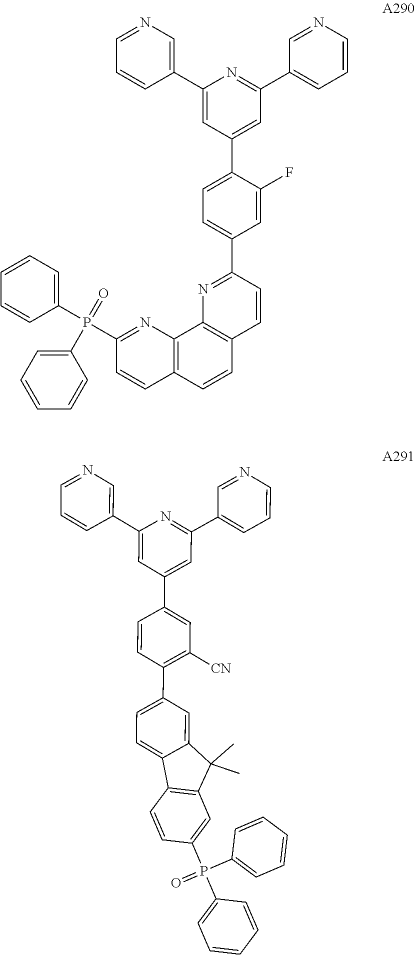 [SMILES: O=P(c1ccccc1)(c1ccccc1)c1ccc2ccc3ccc(-c4ccc(-c5cc(-c6cccnc6)nc(-c6cccnc6)c5)c(F)c4)nc3c2n1 ; CC1(C)c2cc(-c3ccc(-c4cc(-c5cccnc5)nc(-c5cccnc5)c4)cc3C#N)ccc2-c2ccc(P(=O)(c3ccccc3)c3ccccc3)cc21]

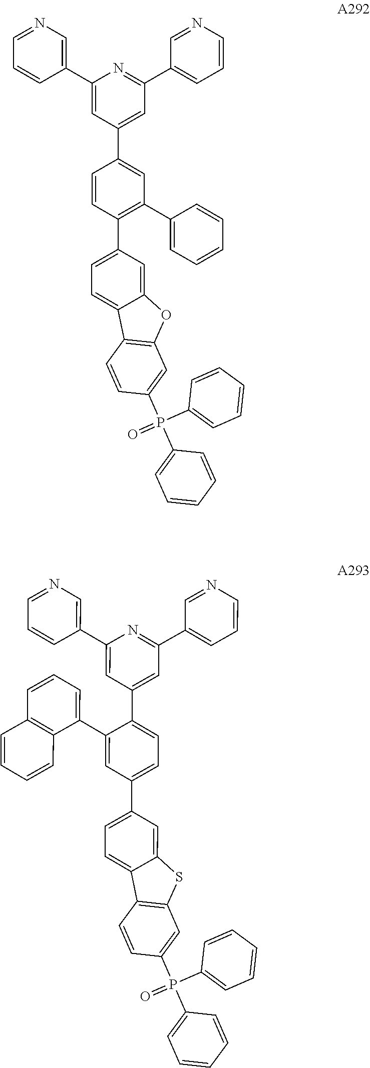 [SMILES: O=P(c1ccccc1)(c1ccccc1)c1ccc2c(c1)oc1cc(-c3ccc(-c4cc(-c5cccnc5)nc(-c5cccnc5)c4)cc3-c3ccccc3)ccc12 ; O=P(c1ccccc1)(c1ccccc1)c1ccc2c(c1)sc1cc(-c3ccc(-c4cc(-c5cccnc5)nc(-c5cccnc5)c4)c(-c4cccc5ccccc45)c3)ccc12]

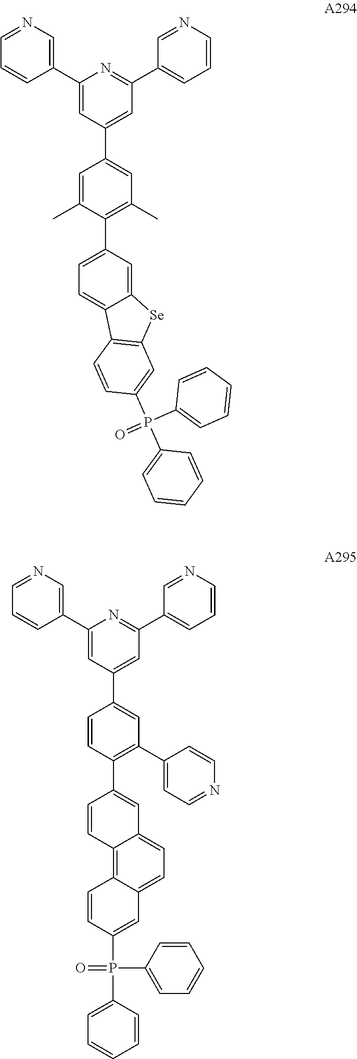 [SMILES: Cc1cc(-c2cc(-c3cccnc3)nc(-c3cccnc3)c2)cc(C)c1-c1ccc2c(c1)[se]c1cc(P(=O)(c3ccccc3)c3ccccc3)ccc12 ; O=P(c1ccccc1)(c1ccccc1)c1ccc2c(ccc3cc(-c4ccc(-c5cc(-c6cccnc6)nc(-c6cccnc6)c5)cc4-c4ccncc4)ccc32)c1]

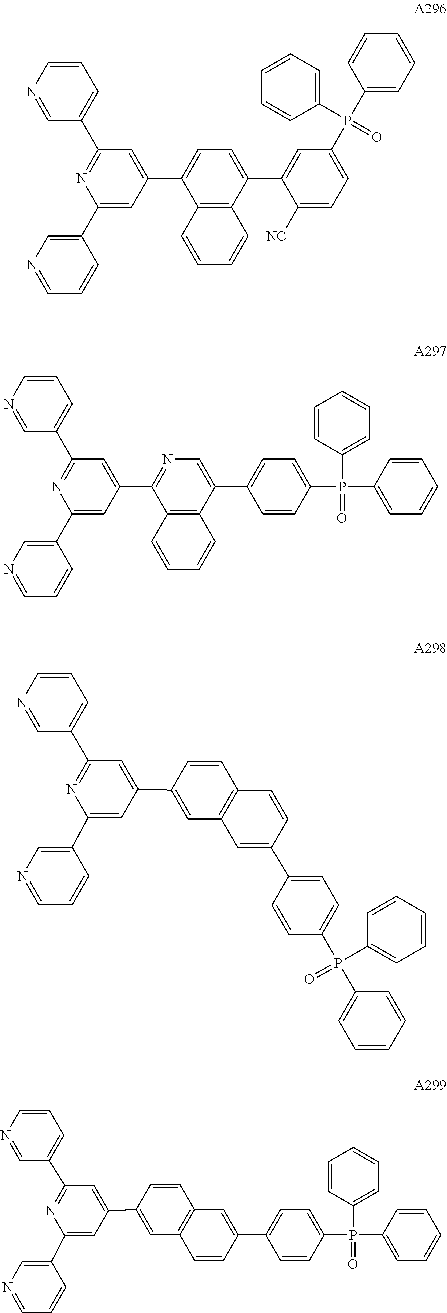 [SMILES: N#Cc1ccc(P(=O)(c2ccccc2)c2ccccc2)cc1-c1ccc(-c2cc(-c3cccnc3)nc(-c3cccnc3)c2)c2ccccc12 ; O=P(c1ccccc1)(c1ccccc1)c1ccc(-c2cnc(-c3cc(-c4cccnc4)nc(-c4cccnc4)c3)c3ccccc23)cc1 ; O=P(c1ccccc1)(c1ccccc1)c1ccc(-c2ccc3ccc(-c4cc(-c5cccnc5)nc(-c5cccnc5)c4)cc3c2)cc1 ; O=P(c1ccccc1)(c1ccccc1)c1ccc(-c2ccc3cc(-c4cc(-c5cccnc5)nc(-c5cccnc5)c4)ccc3c2)cc1]

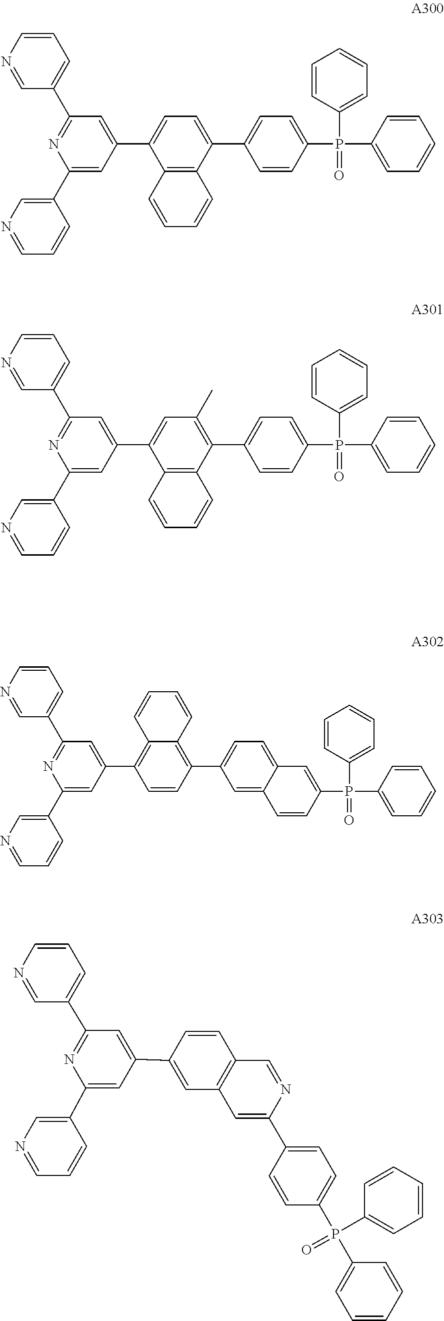 [SMILES: O=P(c1ccccc1)(c1ccccc1)c1ccc(-c2ccc(-c3cc(-c4cccnc4)nc(-c4cccnc4)c3)c3ccccc23)cc1 ; Cc1cc(-c2cc(-c3cccnc3)nc(-c3cccnc3)c2)c2ccccc2c1-c1ccc(P(=O)(c2ccccc2)c2ccccc2)cc1 ; O=P(c1ccccc1)(c1ccccc1)c1ccc2cc(-c3ccc(-c4cc(-c5cccnc5)nc(-c5cccnc5)c4)c4ccccc34)ccc2c1 ; O=P(c1ccccc1)(c1ccccc1)c1ccc(-c2cc3cc(-c4cc(-c5cccnc5)nc(-c5cccnc5)c4)ccc3cn2)cc1]

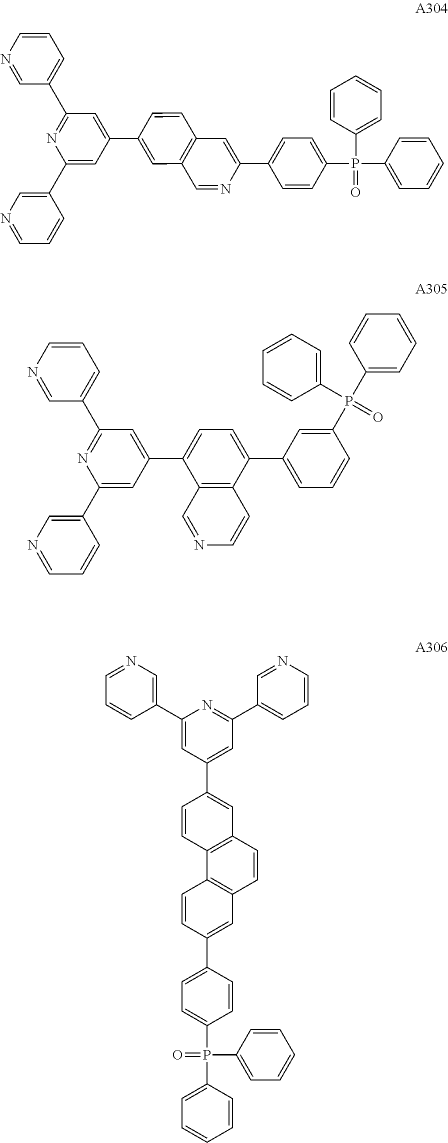 [SMILES: O=P(c1ccccc1)(c1ccccc1)c1ccc(-c2cc3ccc(-c4cc(-c5cccnc5)nc(-c5cccnc5)c4)cc3cn2)cc1 ; O=P(c1ccccc1)(c1ccccc1)c1cccc(-c2ccc(-c3cc(-c4cccnc4)nc(-c4cccnc4)c3)c3cnccc23)c1 ; O=P(c1ccccc1)(c1ccccc1)c1ccc(-c2ccc3c(ccc4cc(-c5cc(-c6cccnc6)nc(-c6cccnc6)c5)ccc43)c2)cc1]

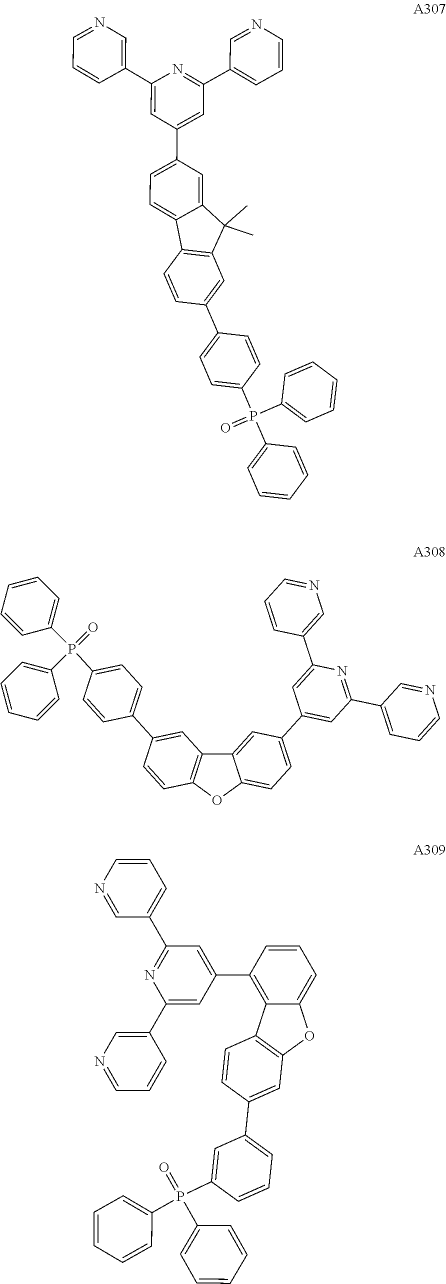 [SMILES: CC1(C)c2cc(-c3ccc(P(=O)(c4ccccc4)c4ccccc4)cc3)ccc2-c2ccc(-c3cc(-c4cccnc4)nc(-c4cccnc4)c3)cc21 ; O=P(c1ccccc1)(c1ccccc1)c1ccc(-c2ccc3oc4ccc(-c5cc(-c6cccnc6)nc(-c6cccnc6)c5)cc4c3c2)cc1 ; O=P(c1ccccc1)(c1ccccc1)c1cccc(-c2ccc3c(c2)oc2cccc(-c4cc(-c5cccnc5)nc(-c5cccnc5)c4)c23)c1]

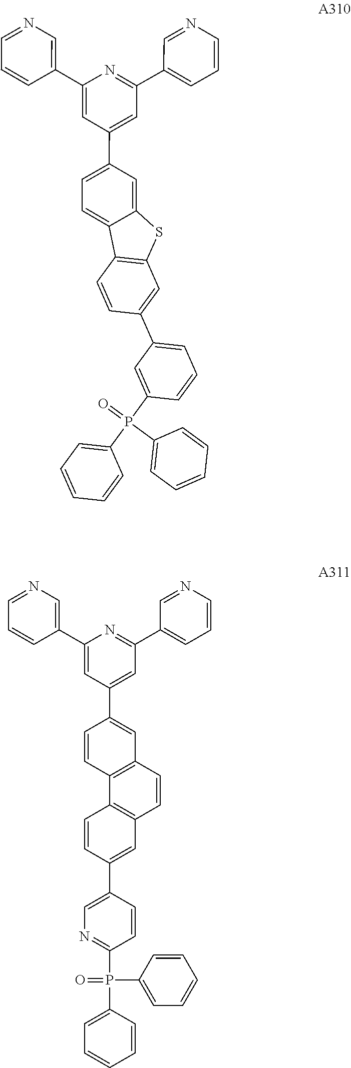 [SMILES: O=P(c1ccccc1)(c1ccccc1)c1cccc(-c2ccc3c(c2)sc2cc(-c4cc(-c5cccnc5)nc(-c5cccnc5)c4)ccc23)c1 ; O=P(c1ccccc1)(c1ccccc1)c1ccc(-c2ccc3c(ccc4cc(-c5cc(-c6cccnc6)nc(-c6cccnc6)c5)ccc43)c2)cn1]

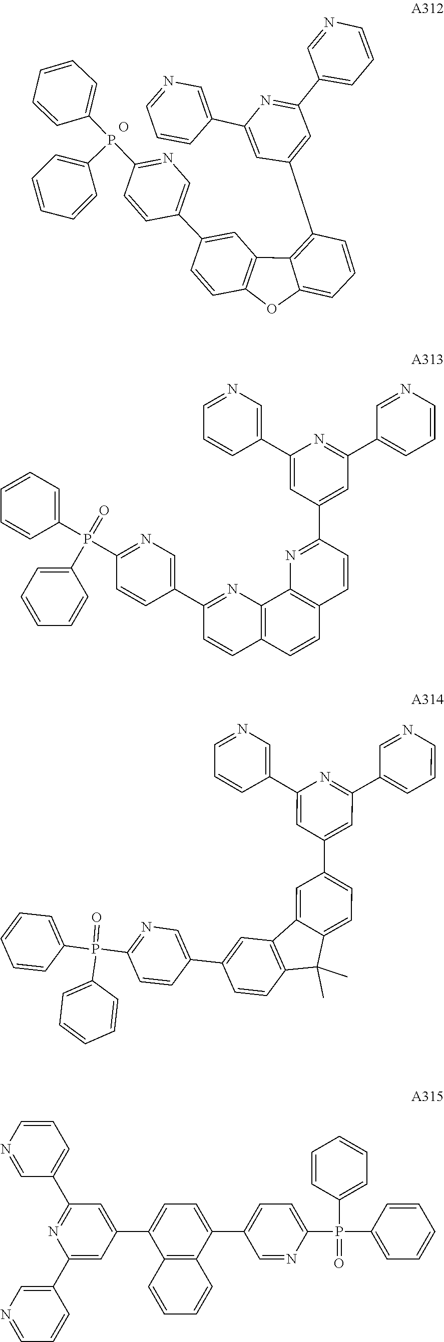

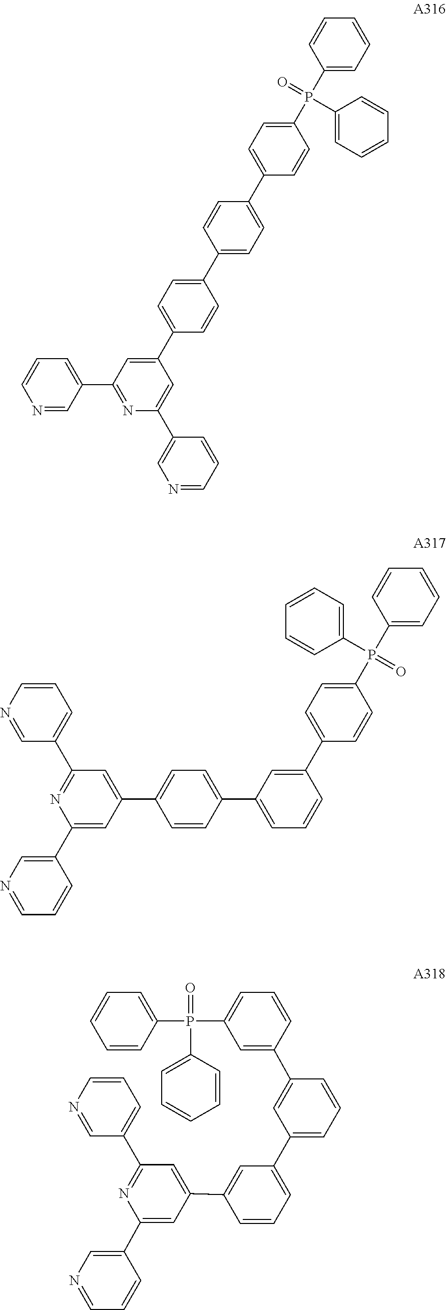 [SMILES: O=P(c1ccccc1)(c1ccccc1)c1ccc(-c2ccc(-c3ccc(-c4cc(-c5cccnc5)nc(-c5cccnc5)c4)cc3)cc2)cc1 ; O=P(c1ccccc1)(c1ccccc1)c1ccc(-c2cccc(-c3ccc(-c4cc(-c5cccnc5)nc(-c5cccnc5)c4)cc3)c2)cc1 ; O=P(c1ccccc1)(c1ccccc1)c1cccc(-c2cccc(-c3cccc(-c4cc(-c5cccnc5)nc(-c5cccnc5)c4)c3)c2)c1]

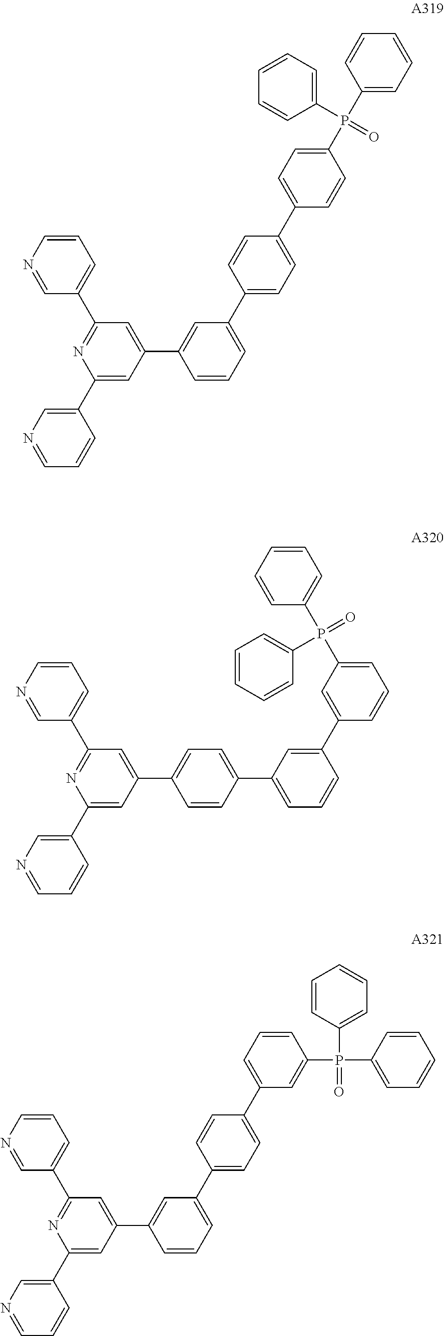 [SMILES: O=P(c1ccccc1)(c1ccccc1)c1ccc(-c2ccc(-c3cccc(-c4cc(-c5cccnc5)nc(-c5cccnc5)c4)c3)cc2)cc1 ; O=P(c1ccccc1)(c1ccccc1)c1cccc(-c2cccc(-c3ccc(-c4cc(-c5cccnc5)nc(-c5cccnc5)c4)cc3)c2)c1 ; O=P(c1ccccc1)(c1ccccc1)c1cccc(-c2ccc(-c3cccc(-c4cc(-c5cccnc5)nc(-c5cccnc5)c4)c3)cc2)c1]

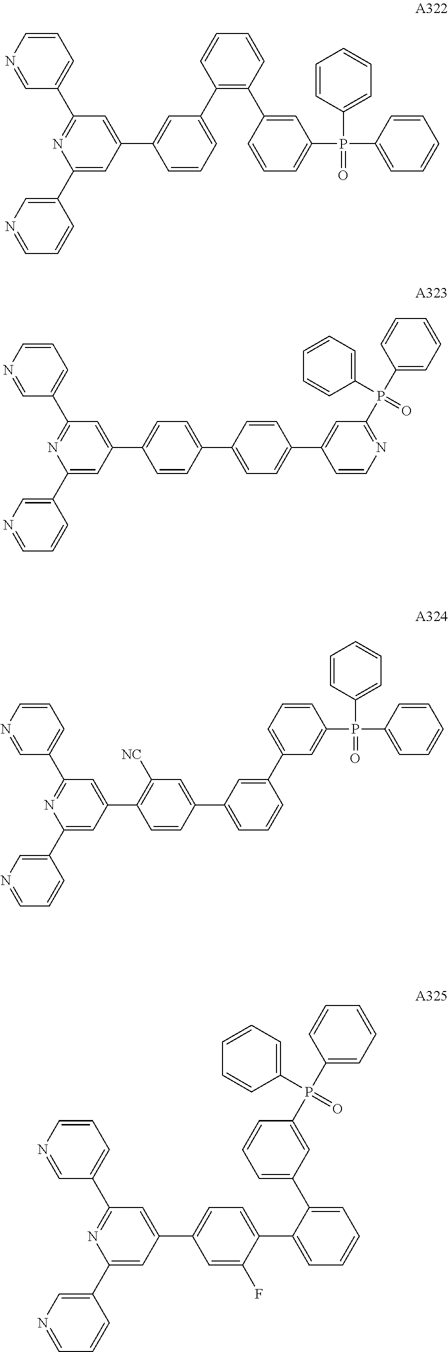 [SMILES: O=P(c1ccccc1)(c1ccccc1)c1cccc(-c2ccccc2-c2cccc(-c3cc(-c4cccnc4)nc(-c4cccnc4)c3)c2)c1 ; O=P(c1ccccc1)(c1ccccc1)c1cc(-c2ccc(-c3ccc(-c4cc(-c5cccnc5)nc(-c5cccnc5)c4)cc3)cc2)ccn1 ; N#Cc1cc(-c2cccc(-c3cccc(P(=O)(c4ccccc4)c4ccccc4)c3)c2)ccc1-c1cc(-c2cccnc2)nc(-c2cccnc2)c1 ; O=P(c1ccccc1)(c1ccccc1)c1cccc(-c2ccccc2-c2ccc(-c3cc(-c4cccnc4)nc(-c4cccnc4)c3)cc2F)c1]

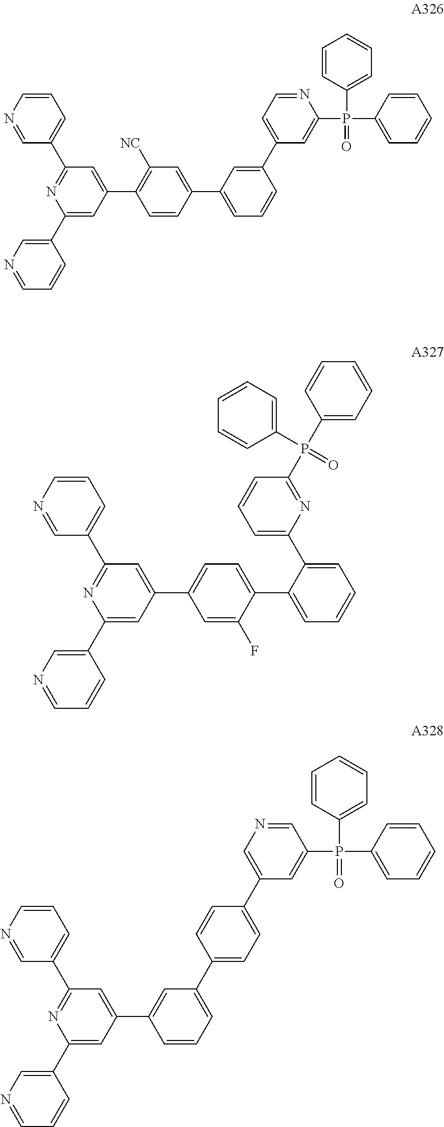 [SMILES: N#Cc1cc(-c2cccc(-c3ccnc(P(=O)(c4ccccc4)c4ccccc4)c3)c2)ccc1-c1cc(-c2cccnc2)nc(-c2cccnc2)c1 ; O=P(c1ccccc1)(c1ccccc1)c1cccc(-c2ccccc2-c2ccc(-c3cc(-c4cccnc4)nc(-c4cccnc4)c3)cc2F)n1 ; O=P(c1ccccc1)(c1ccccc1)c1cncc(-c2ccc(-c3cccc(-c4cc(-c5cccnc5)nc(-c5cccnc5)c4)c3)cc2)c1]

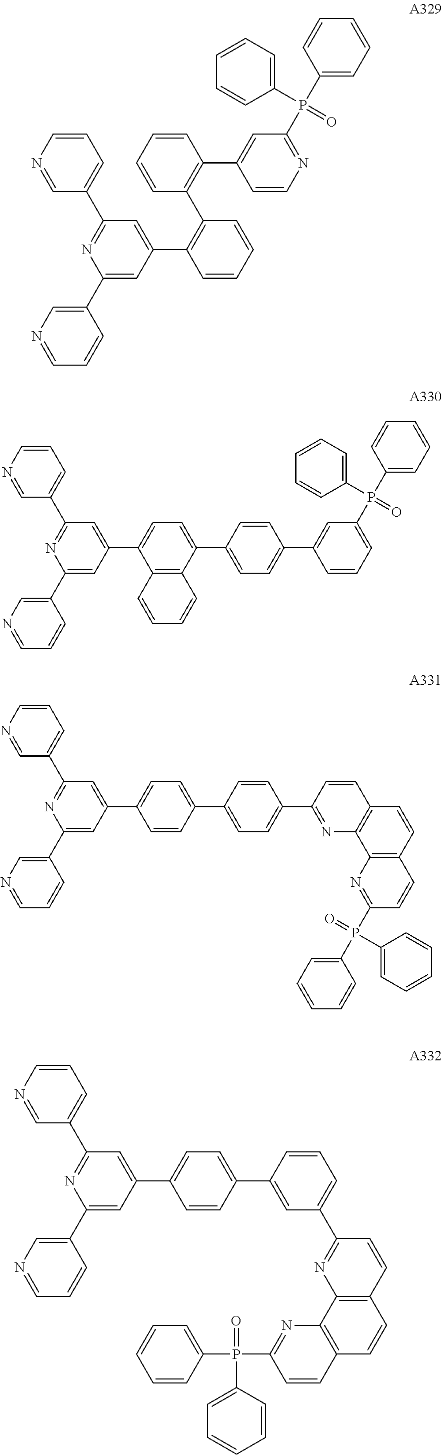 [SMILES: O=P(c1ccccc1)(c1ccccc1)c1cc(-c2ccccc2-c2ccccc2-c2cc(-c3cccnc3)nc(-c3cccnc3)c2)ccn1 ; O=P(c1ccccc1)(c1ccccc1)c1cccc(-c2ccc(-c3ccc(-c4cc(-c5cccnc5)nc(-c5cccnc5)c4)c4ccccc34)cc2)c1 ; O=P(c1ccccc1)(c1ccccc1)c1ccc2ccc3ccc(-c4ccc(-c5ccc(-c6cc(-c7cccnc7)nc(-c7cccnc7)c6)cc5)cc4)nc3c2n1 ; O=P(c1ccccc1)(c1ccccc1)c1ccc2ccc3ccc(-c4cccc(-c5ccc(-c6cc(-c7cccnc7)nc(-c7cccnc7)c6)cc5)c4)nc3c2n1]

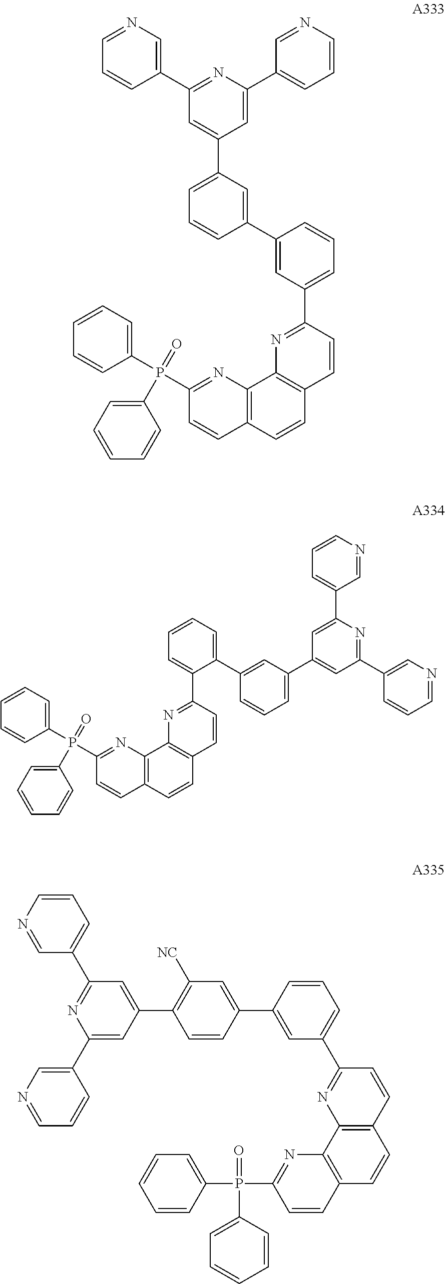 [SMILES: O=P(c1ccccc1)(c1ccccc1)c1ccc2ccc3ccc(-c4cccc(-c5cccc(-c6cc(-c7cccnc7)nc(-c7cccnc7)c6)c5)c4)nc3c2n1 ; O=P(c1ccccc1)(c1ccccc1)c1ccc2ccc3ccc(-c4ccccc4-c4cccc(-c5cc(-c6cccnc6)nc(-c6cccnc6)c5)c4)nc3c2n1 ; N#Cc1cc(-c2cccc(-c3ccc4ccc5ccc(P(=O)(c6ccccc6)c6ccccc6)nc5c4n3)c2)ccc1-c1cc(-c2cccnc2)nc(-c2cccnc2)c1]

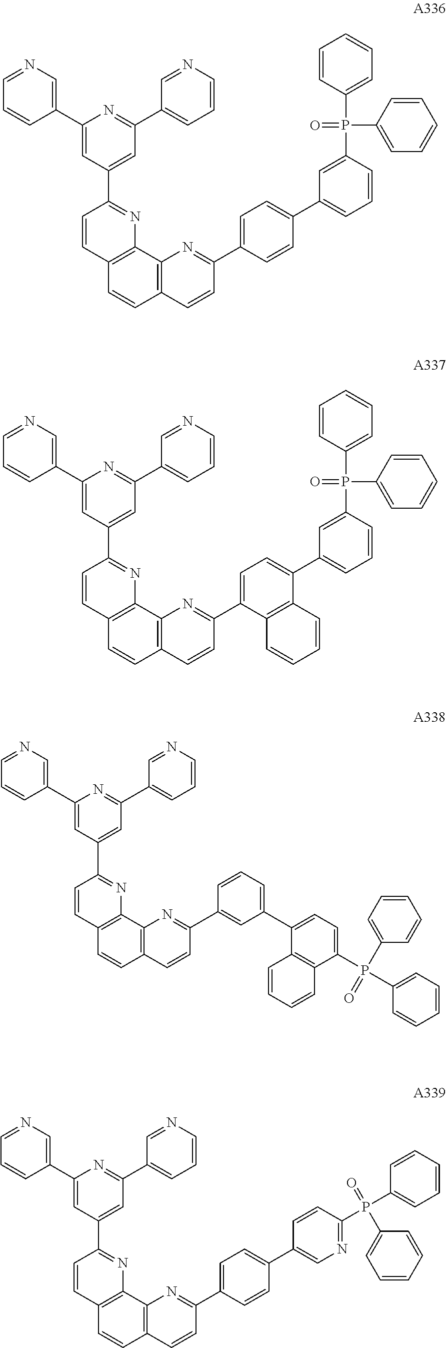 [SMILES: O=P(c1ccccc1)(c1ccccc1)c1cccc(-c2ccc(-c3ccc4ccc5ccc(-c6cc(-c7cccnc7)nc(-c7cccnc7)c6)nc5c4n3)cc2)c1 ; O=P(c1ccccc1)(c1ccccc1)c1cccc(-c2ccc(-c3ccc4ccc5ccc(-c6cc(-c7cccnc7)nc(-c7cccnc7)c6)nc5c4n3)c3ccccc23)c1 ; O=P(c1ccccc1)(c1ccccc1)c1ccc(-c2cccc(-c3ccc4ccc5ccc(-c6cc(-c7cccnc7)nc(-c7cccnc7)c6)nc5c4n3)c2)c2ccccc12 ; O=P(c1ccccc1)(c1ccccc1)c1ccc(-c2ccc(-c3ccc4ccc5ccc(-c6cc(-c7cccnc7)nc(-c7cccnc7)c6)nc5c4n3)cc2)cn1]

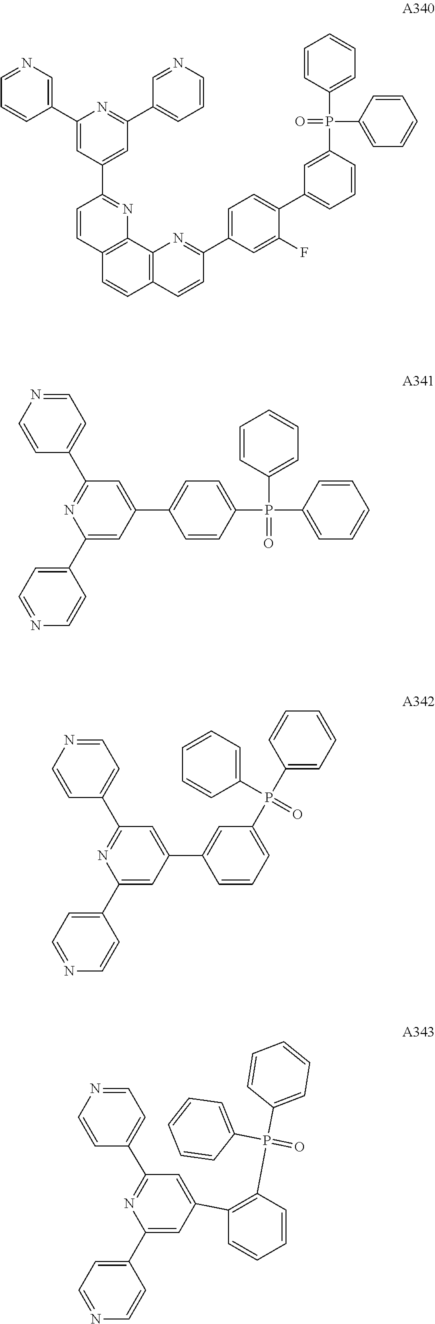 [SMILES: O=P(c1ccccc1)(c1ccccc1)c1cccc(-c2ccc(-c3ccc4ccc5ccc(-c6cc(-c7cccnc7)nc(-c7cccnc7)c6)nc5c4n3)cc2F)c1 ; O=P(c1ccccc1)(c1ccccc1)c1ccc(-c2cc(-c3ccncc3)nc(-c3ccncc3)c2)cc1 ; O=P(c1ccccc1)(c1ccccc1)c1cccc(-c2cc(-c3ccncc3)nc(-c3ccncc3)c2)c1 ; O=P(c1ccccc1)(c1ccccc1)c1ccccc1-c1cc(-c2ccncc2)nc(-c2ccncc2)c1]

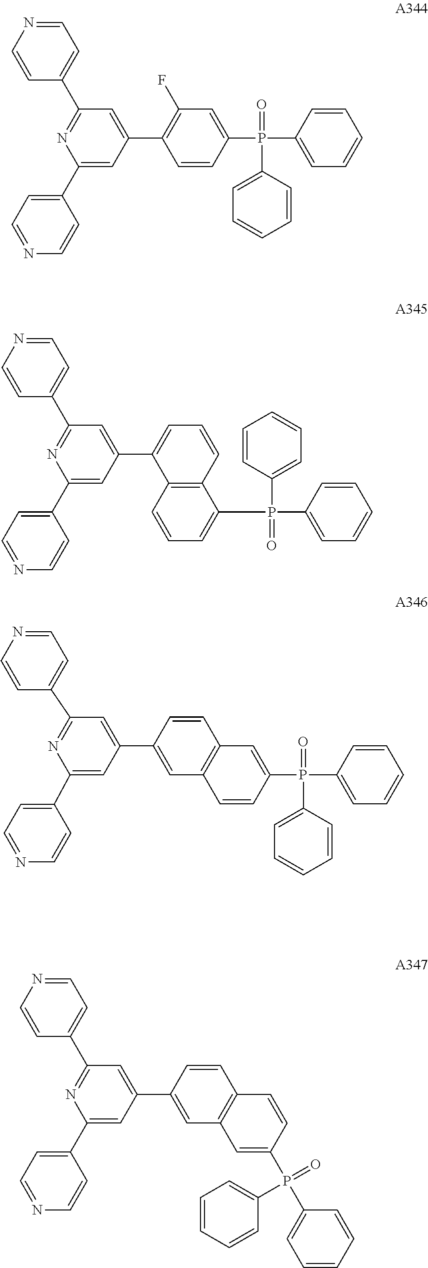 [SMILES: O=P(c1ccccc1)(c1ccccc1)c1ccc(-c2cc(-c3ccncc3)nc(-c3ccncc3)c2)c(F)c1 ; O=P(c1ccccc1)(c1ccccc1)c1cccc2c(-c3cc(-c4ccncc4)nc(-c4ccncc4)c3)cccc12 ; O=P(c1ccccc1)(c1ccccc1)c1ccc2cc(-c3cc(-c4ccncc4)nc(-c4ccncc4)c3)ccc2c1 ; O=P(c1ccccc1)(c1ccccc1)c1ccc2ccc(-c3cc(-c4ccncc4)nc(-c4ccncc4)c3)cc2c1]

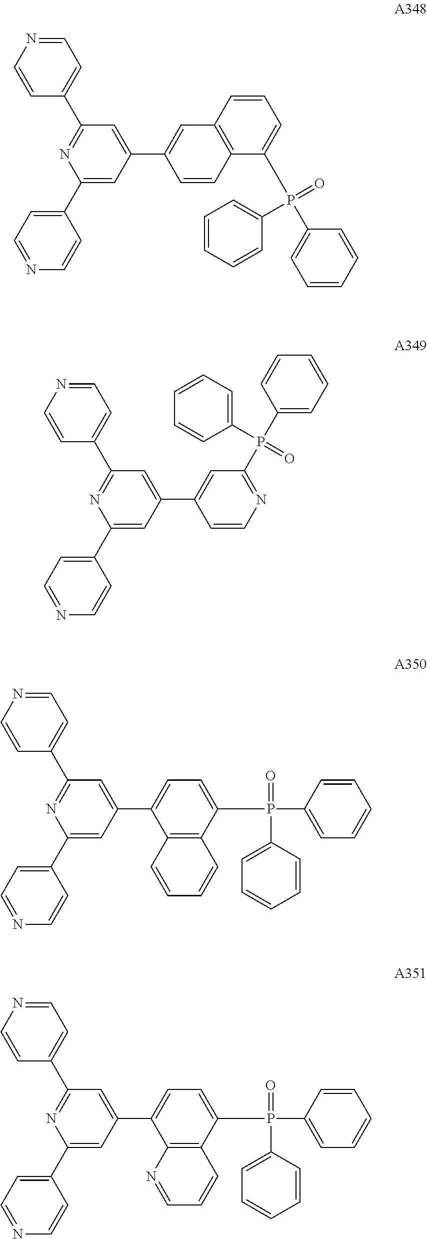 [SMILES: O=P(c1ccccc1)(c1ccccc1)c1cccc2cc(-c3cc(-c4ccncc4)nc(-c4ccncc4)c3)ccc12 ; O=P(c1ccccc1)(c1ccccc1)c1cc(-c2cc(-c3ccncc3)nc(-c3ccncc3)c2)ccn1 ; O=P(c1ccccc1)(c1ccccc1)c1ccc(-c2cc(-c3ccncc3)nc(-c3ccncc3)c2)c2ccccc12 ; O=P(c1ccccc1)(c1ccccc1)c1ccc(-c2cc(-c3ccncc3)nc(-c3ccncc3)c2)c2ncccc12]

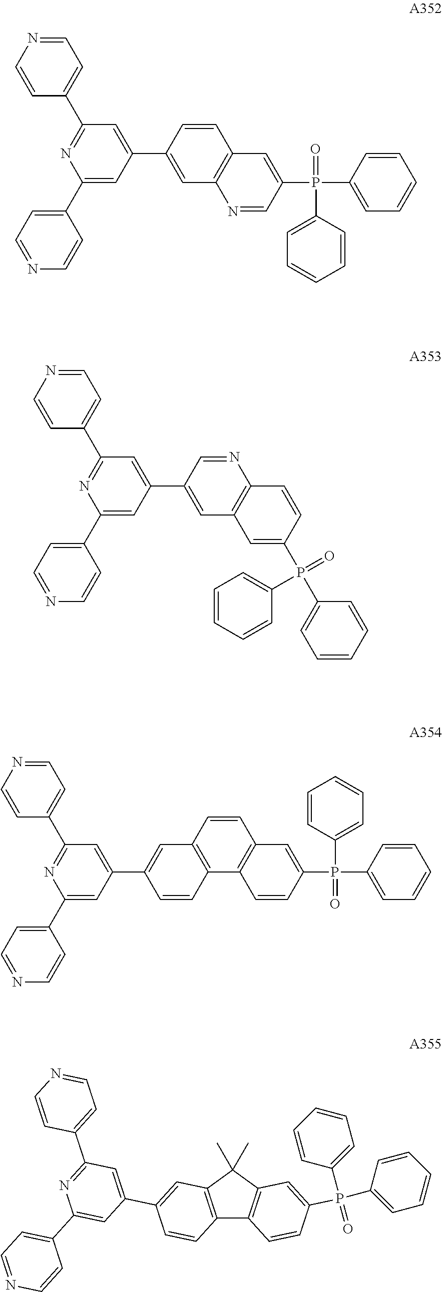 [SMILES: O=P(c1ccccc1)(c1ccccc1)c1cnc2cc(-c3cc(-c4ccncc4)nc(-c4ccncc4)c3)ccc2c1 ; O=P(c1ccccc1)(c1ccccc1)c1ccc2ncc(-c3cc(-c4ccncc4)nc(-c4ccncc4)c3)cc2c1 ; O=P(c1ccccc1)(c1ccccc1)c1ccc2c(ccc3cc(-c4cc(-c5ccncc5)nc(-c5ccncc5)c4)ccc32)c1 ; CC1(C)c2cc(-c3cc(-c4ccncc4)nc(-c4ccncc4)c3)ccc2-c2ccc(P(=O)(c3ccccc3)c3ccccc3)cc21]

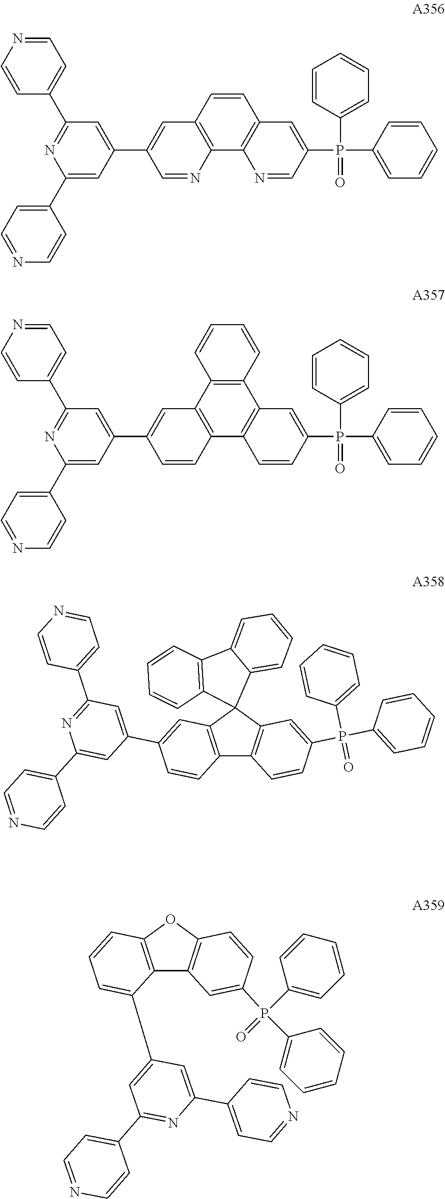 [SMILES: O=P(c1ccccc1)(c1ccccc1)c1cnc2c(ccc3cc(-c4cc(-c5ccncc5)nc(-c5ccncc5)c4)cnc32)c1 ; O=P(c1ccccc1)(c1ccccc1)c1ccc2c3ccc(-c4cc(-c5ccncc5)nc(-c5ccncc5)c4)cc3c3ccccc3c2c1 ; O=P(c1ccccc1)(c1ccccc1)c1ccc2c(c1)C1(c3ccccc3-c3ccccc31)c1cc(-c3cc(-c4ccncc4)nc(-c4ccncc4)c3)ccc1-2 ; O=P(c1ccccc1)(c1ccccc1)c1ccc2oc3cccc(-c4cc(-c5ccncc5)nc(-c5ccncc5)c4)c3c2c1]

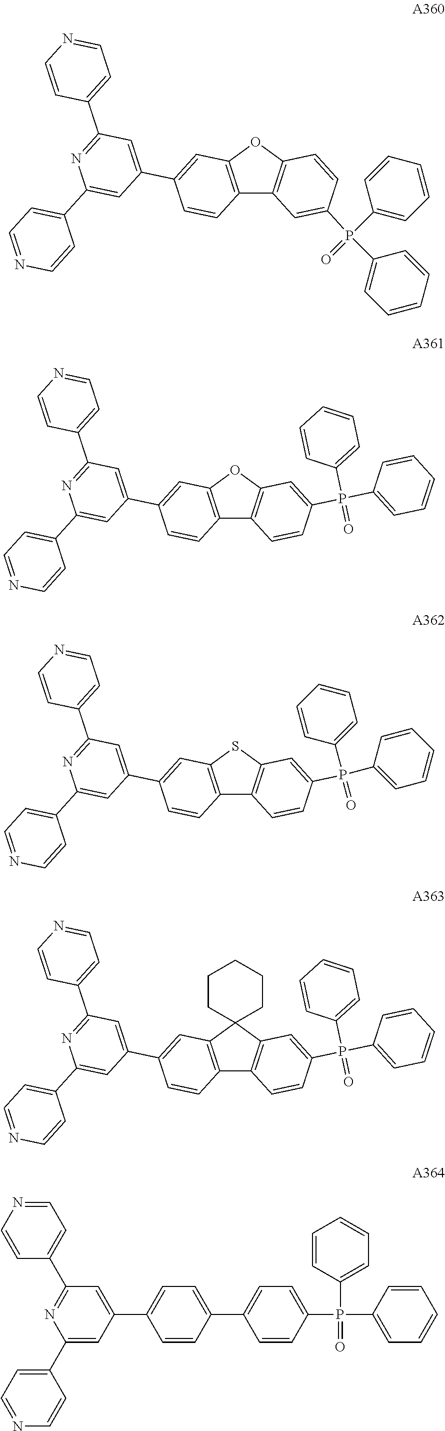 [SMILES: O=P(c1ccccc1)(c1ccccc1)c1ccc2oc3cc(-c4cc(-c5ccncc5)nc(-c5ccncc5)c4)ccc3c2c1 ; O=P(c1ccccc1)(c1ccccc1)c1ccc2c(c1)oc1cc(-c3cc(-c4ccncc4)nc(-c4ccncc4)c3)ccc12 ; O=P(c1ccccc1)(c1ccccc1)c1ccc2c(c1)sc1cc(-c3cc(-c4ccncc4)nc(-c4ccncc4)c3)ccc12 ; O=P(c1ccccc1)(c1ccccc1)c1ccc2c(c1)C1(CCCCC1)c1cc(-c3cc(-c4ccncc4)nc(-c4ccncc4)c3)ccc1-2 ; O=P(c1ccccc1)(c1ccccc1)c1ccc(-c2ccc(-c3cc(-c4ccncc4)nc(-c4ccncc4)c3)cc2)cc1]

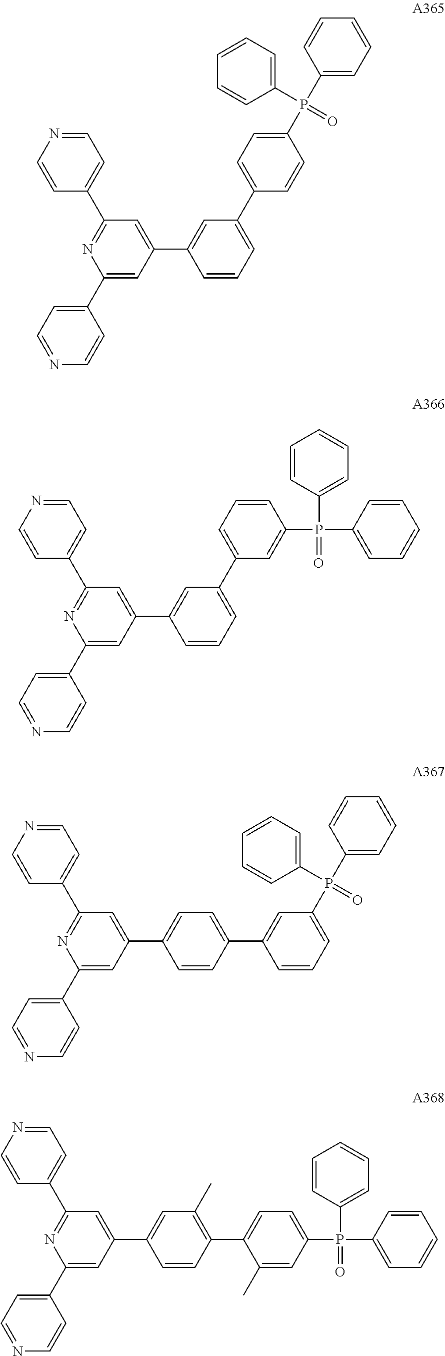 [SMILES: O=P(c1ccccc1)(c1ccccc1)c1ccc(-c2cccc(-c3cc(-c4ccncc4)nc(-c4ccncc4)c3)c2)cc1 ; O=P(c1ccccc1)(c1ccccc1)c1cccc(-c2cccc(-c3cc(-c4ccncc4)nc(-c4ccncc4)c3)c2)c1 ; O=P(c1ccccc1)(c1ccccc1)c1cccc(-c2ccc(-c3cc(-c4ccncc4)nc(-c4ccncc4)c3)cc2)c1 ; Cc1cc(-c2cc(-c3ccncc3)nc(-c3ccncc3)c2)ccc1-c1ccc(P(=O)(c2ccccc2)c2ccccc2)cc1C]

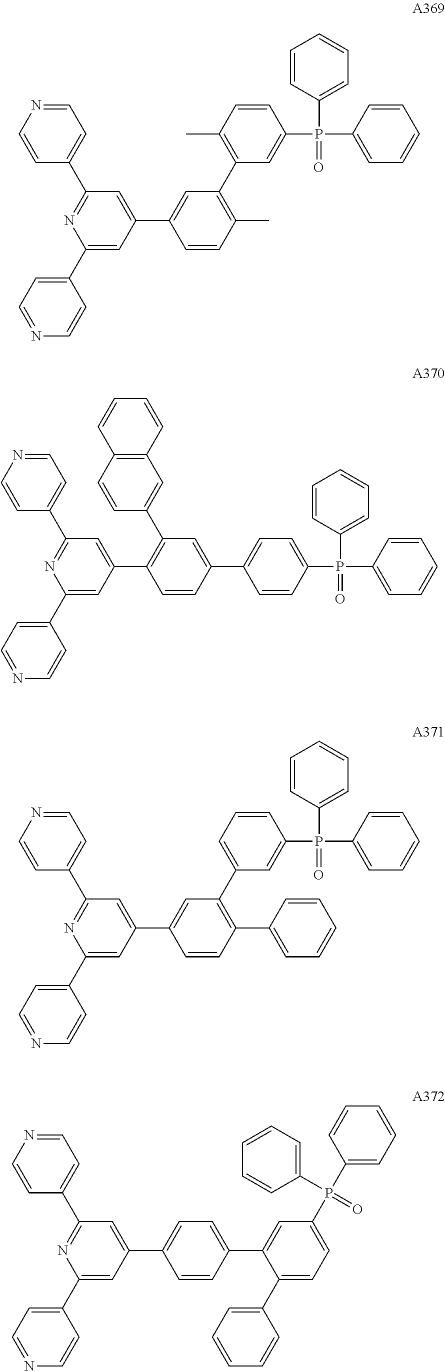 [SMILES: Cc1ccc(-c2cc(-c3ccncc3)nc(-c3ccncc3)c2)cc1-c1cc(P(=O)(c2ccccc2)c2ccccc2)ccc1C ; O=P(c1ccccc1)(c1ccccc1)c1ccc(-c2ccc(-c3cc(-c4ccncc4)nc(-c4ccncc4)c3)c(-c3ccc4ccccc4c3)c2)cc1 ; O=P(c1ccccc1)(c1ccccc1)c1cccc(-c2cc(-c3cc(-c4ccncc4)nc(-c4ccncc4)c3)ccc2-c2ccccc2)c1 ; O=P(c1ccccc1)(c1ccccc1)c1ccc(-c2ccccc2)c(-c2ccc(-c3cc(-c4ccncc4)nc(-c4ccncc4)c3)cc2)c1]

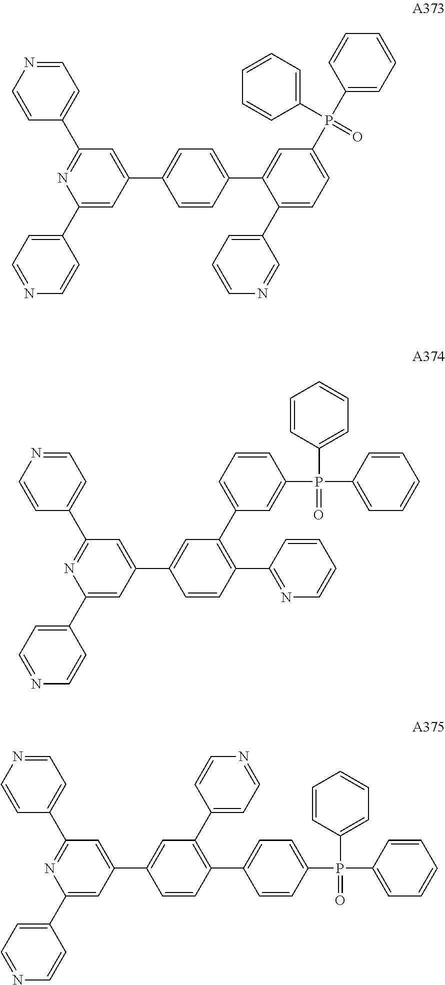 [SMILES: O=P(c1ccccc1)(c1ccccc1)c1ccc(-c2cccnc2)c(-c2ccc(-c3cc(-c4ccncc4)nc(-c4ccncc4)c3)cc2)c1 ; O=P(c1ccccc1)(c1ccccc1)c1cccc(-c2cc(-c3cc(-c4ccncc4)nc(-c4ccncc4)c3)ccc2-c2ccccn2)c1 ; O=P(c1ccccc1)(c1ccccc1)c1ccc(-c2ccc(-c3cc(-c4ccncc4)nc(-c4ccncc4)c3)cc2-c2ccncc2)cc1]

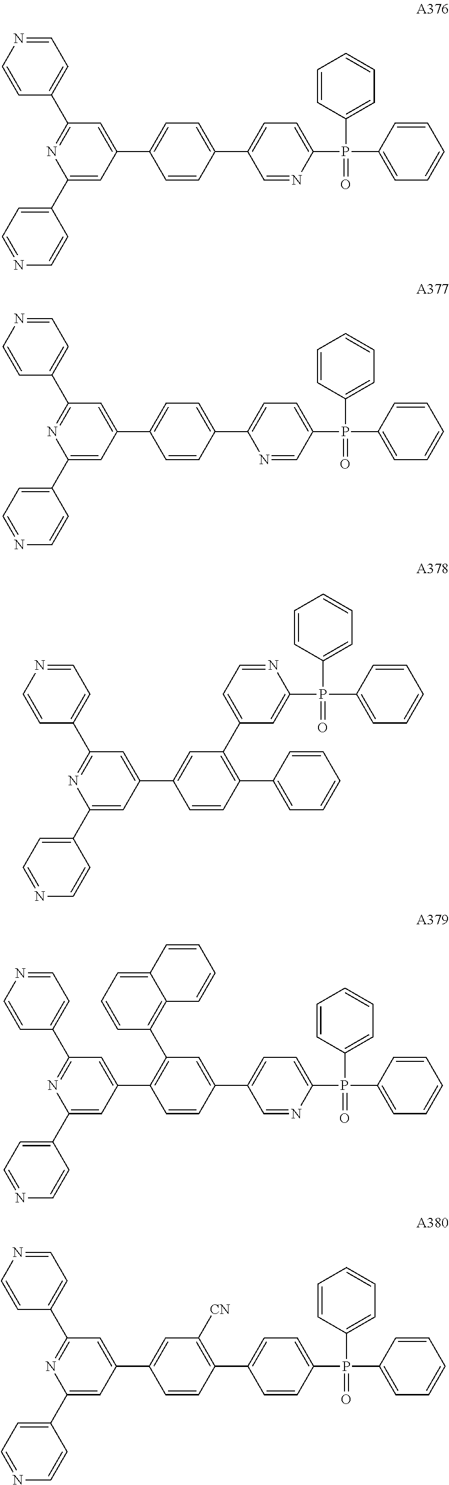 [SMILES: O=P(c1ccccc1)(c1ccccc1)c1ccc(-c2ccc(-c3cc(-c4ccncc4)nc(-c4ccncc4)c3)cc2)cn1 ; O=P(c1ccccc1)(c1ccccc1)c1ccc(-c2ccc(-c3cc(-c4ccncc4)nc(-c4ccncc4)c3)cc2)nc1 ; O=P(c1ccccc1)(c1ccccc1)c1cc(-c2cc(-c3cc(-c4ccncc4)nc(-c4ccncc4)c3)ccc2-c2ccccc2)ccn1 ; O=P(c1ccccc1)(c1ccccc1)c1ccc(-c2ccc(-c3cc(-c4ccncc4)nc(-c4ccncc4)c3)c(-c3cccc4ccccc34)c2)cn1 ; N#Cc1cc(-c2cc(-c3ccncc3)nc(-c3ccncc3)c2)ccc1-c1ccc(P(=O)(c2ccccc2)c2ccccc2)cc1]

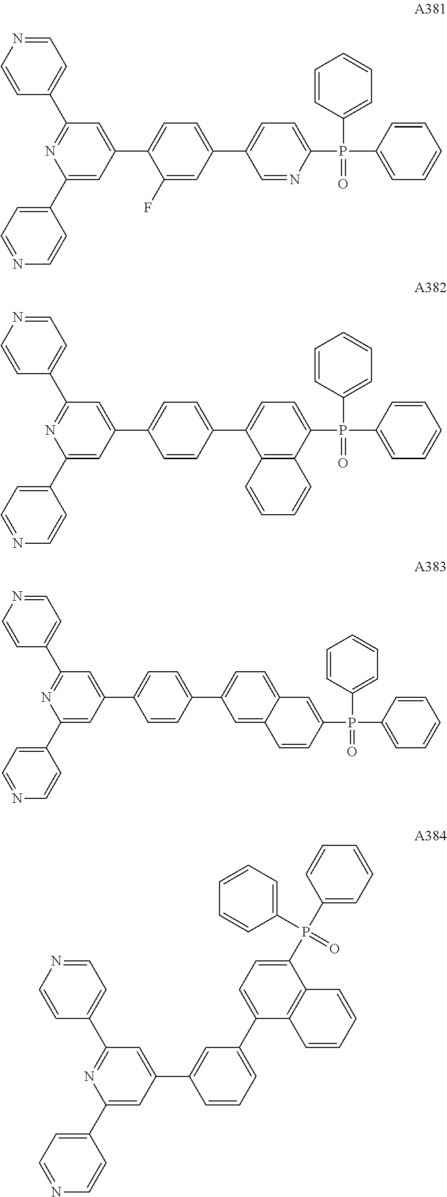 [SMILES: O=P(c1ccccc1)(c1ccccc1)c1ccc(-c2ccc(-c3cc(-c4ccncc4)nc(-c4ccncc4)c3)c(F)c2)cn1 ; O=P(c1ccccc1)(c1ccccc1)c1ccc(-c2ccc(-c3cc(-c4ccncc4)nc(-c4ccncc4)c3)cc2)c2ccccc12 ; O=P(c1ccccc1)(c1ccccc1)c1ccc2cc(-c3ccc(-c4cc(-c5ccncc5)nc(-c5ccncc5)c4)cc3)ccc2c1 ; O=P(c1ccccc1)(c1ccccc1)c1ccc(-c2cccc(-c3cc(-c4ccncc4)nc(-c4ccncc4)c3)c2)c2ccccc12]

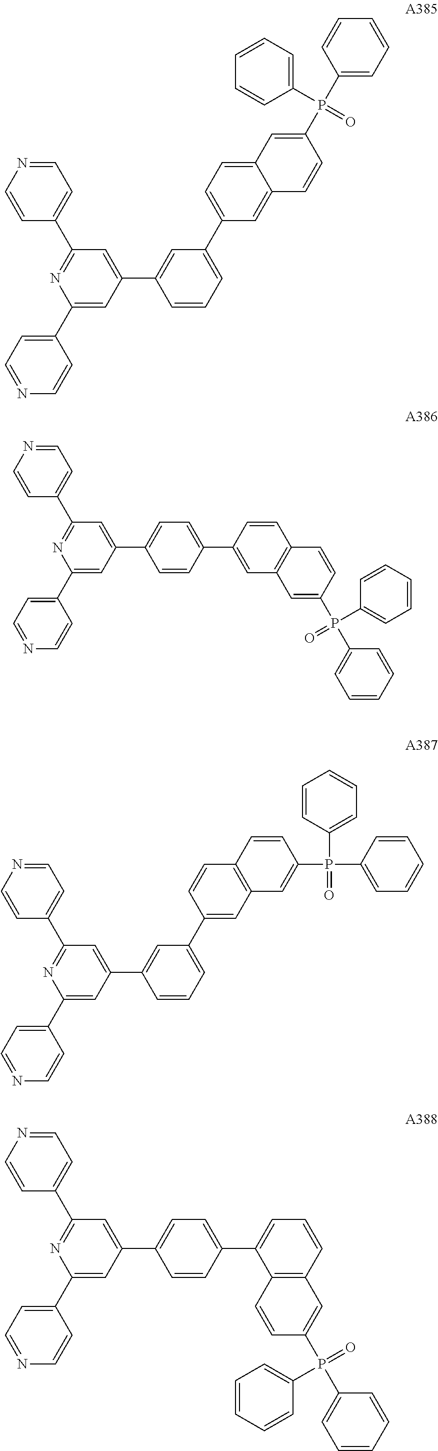 [SMILES: O=P(c1ccccc1)(c1ccccc1)c1ccc2cc(-c3cccc(-c4cc(-c5ccncc5)nc(-c5ccncc5)c4)c3)ccc2c1 ; O=P(c1ccccc1)(c1ccccc1)c1ccc2ccc(-c3ccc(-c4cc(-c5ccncc5)nc(-c5ccncc5)c4)cc3)cc2c1 ; O=P(c1ccccc1)(c1ccccc1)c1ccc2ccc(-c3cccc(-c4cc(-c5ccncc5)nc(-c5ccncc5)c4)c3)cc2c1 ; O=P(c1ccccc1)(c1ccccc1)c1ccc2c(-c3ccc(-c4cc(-c5ccncc5)nc(-c5ccncc5)c4)cc3)cccc2c1]

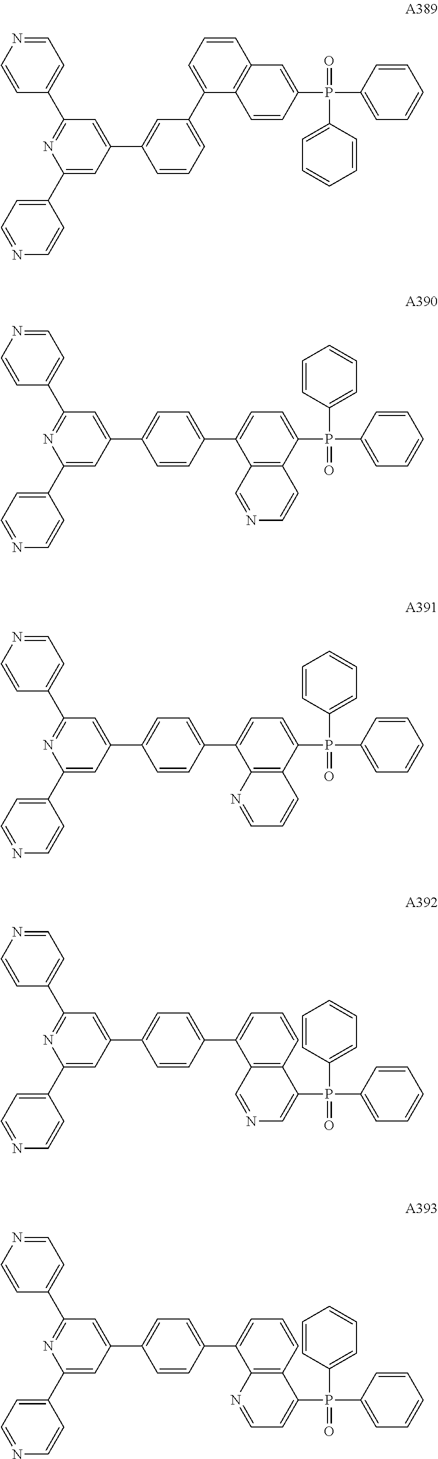 [SMILES: O=P(c1ccccc1)(c1ccccc1)c1ccc2c(-c3cccc(-c4cc(-c5ccncc5)nc(-c5ccncc5)c4)c3)cccc2c1 ; O=P(c1ccccc1)(c1ccccc1)c1ccc(-c2ccc(-c3cc(-c4ccncc4)nc(-c4ccncc4)c3)cc2)c2cnccc12 ; O=P(c1ccccc1)(c1ccccc1)c1ccc(-c2ccc(-c3cc(-c4ccncc4)nc(-c4ccncc4)c3)cc2)c2ncccc12 ; O=P(c1ccccc1)(c1ccccc1)c1cncc2c(-c3ccc(-c4cc(-c5ccncc5)nc(-c5ccncc5)c4)cc3)cccc12 ; O=P(c1ccccc1)(c1ccccc1)c1ccnc2c(-c3ccc(-c4cc(-c5ccncc5)nc(-c5ccncc5)c4)cc3)cccc12]

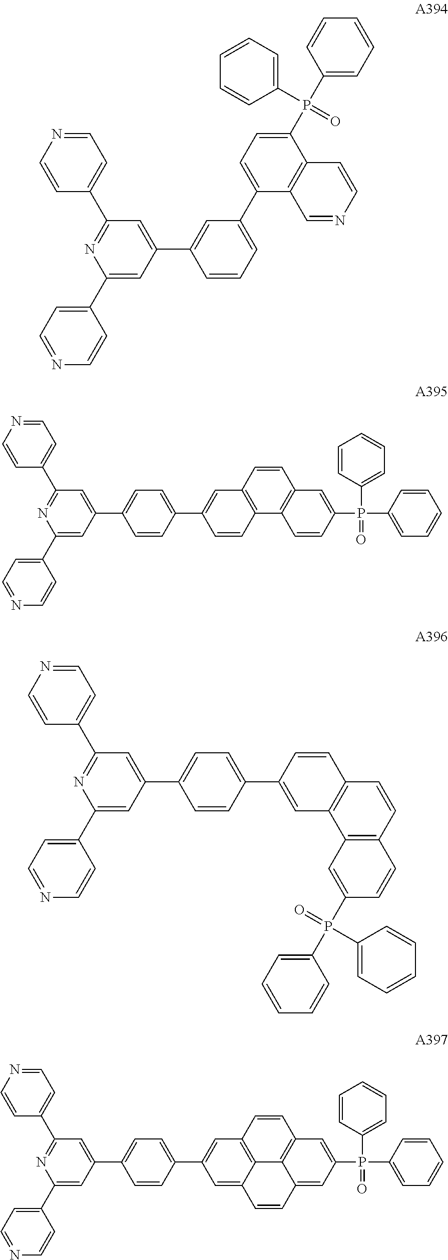 [SMILES: O=P(c1ccccc1)(c1ccccc1)c1ccc(-c2cccc(-c3cc(-c4ccncc4)nc(-c4ccncc4)c3)c2)c2cnccc12 ; O=P(c1ccccc1)(c1ccccc1)c1ccc2c(ccc3cc(-c4ccc(-c5cc(-c6ccncc6)nc(-c6ccncc6)c5)cc4)ccc32)c1 ; O=P(c1ccccc1)(c1ccccc1)c1ccc2ccc3ccc(-c4ccc(-c5cc(-c6ccncc6)nc(-c6ccncc6)c5)cc4)cc3c2c1 ; O=P(c1ccccc1)(c1ccccc1)c1cc2ccc3cc(-c4ccc(-c5cc(-c6ccncc6)nc(-c6ccncc6)c5)cc4)cc4ccc(c1)c2c34]

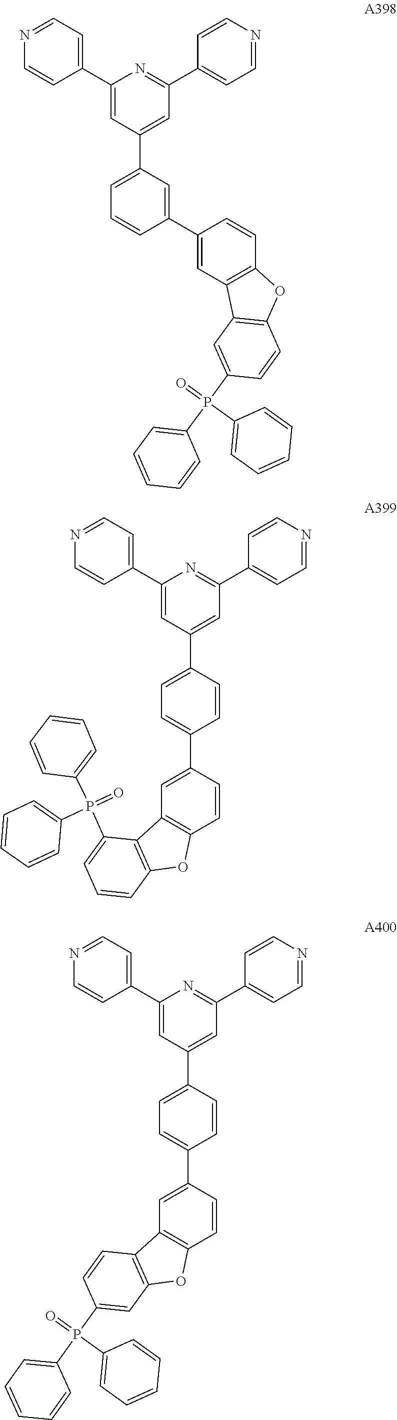

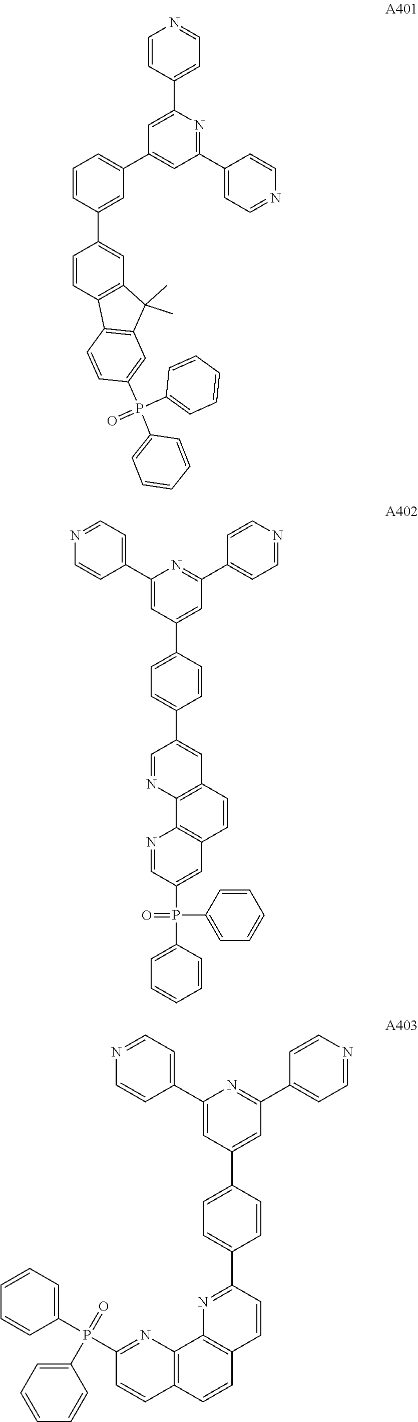 [SMILES: CC1(C)c2cc(-c3cccc(-c4cc(-c5ccncc5)nc(-c5ccncc5)c4)c3)ccc2-c2ccc(P(=O)(c3ccccc3)c3ccccc3)cc21 ; O=P(c1ccccc1)(c1ccccc1)c1cnc2c(ccc3cc(-c4ccc(-c5cc(-c6ccncc6)nc(-c6ccncc6)c5)cc4)cnc32)c1 ; O=P(c1ccccc1)(c1ccccc1)c1ccc2ccc3ccc(-c4ccc(-c5cc(-c6ccncc6)nc(-c6ccncc6)c5)cc4)nc3c2n1]

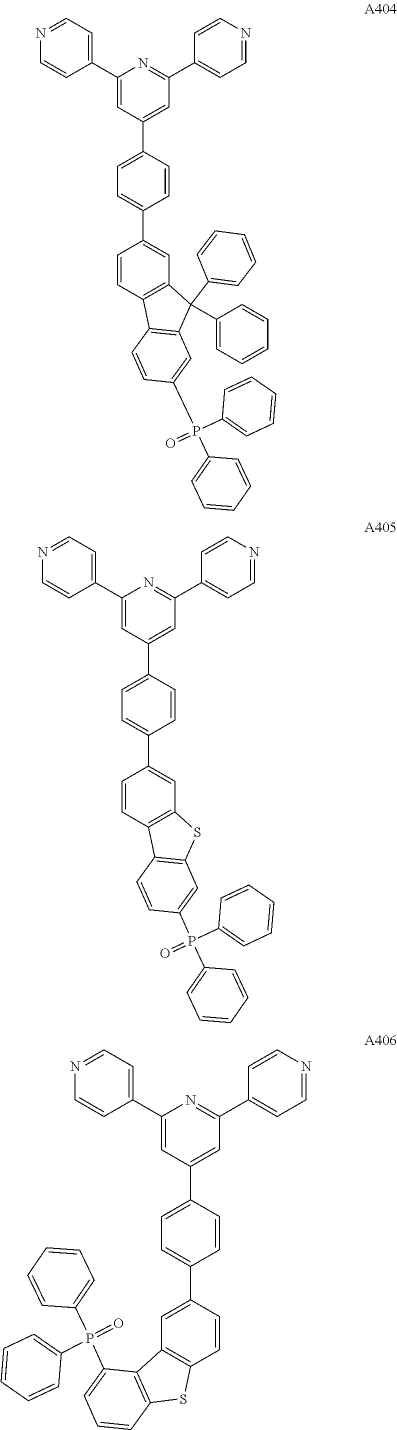

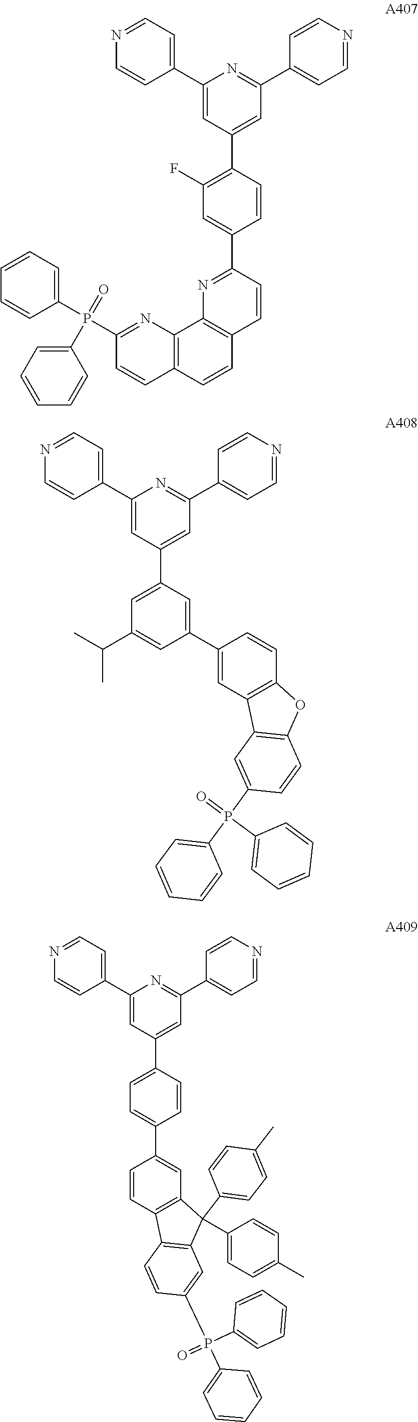

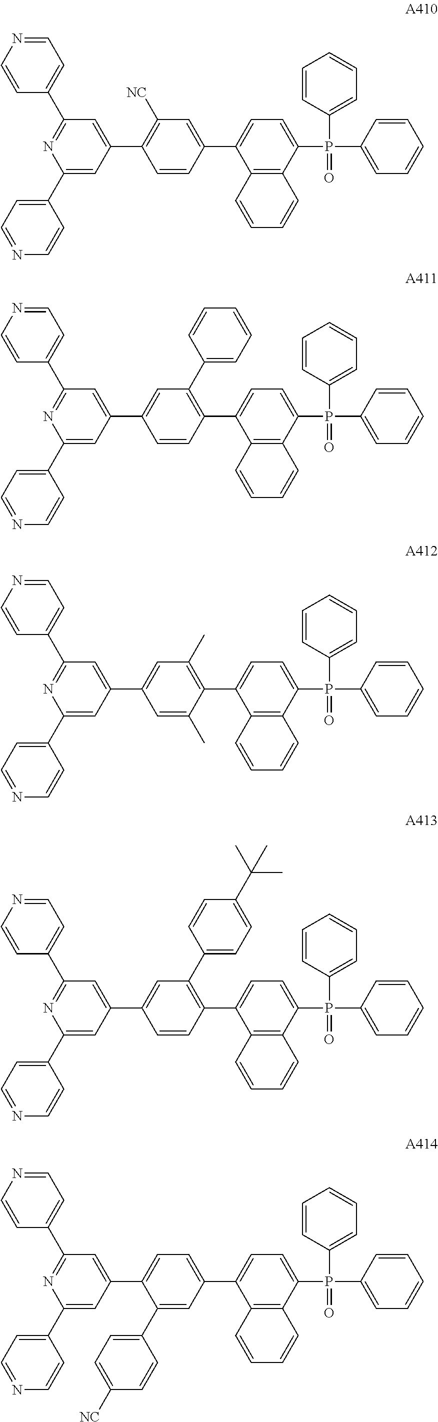 [SMILES: N#Cc1cc(-c2ccc(P(=O)(c3ccccc3)c3ccccc3)c3ccccc23)ccc1-c1cc(-c2ccncc2)nc(-c2ccncc2)c1 ; O=P(c1ccccc1)(c1ccccc1)c1ccc(-c2ccc(-c3cc(-c4ccncc4)nc(-c4ccncc4)c3)cc2-c2ccccc2)c2ccccc12 ; Cc1cc(-c2cc(-c3ccncc3)nc(-c3ccncc3)c2)cc(C)c1-c1ccc(P(=O)(c2ccccc2)c2ccccc2)c2ccccc12 ; CC(C)(C)c1ccc(-c2cc(-c3cc(-c4ccncc4)nc(-c4ccncc4)c3)ccc2-c2ccc(P(=O)(c3ccccc3)c3ccccc3)c3ccccc23)cc1 ; N#Cc1ccc(-c2cc(-c3ccc(P(=O)(c4ccccc4)c4ccccc4)c4ccccc34)ccc2-c2cc(-c3ccncc3)nc(-c3ccncc3)c2)cc1]

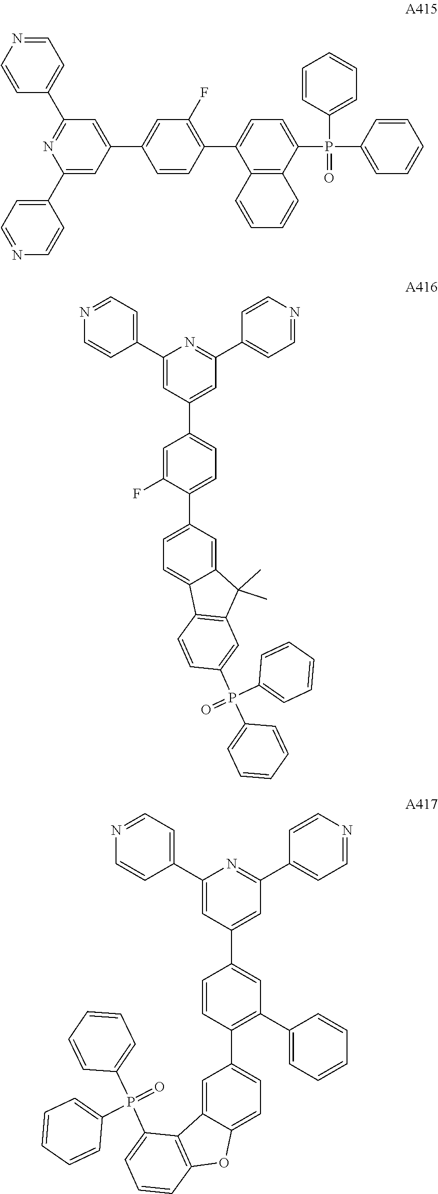 [SMILES: O=P(c1ccccc1)(c1ccccc1)c1ccc(-c2ccc(-c3cc(-c4ccncc4)nc(-c4ccncc4)c3)cc2F)c2ccccc12 ; CC1(C)c2cc(-c3ccc(-c4cc(-c5ccncc5)nc(-c5ccncc5)c4)cc3F)ccc2-c2ccc(P(=O)(c3ccccc3)c3ccccc3)cc21 ; O=P(c1ccccc1)(c1ccccc1)c1cccc2oc3ccc(-c4ccc(-c5cc(-c6ccncc6)nc(-c6ccncc6)c5)cc4-c4ccccc4)cc3c12]

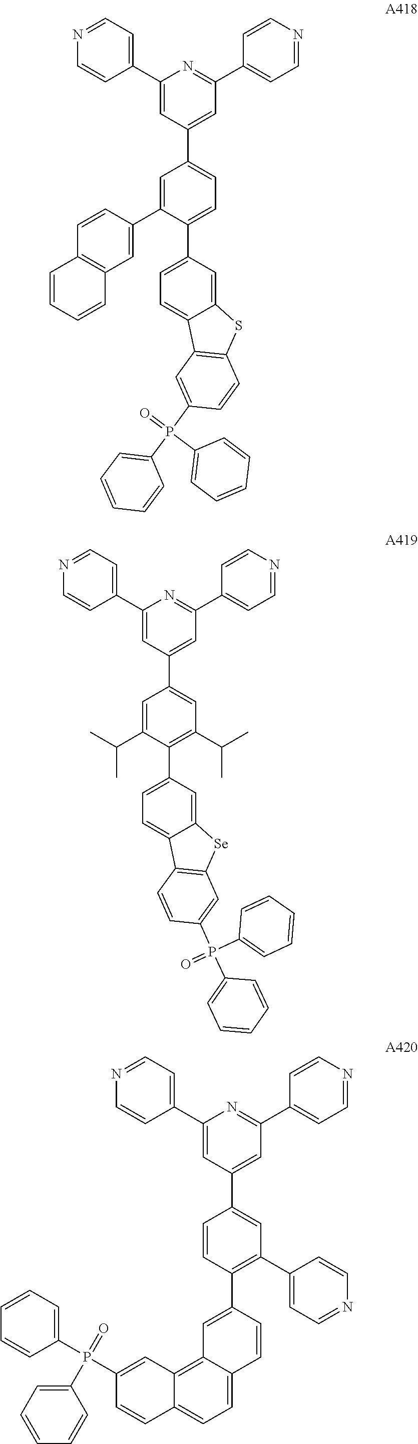 [SMILES: O=P(c1ccccc1)(c1ccccc1)c1ccc2sc3cc(-c4ccc(-c5cc(-c6ccncc6)nc(-c6ccncc6)c5)cc4-c4ccc5ccccc5c4)ccc3c2c1 ; CC(C)c1cc(-c2cc(-c3ccncc3)nc(-c3ccncc3)c2)cc(C(C)C)c1-c1ccc2c(c1)[se]c1cc(P(=O)(c3ccccc3)c3ccccc3)ccc12 ; O=P(c1ccccc1)(c1ccccc1)c1ccc2ccc3ccc(-c4ccc(-c5cc(-c6ccncc6)nc(-c6ccncc6)c5)cc4-c4ccncc4)cc3c2c1]

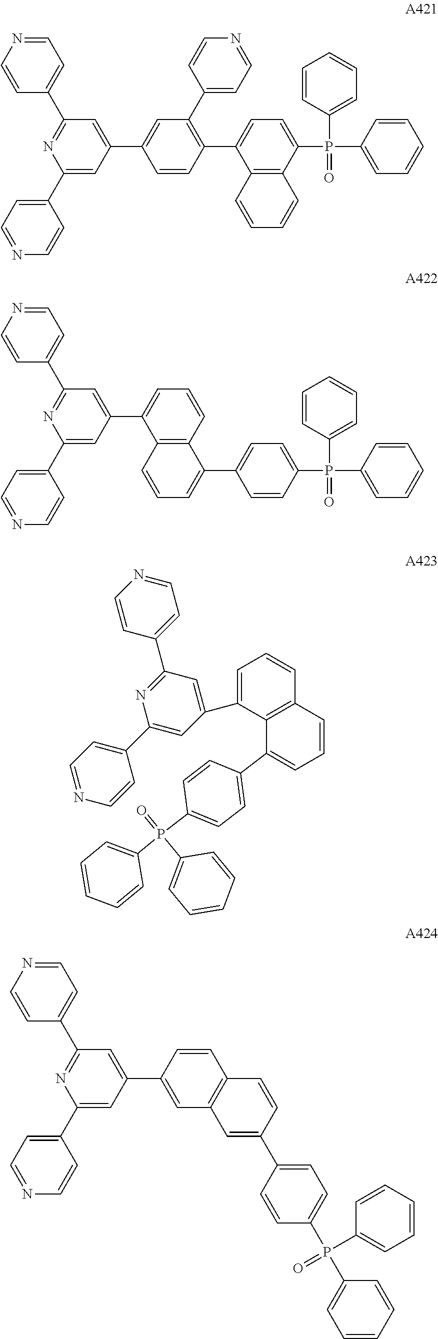 [SMILES: O=P(c1ccccc1)(c1ccccc1)c1ccc(-c2ccc(-c3cc(-c4ccncc4)nc(-c4ccncc4)c3)cc2-c2ccncc2)c2ccccc12 ; O=P(c1ccccc1)(c1ccccc1)c1ccc(-c2cccc3c(-c4cc(-c5ccncc5)nc(-c5ccncc5)c4)cccc23)cc1 ; O=P(c1ccccc1)(c1ccccc1)c1ccc(-c2cccc3cccc(-c4cc(-c5ccncc5)nc(-c5ccncc5)c4)c23)cc1 ; O=P(c1ccccc1)(c1ccccc1)c1ccc(-c2ccc3ccc(-c4cc(-c5ccncc5)nc(-c5ccncc5)c4)cc3c2)cc1]

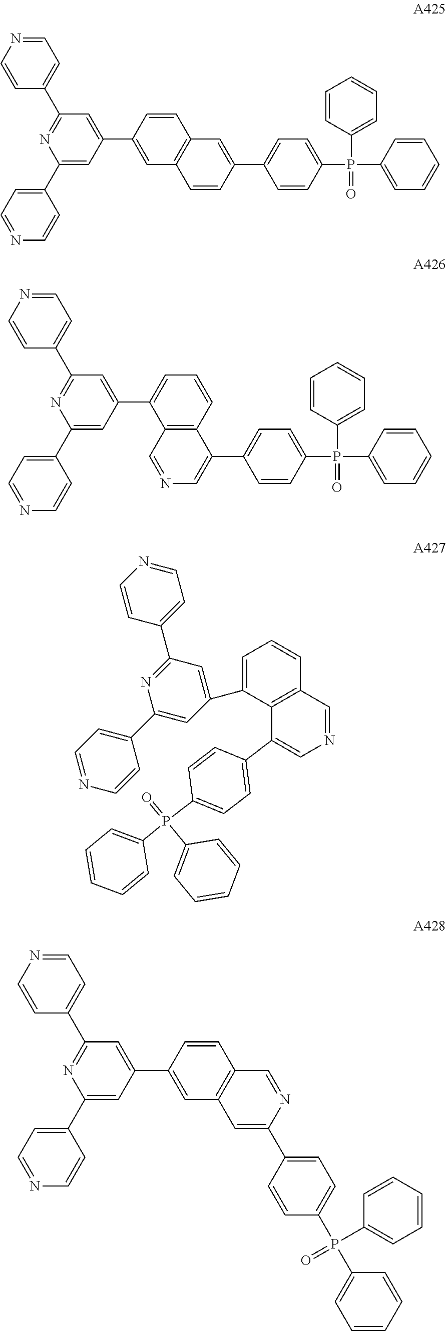 [SMILES: O=P(c1ccccc1)(c1ccccc1)c1ccc(-c2ccc3cc(-c4cc(-c5ccncc5)nc(-c5ccncc5)c4)ccc3c2)cc1 ; O=P(c1ccccc1)(c1ccccc1)c1ccc(-c2cncc3c(-c4cc(-c5ccncc5)nc(-c5ccncc5)c4)cccc23)cc1 ; O=P(c1ccccc1)(c1ccccc1)c1ccc(-c2cncc3cccc(-c4cc(-c5ccncc5)nc(-c5ccncc5)c4)c23)cc1 ; O=P(c1ccccc1)(c1ccccc1)c1ccc(-c2cc3cc(-c4cc(-c5ccncc5)nc(-c5ccncc5)c4)ccc3cn2)cc1]

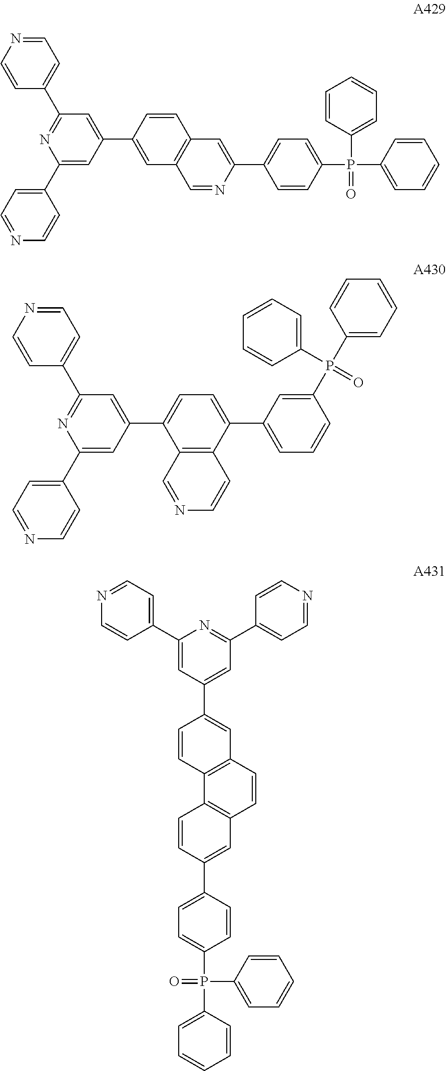 [SMILES: O=P(c1ccccc1)(c1ccccc1)c1ccc(-c2cc3ccc(-c4cc(-c5ccncc5)nc(-c5ccncc5)c4)cc3cn2)cc1 ; O=P(c1ccccc1)(c1ccccc1)c1cccc(-c2ccc(-c3cc(-c4ccncc4)nc(-c4ccncc4)c3)c3cnccc23)c1 ; O=P(c1ccccc1)(c1ccccc1)c1ccc(-c2ccc3c(ccc4cc(-c5cc(-c6ccncc6)nc(-c6ccncc6)c5)ccc43)c2)cc1]

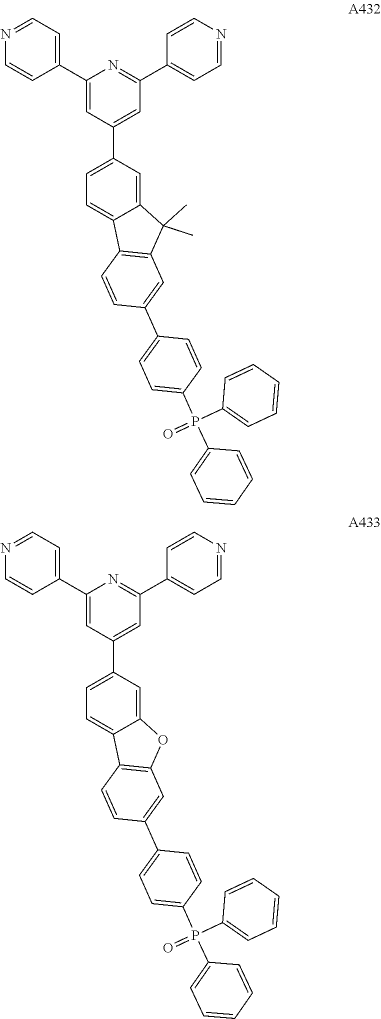

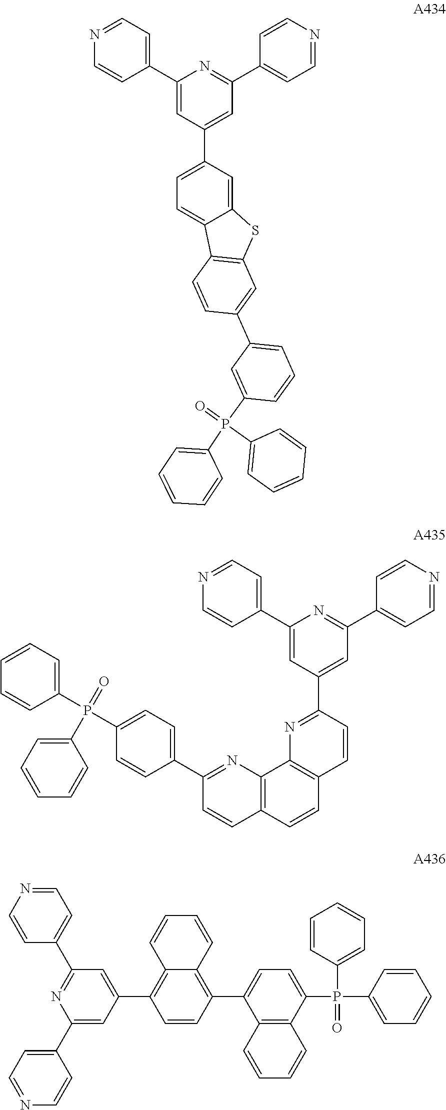 [SMILES: O=P(c1ccccc1)(c1ccccc1)c1cccc(-c2ccc3c(c2)sc2cc(-c4cc(-c5ccncc5)nc(-c5ccncc5)c4)ccc23)c1 ; O=P(c1ccccc1)(c1ccccc1)c1ccc(-c2ccc3ccc4ccc(-c5cc(-c6ccncc6)nc(-c6ccncc6)c5)nc4c3n2)cc1 ; O=P(c1ccccc1)(c1ccccc1)c1ccc(-c2ccc(-c3cc(-c4ccncc4)nc(-c4ccncc4)c3)c3ccccc23)c2ccccc12]

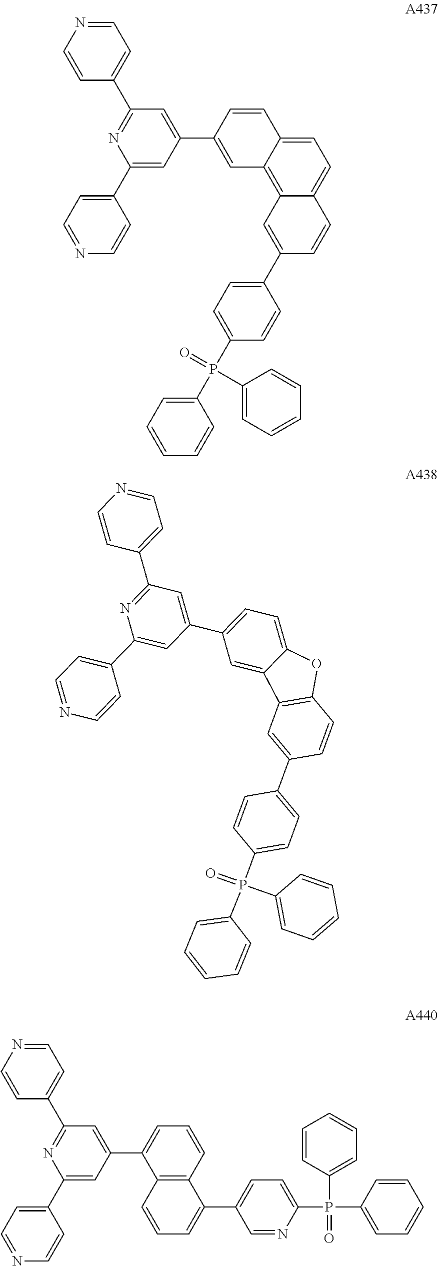

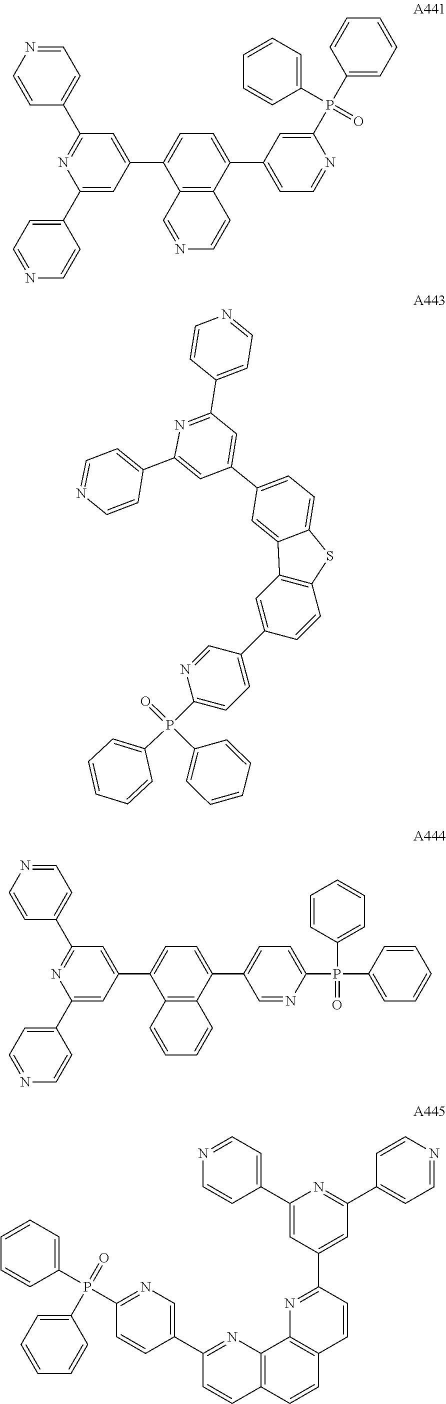 [SMILES: O=P(c1ccccc1)(c1ccccc1)c1cc(-c2ccc(-c3cc(-c4ccncc4)nc(-c4ccncc4)c3)c3cnccc23)ccn1 ; O=P(c1ccccc1)(c1ccccc1)c1ccc(-c2ccc3sc4ccc(-c5cc(-c6ccncc6)nc(-c6ccncc6)c5)cc4c3c2)cn1 ; O=P(c1ccccc1)(c1ccccc1)c1ccc(-c2ccc(-c3cc(-c4ccncc4)nc(-c4ccncc4)c3)c3ccccc23)cn1 ; O=P(c1ccccc1)(c1ccccc1)c1ccc(-c2ccc3ccc4ccc(-c5cc(-c6ccncc6)nc(-c6ccncc6)c5)nc4c3n2)cn1]

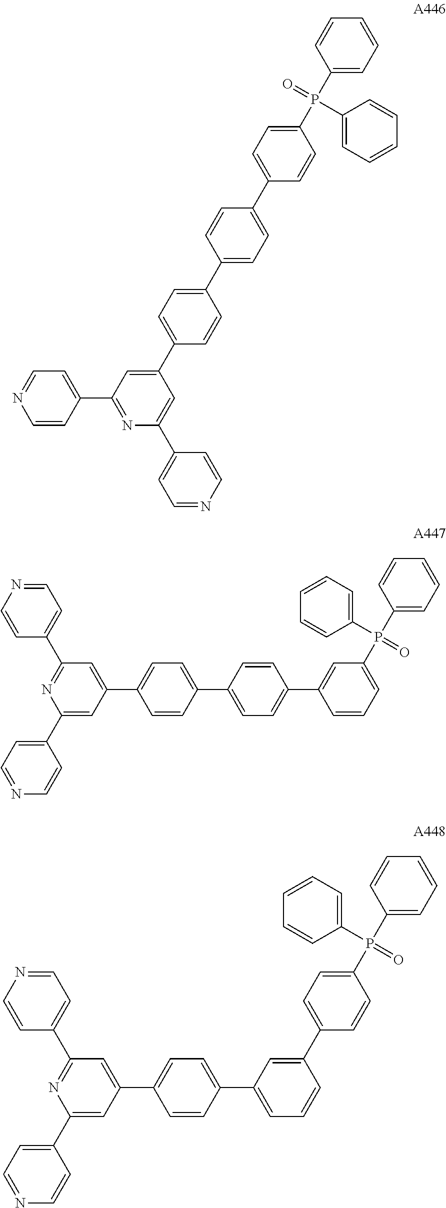 [SMILES: O=P(c1ccccc1)(c1ccccc1)c1ccc(-c2ccc(-c3ccc(-c4cc(-c5ccncc5)nc(-c5ccncc5)c4)cc3)cc2)cc1 ; O=P(c1ccccc1)(c1ccccc1)c1cccc(-c2ccc(-c3ccc(-c4cc(-c5ccncc5)nc(-c5ccncc5)c4)cc3)cc2)c1 ; O=P(c1ccccc1)(c1ccccc1)c1ccc(-c2cccc(-c3ccc(-c4cc(-c5ccncc5)nc(-c5ccncc5)c4)cc3)c2)cc1]

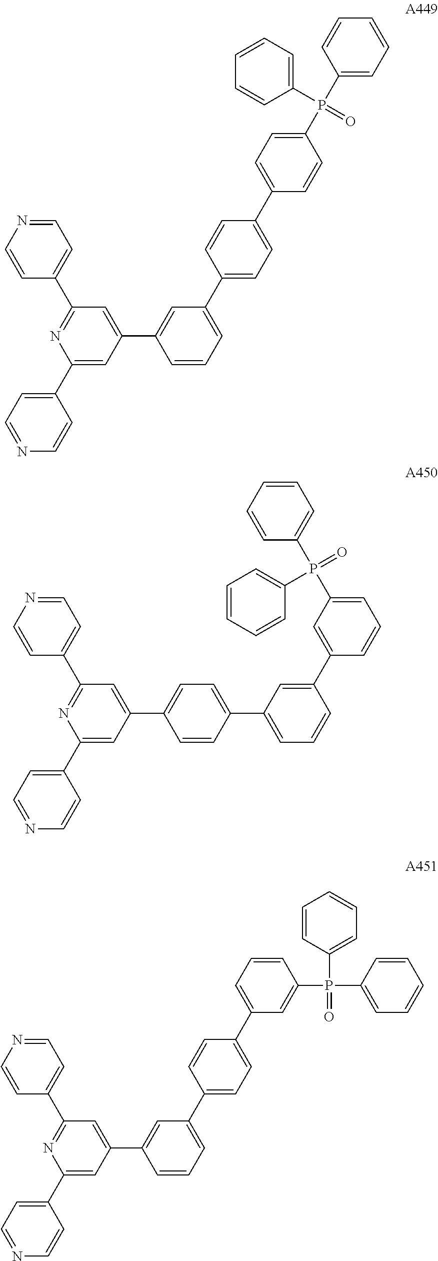 [SMILES: O=P(c1ccccc1)(c1ccccc1)c1ccc(-c2ccc(-c3cccc(-c4cc(-c5ccncc5)nc(-c5ccncc5)c4)c3)cc2)cc1 ; O=P(c1ccccc1)(c1ccccc1)c1cccc(-c2cccc(-c3ccc(-c4cc(-c5ccncc5)nc(-c5ccncc5)c4)cc3)c2)c1 ; O=P(c1ccccc1)(c1ccccc1)c1cccc(-c2ccc(-c3cccc(-c4cc(-c5ccncc5)nc(-c5ccncc5)c4)c3)cc2)c1]

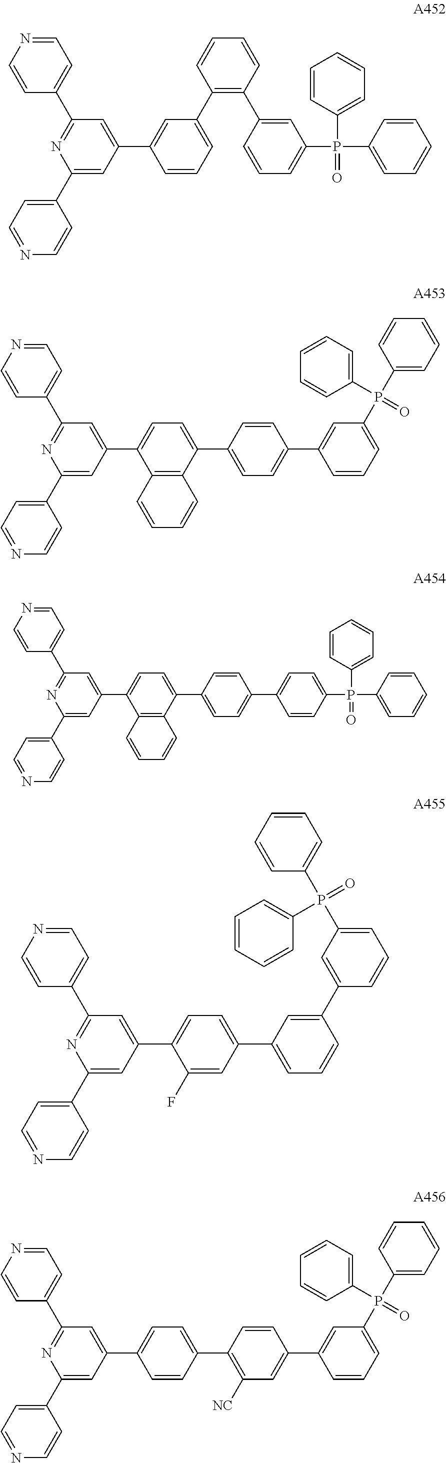 [SMILES: O=P(c1ccccc1)(c1ccccc1)c1cccc(-c2ccccc2-c2cccc(-c3cc(-c4ccncc4)nc(-c4ccncc4)c3)c2)c1 ; O=P(c1ccccc1)(c1ccccc1)c1cccc(-c2ccc(-c3ccc(-c4cc(-c5ccncc5)nc(-c5ccncc5)c4)c4ccccc34)cc2)c1 ; O=P(c1ccccc1)(c1ccccc1)c1ccc(-c2ccc(-c3ccc(-c4cc(-c5ccncc5)nc(-c5ccncc5)c4)c4ccccc34)cc2)cc1 ; O=P(c1ccccc1)(c1ccccc1)c1cccc(-c2cccc(-c3ccc(-c4cc(-c5ccncc5)nc(-c5ccncc5)c4)c(F)c3)c2)c1 ; N#Cc1cc(-c2cccc(P(=O)(c3ccccc3)c3ccccc3)c2)ccc1-c1ccc(-c2cc(-c3ccncc3)nc(-c3ccncc3)c2)cc1]

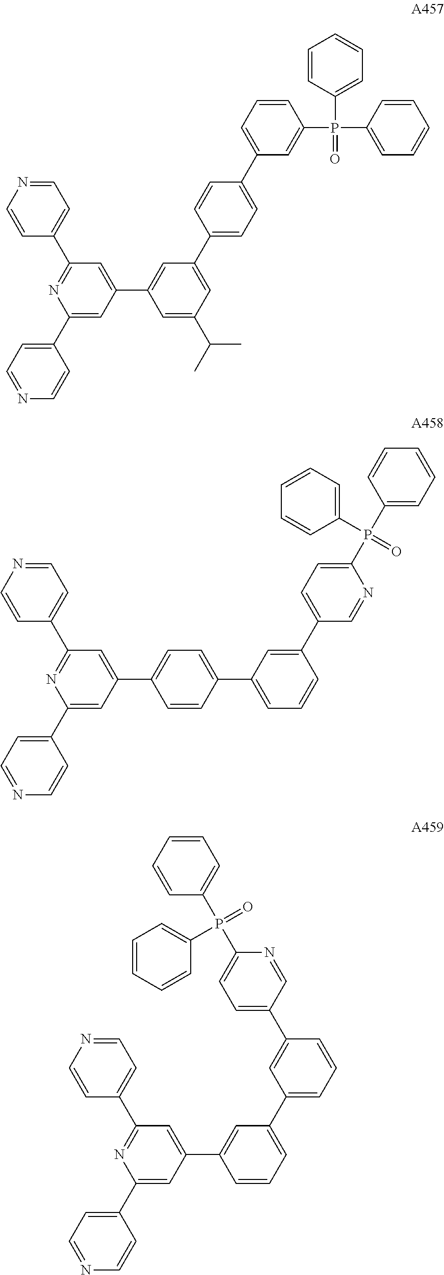 [SMILES: CC(C)c1cc(-c2ccc(-c3cccc(P(=O)(c4ccccc4)c4ccccc4)c3)cc2)cc(-c2cc(-c3ccncc3)nc(-c3ccncc3)c2)c1 ; O=P(c1ccccc1)(c1ccccc1)c1ccc(-c2cccc(-c3ccc(-c4cc(-c5ccncc5)nc(-c5ccncc5)c4)cc3)c2)cn1 ; O=P(c1ccccc1)(c1ccccc1)c1ccc(-c2cccc(-c3cccc(-c4cc(-c5ccncc5)nc(-c5ccncc5)c4)c3)c2)cn1]

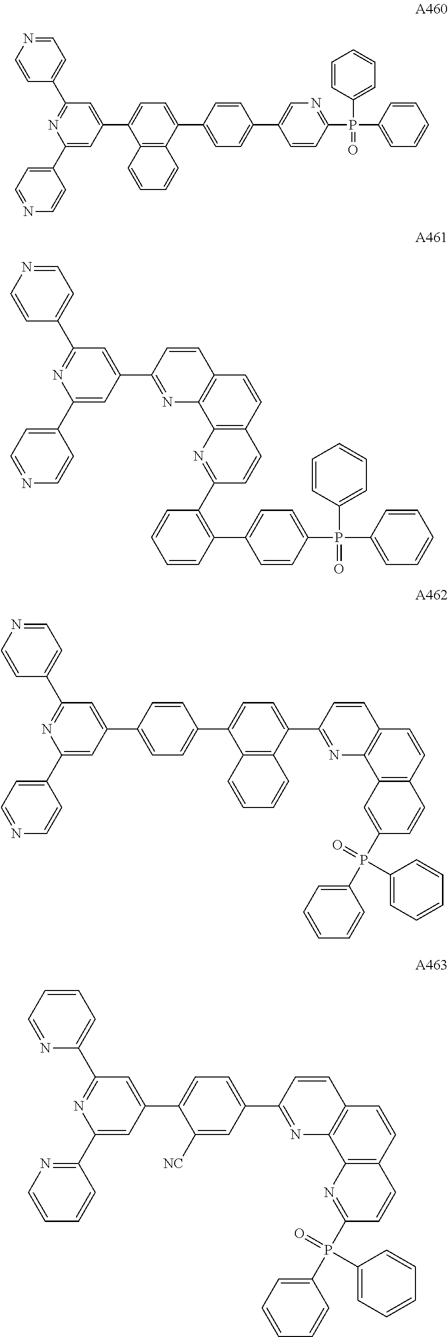 [SMILES: O=P(c1ccccc1)(c1ccccc1)c1ccc(-c2ccc(-c3ccc(-c4cc(-c5ccncc5)nc(-c5ccncc5)c4)c4ccccc34)cc2)cn1 ; O=P(c1ccccc1)(c1ccccc1)c1ccc(-c2ccccc2-c2ccc3ccc4ccc(-c5cc(-c6ccncc6)nc(-c6ccncc6)c5)nc4c3n2)cc1 ; O=P(c1ccccc1)(c1ccccc1)c1ccc2ccc3ccc(-c4ccc(-c5ccc(-c6cc(-c7ccncc7)nc(-c7ccncc7)c6)cc5)c5ccccc45)nc3c2c1 ; N#Cc1cc(-c2ccc3ccc4ccc(P(=O)(c5ccccc5)c5ccccc5)nc4c3n2)ccc1-c1cc(-c2ccccn2)nc(-c2ccccn2)c1]

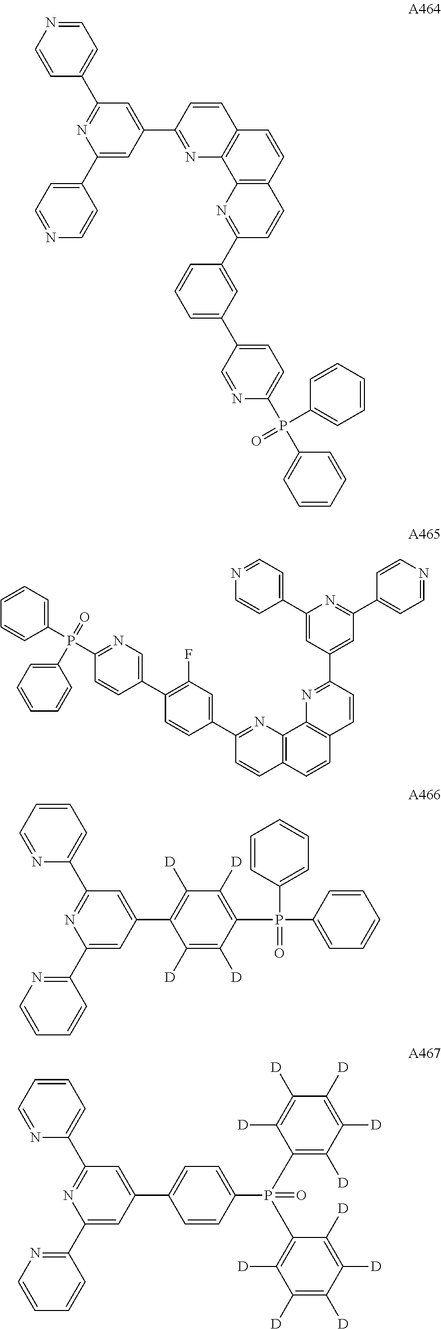 [SMILES: O=P(c1ccccc1)(c1ccccc1)c1ccc(-c2cccc(-c3ccc4ccc5ccc(-c6cc(-c7ccncc7)nc(-c7ccncc7)c6)nc5c4n3)c2)cn1 ; O=P(c1ccccc1)(c1ccccc1)c1ccc(-c2ccc(-c3ccc4ccc5ccc(-c6cc(-c7ccncc7)nc(-c7ccncc7)c6)nc5c4n3)cc2F)cn1 ; [2H]c1c([2H])c(P(=O)(c2ccccc2)c2ccccc2)c([2H])c([2H])c1-c1cc(-c2ccccn2)nc(-c2ccccn2)c1 ; [2H]c1c([2H])c([2H])c(P(=O)(c2ccc(-c3cc(-c4ccccn4)nc(-c4ccccn4)c3)cc2)c2c([2H])c([2H])c([2H])c([2H])c2[2H])c([2H])c1[2H]]

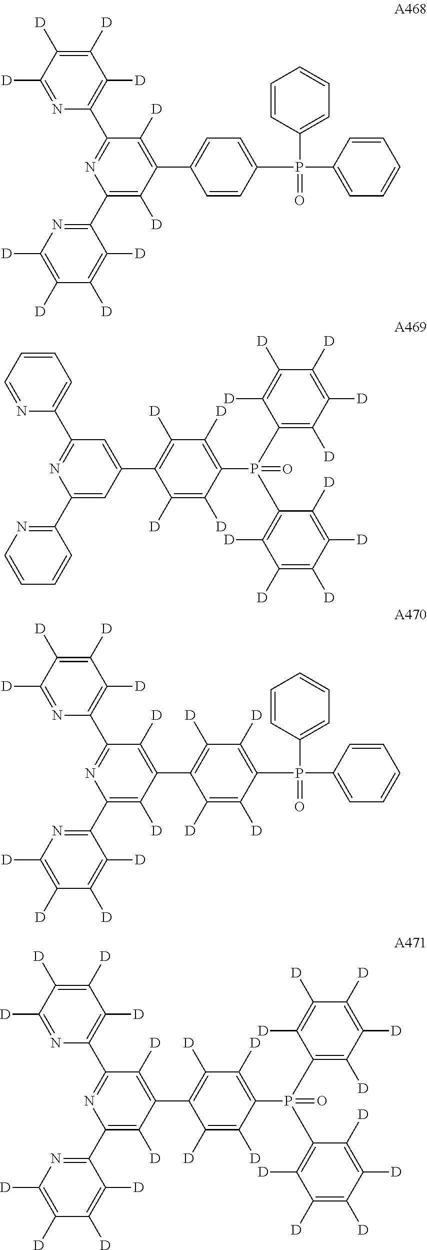

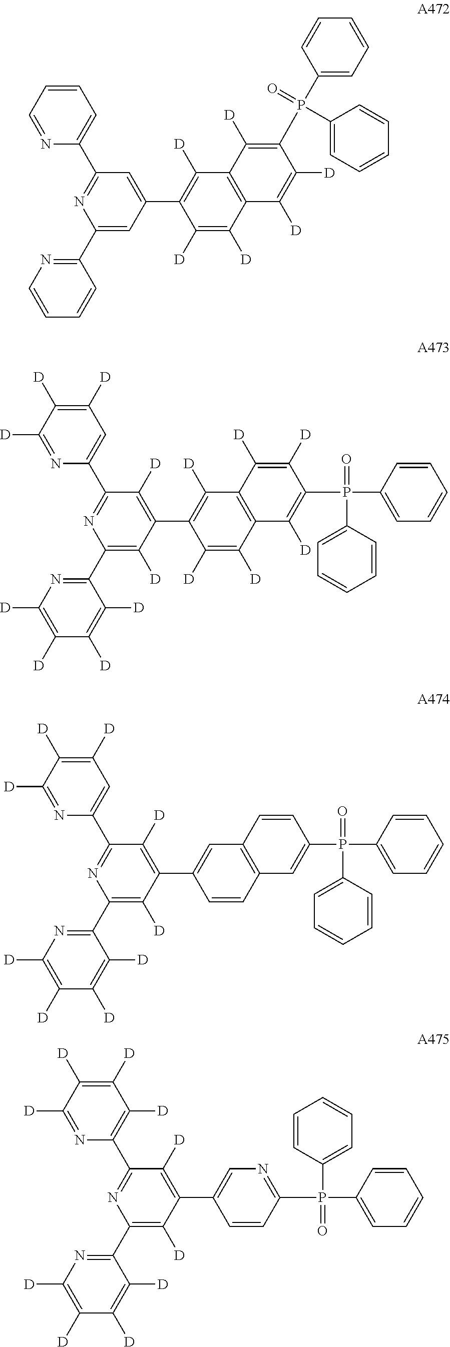

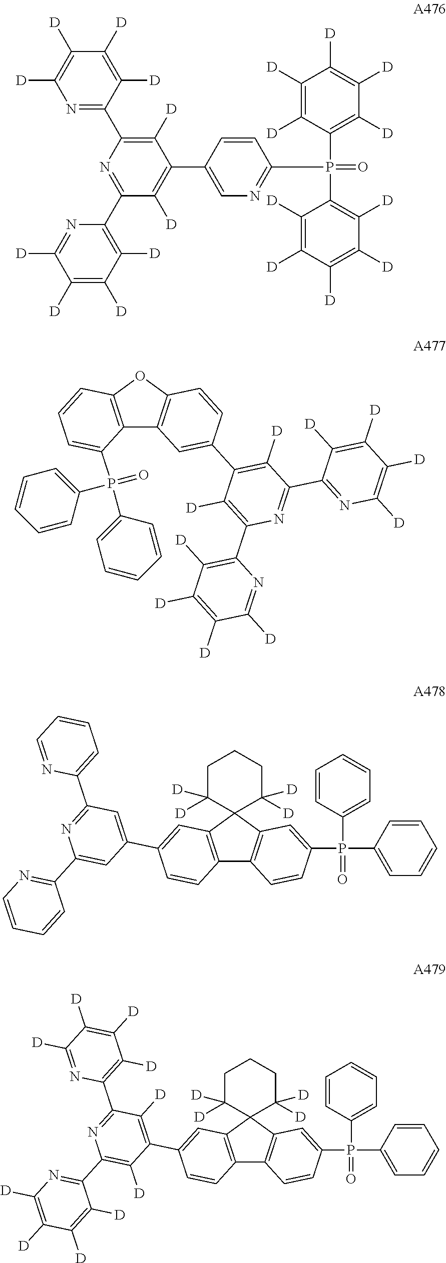

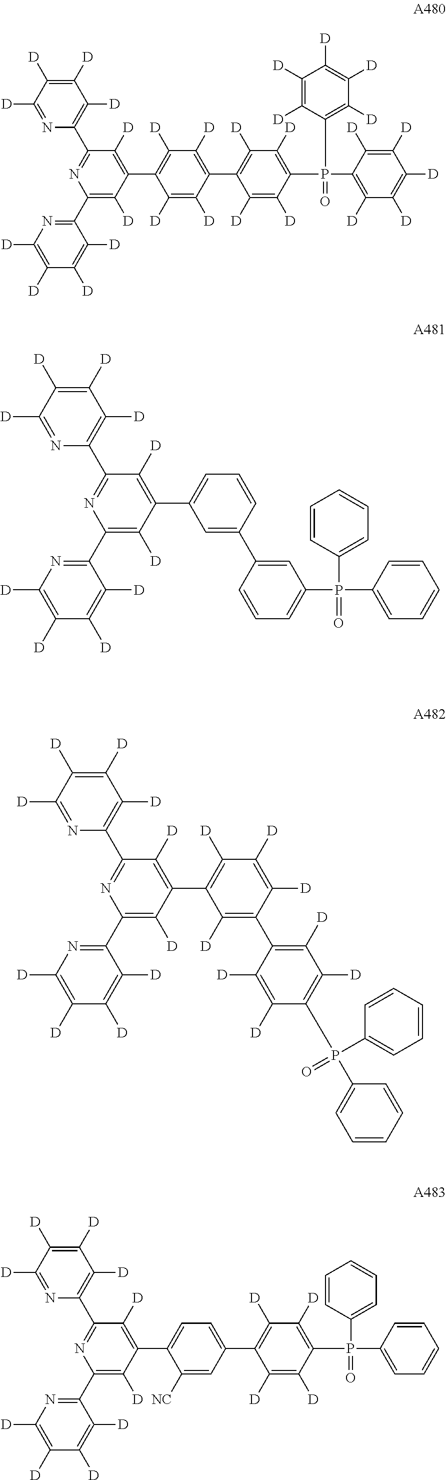

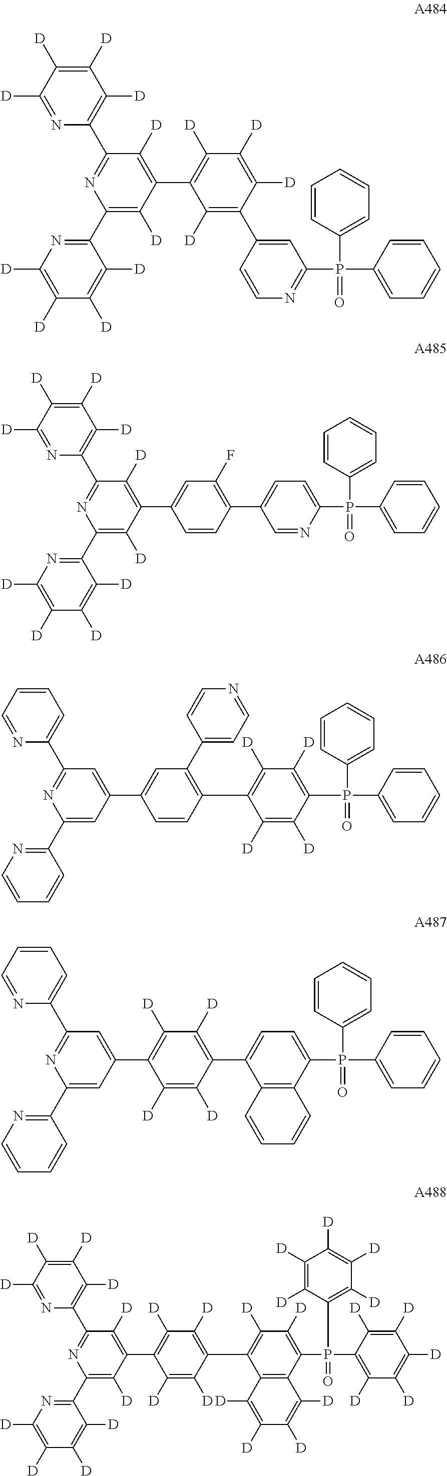

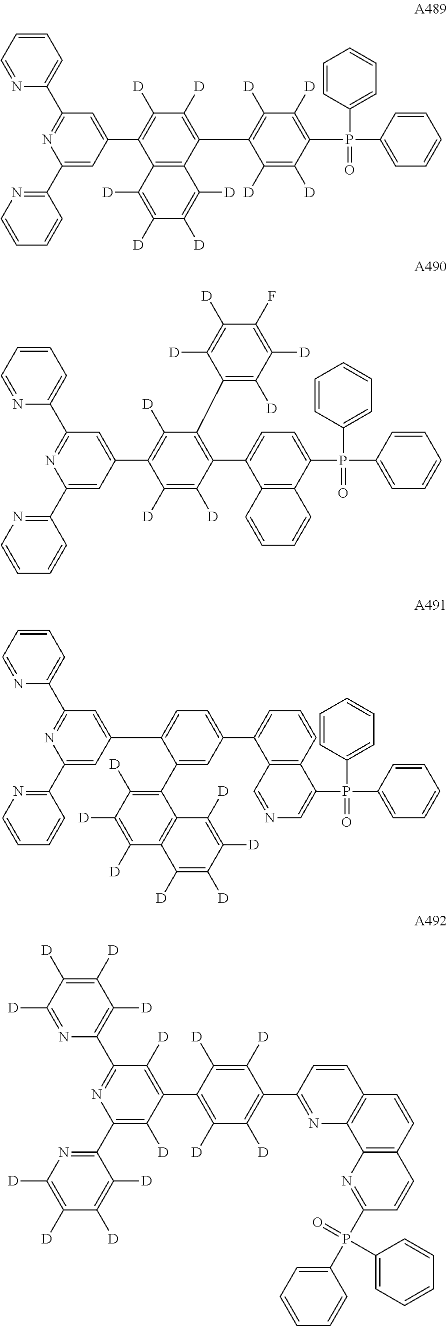

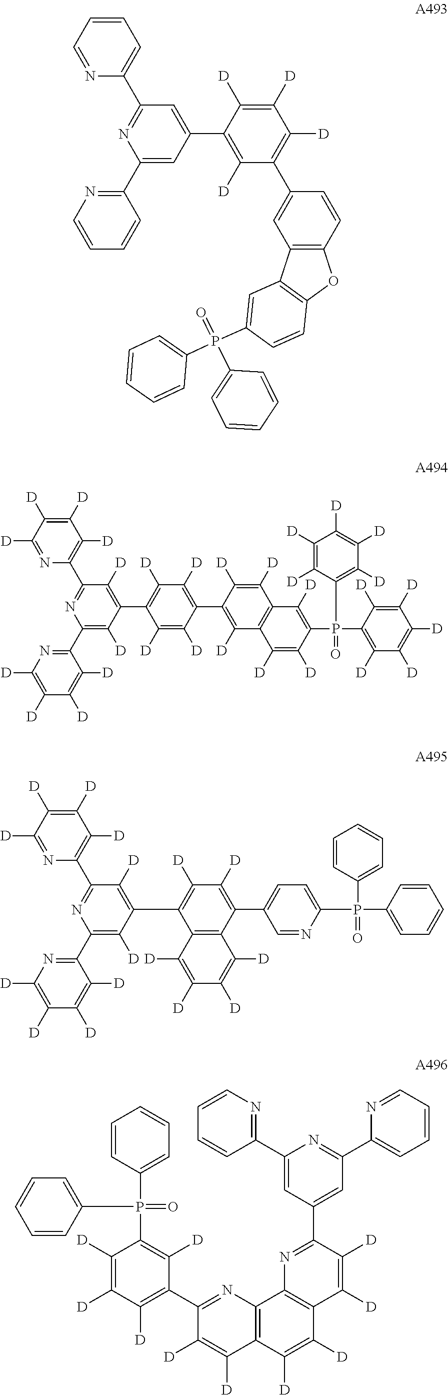

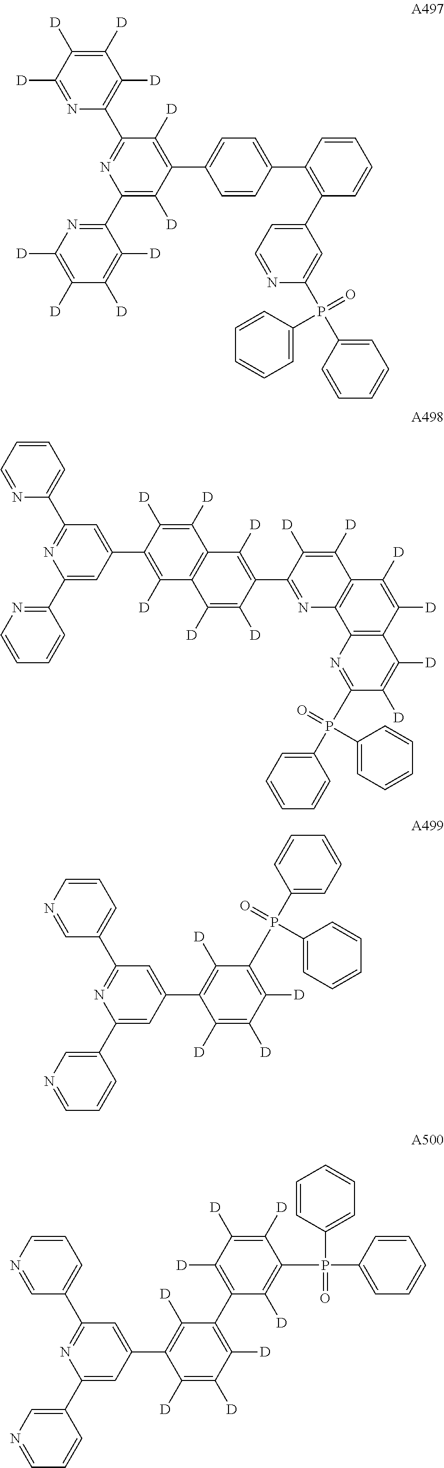

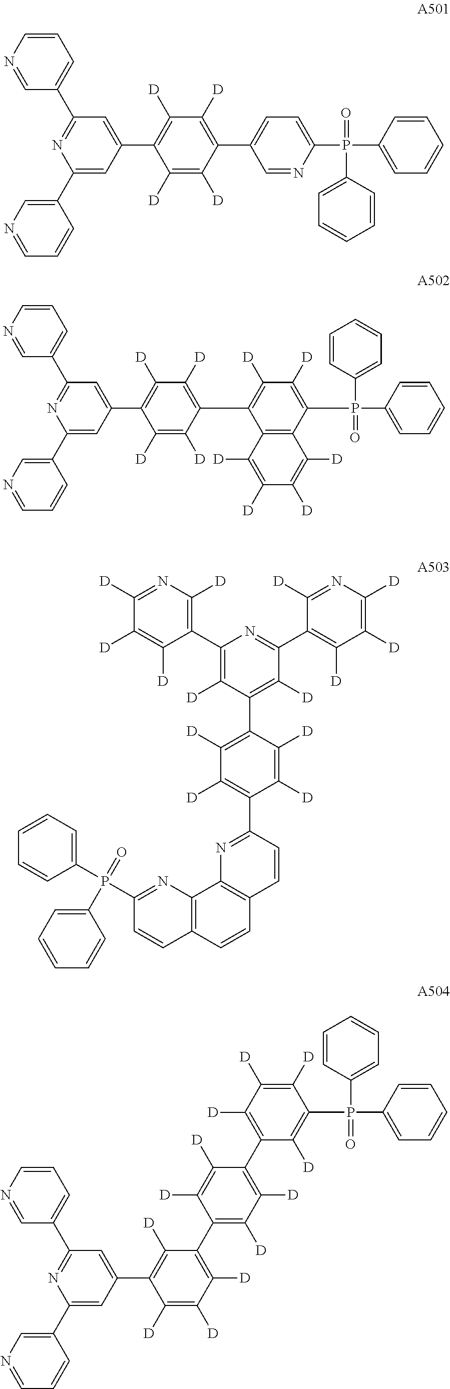

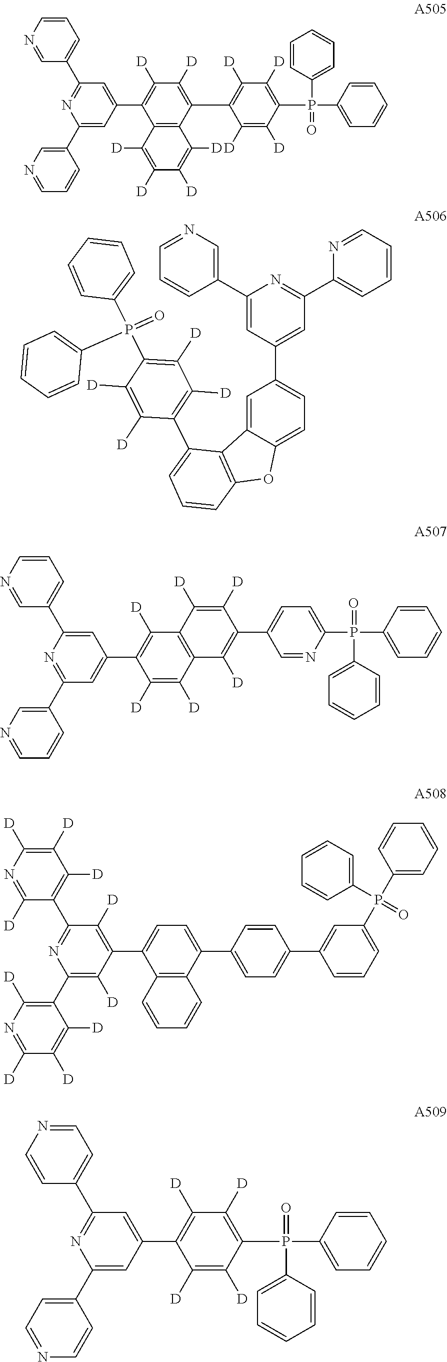

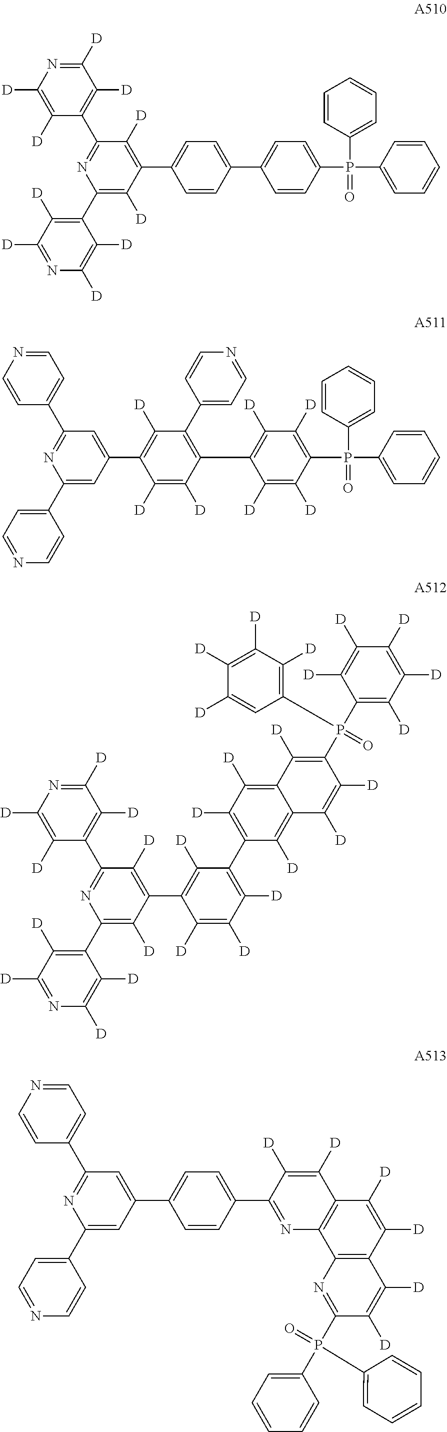

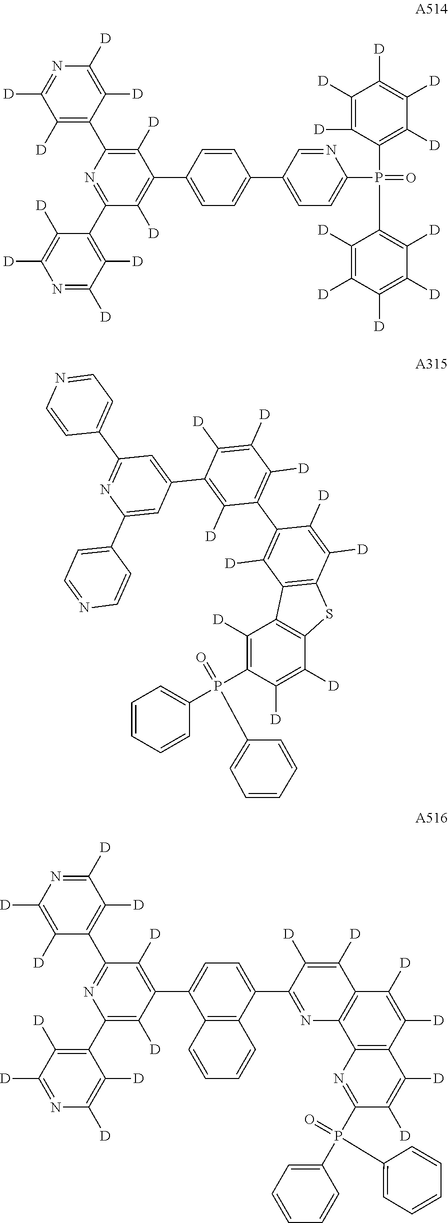

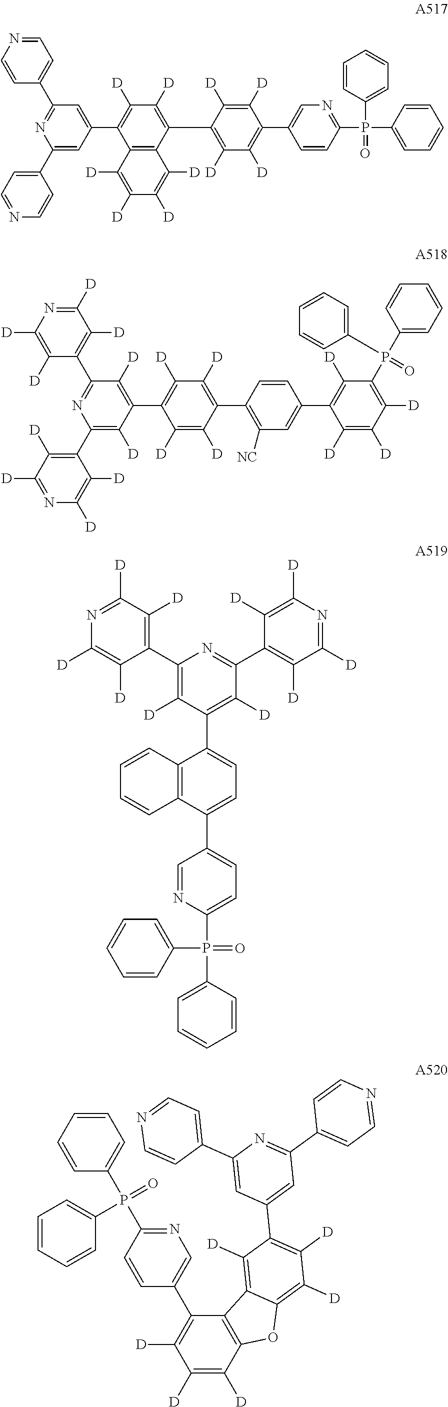

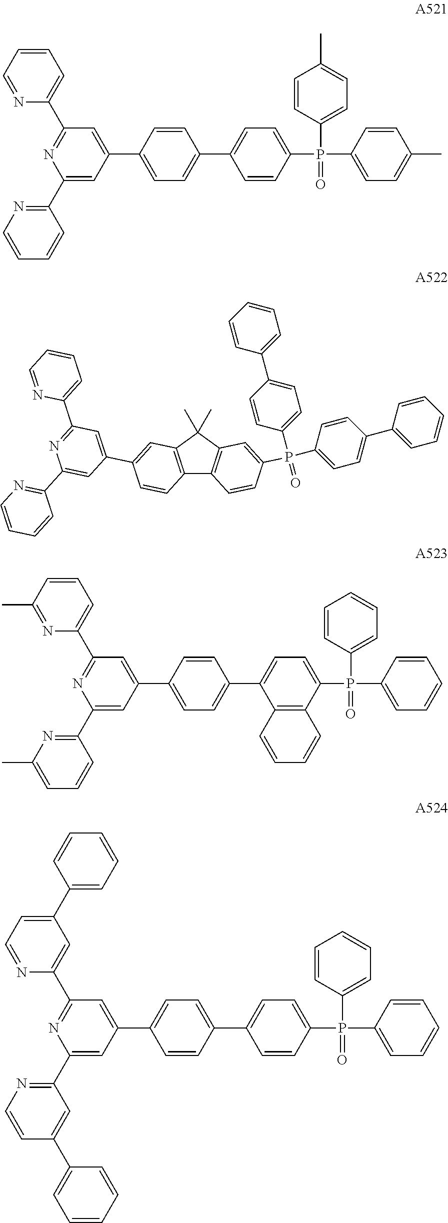

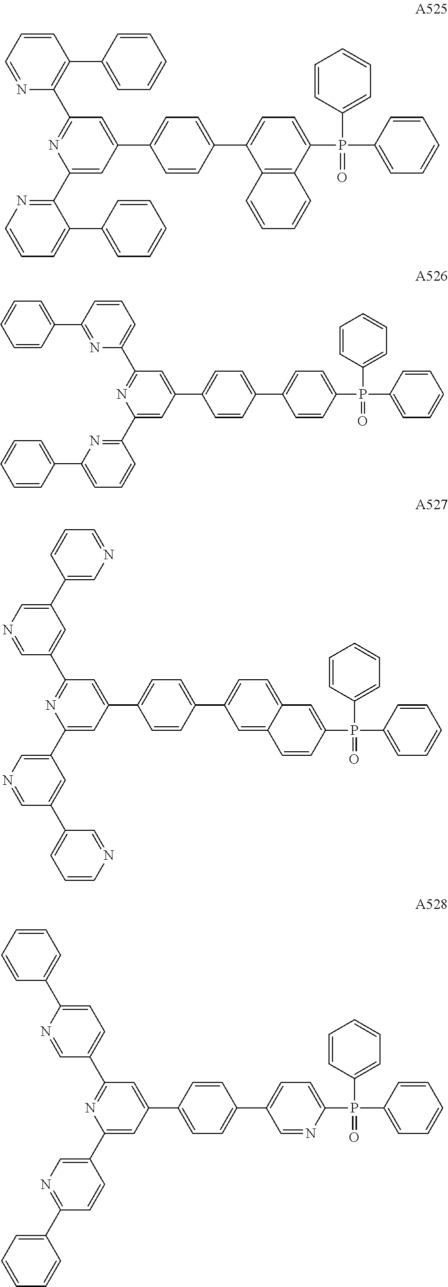 [SMILES: O=P(c1ccccc1)(c1ccccc1)c1ccc(-c2ccc(-c3cc(-c4ncccc4-c4ccccc4)nc(-c4ncccc4-c4ccccc4)c3)cc2)c2ccccc12 ; O=P(c1ccccc1)(c1ccccc1)c1ccc(-c2ccc(-c3cc(-c4cccc(-c5ccccc5)n4)nc(-c4cccc(-c5ccccc5)n4)c3)cc2)cc1 ; O=P(c1ccccc1)(c1ccccc1)c1ccc2cc(-c3ccc(-c4cc(-c5cncc(-c6cccnc6)c5)nc(-c5cncc(-c6cccnc6)c5)c4)cc3)ccc2c1 ; O=P(c1ccccc1)(c1ccccc1)c1ccc(-c2ccc(-c3cc(-c4ccc(-c5ccccc5)nc4)nc(-c4ccc(-c5ccccc5)nc4)c3)cc2)cn1]

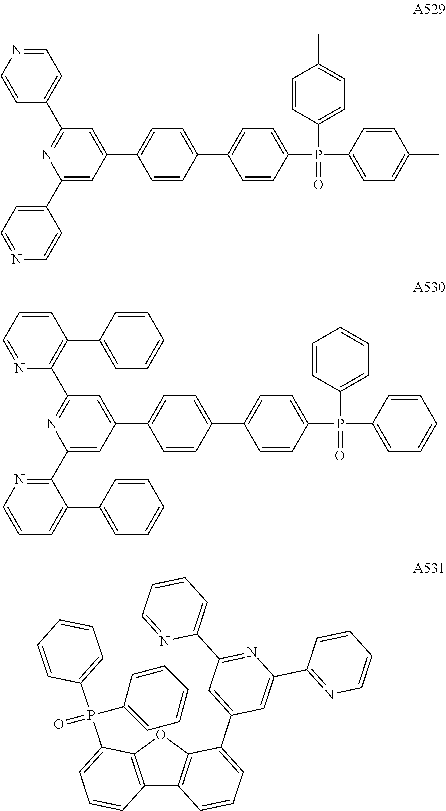 [SMILES: Cc1ccc(P(=O)(c2ccc(C)cc2)c2ccc(-c3ccc(-c4cc(-c5ccncc5)nc(-c5ccncc5)c4)cc3)cc2)cc1 ; O=P(c1ccccc1)(c1ccccc1)c1ccc(-c2ccc(-c3cc(-c4ncccc4-c4ccccc4)nc(-c4ncccc4-c4ccccc4)c3)cc2)cc1 ; O=P(c1ccccc1)(c1ccccc1)c1cccc2c1oc1c(-c3cc(-c4ccccn4)nc(-c4ccccn4)c3)cccc12]

In a second aspect, an embodiment of the present disclosure provides an organic electroluminescent device including the above heterocyclic compound.

In some embodiments, the organic electroluminescent device includes an anode and a cathode, with a functional layer disposed between the anode and the cathode, wherein the functional layer includes the heterocyclic compound.

In some embodiments, a first light-emitting unit, a charge generation layer, and a second light-emitting unit are sequentially stacked from a side of the anode to a side of the cathode in the functional layer, wherein the charge generation layer includes the heterocyclic compound.

In some embodiments, an N-type charge generation layer and a P-type charge generation layer are sequentially stacked from a side of the first light-emitting unit to a side of the second light-emitting unit, wherein the N-type charge generation layer includes the heterocyclic compound.

In some embodiments, the N-type charge generation layer further includes a dopant material.

In some embodiments, the dopant material is at least one selected from the group consisting of an alkali metal (e.g., Li, Na, K), an alkaline earth metal (e.g., Ca, Mg) and a lanthanide metal (e.g., La, Yb, Ce).

In some embodiments, the mass percentage of the dopant material in the N-type charge generation layer can be 0.1%-20%, 1%-10%, or 1%-5%. The mass percentage of the aforementioned heterocyclic compound can be 80%-99.9%, 90%-99%, or 95%-99%.

In some embodiments, the first light-emitting unit is provided with a first hole functional layer, a first light-emitting layer and a first electron functional layer stacked sequentially from a side of the anode to a side of the charge generation layer. By way of example, the first hole functional layer is provided with a hole injection layer, a first hole transport layer and a first electron blocking layer stacked sequentially from a side of the anode to a side of the first light-emitting layer; and the first electronic functional layer includes a first electron transport layer.

In some embodiments, the second light-emitting unit is provided with a second hole functional layer, a second light-emitting layer and a second electron functional layer stacked sequentially from a side of the charge generation layer to a side of the cathode. By way of example, the second hole functional layer is provided with a second hole transport layer and a second electron blocking layer stacked sequentially from a side of the charge generation layer to a side of the second light-emitting layer; and the second electron functional layer is provided with a second electron transport layer and an electron injection layer stacked sequentially from a side of the second light-emitting layer to a side of the cathode.

In some embodiments, the functional layer is provided with a hole injection layer, a first hole transport layer, a first electron blocking layer, a first light-emitting layer, a first electron transport layer, an N-type charge generation layer, a P-type charge generation layer, a second hole transport layer, a second electron blocking layer, a second light-emitting layer, a second electron transport layer and an electron injection layer stacked sequentially from a side of the anode to a side of the cathode. The N-type charge generation layer includes the heterocyclic compound.

It should be noted that the present disclosure is not limited to the stacked structure of the light-emitting units, and those skilled in the art may use any stacked structure known in the existing technologies.

In a third aspect, an embodiment of the present disclosure provides an optoelectronic element including the organic electroluminescent device described above.

Non-limiting examples of the optoelectronic element includes: a lighting device (such as a lamp), displays (such as an automotive display, a computer display, or a television display, where the display type can be an AMOLED display), or a sensor.

Based on the effect of this heterocyclic compound in improving electron mobility, it can be used as a charge generation layer material in OLED devices, which can effectively reduce driving voltage, improve luminous efficiency, and extend device lifetime, thus having the potential for application in the AMOLED industry. Specifically, this compound can coordinate with a dopant (such as an alkali metal, an alkaline earth metal, and a lanthanide metal) to reduce the energy level difference between the N-type charge generation layer and the P-type charge generation layer, thereby promoting electron injection into the N-type charge generation layer and maximizing electron transfer from the N-type charge generation layer to the adjacent electron transport layer, further improving device performance.

### Definitions

Unless otherwise specified, symbols (e.g., group designation Ar₁, etc.) in all general formulas and their subordinate general formulas involved in the present disclosure have the same scope of interpretation in all embodiments of the present disclosure. The definitions of different symbols can be freely combined, and all such combinations fall within the protection scope of the present disclosure.

The term “halogen” refers to one or more of fluorine, chlorine, bromine, or iodine, typically including fluorine, chlorine, or bromine.

The term “alkyl” refers to a linear or branched saturated hydrocarbyl group, and “cycloalkyl” refers to a non-aromatic carbocyclic ring consisting of at least three carbon atoms, which may include monocyclic, polycyclic, and spiroalkyl structures.

The term “heteroalkyl” refers to an alkyl group as defined above in which at least one carbon atom is replaced by a non-carbon atom, excluding cases where the carbon atom serving as a linking site is replaced by a non-carbon atom (e.g., alkoxy, alkylsilyl). The term “heterocyclic alkyl” refers to a group formed by replacing at least one carbon atom with a non-carbon atom on the basis of a cycloalkyl group. The non-carbon atoms can be at least one selected from the group consisting of O, S, N, Se, Si and Ge.

The term “aryl” refers to an aromatic hydrocarbyl group derived from an aromatic ring compound by removing a hydrogen atom, which can be a monocyclic aryl or a polycyclic aryl. At least one ring in a polycyclic aryl group is an aromatic ring system. In polycyclic aryl groups, multiple rings can be connected to each other via single bonds or can be fused together. Specific examples of aryl groups include phenyl, naphthyl, anthracenyl, phenanthryl, tetracenyl, pyrenyl, chrysenyl, acenaphthyl, benzo[a]pyrenyl, benzo[c]phenanthryl, benzo[g]chrysenyl, fluorenyl, benzofluorenyl, spirodifluorenyl, dibenzofluorenyl, biphenyl, terphenyl, quaterphenyl, and fluoranthenyl.

The term “heteroaryl” refers to refers to a monovalent group of a heterocyclic aromatic system based on the aryl group, wherein at least one carbon atom is replaced by a non-carbon atom (the non-carbon atom(s) can be selected from O, S, N, Se, Si, or Ge), excluding the case where the aryl group has a non-carbon atom serving as the linking site (e.g., aryloxy, arylsilyl, arylamine). Specific examples of heteroaryl groups include pyrrolyl, pyrrolopyrrolyl, furanopyrrolyl, thiophenopyrrolyl, pyridyl, pyrazolyl, pyrimidinyl, pyrazinyl, triazinyl, pyridazinyl, phenazinyl, phenothiazinyl, phenoxazinyl, indolyl, isoindolyl, imidazolyl, benzimidazolyl, triazolyl, tetrazolyl, furyl, benzofuranyl, isobenzofuranyl, dibenzofuranyl, furofuranyl, aza-dibenzofuranyl, thiophenofuranyl, diaza-dibenzofuranyl, benzo[b]naphtho[1,2-d]furanyl, quinolyl, isoquinolyl, quinoxalinyl, quinazolinyl, quinazolinonyl, carbazolyl, aza-carbazolyl, diaza-carbazolyl, phenanthridinyl, perimidinyl, acridinyl, dihydroacridinyl, phenanthrolinyl, oxazolinyl, oxazolyl, oxadiazolyl, benzoisoxazolyl, thiazolyl, benzothiazolyl, benzoisothiazolyl, pyrroloimidazolyl, furazanyl, thienyl, benzothienyl, dibenzothienyl, aza-dibenzothienyl, diaza-dibenzothienyl, thienothienyl, or phthalazinyl.

The terms “aryl” and “heteroaryl” correspond to divalent groups with the same structure as aryl and heteroaryl groups, respectively.

The term “hydrocarbyl group” refers to a group consisting only of carbon and hydrogen atoms, including saturated hydrocarbyl groups (such as alkyl and cycloalkyl), unsaturated non-aromatic hydrocarbyl groups (such as alkenyl and alkynyl), and aromatic hydrocarbyls (such as phenyl).

In the term “alkylsilyl” or “arylsilyl”, the number of alkyl or aryl groups can be from 1 to 3. “Alkylboryl” includes monoalkylboryl and dialkylboryl; “arylboryl” includes monoarylboryl and diarylboryl; “arylphosphino” includes monoarylphosphino and diarylphosphino; and “arylamino” includes monoarylamino and diarylamino. For alkylsilyl, arylsilyl, alkylboryl, arylboryl, arylphosphino, and arylamino, the defined carbon number refers to the total number of carbons in the corresponding group.

In the expression “substituted or unsubstituted X group having a carbon number of a-b”, the “carbon number of a-b” refers to the number of carbons of the unsubstituted X group, excluding the number of carbons of the substituents when the X group is substituted.

“Substituted” in the expression “substituted or unsubstituted” means that one or more hydrogen atoms are replaced by other atoms or functional groups (i.e., substituents), and unless otherwise defined, also includes one or more hydrogen atoms being replaced by groups formed by the connection of two or more of the aforementioned substituents.

The following embodiments are merely for facilitating the understanding of the technical invention and should not be regarded as specific limitations of the present disclosure.

The raw materials and solvents involved in the synthesis of the compounds in the present disclosure are all purchased from suppliers well known to those skilled in the art, such as Alfa and Acros.

### Synthesis of Compound A10

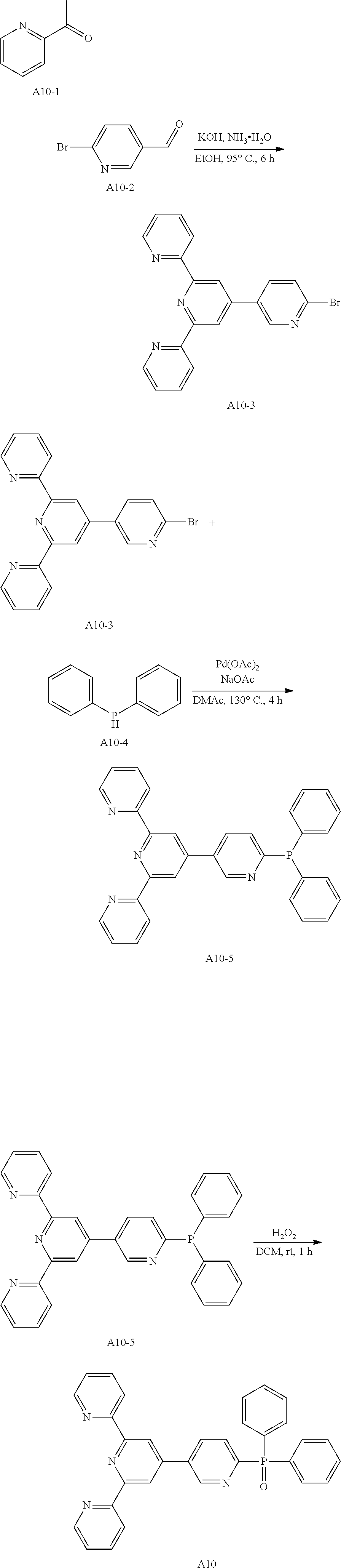

### Synthesis of Compound A10-3

Compound A10-1 (13.03 g, 107.52 mmol) and potassium hydroxide (9.05 g, 161.28 mmol) were added sequentially to a 1,000 mL three-necked round-bottom flask containing aqueous ammonia (25%, 190 mL) and ethanol (150 mL). A solution prepared from compound A10-2 (10 g, 53.76 mmol) and ethanol (150 mL) was added dropwise under ice bath (0° C.) conditions. After the dropwise addition was completed, the reaction mixture was naturally warmed to room temperature, then heated to 95° C. and reacted for 6 hours. The reaction progress was monitored by TLC (developing solvent: ethyl acetate) until compound A10-1 was completely consumed, and heating was stopped.

After the reaction, a large amount of solid precipitated out. The solid was directly filtered to obtain 13 g of yellow solid. Then dichloromethane (300 mL) and deionized water (150 mL) were added for extraction. The obtained organic phase was concentrated under reduced pressure by rotary evaporation (60° C.) to obtain a pale yellow solid. The crude product was purified by column chromatography under reduced pressure (200 g of silica gel, particle size 100-200 mesh, eluent: dichloromethane:methanol=30:1), finally yielded a white solid compound A10-3 (11.68 g, purity: 99.20%, yield: 55.81%), with a mass spectrometry of 389.03 (M+H).

### Synthesis of Compound A10-5

Compound A10-3 (11.00 g, 28.26 mmol), compound A10-4 (5.26 g, 28.26 mmol), palladium acetate (0.32 g, 1.41 mmol), sodium acetate (6.95 g, 84.78 mmol), and N,N-dimethylacetamide (350 mL) were added to a 1,000 mL three-necked round-bottom flask. After three cycles of vacuum-nitrogen purging, the mixture was heated to 130° C. and stirred to react for 4 hours. The reaction progress was monitored by TLC (developing solvent: dichloromethane:methanol=10:1) until compound A10-3 was completely consumed.

The reaction mixture was cooled to room temperature, and dichloromethane (500 mL) was added. The resulting mixture was washed three times with deionized water (300 mL×3). The layers were separated, and the organic phase was collected. The organic phase was mixed with silica gel for dry loading onto a chromatographic column, then purified by silica gel column chromatography (200-300 mesh silica gel, eluent: dichloromethane:methanol=10:1). After elution, the elute was concentrated under reduced pressure at 60° C. for 1 hour to give a white solid compound A10-5 (8.96 g, purity: 99.47%, yield: 64.11%), with a mass spectrometry of 495.17 (M+H).

### Synthesis of Compound A10

Compound A10-5 (8.50 g, 17.19 mmol) was added to a 500 mL single-necked reaction flask, followed by the addition of 300 mL of dichloromethane. The mixture was stirred until homogeneous at room temperature. Hydrogen peroxide (30%, 6.44 mL) was then slowly added dropwise. After reacting for 1 hour, a sample was taken for TLC analysis (developing solvent: dichloromethane:ethyl acetate=10:1) to monitor the reaction progress until Compound A10-5 was completely consumed.

After the reaction, the mixture was directly subjected to liquid-liquid separation. The organic phase was collected and concentrated by rotary evaporation (60° C.). The residue was purified by column chromatography using silica gel (200-300 mesh, 100 g) with an eluent (dichloromethane: ethyl acetate=7:1). After elution, the eluate was concentrated under reduced pressure at 60° C. for 1 hour to obtain a yellow, oily crude product. The yellow, oily crude product was placed in a 500 mL flask, and 200 mL of n-hexane was added for slurrying at room temperature for 2 hours. After filtration, a white solid was obtained, which was the crude product of compound A10 (4.92 g, purity: 99.92%, yield: 56.07%). After sublimation purification of 4.92 g of crude compound A10, 3.22 g of sublimed pure compound A10 (3.22 g, purity: 99.95%, yield: 65.44%) was obtained, with a mass spectrometry of 511.16 (M+H).

¹H NMR (400 MHz, CDCl₃) δ 9.18 (dd, J=14.9, 3.0 Hz, 2H), 9.14 (s, 2H), 9.09 (d, J=2.9 Hz, 1H), 8.55 (dd, J=15.0, 2.9 Hz, 2H), 8.47 (d, J=15.0 Hz, 1H), 8.17 (dd, J=15.0, 2.9 Hz, 1H), 7.83-7.69 (m, 6H), 7.56-7.47 (m, 6H), 7.27-7.19 (m, 2H).

### Synthesis of Compound A17

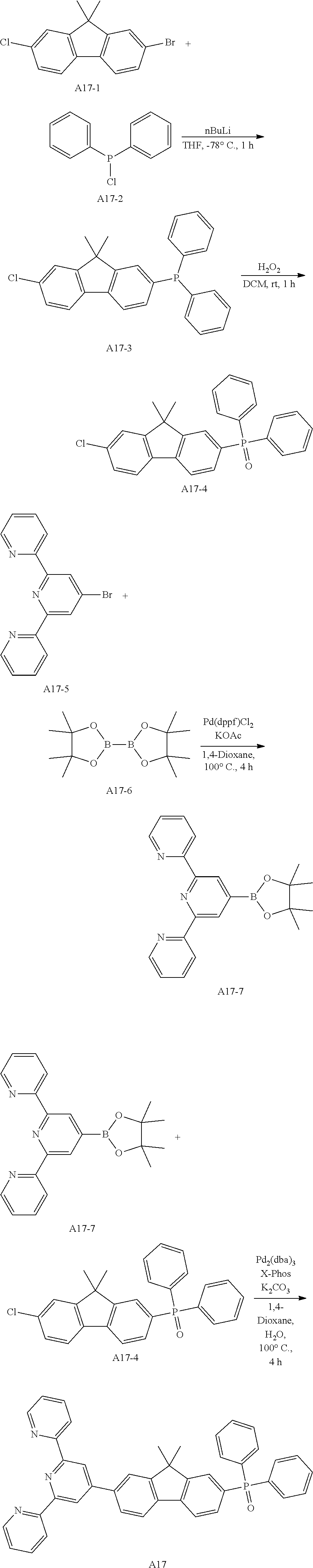

### Synthesis of Compound A17-3

Compound A17-1 (10.00 g, 32.51 mmol) and dry tetrahydrofuran (250 mL) were added to a 500 mL three-necked round-bottom flask. After three cycles of vacuum-nitrogen purging, the system was cooled to −78° C. Then, a n-hexane solution of n-butyllithium (15.60 mL, 39.01 mmol, concentration: 2.5 mol/L) was added dropwise, with the internal temperature of the system controlled not to exceed −70° C. The dropwise addition was completed in 5 minutes, and the system was stirred at −78° C. for 1 hour. Finally, compound A17-2 (8.61 g, 39.01 mmol) was added dropwise over 10 minutes. After the dropwise addition was completed, the system was naturally warmed to room temperature. The reaction progress was monitored by TLC (developing solvent: dichloromethane:methanol=10:1) to confirm that Compound A17-1 was completely consumed.

Deionized water (100 mL) was added dropwise to the system to quench the reaction, followed by liquid-liquid separation. The aqueous phase was extracted twice with dichloromethane (200 mL×2). The organic phases were combined and concentrated under reduced pressure at 65° C. for 1 hour to obtain a pale yellow oily substance as compound A17-3 (12.09 g, yield: 90.07%). The resulting compound was used directly in the next step without purification, with a mass spectrometry of 413.12 (M+H).

### Synthesis of Compound A17-4

By referring to the synthesis and purification method of compound A10, only the corresponding raw materials need to be changed to obtain the target compound A17-4 (6.97 g, purity: 99.19%, yield: 55.92%), with a mass spectrometry of 429.11 (M+H).

### Synthesis of Compound A17-7

Compound A17-5 (10.00 g, 32.03 mmol), compound A17-6 (12.20 g, 48.05 mmol), [1,1′-bis(diphenylphosphino)ferrocene]dichloropalladium (0.47 g, 0.64 mmol), potassium acetate (9.43 g, 96.10 mmol), and 1,4-dioxane (350 mL) were added to a 1,000 mL three-necked round-bottom flask. After three cycles of vacuum-nitrogen purging, the mixture was heated to 100° C. and reacted for 4 hours. The reaction progress was monitored by TLC (developing solvent: dichloromethane:methanol=5:1) to confirm that compound A17-5 was completely consumed.

The mixture was cooled to 60° C. and concentrated under reduced pressure to remove the solvent. Dichloromethane (300 mL) was added, and the resulting mixture was washed with deionized water three times (300 mL×3). The layers were separated, and the organic phase was collected. The organic phase was mixed with silica gel for dry loading onto a chromatographic column, then purified by silica gel column chromatography (200-300 mesh silica gel, eluent: dichloromethane). After elution, the eluate was concentrated under reduced pressure at 60° C. for 1 hour to obtain a white solid, which was compound A17-7 (8.79 g, purity: 99.35%, yield: 76.38%), with a mass spectrometry of 360.18 (M+H).

### Synthesis of Compound A17

Compound A17-7 (5.50 g, 15.31 mmol), compound A17-4 (6.57 g, 15.31 mmol), tris(dibenzylideneacetone)dipalladium (0.28 g, 0.31 mmol), 2-dicyclohexylphosphino-2′,4′,6′-triisopropylbiphenyl (0.36 g, 0.77 mmol), potassium carbonate (6.35 g, 45.93 mmol), 1,4-dioxane (225 mL), and deionized water (75 mL) were added to a 500 mL three-necked round-bottom flask. After three cycles of vacuum-nitrogen purging, the oil bath temperature was raised to 100° C., and the reaction was carried out for 4 hours. The reaction progress was monitored by TLC (developing solvent: dichloromethane:methanol=9:1). Once compound A17-6 was completely consumed, heating was stopped.

The reaction solution was cooled to room temperature, and dichloromethane (300 mL) was added. The resulting solution was washed three times with deionized water (300 mL×3). The layers were separated, and the organic phase was collected. The organic phase was mixed with silica gel for dry loading onto a chromatographic column, then purified by silica gel column chromatography (200-300 mesh silica gel, eluent: dichloromethane:methanol=60:1). After elution, the resulting liquid was concentrated by rotary evaporation (60° C.) to obtain 8.31 g of white solid. The resulting white solid was added to a 100 mL flask, and ethyl acetate (60 mL) was added for slurrying under reflux (80° C., 4 hours). The mixture was then filtered to obtain a filter cake, which was dried under vacuum at 90° C. for 3 hours to obtain a white solid, which was crude compound A17 (7.49 g, purity: 99.98%, yield: 78.19%). After sublimation purification of 7.49 g of crude compound A17, 5.36 g of sublimed pure compound A17 (purity: 99.99%, yield: 71.56%) were obtained, with a mass spectrometry of 626.23 (M+H).

¹H NMR (400 MHz, CDCl₃) δ 9.22 (dd, J=14.9, 3.0 Hz, 2H), 9.12 (s, 2H), 8.55 (dd, J=15.0, 2.9 Hz, 2H), 8.22 (d, J=2.9 Hz, 1H), 8.10 (dd, J=15.0, 6.0 Hz, 2H), 8.05 (d, J=3.1 Hz, 1H), 8.01 (dd, J=15.0, 2.9 Hz, 1H), 7.83-7.69 (m, 7H), 7.56-7.47 (m, 6H), 7.30-7.23 (m, 2H), 1.69 (s, 6H).

### Synthesis of Compound A30

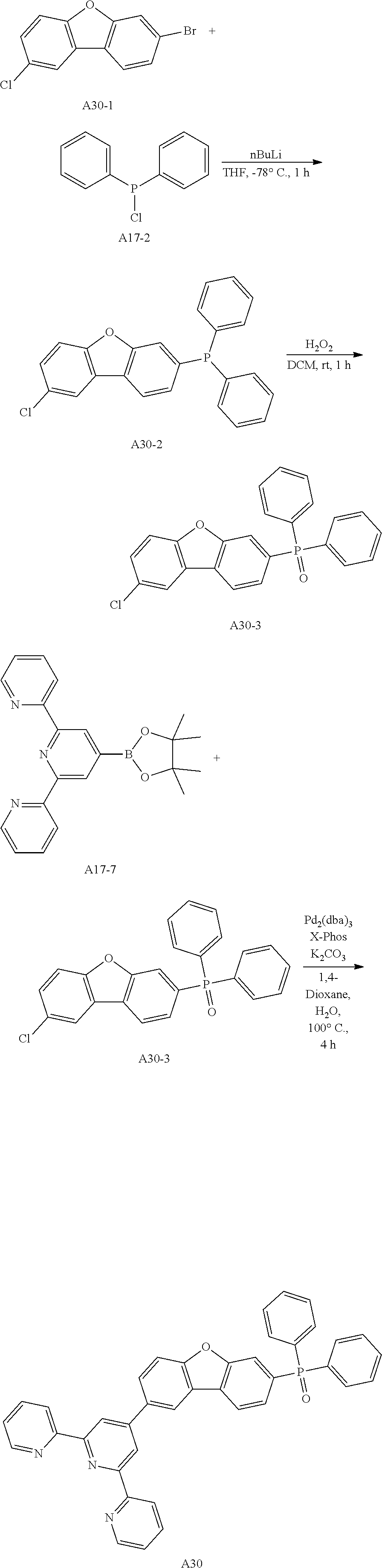

### Synthesis of Compound A30-2

By referring to the synthesis and purification method of compound A17-3, only the corresponding raw materials need to be changed to obtain the target compound A30-2 (12.29 g, yield: 89.45%), with a mass spectrometry of 387.06 (M+H).

### Synthesis of Compound A30-3

By referring to the synthesis and purification method of compound A10, only the corresponding raw materials need to be changed to obtain the target compound A30-3 (6.75 g, purity: 99.39%, yield: 54.02%), with a mass spectrometry of 403.06 (M+H).

### Synthesis of Compound A30

By referring to the synthesis and purification method of compound A17, only the corresponding raw materials need to be changed to obtain crude product of target compound A30 (6.38 g, purity: 99.94%, yield: 76.44%). After sublimation purification of 6.38 g of crude compound A30, 4.03 g of sublimed pure compound A30 (purity: 99.97%, yield: 63.20%) were obtained, with a mass spectrometry of 600.18 (M+H).

¹H NMR (400 MHz, CDCl₃) δ 9.15 (dd, J=14.9, 3.0 Hz, 2H), 9.14 (s, 2H), 8.55 (dd, J=15.0, 2.9 Hz, 2H), 8.27 (dd, J=11.0, 2.8 Hz, 2H), 7.84-7.60 (m, 10H), 7.56-7.47 (m, 6H), 7.29-7.24 (m, 2H).

### Synthesis of Compound A32

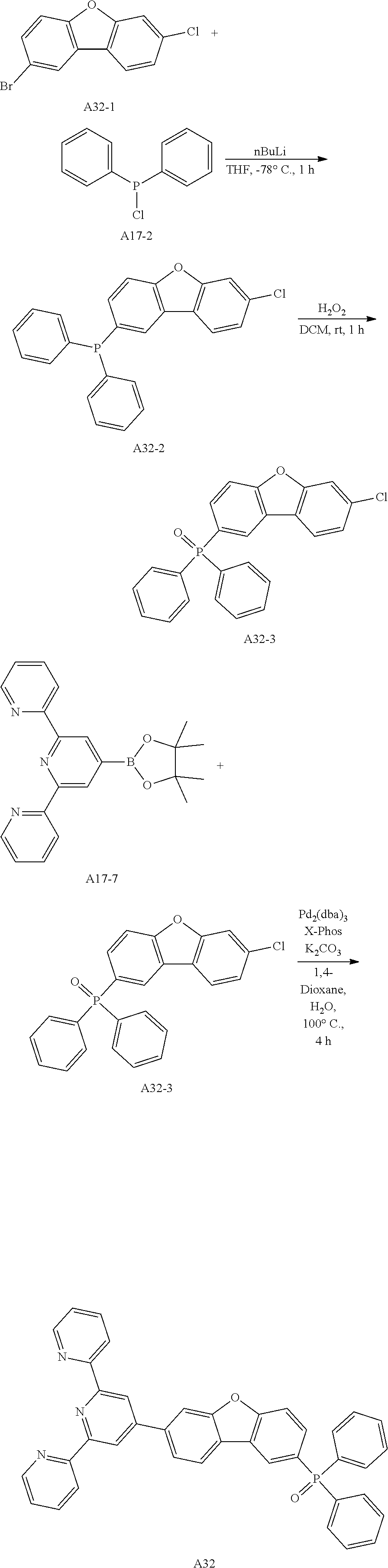

### Synthesis of Compound A32-2

By referring to the synthesis and purification method of compound A17-3, only the corresponding raw materials need to be changed to obtain the target compound A32-2 (12.50 g, yield: 90.98%), with a mass spectrometry of 387.06 (M+H).

### Synthesis of Compound A32-3

By referring to the synthesis and purification method of compound A10, only the corresponding raw materials need to be changed to obtain the target compound A32-3 (7.48 g, purity: 99.52%, yield: 59.86%), with a mass spectrometry of 403.06 (M+H).

### Synthesis of Compound A32

By referring to the synthesis and purification method of compound A17, only the corresponding raw materials need to be changed to obtain crude product of target compound A32 (8.07 g, purity: 99.92%, yield: 74.38%). After sublimation purification of 8.07 g of crude compound A32, 5.22 g of sublimed pure compound A32 (purity: 99.95%, yield: 64.68%) were obtained, with a mass spectrometry of 600.18 (M+H).

¹H NMR (400 MHz, CDCl₃) δ 9.12 (dd, J=14.9, 3.0 Hz, 2H), 9.09 (s, 2H), 8.55 (dd, J=15.0, 2.9 Hz, 2H), 8.50 (d, J=3.1 Hz, 1H), 8.01 (d, J=3.1 Hz, 1H), 7.87 (dd, J=15.0, 2.9 Hz, 1H), 7.82-7.68 (m, 8H), 7.60-7.48 (m, 7H), 7.28-7.18 (m, 2H).

### Synthesis of Compound A33

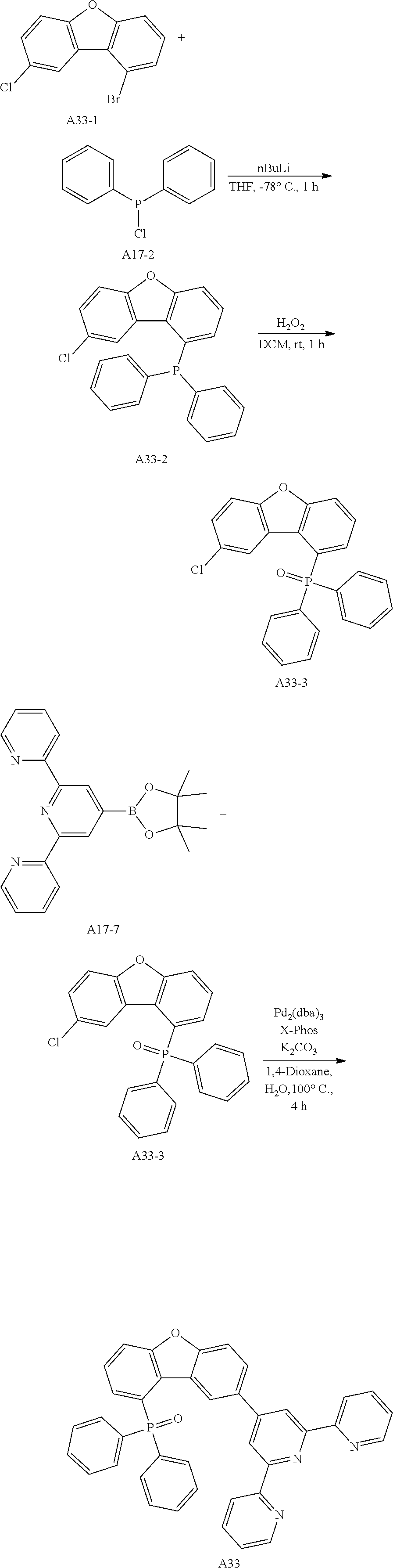

### Synthesis of Compound A33-2

By referring to the synthesis and purification method of compound A17-3, only the corresponding raw materials need to be changed to obtain the target compound A33-2 (12.08 g, yield: 87.92%), with a mass spectrometry of 387.06 (M+H).

### Synthesis of Compound A33-3

By referring to the synthesis and purification method of compound A10, only the corresponding raw materials need to be changed to obtain the target compound A33-3 (5.97 g, purity: 99.24%, yield: 49.85%), with a mass spectrometry of 403.06 (M+H).

### Synthesis of Compound A33

By referring to the synthesis and purification method of compound A17, only the corresponding raw materials need to be changed to obtain crude product of target compound A33 (5.72 g, purity: 99.90%, yield: 68.54%). After sublimation purification of 5.72 g of crude compound A33, 3.85 g of sublimed pure compound A33 (purity: 99.90%, yield: 67.30%) were obtained, with a mass spectrometry of 600.18 (M+H).

¹H NMR (400 MHz, CDCl₃) δ 9.20 (dd, J=14.9, 3.0 Hz, 2H), 9.14 (s, 2H), 8.55 (dd, J=15.0, 2.9 Hz, 2H), 8.37 (d, J=2.9 Hz, 1H), 7.82-7.72 (m, 7H), 7.72-7.66 (m, 3H), 7.63 (dd, J=15.0, 2.7 Hz, 1H), 7.56-7.46 (m, 6H), 7.26-7.19 (m, 2H).

### Synthesis of Compound A38

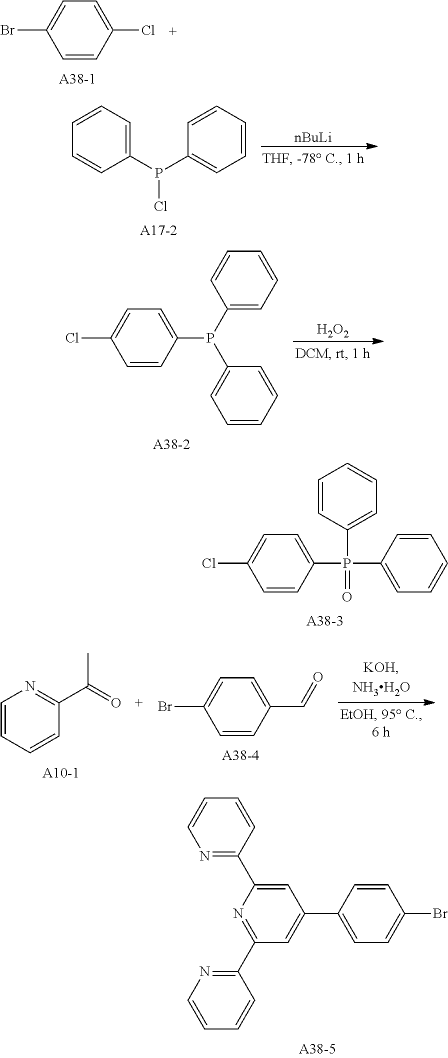

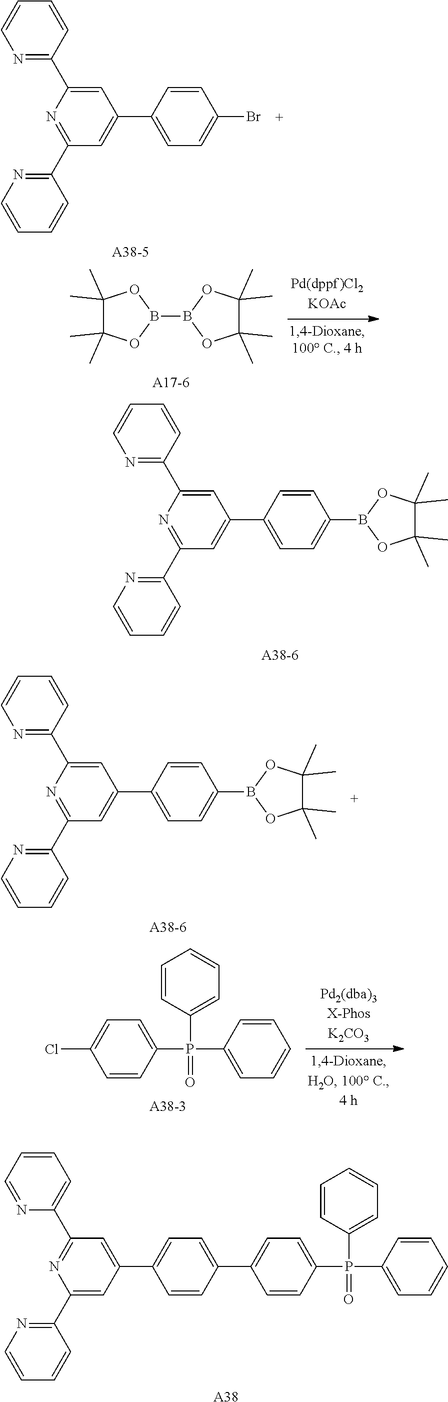

### Synthesis of Compound A38-2

By referring to the synthesis and purification method of compound A17-3, only the corresponding raw materials need to be changed to obtain the target compound A38-2 (14.07 g, yield: 90.78%), with a mass spectrometry of 297.05 (M+H).

### Synthesis of Compound A38-3

By referring to the synthesis and purification method of compound A10, only the corresponding raw materials need to be changed to obtain the target compound A38-3 (8.43 g, purity: 99.41%, yield: 57.13%), with a mass spectrometry of 313.05 (M+H).

### Synthesis of Compound A38-5

By referring to the synthesis and purification method of compound A10-3, only the corresponding raw materials need to be changed to obtain the target compound A38-5 (19.76 g, purity: 99.67%, yield: 61.65%), with a mass spectrometry of 388.04 (M+H).

### Synthesis of Compound A38-6

By referring to the synthesis and purification method of compound A17-7, only the corresponding raw materials need to be changed to obtain the target compound A38-6 (17.15 g, purity: 99.17%, yield: 78.44%), with a mass spectrometry of 436.21 (M+H).

### Synthesis of Compound A38

By referring to the synthesis and purification method of compound A17, only the corresponding raw materials need to be changed to obtain crude product of target compound A38 (8.28 g, purity: 99.96%, yield: 76.94%). After sublimation purification of 8.28 g of crude compound A38, 5.75 g of sublimed pure compound A38 (purity: 99.98%, yield: 69.44%) were obtained, with a mass spectrometry of 586.20 (M+H).

¹H NMR (400 MHz, CDCl₃) δ 8.77 (s, 2H), 8.72 (d, J=4.1 Hz, 2H), 8.67 (d, J=7.9 Hz, 2H), 7.99 (d, J=8.2 Hz, 2H), 7.87 (t, J=7.7 Hz, 2H), 7.81-7.68 (m, 10H), 7.55 (d, J=7.4 Hz, 2H), 7.49 (dd, J=10.0, 4.6 Hz, 4H), 7.37-7.32 (m, 2H).

### Synthesis of Compound A59

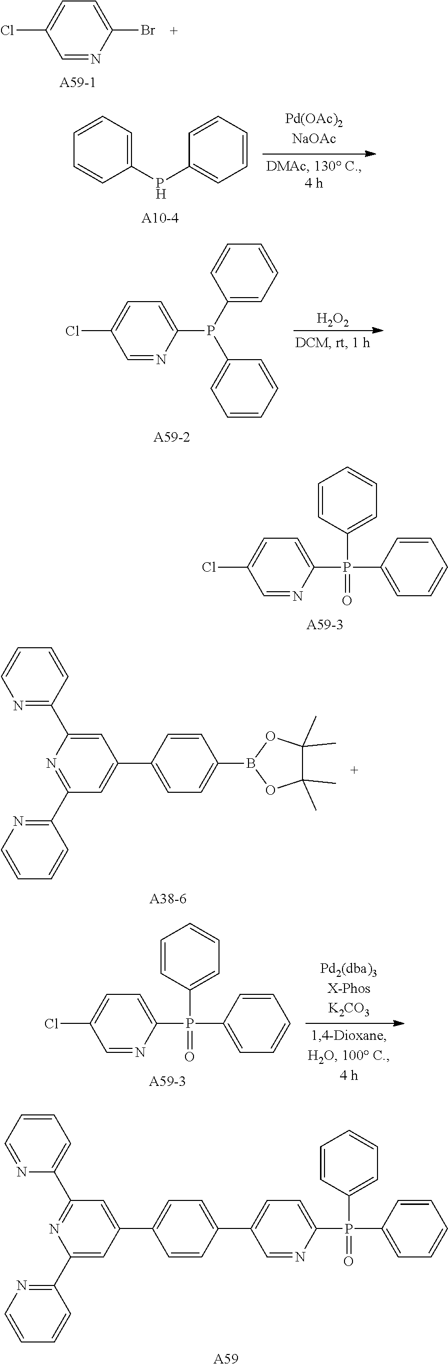

### Synthesis of Compound A59-2

By referring to the synthesis and purification method of compound A10-5, only the corresponding raw materials need to be changed to obtain the target compound A59-2 (11.60 g, purity: 99.71%, yield: 74.98%), with a mass spectrometry of 298.05 (M+H).

### Synthesis of Compound A59-3

By referring to the synthesis and purification method of compound A10, only the corresponding raw materials need to be changed to obtain the target compound A59-3 (7.81 g, purity: 99.42%, yield: 64.45%), with a mass spectrometry of 314.04 (M+H).

### Synthesis of Compound A59

By referring to the synthesis and purification method of compound A17, only the corresponding raw materials need to be changed to obtain the crude product of the target compound A59 (7.86 g, purity: 99.97%, yield: 72.91%). After sublimation purification of 7.86 g of crude compound A59, 5.16 g of sublimed pure compound A59 (purity: 99.94%, yield: 65.64%) were obtained, with a mass spectrometry of 587.19 (M+H).

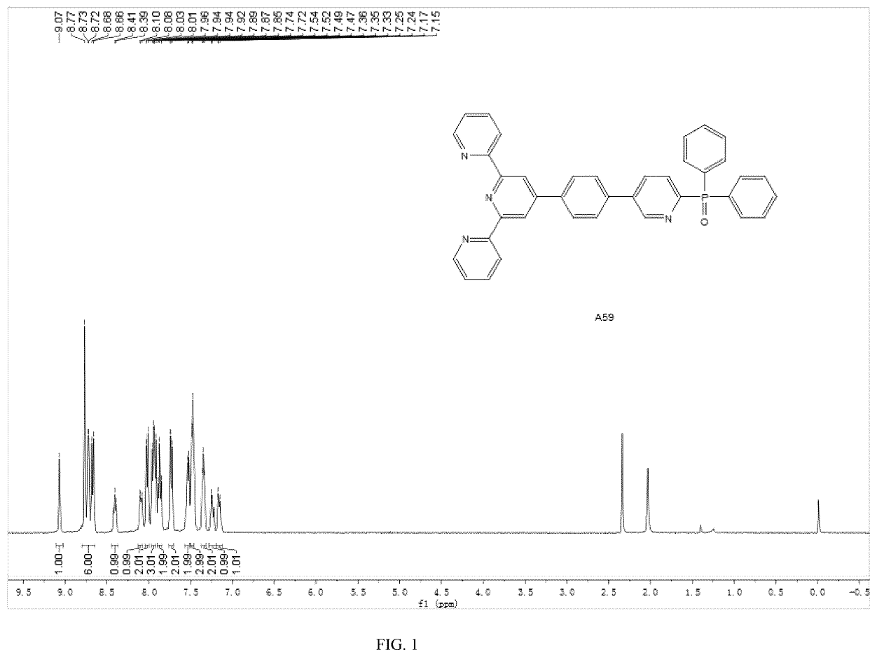

¹H NMR (400 MHz, CDCl₃) δ 9.07 (s, 1H), 8.80-8.64 (m, 6H), 8.40 (d, J=7.2 Hz, 1H), 8.09 (d, J=7.5 Hz, 1H), 8.02 (d, J=8.0 Hz, 2H), 7.97-7.92 (m, 3H), 7.87 (t, J=7.7 Hz, 2H), 7.73 (d, J=8.0 Hz, 2H), 7.53 (d, J=6.7 Hz, 2H), 7.48 (d, J=5.7 Hz, 3H), 7.37-7.31 (m, 2H), 7.25 (d, J=4.2 Hz, 1H), 7.16 (d, J=7.5 Hz, 1H) The ¹H NMR spectrum was shown in FIG. 1.

### Synthesis of Compound A68

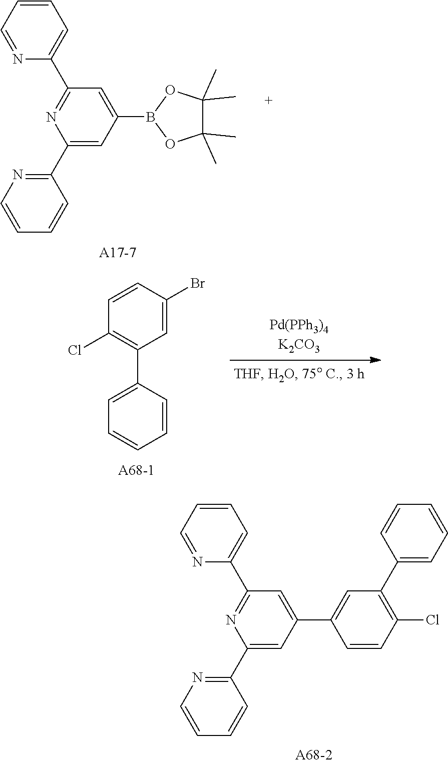 [SMILES: CC1(C)OB(c2cc(-c3ccccn3)nc(-c3ccccn3)c2)OC1(C)C ; Clc1ccc(Br)cc1-c1ccccc1 ; Clc1ccc(-c2cc(-c3ccccn3)nc(-c3ccccn3)c2)cc1-c1ccccc1]

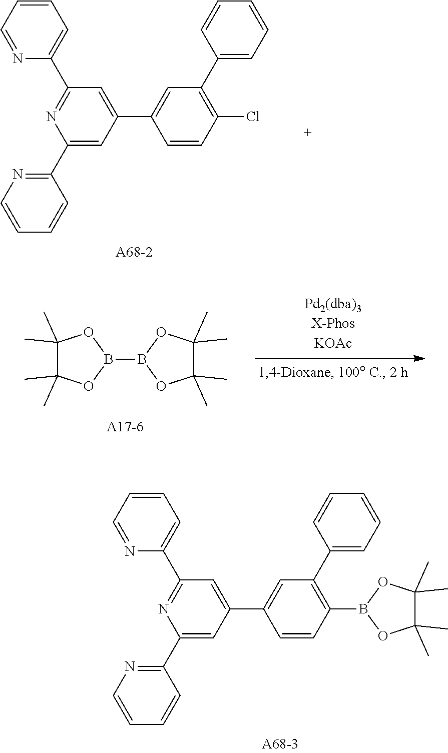

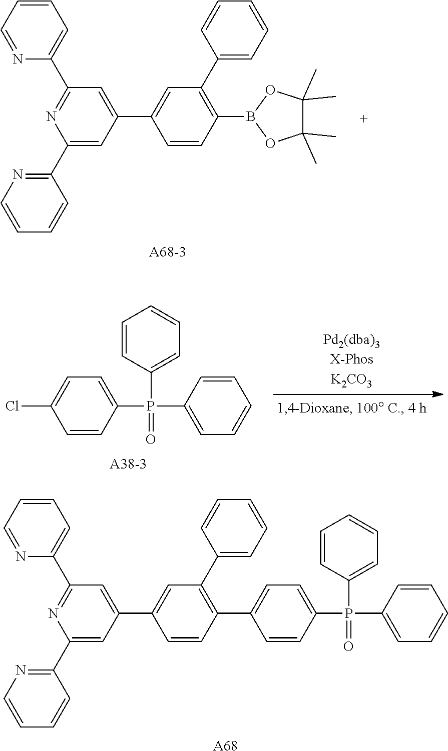 [SMILES: CC1(C)OB(c2ccc(-c3cc(-c4ccccn4)nc(-c4ccccn4)c3)cc2-c2ccccc2)OC1(C)C ; O=P(c1ccccc1)(c1ccccc1)c1ccc(Cl)cc1 ; O=P(c1ccccc1)(c1ccccc1)c1ccc(-c2ccc(-c3cc(-c4ccccn4)nc(-c4ccccn4)c3)cc2-c2ccccc2)cc1 ; "A68"]

### Synthesis of Compound A68-2

By referring to the synthesis and purification method of compound A17, only the corresponding raw materials need to be changed to obtain the target compound A68-2 (8.82 g, purity: 99.40%, yield: 75.46%), with a mass spectrometry of 420.12 (M+H).

### Synthesis of Compound A68-3

By referring to the synthesis and purification method of compound A17-7, only the corresponding raw materials need to be changed to obtain the target compound A68-3 (8.11 g, purity: 99.26%, yield: 78.34%), with a mass spectrometry of 512.24 (M+H).

### Synthesis of Compound A68

By referring to the synthesis and purification method of compound A17, only the corresponding raw materials need to be changed to obtain the crude product of the target compound A68 (7.42 g, purity: 99.96%, yield: 71.68%). 7.42 g of crude compound A68 were sublimated and purified to obtain sublimed pure compound A68 (5.17 g, purity: 99.99%, yield: 69.70%), with a mass spectrometry of 662.23 (M+H).

¹H NMR (400 MHz, CDCl₃) δ 9.19 (dd, J=14.9, 3.0 Hz, 2H), 9.10 (s, 2H), 8.55 (dd, J=15.0, 2.9 Hz, 2H), 8.22 (d, J=2.9 Hz, 1H), 8.15 (d, J=15.0 Hz, 1H), 7.97 (s, 4H), 7.83-7.70 (m, 8H), 7.57-7.32 (m, 10H), 7.27-7.18 (m, 2H).

### Synthesis of Compound A78

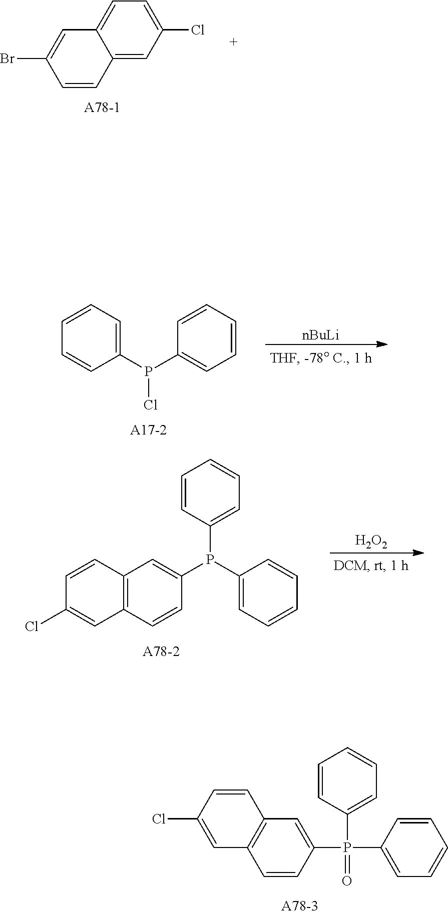

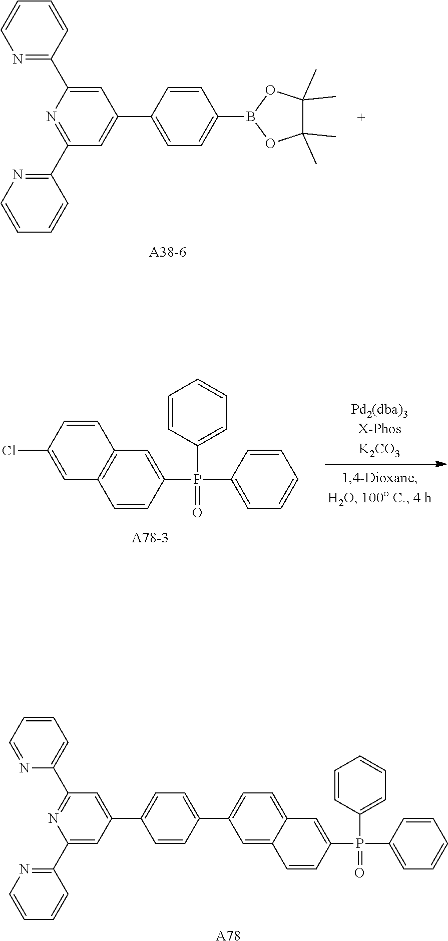 [SMILES: CC1(C)OB(c2ccc(-c3cc(-c4ccccn4)nc(-c4ccccn4)c3)cc2)OC1(C)C ; O=P(c1ccccc1)(c1ccccc1)c1ccc2cc(Cl)ccc2c1 ; O=P(c1ccccc1)(c1ccccc1)c1ccc2cc(-c3ccc(-c4cc(-c5ccccn5)nc(-c5ccccn5)c4)cc3)ccc2c1 ; "A78"]

### Synthesis of Compound A78-2

By referring to the synthesis and purification method of compound A17-3, only the corresponding raw materials need to be changed to obtain the target compound A78-2 (13.41 g, yield: 93.39%), with a mass spectrometry of 347.07 (M+H).

### Synthesis of Compound A78-3

By referring to the synthesis and purification method of compound A10, only the corresponding raw materials need to be changed to obtain the target compound A78-3 (7.30 g, purity: 99.52%, yield: 52.08%), with a mass spectrometry of 363.06 (M+H).

### Synthesis of Compound A78

By referring to the synthesis and purification method of compound A17, only the corresponding raw materials need to be changed to obtain the crude product of the target compound A78 (8.21 g, purity: 99.90%, yield: 70.28%). After sublimation purification of 8.21 g of crude compound A78, 5.31 g of sublimed pure compound A78 (purity: 99.96%, yield: 64.78%) were obtained, with a mass spectrometry of 636.21 (M+H).

¹H NMR (400 MHz, CDCl₃) δ 9.18 (dd, J=14.9, 3.0 Hz, 2H), 9.14 (s, 2H), 8.64-8.61 (m, 1H), 8.55 (dd, J=15.0, 2.9 Hz, 2H), 8.02-7.95 (m, 3H), 7.83-7.70 (m, 6H), 7.57-7.47 (m, 7H), 7.38 (dd, J=15.0, 3.1 Hz, 1H), 7.28-7.19 (m, 6H).

### Synthesis of Compound A99

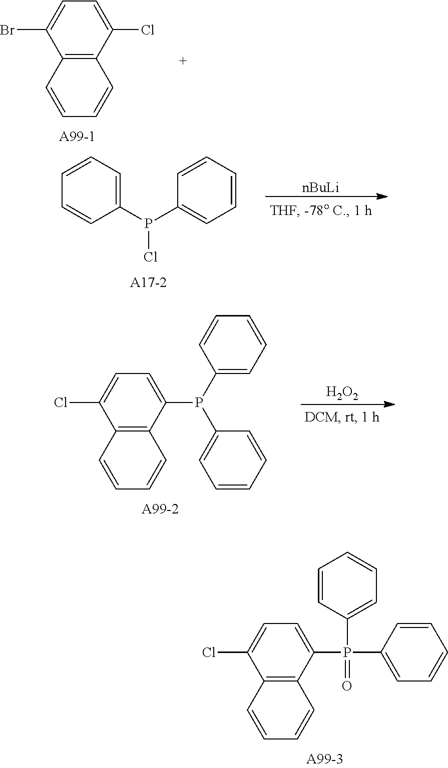

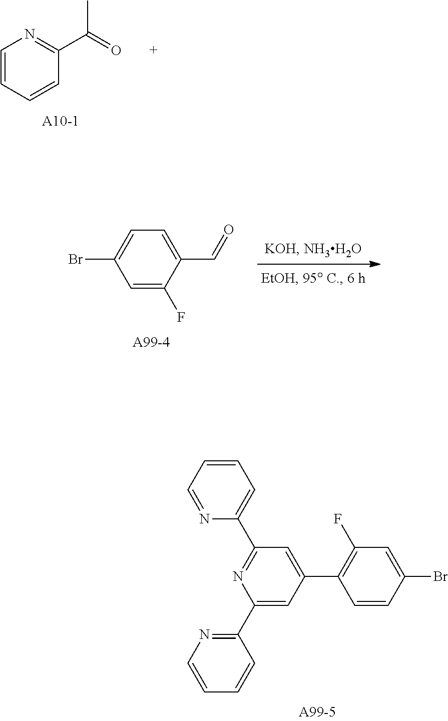

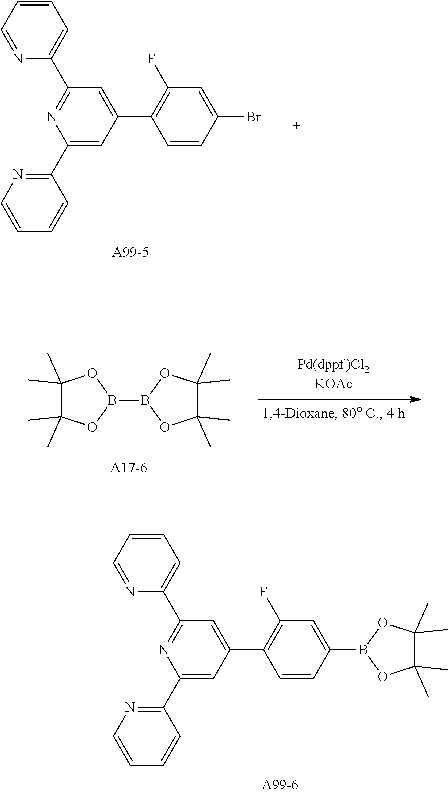

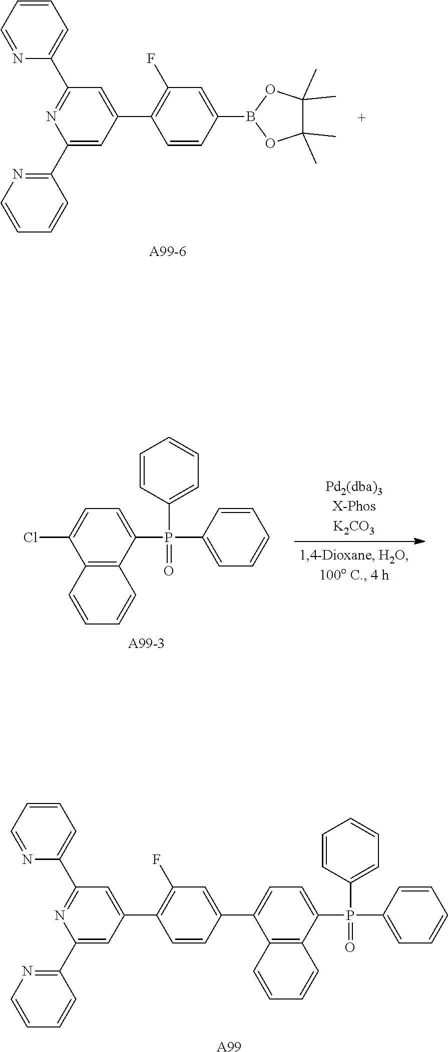 [SMILES: CC1(C)OB(c2ccc(-c3cc(-c4ccccn4)nc(-c4ccccn4)c3)c(F)c2)OC1(C)C ; O=P(c1ccccc1)(c1ccccc1)c1ccc(Cl)c2ccccc12 ; O=P(c1ccccc1)(c1ccccc1)c1ccc(-c2ccc(-c3cc(-c4ccccn4)nc(-c4ccccn4)c3)c(F)c2)c2ccccc12 ; "A99"]

### Synthesis of Compound A99-2

By referring to the synthesis and purification method of compound A17-3, only the corresponding raw materials need to be changed to obtain the target compound A99-2 (12.85 g, yield: 89.49%), with a mass spectrometry of 347.07 (M+H).

### Synthesis of Compound A99-3

By referring to the synthesis and purification method of compound A10, only the corresponding raw materials need to be changed to obtain the target compound A99-3 (7.62 g, purity: 99.34%, yield: 58.27%), with a mass spectrometry of 363.06 (M+H).

### Synthesis of Compound A99-5

By referring to the synthesis and purification method of compound A10-3, only the corresponding raw materials need to be changed to obtain the target compound A99-5 (9.42 g, purity: 99.50%, yield: 56.18%), with a mass spectrometry of 406.03 (M+H).

### Synthesis of Compound A99-6

By referring to the synthesis and purification method of compound A17-7, only the corresponding raw materials need to be changed to obtain the target compound A99-6 (7.76 g, purity: 99.33%, yield: 77.27%), with a mass spectrometry of 454.20 (M+H).

### Synthesis of Compound A99

By referring to the synthesis and purification method of compound A17, only the corresponding raw materials need to be changed to obtain the crude product of the target compound A99 (7.62 g, purity: 99.95%, Yield: 75.49%). After sublimation purification of 7.62 g of crude compound A99, 5.05 g of sublimed pure compound A99 (purity: 99.97%, yield: 66.40%) were obtained, with a mass spectrometry of 654.20 (M+H).

¹H NMR (400 MHz, CDCl₃) δ 9.15 (dd, J=14.9, 3.0 Hz, 2H), 9.07 (s, 2H), 8.95 (dd, J=14.2, 3.7 Hz, 1H), 8.55 (dd, J=15.0, 2.9 Hz, 2H), 7.98-7.86 (m, 3H), 7.83-7.68 (m, 7H), 7.57 (d, J=15.0 Hz, 1H), 7.54-7.48 (m, 6H), 7.45-7.29 (m, 2H), 7.27-7.19 (m, 2H), 7.02 (dd, J=15.0, 2.9 Hz, 1H).

### Synthesis of Compound A106

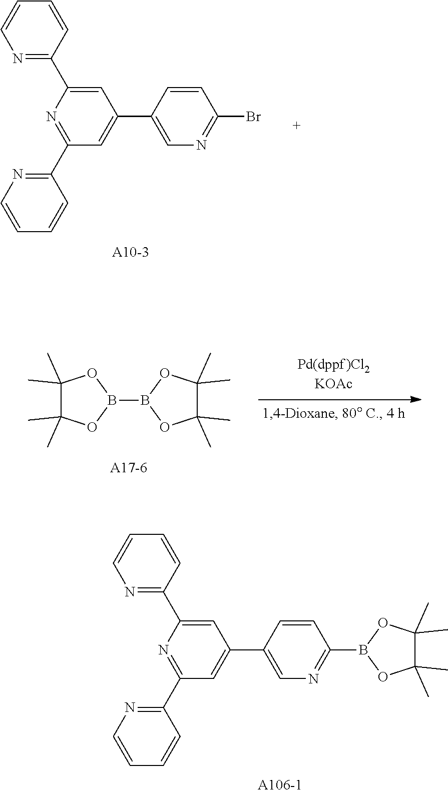

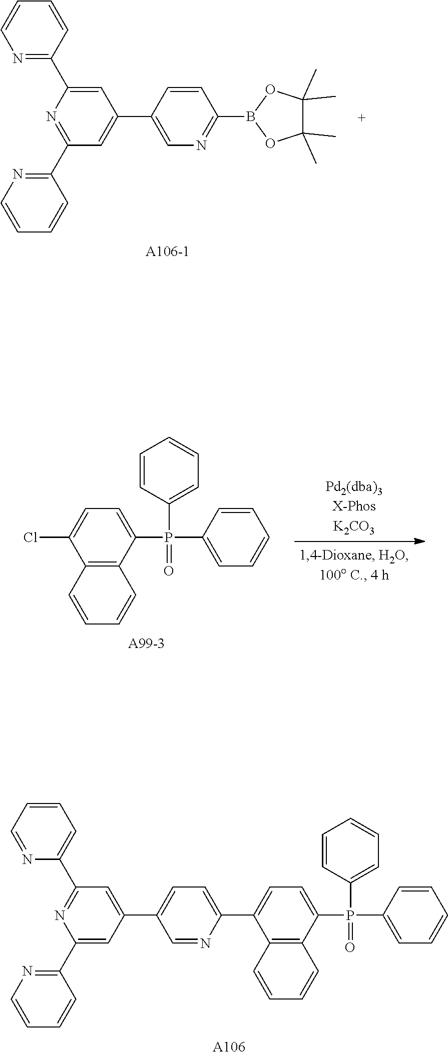 [SMILES: CC1(C)OB(c2ccc(-c3cc(-c4ccccn4)nc(-c4ccccn4)c3)cn2)OC1(C)C ; O=P(c1ccccc1)(c1ccccc1)c1ccc(Cl)c2ccccc12 ; O=P(c1ccccc1)(c1ccccc1)c1ccc(-c2ccc(-c3cc(-c4ccccn4)nc(-c4ccccn4)c3)cn2)c2ccccc12 ; "A106"]

### Synthesis of Compound A106-1

By referring to the synthesis and purification method of compound A17-7, only the corresponding raw materials need to be changed to obtain the target compound A106-1 (8.51 g, purity: 99.26%, yield: 75.92%), with a mass spectrometry of 437.21 (M+H).

### Synthesis of Compound A106

By referring to the synthesis and purification method of compound A17, only the corresponding raw materials need to be changed to obtain the crude product of the target compound A106 (7.92 g, purity: 99.95%, yield: 67.84%). After sublimation purification of 7.92 g of crude compound A106, 5.06 g of sublimed pure compound A106 (purity: 99.95%, yield: 63.88%) were obtained, with a mass spectrometry of 637.21 (M+H).

¹H NMR (400 MHz, CDCl₃) δ 9.18 (dd, J=14.9, 3.0 Hz, 2H), 9.14 (s, 2H), 9.00-8.94 (m, 2H), 8.55 (dd, J=15.0, 2.9 Hz, 2H), 8.41 (d, J=15.0 Hz, 1H), 8.06-7.95 (m, 3H), 7.87-7.70 (m, 7H), 7.55-7.44 (m, 8H), 7.28-7.18 (m, 2H).

### Synthesis of Compound A116

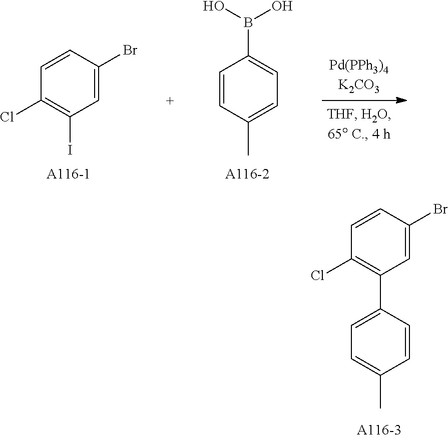

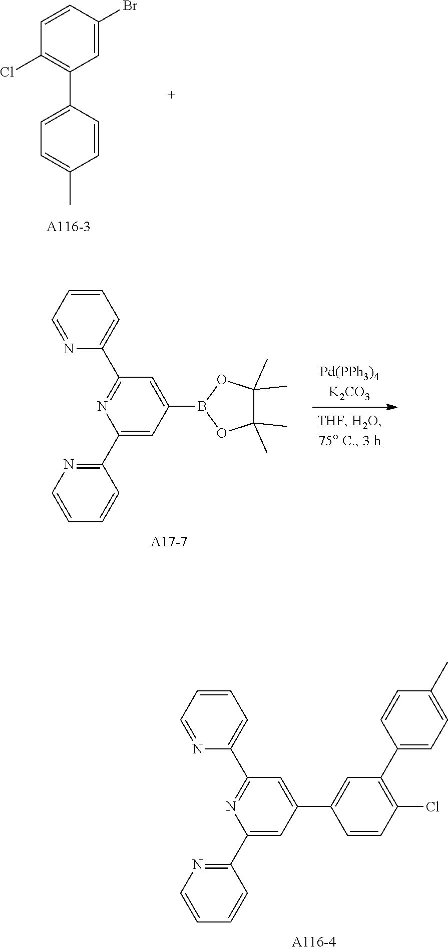 [SMILES: Cc1ccc(-c2cc(Br)ccc2Cl)cc1 ; CC1(C)OB(c2cc(-c3ccccn3)nc(-c3ccccn3)c2)OC1(C)C ; Cc1ccc(-c2cc(-c3cc(-c4ccccn4)nc(-c4ccccn4)c3)ccc2Cl)cc1]

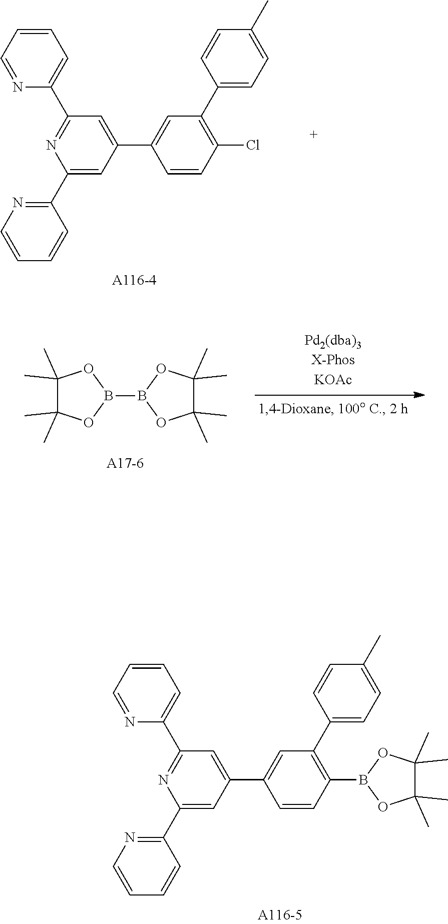

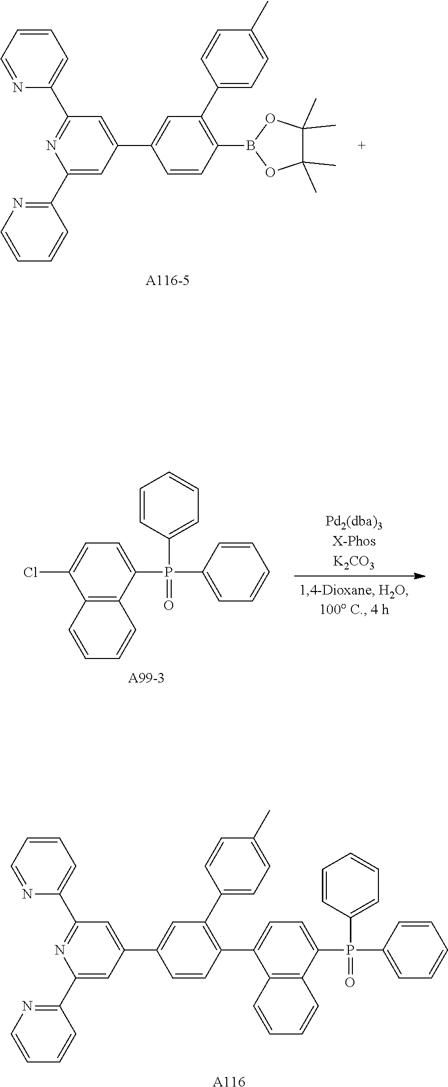 [SMILES: Cc1ccc(-c2cc(-c3cc(-c4ccccn4)nc(-c4ccccn4)c3)ccc2B2OC(C)(C)C(C)(C)O2)cc1 ; O=P(c1ccccc1)(c1ccccc1)c1ccc(Cl)c2ccccc12 ; Cc1ccc(-c2cc(-c3cc(-c4ccccn4)nc(-c4ccccn4)c3)ccc2-c2ccc(P(=O)(c3ccccc3)c3ccccc3)c3ccccc23)cc1 ; "A116"]

### Synthesis of Compound A116-3

By referring to the synthesis and purification method of compound A17, only the corresponding raw materials need to be changed to obtain the target compound A116-3 (10.82 g, purity: 99.46%, yield: 73.26%), with a mass spectrometry of 280.96 (M+H).

### Synthesis of Compound A116-4

By referring to the synthesis and purification method of compound A17, only the corresponding raw materials need to be changed to obtain the target compound A116-4 (9.72 g, purity: 99.35%, yield: 78.16%), with a mass spectrometry of 434.13 (M+H).

### Synthesis of Compound A116-5

By referring to the synthesis and purification method of compound A17-7, only the corresponding raw materials need to be changed to obtain the target compound A116-5 (8.37 g, purity: 99.52%, yield: 76.50%), with a mass spectrometry of 526.26 (M+H).

### Synthesis of Compound A116

By referring to the synthesis and purification method of compound A17, only the corresponding raw materials need to be changed to obtain the crude product of the target compound A116 (6.13 g, purity: 99.94%, yield: 70.73%). After sublimation purification of 6.13 g of crude compound A116, 3.70 g of sublimed pure compound A116 (purity: 99.98%, yield: 60.35%) were obtained, with a mass spectrometry of 726.26 (M+H).

¹H NMR (400 MHz, CDCl₃) δ 9.18 (dd, J=7.5, 1.6 Hz, 2H), 9.10 (s, 2H), 8.95 (dd, J=7.4, 1.5 Hz, 1H), 8.55 (dd, J=7.5, 1.4 Hz, 2H), 8.25 (d, J=1.4 Hz, 1H), 8.15 (d, J=7.5 Hz, 1H), 7.89 (dd, J=7.4, 1.5 Hz, 1H), 7.82 (d, J=7.5 Hz, 1H), 7.80-7.71 (m, 6H), 7.57 (d, J=7.5 Hz, 1H), 7.53-7.47 (m, 8H), 7.42-7.38 (m, 1H), 7.36-7.32 (m, 2H), 7.25-7.21 (m, 2H), 7.16 (d, J=7.5 Hz, 2H), 2.34 (s, 3H).

### Synthesis of Compound A131

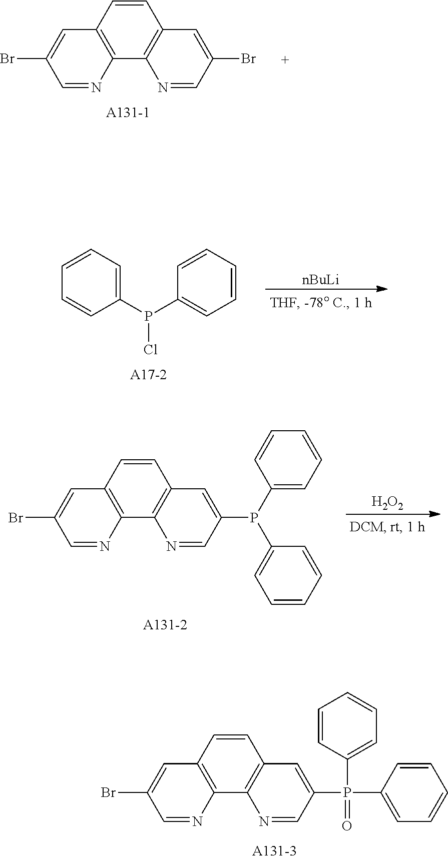

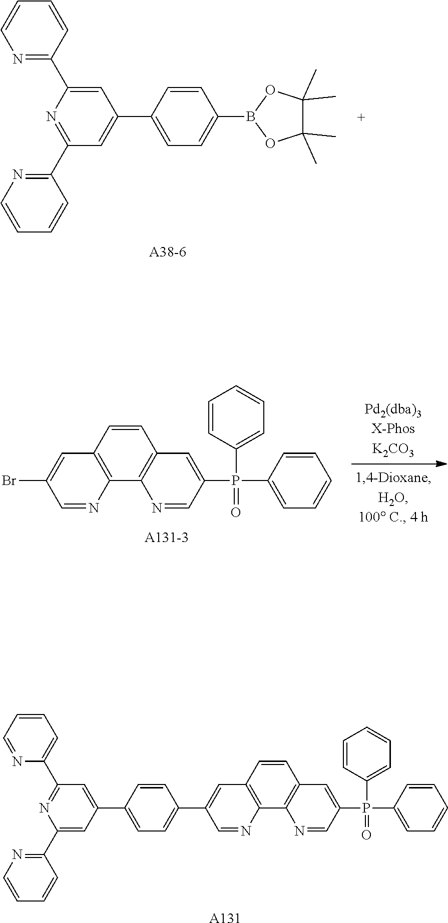 [SMILES: CC1(C)OB(c2ccc(-c3cc(-c4ccccn4)nc(-c4ccccn4)c3)cc2)OC1(C)C ; O=P(c1ccccc1)(c1ccccc1)c1cnc2c(ccc3cc(Br)cnc32)c1 ; O=P(c1ccccc1)(c1ccccc1)c1cnc2c(ccc3cc(-c4ccc(-c5cc(-c6ccccn6)nc(-c6ccccn6)c5)cc4)cnc32)c1 ; "A131"]

### Synthesis of Compound A131-2

By referring to the synthesis and purification method of compound A17-3, only the corresponding raw materials need to be changed to obtain the target compound A131-2 (11.95 g, yield: 87.62%), with a mass spectrometry of 443.02 (M+H).

### Synthesis of Compound A131-3

By referring to the synthesis and purification method of compound A10, only the corresponding raw materials need to be changed to obtain the target compound A131-3 (6.75 g, purity: 99.59%, yield: 57.34%), with a mass spectrometry of 459.02 (M+H).

### Synthesis of Compound A131

By referring to the synthesis and purification method of compound A17, only the corresponding raw materials need to be changed to obtain crude product of target compound A131 (7.03 g, purity: 99.93%, yield: 72.46%). After sublimation purification of 7.03 g of crude compound A131, 4.59 g of sublimed pure compound A131 (purity: 99.98%, yield: 65.29%) were obtained, with a mass spectrometry of 688.22 (M+H).

¹H NMR (400 MHz, CDCl₃) δ 9.61 (d, J=2.9 Hz, 1H), 9.18 (dd, J=14.9, 3.0 Hz, 2H), 9.14 (s, 2H), 8.60 (t, J=3.0 Hz, 1H), 8.55 (dd, J=15.0, 2.9 Hz, 2H), 8.49 (t, J=3.0 Hz, 1H), 8.26 (d, J=3.1 Hz, 1H), 7.85-7.70 (m, 7H), 7.57 (dd, J=15.0, 2.9 Hz, 1H), 7.54-7.48 (m, 6H), 7.27-7.19 (m, 6H).

### Synthesis of Compound A155

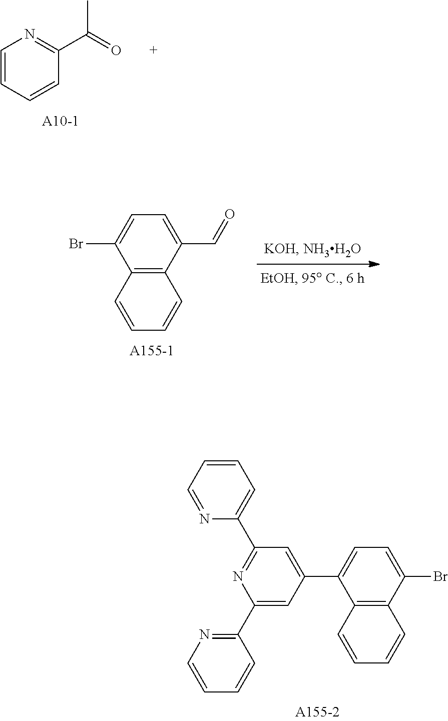

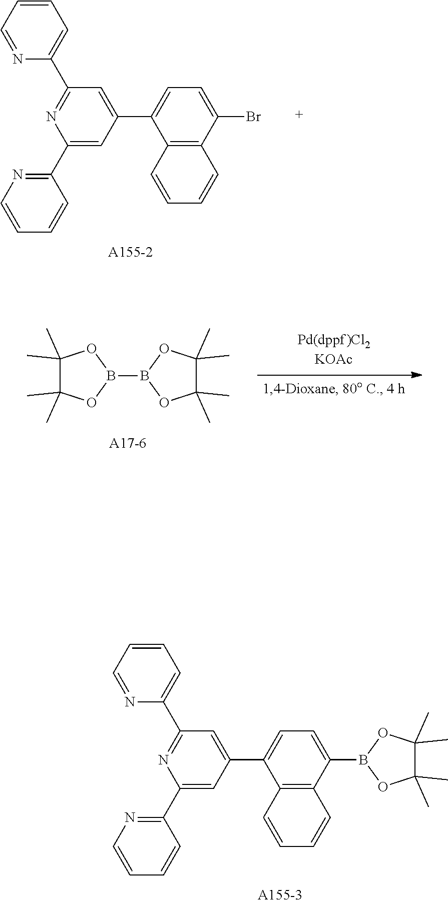

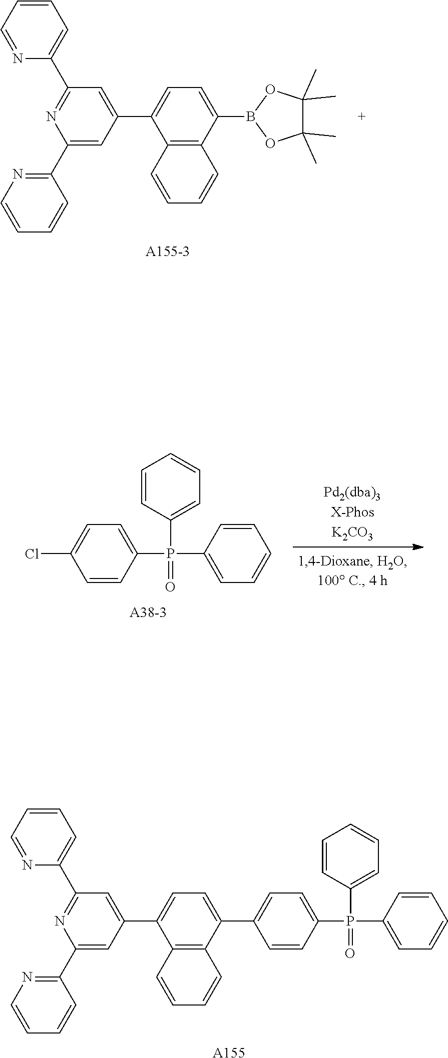 [SMILES: CC1(C)OB(c2ccc(-c3cc(-c4ccccn4)nc(-c4ccccn4)c3)c3ccccc23)OC1(C)C ; O=P(c1ccccc1)(c1ccccc1)c1ccc(Cl)cc1 ; O=P(c1ccccc1)(c1ccccc1)c1ccc(-c2ccc(-c3cc(-c4ccccn4)nc(-c4ccccn4)c3)c3ccccc23)cc1 ; "A155"]

### Synthesis of Compound A155-2

By referring to the synthesis and purification method of compound A10-3, only the corresponding raw materials need to be changed to obtain the target compound A155-2 (9.58 g, purity: 99.37%, yield: 52.95%), with a mass spectrometry of 438.05 (M+H).

### Synthesis of Compound A155-3

By referring to the synthesis and purification method of compound A17-7, only the corresponding raw materials need to be changed to obtain the target compound A155-3 (7.92 g, purity: 99.55%, yield: 75.28%), with a mass spectrometry of 486.23 (M+H).

### Synthesis of Compound A155

By referring to the synthesis and purification method of compound A17, only the corresponding raw materials need to be changed to obtain the crude product of the target compound A155 (7.37 g, purity: 99.92%, yield: 75.03%). After sublimation purification of 7.37 g of crude compound A155, 4.83 g of sublimed pure compound A155 (purity: 99.95%, yield: 65.60%) were obtained, with a mass spectrometry of 636.21 (M+H).

¹H NMR (400 MHz, CDCl₃) δ 9.18 (dd, J=7.5, 1.6 Hz, 2H), 9.14 (s, 2H), 9.02 (dd, J=7.5, 1.6 Hz, 1H), 8.95 (dd, J=7.4, 1.5 Hz, 1H), 8.55 (dd, J=7.5, 1.4 Hz, 2H), 7.97 (s, 4H), 7.81-7.72 (m, 7H), 7.56 (d, J=7.5 Hz, 1H), 7.53-7.48 (m, 6H), 7.42-7.38 (m, 1H), 7.36-7.31 (m, 1H), 7.25-7.20 (m, 2H).

### Synthesis of Compound A184

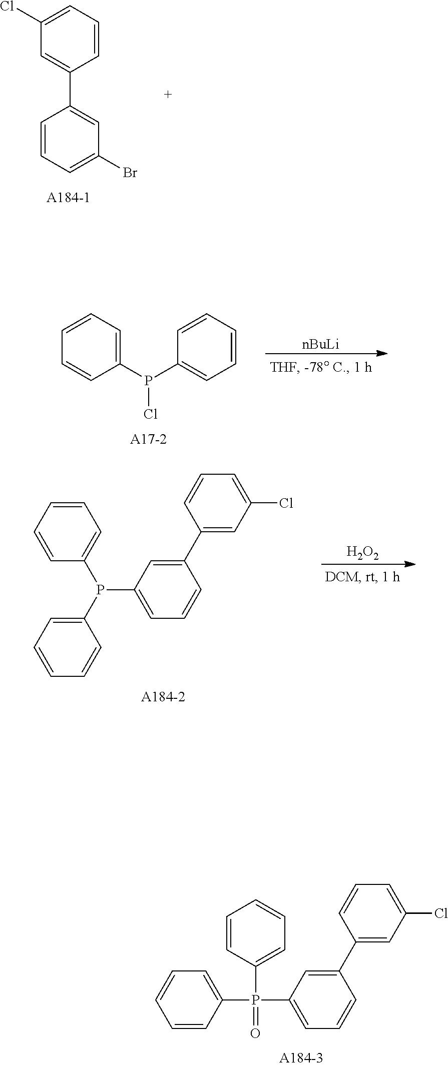

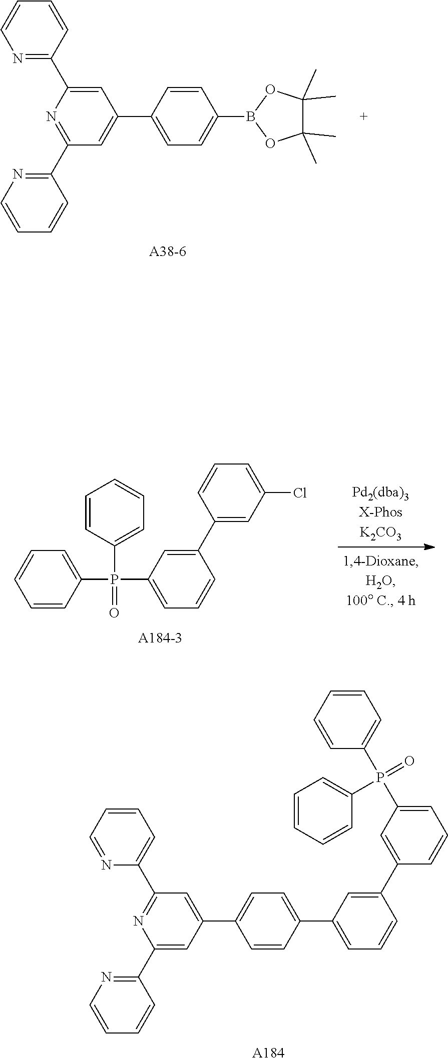 [SMILES: CC1(C)OB(c2ccc(-c3cc(-c4ccccn4)nc(-c4ccccn4)c3)cc2)OC1(C)C ; O=P(c1ccccc1)(c1ccccc1)c1cccc(-c2cccc(Cl)c2)c1 ; O=P(c1ccccc1)(c1ccccc1)c1cccc(-c2cccc(-c3ccc(-c4cc(-c5ccccn5)nc(-c5ccccn5)c4)cc3)c2)c1 ; "A184"]

### Synthesis of Compound A184-2

By referring to the synthesis and purification method of compound A10-5, only the corresponding raw materials need to be changed to obtain the target compound A184-2 (10.45 g, yield: 89.24%), with a mass spectrometry of 373.08 (M+H).

### Synthesis of Compound A184-3

By referring to the synthesis and purification method of compound A10, only the corresponding raw materials need to be changed to obtain the target compound A184-3 (7.39 g, purity: 99.51%, yield: 65.17%), with a mass spectrometry of 389.08 (M+H).

### Synthesis of Compound A184

By referring to the synthesis and purification method of compound A17, only the corresponding raw materials need to be changed to obtain crude product of the target compound A184 (6.88 g, purity: 99.96%, yield: 74.82%). After sublimation purification of 6.88 g of crude compound A184, 4.36 g of sublimed pure compound A184 (purity: 99.96%, yield: 63.37%) were obtained, with a mass spectrometry of 662.23 (M+H).

¹H NMR (400 MHz, CDCl₃) δ 9.15 (dd, J=14.9, 3.0 Hz, 2H), 9.08 (s, 2H), 8.55 (dd, J=15.0, 2.9 Hz, 2H), 8.23 (t, J=2.9 Hz, 1H), 8.04 (t, J=2.9 Hz, 1H), 7.91-7.85 (m, 1H), 7.80-7.67 (m, 9H), 7.63-7.58 (m, 2H), 7.53-7.49 (m, 6H), 7.27-7.19 (m, 6H).

### Synthesis of Compound A240

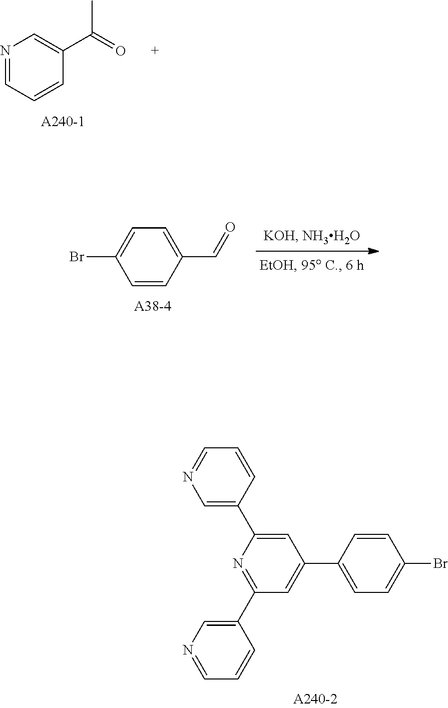

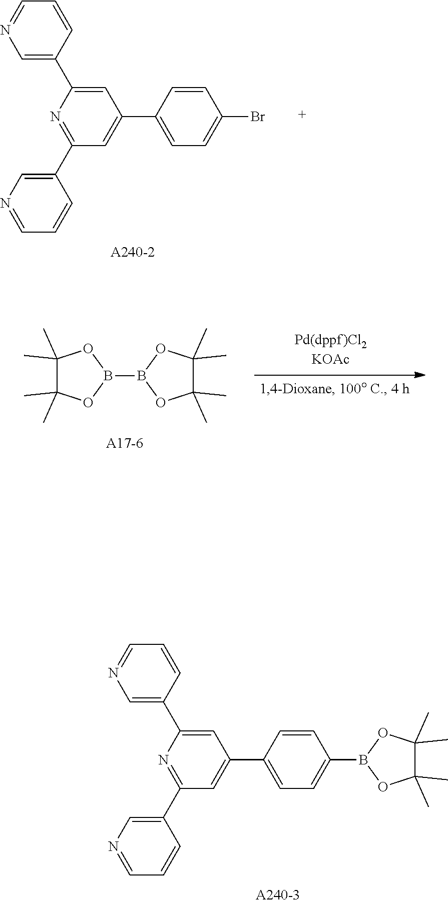

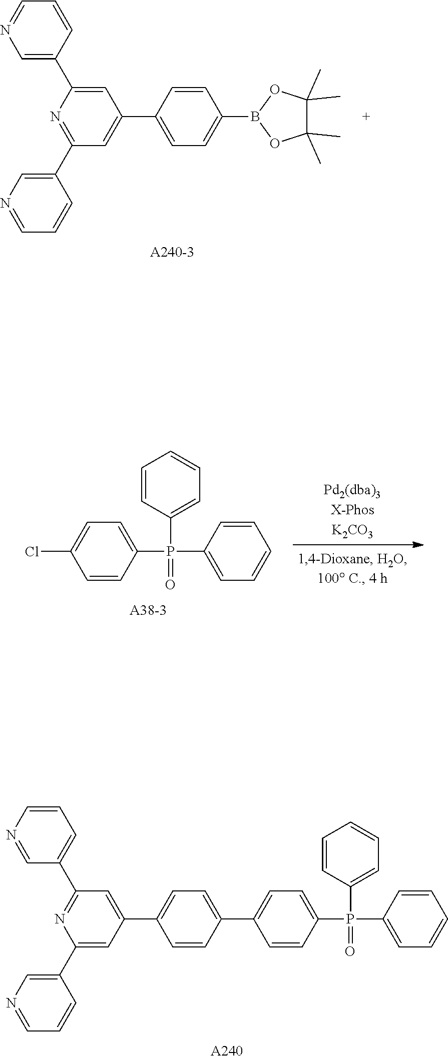 [SMILES: CC1(C)OB(c2ccc(-c3cc(-c4cccnc4)nc(-c4cccnc4)c3)cc2)OC1(C)C ; O=P(c1ccccc1)(c1ccccc1)c1ccc(Cl)cc1 ; O=P(c1ccccc1)(c1ccccc1)c1ccc(-c2ccc(-c3cc(-c4cccnc4)nc(-c4cccnc4)c3)cc2)cc1 ; "A240"]

### Synthesis of Compound A240-2

By referring to the synthesis and purification method of compound A10-3, only the corresponding raw materials need to be changed to obtain the target compound A240-2 (10.27 g, purity: 99.72%, yield: 61.24%), with a mass spectrometry of 388.04 (M+H).

### Synthesis of Compound A240-3

By referring to the synthesis and purification method of compound A17-6, only the corresponding raw materials need to be changed to obtain the target compound A240-3 (8.72 g, purity: 99.36%, yield: 73.67%), with a mass spectrometry of 436.21 (M+H).

### Synthesis of Compound A240

By referring to the synthesis and purification method of compound A17, only the corresponding raw materials need to be changed to obtain crude product of target compound A240 (7.72 g, purity: 99.89%, yield: 78.49%). After sublimation purification of 7.72 g of crude compound A240, 5.12 g of sublimed pure compound A240 (purity: 99.95%, yield: 66.40%) were obtained, with a mass spectrometry of 586.20 (M+H).

¹H NMR (400 MHz, CDCl₃) δ 9.65 (dd, J=2.8, 0.6 Hz, 2H), 8.88 (s, 2H), 8.75-8.67 (m, 4H), 7.97 (s, 4H), 7.81-7.75 (m, 4H), 7.54-7.43 (m, 8H), 7.25 (s, 4H).

### Synthesis of Compound A273

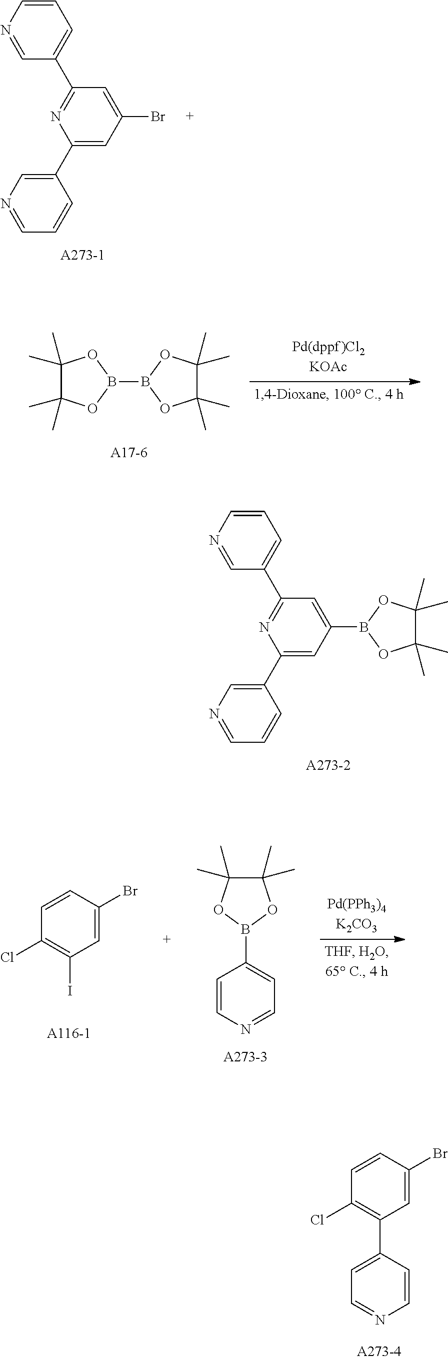

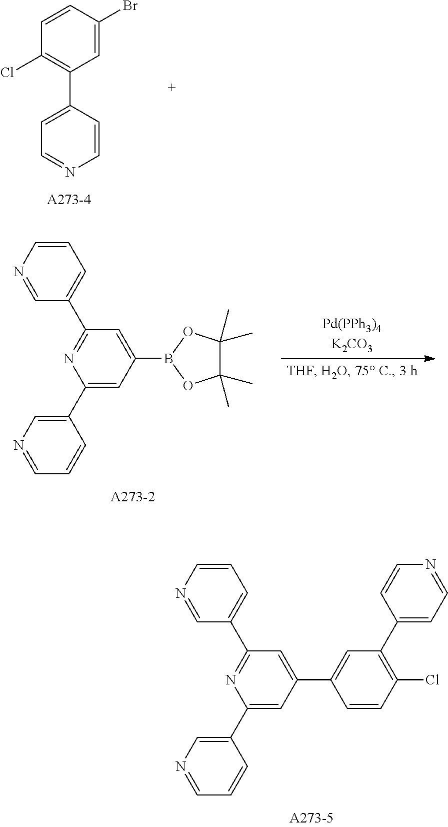 [SMILES: Clc1ccc(Br)cc1-c1ccncc1 ; CC1(C)OB(c2cc(-c3cccnc3)nc(-c3cccnc3)c2)OC1(C)C ; Clc1ccc(-c2cc(-c3cccnc3)nc(-c3cccnc3)c2)cc1-c1ccncc1]

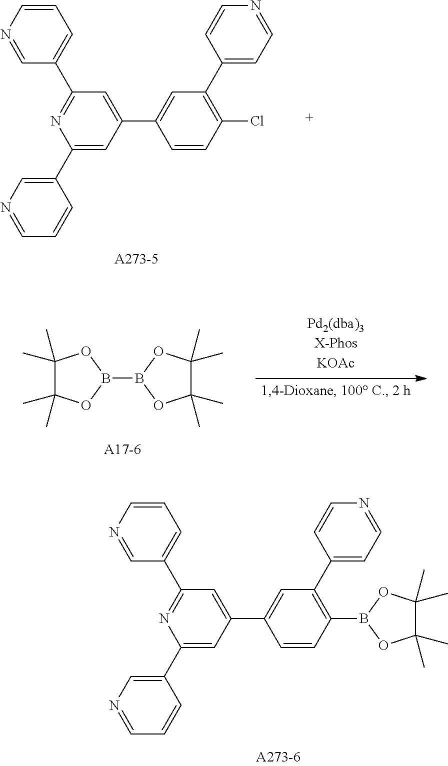

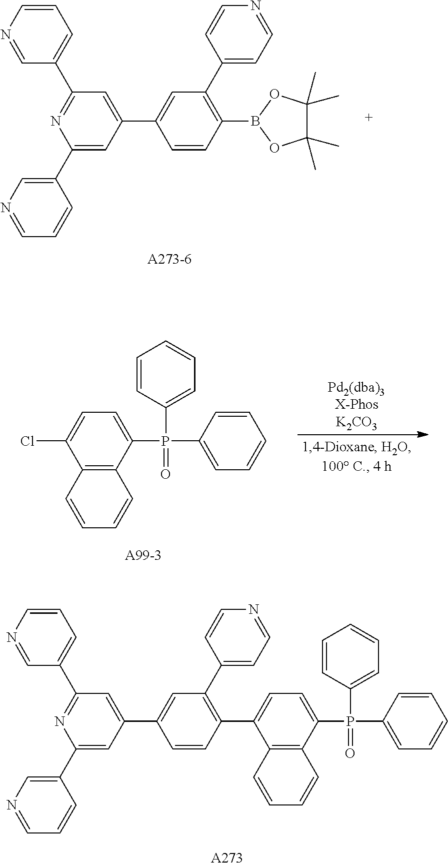 [SMILES: CC1(C)OB(c2ccc(-c3cc(-c4cccnc4)nc(-c4cccnc4)c3)cc2-c2ccncc2)OC1(C)C ; O=P(c1ccccc1)(c1ccccc1)c1ccc(Cl)c2ccccc12 ; O=P(c1ccccc1)(c1ccccc1)c1ccc(-c2ccc(-c3cc(-c4cccnc4)nc(-c4cccnc4)c3)cc2-c2ccncc2)c2ccccc12 ; "A273"]

### Synthesis of Compound A273-2

By referring to the synthesis and purification method of compound A17-7, only the corresponding raw materials need to be changed to obtain the target compound A273-2 (9.03 g, purity: 99.54%, yield: 78.47%), with a mass spectrometry of 360.18 (M+H).

### Synthesis of Compound A273-4

By referring to the synthesis and purification method of compound A17, only the corresponding raw materials need to be changed to obtain the target compound A273-4 (6.41 g, purity: 99.60%, yield: 75.75%), with a mass spectrometry of 267.95 (M+H).

### Synthesis of Compound A273-5

By referring to the synthesis and purification method of compound A17, only the corresponding raw materials need to be changed to obtain the target compound A273-5 (7.14 g, purity: 99.46%, yield: 75.92%), with a mass spectrometry of 421.11 (M+H).

### Synthesis of Compound A273-6

By referring to the synthesis and purification method of compound A17-7, only the corresponding raw materials need to be changed to obtain the target compound A273-6 (6.57 g, purity: 99.72%, yield: 77.09%), with a mass spectrometry of 513.24 (M+H).

### Synthesis of Compound A273

By referring to the synthesis and purification method of compound A17, only the corresponding raw materials need to be changed to obtain the crude product of the target compound A273 (6.18 g, purity: 99.94%, yield: 74.05%). After sublimation purification of 6.18 g of crude compound A273, 4.27 g of sublimed pure compound A273 (purity: 99.96%, yield: 69.09%) were obtained, with a mass spectrometry of 713.24 (M+H).

¹H NMR (400 MHz, CDCl₃) δ 9.60 (d, J=1.4 Hz, 2H), 8.95 (dd, J=7.4, 1.5 Hz, 1H), 8.86 (s, 2H), 8.74-8.68 (m, 6H), 8.23 (d, J=1.6 Hz, 1H), 8.15 (d, J=7.5 Hz, 1H), 7.92-7.88 (m, 3H), 7.85 (d, J=7.5 Hz, 1H), 7.80-7.76 (m, 4H), 7.57 (d, J=7.5 Hz, 1H), 7.53-7.49 (m, 6H), 7.47 (t, J=7.5 Hz, 2H), 7.42-7.38 (m, 1H), 7.36-7.32 (m, 2H).

### Synthesis of Compound A358

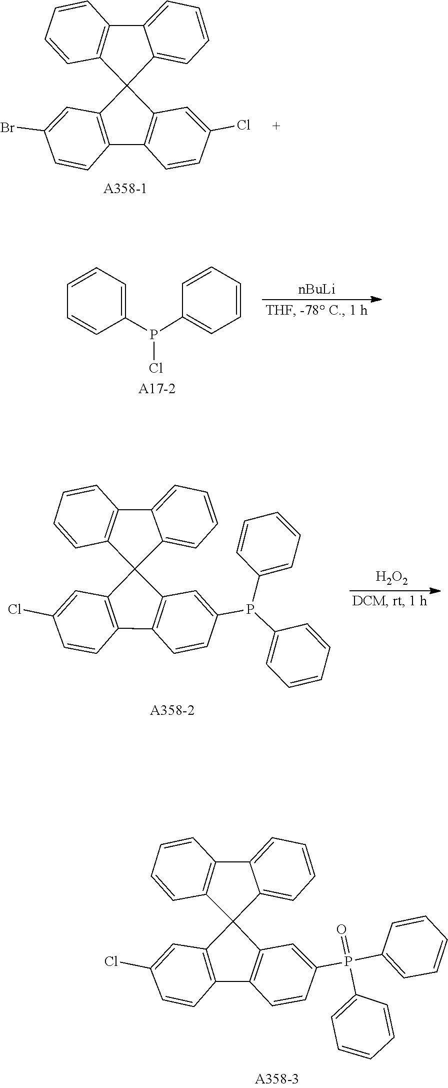

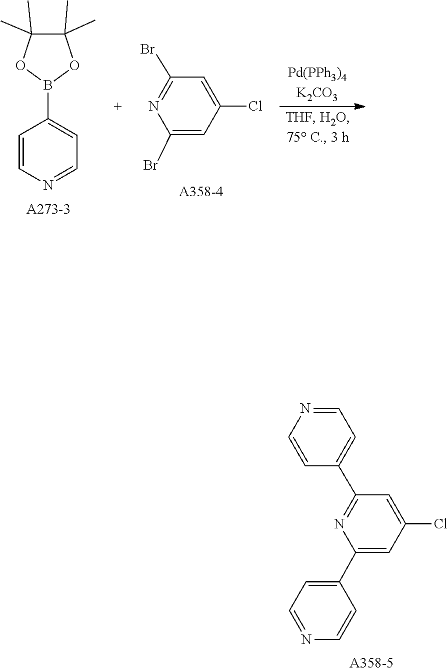

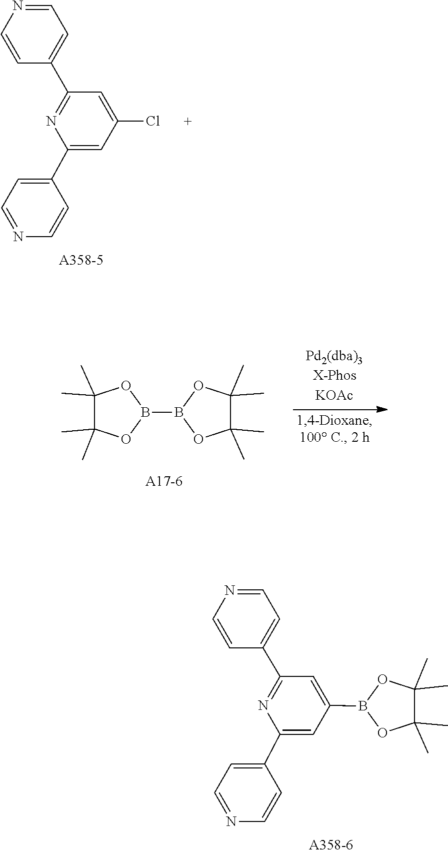

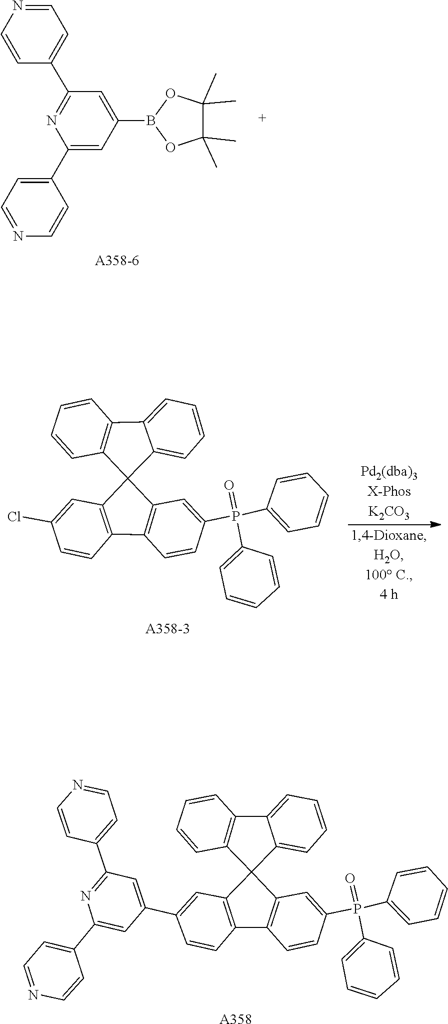 [SMILES: CC1(C)OB(c2cc(-c3ccncc3)nc(-c3ccncc3)c2)OC1(C)C ; O=P(c1ccccc1)(c1ccccc1)c1ccc2c(c1)C1(c3ccccc3-c3ccccc31)c1cc(Cl)ccc1-2 ; O=P(c1ccccc1)(c1ccccc1)c1ccc2c(c1)C1(c3ccccc3-c3ccccc31)c1cc(-c3cc(-c4ccncc4)nc(-c4ccncc4)c3)ccc1-2 ; "A358"]

### Synthesis of Compound A358-2

By referring to the synthesis and purification method of compound A17-3, only the corresponding raw materials need to be changed to obtain the target compound A358-2 (16.82 g, yield: 90.07%), with a mass spectrometry of 535.13 (M+H).

### Synthesis of Compound A358-3

By referring to the synthesis and purification method of compound A10, only the corresponding raw materials need to be changed to obtain the target compound A358-3 (9.53 g, purity: 99.44%, yield: 57.83%), with a mass spectrometry of 551.13 (M+H).

### Synthesis of Compound A358-5

By referring to the synthesis and purification method of compound A17, only the corresponding raw materials need to be changed to obtain the target compound A358-5 (9.51 g, purity: 99.62%, yield: 72.84%), with a mass spectrometry of 268.06 (M+H).

### Synthesis of Compound A358-6

By referring to the synthesis and purification method of compound A17-7, only the corresponding raw materials need to be changed to obtain the target compound A358-6 (9.60 g, purity: 99.39%, yield: 75.31%), with a mass spectrometry of 360.18 (M+H).

### Synthesis of Compound A358

By referring to the synthesis and purification method of compound A17, only the corresponding raw materials need to be changed to obtain crude product of the target compound A358 (8.24 g, purity: 99.97%, yield: 78.20%). After sublimation purification of 8.24 g of crude compound A358, 6.25 g of sublimed pure compound A358 (purity: 99.97%, yield: 75.84%) were obtained, with a mass spectrometry of 748.24 (M+H).

¹H NMR (400 MHz, CDCl₃) δ 8.89 (s, 2H), 8.75 (d, J=15.0 Hz, 4H), 8.28 (d, J=15.0 Hz, 4H), 8.16 (dd, J=14.8, 2.9 Hz, 1H), 8.12-8.05 (m, 3H), 7.97 (d, J=2.9 Hz, 1H), 7.90 (dd, J=14.7, 3.2 Hz, 2H), 7.81-7.75 (m, 4H), 7.70-7.62 (m, 3H), 7.53-7.49 (m, 6H), 7.38-7.30 (m, 2H), 7.28-7.20 (m, 2H).

### Synthesis of Compound A431

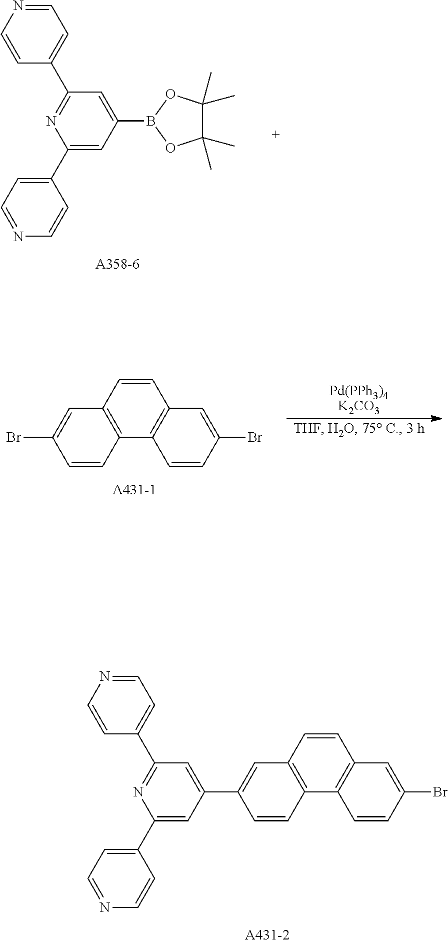

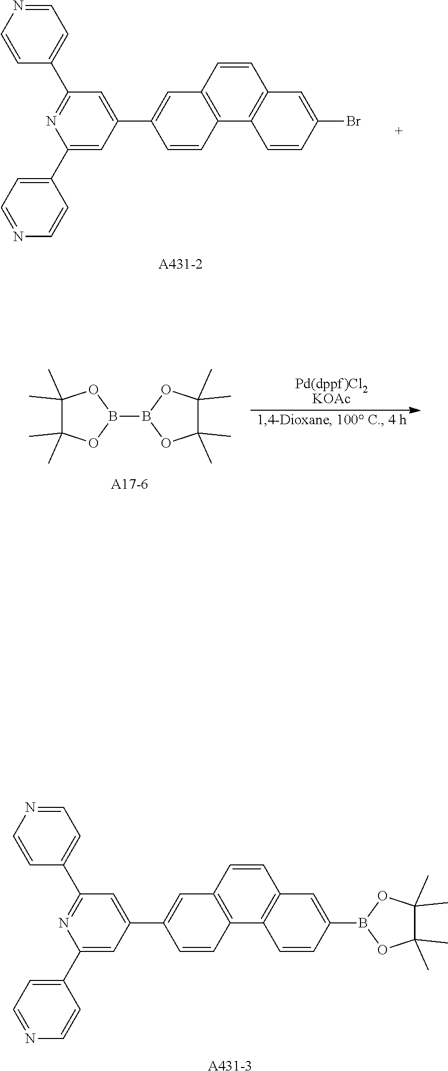

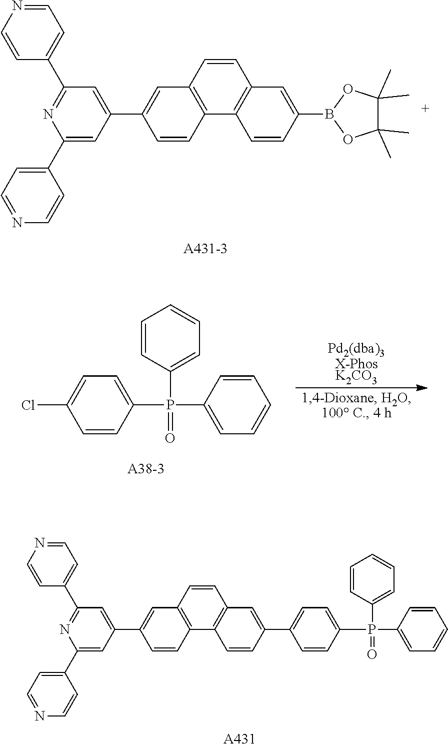

### Synthesis of Compound A431-2

By referring to the synthesis and purification method of compound A17, only the corresponding raw materials need to be changed to obtain the target compound A431-2 (11.62 g, purity: 99.47%, yield: 79.16%), with a mass spectrometry of 488.07 (M+H).

### Synthesis of Compound A431-3

By referring to the synthesis and purification method of compound A17-7, only the corresponding raw materials need to be changed to obtain the target compound A431-3 (9.52 g, purity: 99.36%, yield: 78.94%), with a mass spectrometry of 536.24 (M+H).

### Synthesis of Compound A431

By referring to the synthesis and purification method of compound A17, only the corresponding raw materials need to be changed to obtain the crude product of the target compound A431 (9.06 g, purity: 99.92%, yield: 78.60%). After sublimation purification of 9.06 g of crude compound A431, 6.95 g of sublimed pure compound A431 (purity: 99.97%, yield: 76.82%) were obtained, with a mass spectrometry of 686.23 (M+H).

¹H NMR (400 MHz, CDCl₃) δ 9.11 (d, J=15.0 Hz, 2H), 8.85 (s, 2H), 8.75 (d, J=15.0 Hz, 4H), 8.45-7.38 (m, 4H), 8.28 (d, J=15.0 Hz, 4H), 7.97 (s, 4H), 7.92 (t, J=1.2 Hz, 2H), 7.82-7.74 (m, 4H), 7.55-7.48 (m, 6H).

### Synthesis of Compound A480

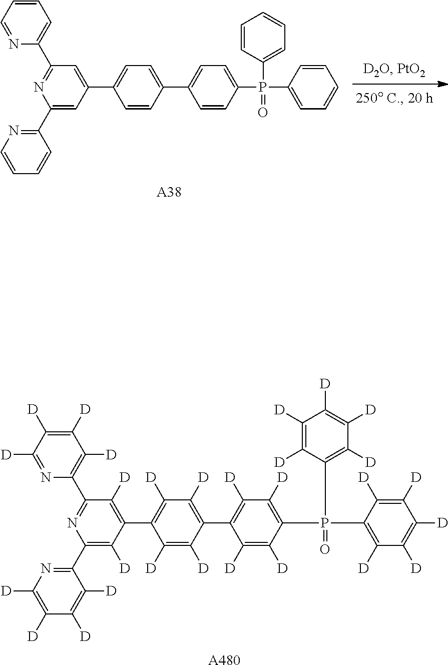 [SMILES: O=P(c1ccccc1)(c1ccccc1)c1ccc(-c2ccc(-c3cc(-c4ccccn4)nc(-c4ccccn4)c3)cc2)cc1 ; "A38" ; [2H]c1nc(-c2nc(-c3nc([2H])c([2H])c([2H])c3[2H])c([2H])c(-c3c([2H])c([2H])c(-c4c([2H])c([2H])c(P(=O)(c5c([2H])c([2H])c([2H])c([2H])c5[2H])c5c([2H])c([2H])c([2H])c([2H])c5[2H])c([2H])c4[2H])c([2H])c3[2H])c2[2H])c([2H])c([2H])c1[2H] ; "A480"]

### Synthesis of Compound A480

Compound A38 (10.00 g, 17.08 mmol), platinum dioxide (0.47 g, 2.05 mmol), and deuterium oxide (200 mL) were added to a 500 mL pressure-resistant reactor. After three cycles of vacuum-nitrogen purging, the reactor was heated to 250° C. and reacted for 20 hours.

The reaction mixture was cooled to room temperature, and dichloromethane (300 mL) was added. The resulting mixture was washed with deionized water three times (100 mL×3). The layers were separated, and the organic phase was collected. The organic phase was mixed with silica gel for dry loading onto a chromatographic column, then purified by silica gel column chromatography (200-300 mesh silica gel, eluent: dichloromethane:methanol=10:1). After elution, the eluate was concentrated under reduced pressure at 60° C. for 1 hour to obtain the crude product of the target compound A480 (4.92 g, purity: 99.85%, yield: 46.94%). After sublimation purification of 4.92 g of crude compound A480, 2.76 g of sublimed pure compound A480 (purity: 99.90%, yield: 56.16%) were obtained, with a mass spectrometry of 614.37 (M+H).

### Synthesis of Compound A483

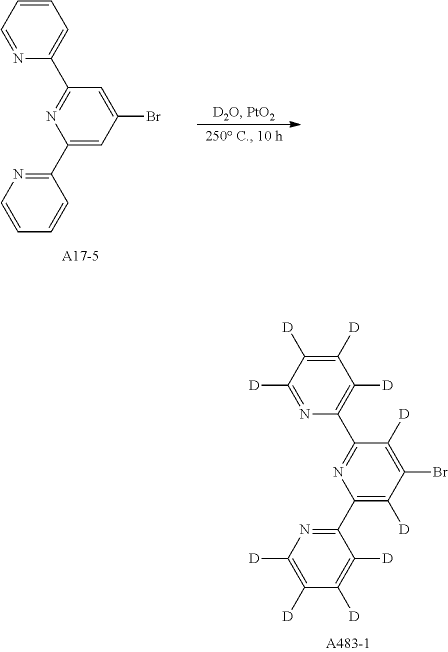

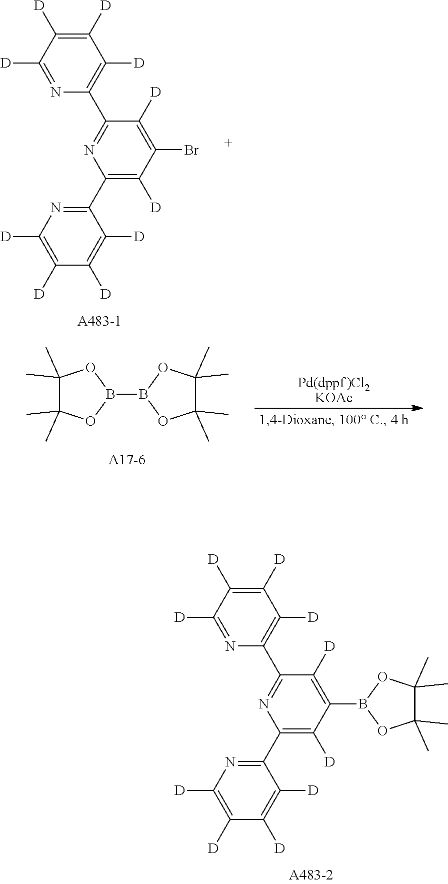

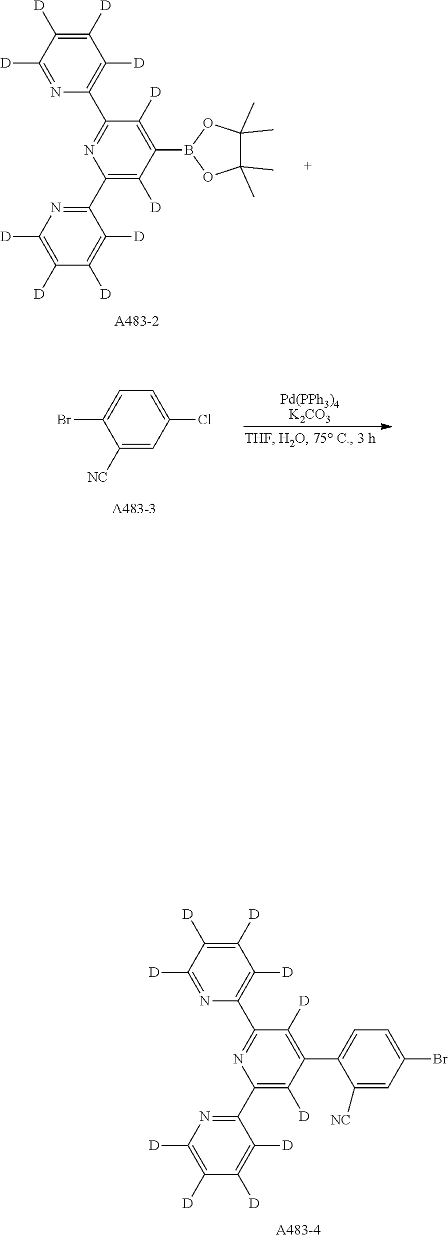 [SMILES: [2H]c1nc(-c2nc(-c3nc([2H])c([2H])c([2H])c3[2H])c([2H])c(B3OC(C)(C)C(C)(C)O3)c2[2H])c([2H])c([2H])c1[2H] ; N#Cc1cc(Cl)ccc1Br ; "THF, H2O, 75° C., 3 h" ; [2H]c1nc(-c2nc(-c3nc([2H])c([2H])c([2H])c3[2H])c([2H])c(-c3ccc(Br)cc3C#N)c2[2H])c([2H])c([2H])c1[2H] ; "Pd(PPh3)4K2CO3"]

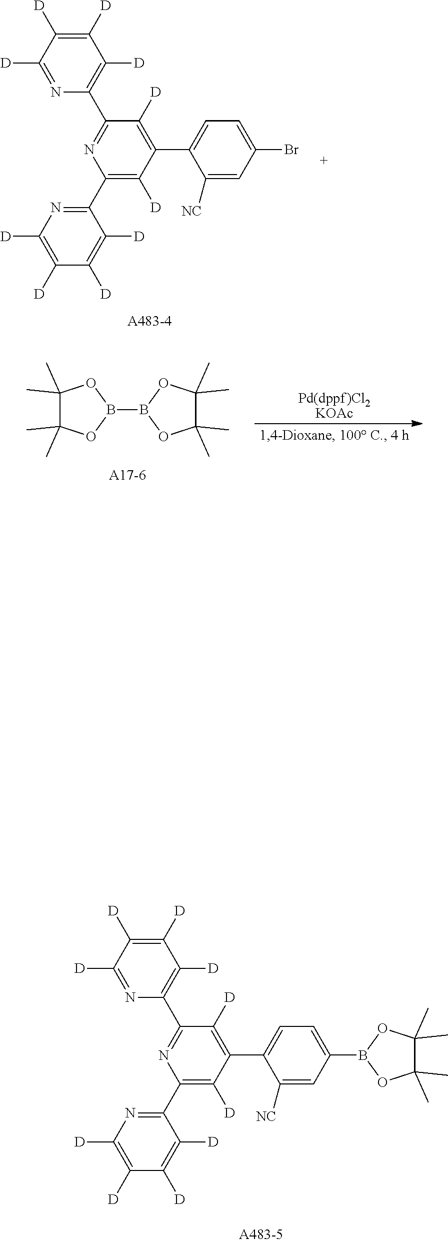

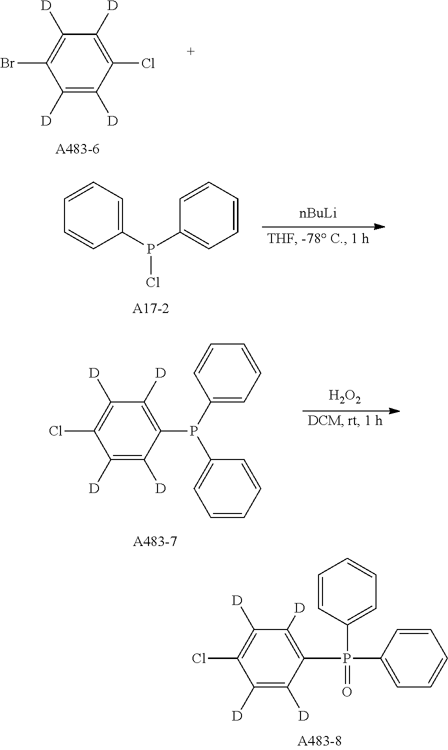

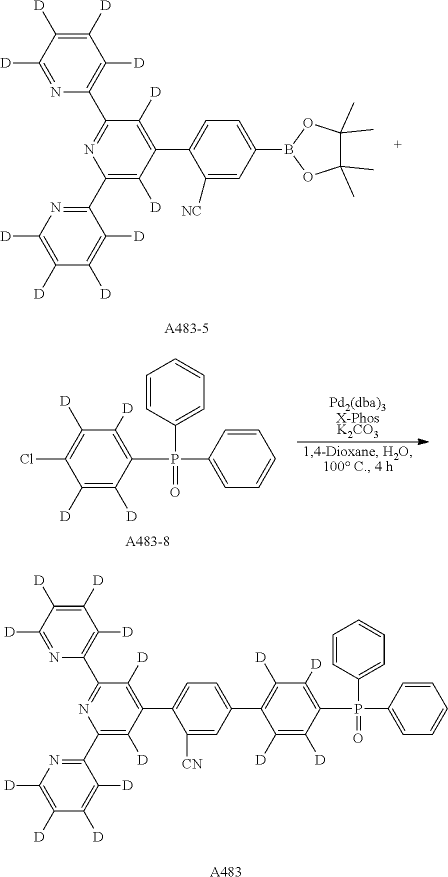 [SMILES: [2H]c1nc(-c2nc(-c3nc([2H])c([2H])c([2H])c3[2H])c([2H])c(-c3ccc(B4OC(C)(C)C(C)(C)O4)cc3C#N)c2[2H])c([2H])c([2H])c1[2H] ; [2H]c1c([2H])c(P(=O)(c2ccccc2)c2ccccc2)c([2H])c([2H])c1Cl ; "1,4-Dioxane, H2O,100° C., 4 h" ; "Pd2(dba)3X-PhosK2CO3" ; [2H]c1nc(-c2nc(-c3nc([2H])c([2H])c([2H])c3[2H])c([2H])c(-c3ccc(-c4c([2H])c([2H])c(P(=O)(c5ccccc5)c5ccccc5)c([2H])c4[2H])cc3C#N)c2[2H])c([2H])c([2H])c1[2H] ; "A483"]

### Synthesis of Compound A483-1

By referring to the synthesis and purification method of compound A480, only the corresponding raw materials need to be changed to obtain the target compound A483-1 (6.14 g, purity: 99.07%, yield: 59.48%), with a mass spectrometry of 322.07 (M+H).

### Synthesis of Compound A483-2

By referring to the synthesis and purification method of compound A17-7, only the corresponding raw materials need to be changed to obtain the target compound A483-2 (5.47 g, purity: 99.29%, yield: 79.55%), with a mass spectrometry of 370.24 (M+H).

### Synthesis of Compound A483-4

By referring to the synthesis and purification method of compound A17, only the corresponding raw materials need to be changed to obtain the target compound A483-4 (4.52 g, purity: 99.62%, yield: 78.86%), with a mass spectrometry of 423.09 (M+H).

### Synthesis of Compound A483-5

By referring to the synthesis and purification method of compound A17-7, only the corresponding raw materials need to be changed to obtain the target compound A483-5 (4.09 g, purity: 99.17%, yield: 81.80%), with a mass spectrometry of 471.27 (M+H).

### Synthesis of Compound A483-7

By referring to the synthesis and purification method of compound A17-3, only the corresponding raw materials need to be changed to obtain the target compound A483-7 (6.95 g, yield: 90.34%), with a mass spectrometry of 301.08 (M+H).

### Synthesis of Compound A483-8

By referring to the synthesis and purification method of compound A10, only the corresponding raw materials need to be changed to obtain the target compound A483-8 (4.08 g, purity: 99.56%, yield: 59.60%), with a mass spectrometry of 317.07 (M+H).

### Synthesis of Compound A483

By referring to the synthesis and purification method of compound A17, only the corresponding raw materials need to be changed to obtain the crude product of the target compound A483 (4.14 g, purity: 99.96%, yield: 77.93%). After sublimation purification of 4.14 g of crude compound A483, 2.51 g of sublimed pure compound A483 (purity: 99.97%, yield: 60.80%) were obtained, with a mass spectrometry of 625.28 (M+H).

¹H NMR (400 MHz, CDCl₃) δ 8.22 (d, J=2.9 Hz, 1H), 8.14 (d, J=15.0 Hz, 1H), 7.82-7.75 (m, 4H), 7.56-7.48 (m, 7H).

### Synthesis of Compound A487

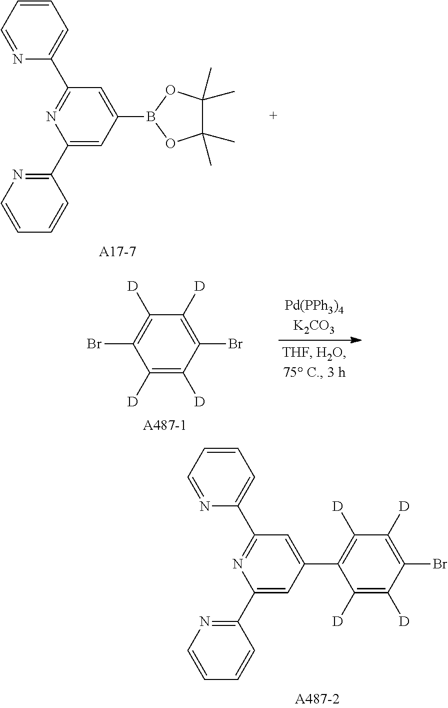 [SMILES: CC1(C)OB(c2cc(-c3ccccn3)nc(-c3ccccn3)c2)OC1(C)C ; [2H]c1c([2H])c(Br)c([2H])c([2H])c1Br ; [2H]c1c([2H])c(-c2cc(-c3ccccn3)nc(-c3ccccn3)c2)c([2H])c([2H])c1Br]

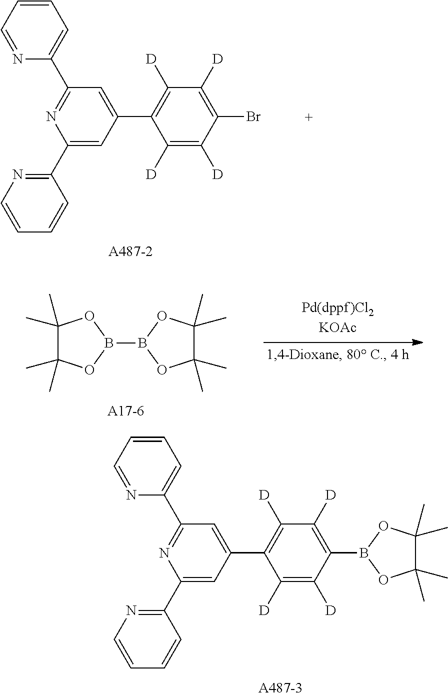

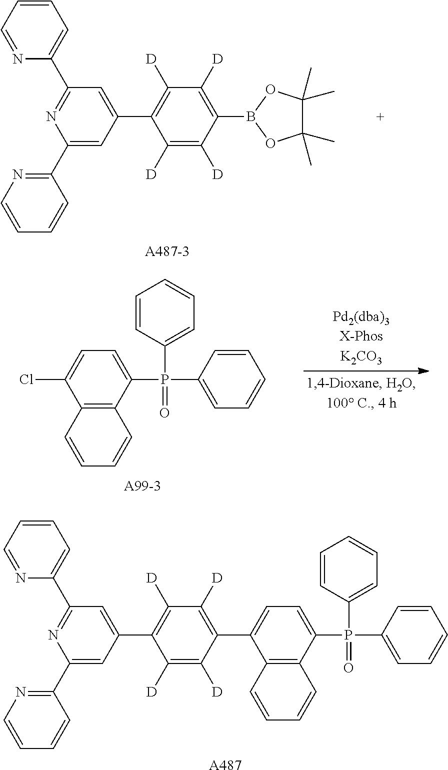 [SMILES: [2H]c1c([2H])c(-c2cc(-c3ccccn3)nc(-c3ccccn3)c2)c([2H])c([2H])c1B1OC(C)(C)C(C)(C)O1 ; O=P(c1ccccc1)(c1ccccc1)c1ccc(Cl)c2ccccc12 ; [2H]c1c([2H])c(-c2ccc(P(=O)(c3ccccc3)c3ccccc3)c3ccccc23)c([2H])c([2H])c1-c1cc(-c2ccccn2)nc(-c2ccccn2)c1 ; "A487"]

### Synthesis of Compound A487-2

By referring to the synthesis and purification method of compound A17, only the corresponding raw materials need to be changed to obtain the target compound A487-2 (8.10 g, purity: 99.67%, yield: 74.17%), with a mass spectrometry of 392.06 (M+H).

### Synthesis of Compound A487-3

By referring to the synthesis and purification method of compound A17-7, only the corresponding raw materials need to be changed to obtain the target compound A487-3 (6.73 g, purity: 99.28%, yield: 75.11%), with a mass spectrometry of 440.24 (M+H).

### Synthesis of Compound A487

By referring to the synthesis and purification method of compound A17, only the corresponding raw materials need to be changed to obtain crude product of the target compound A487 (7.19 g, purity: 99.92%, yield: 75.97%). After sublimation purification of 7.19 g of crude compound A487, 4.29 g of sublimed pure compound A487 (purity: 99.97%, yield: 59.66%), with a mass spectrometry of 640.24 (M+H).

¹H NMR (400 MHz, CDCl₃) δ 9.18 (dd, J=14.9, 3.0 Hz, 2H), 9.14 (s, 2H), 8.95 (dd, J=14.2, 3.7 Hz, 1H), 8.55 (dd, J=15.0, 2.9 Hz, 2H), 7.97-7.86 (m, 2H), 7.83-7.69 (m, 6H), 7.57 (d, J=15.0 Hz, 1H), 7.54-7.47 (m, 6H), 7.44-7.29 (m, 2H), 7.27-7.19 (m, 2H).

### Synthesis of Compound A521

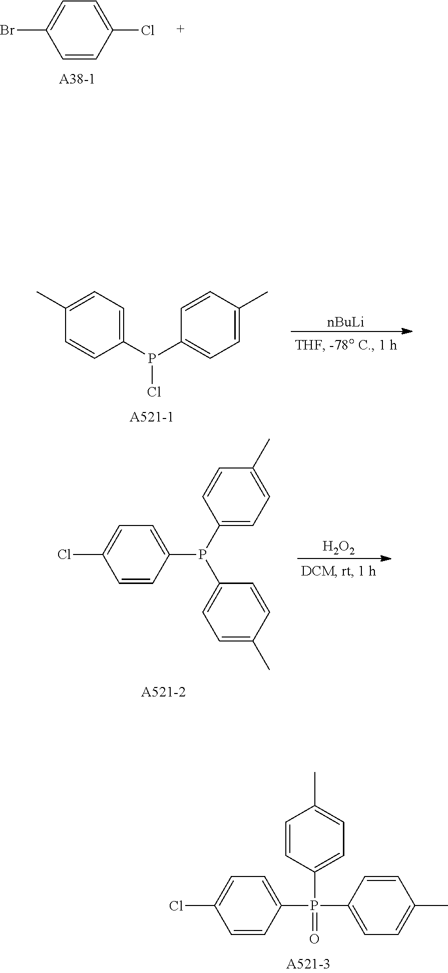

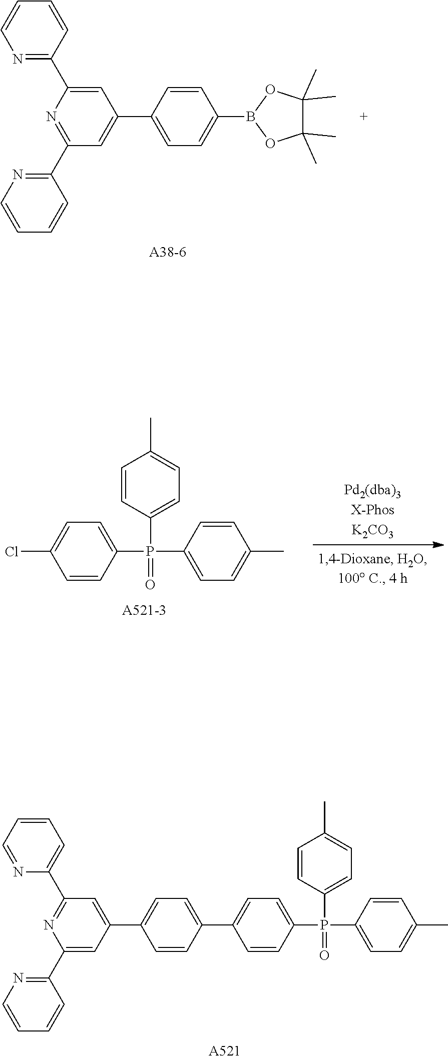 [SMILES: CC1(C)OB(c2ccc(-c3cc(-c4ccccn4)nc(-c4ccccn4)c3)cc2)OC1(C)C ; Cc1ccc(P(=O)(c2ccc(C)cc2)c2ccc(Cl)cc2)cc1 ; Cc1ccc(P(=O)(c2ccc(C)cc2)c2ccc(-c3ccc(-c4cc(-c5ccccn5)nc(-c5ccccn5)c4)cc3)cc2)cc1 ; "A521"]

### Synthesis of Compound A521-2

By referring to the synthesis and purification method of compound A17-3, only the corresponding raw materials need to be changed to obtain the target compound A521-2 (15.24 g, yield: 89.83%), with a mass spectrometry of 325.08 (M+H).

### Synthesis of Compound A521-3

By referring to the synthesis and purification method of compound A10, only the corresponding raw materials need to be changed to obtain the target compound A521-3 (8.41 g, purity: 99.18%, yield: 53.43%), with a mass spectrometry of 341.08 (M+H).

### Synthesis of Compound A521

By referring to the synthesis and purification method of compound A17, only the corresponding raw materials need to be changed to obtain the crude product of the target compound A521 (8.39 g, purity: 99.92%, yield: 74.39%). After sublimation purification of 8.39 g of crude compound A521, 5.04 g of sublimed pure compound A521 (purity: 99.98%, yield: 60.07%) were obtained, with a mass spectrometry of 614.23 (M+H).

¹H NMR (400 MHz, CDCl₃) δ 9.07 (dd, J=14.9, 3.0 Hz, 2H), 9.10 (s, 2H), 8.55 (dd, J=15.0, 2.9 Hz, 2H), 7.97 (s, 4H), 7.79-7.69 (m, 6H), 7.45-7.39 (m, 4H), 7.28-7.18 (m, 6H), 2.34 (s, 6H).

### Synthesis of Compound A530

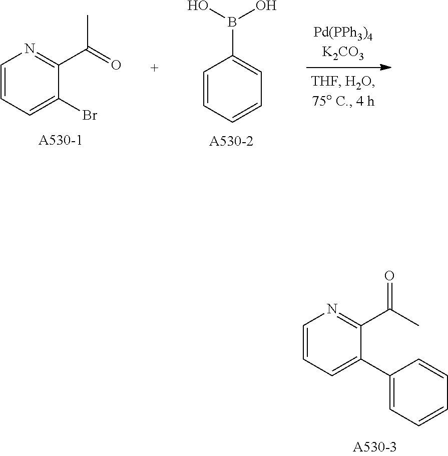

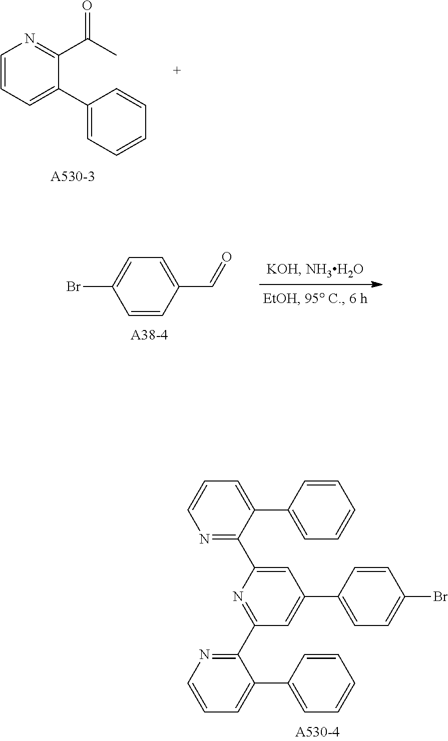 [SMILES: CC(=O)c1ncccc1-c1ccccc1 ; O=Cc1ccc(Br)cc1 ; Brc1ccc(-c2cc(-c3ncccc3-c3ccccc3)nc(-c3ncccc3-c3ccccc3)c2)cc1]

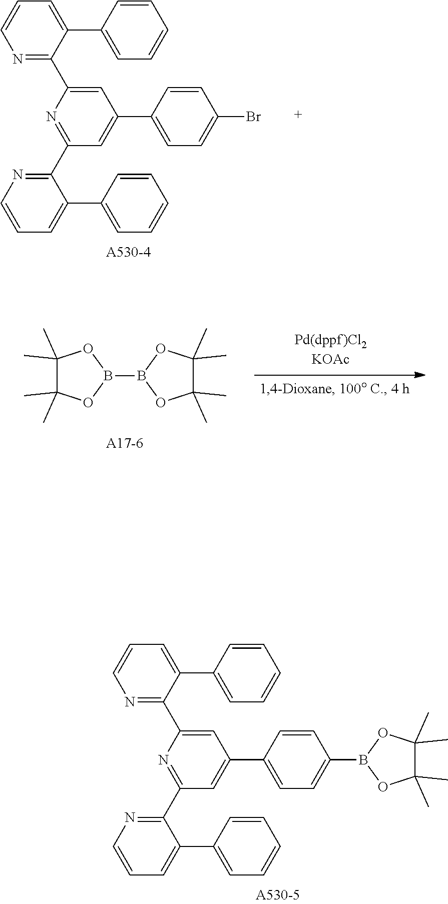

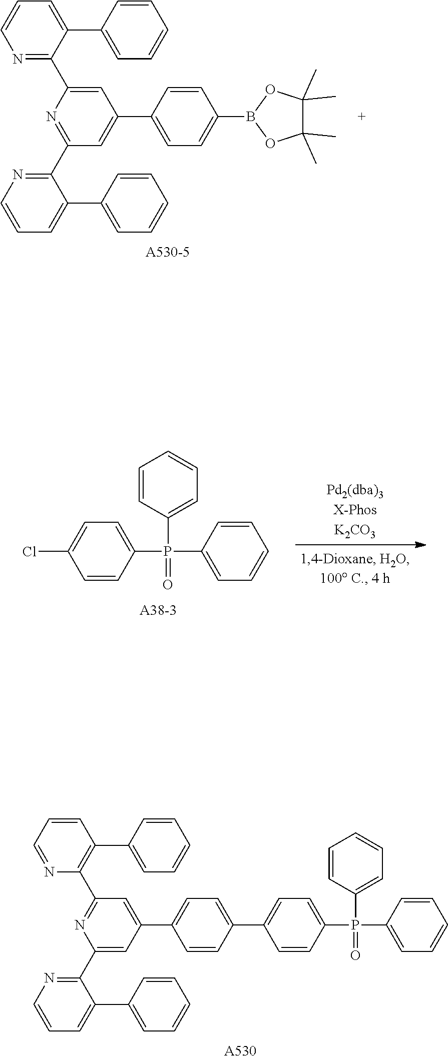 [SMILES: CC1(C)OB(c2ccc(-c3cc(-c4ncccc4-c4ccccc4)nc(-c4ncccc4-c4ccccc4)c3)cc2)OC1(C)C ; O=P(c1ccccc1)(c1ccccc1)c1ccc(Cl)cc1 ; O=P(c1ccccc1)(c1ccccc1)c1ccc(-c2ccc(-c3cc(-c4ncccc4-c4ccccc4)nc(-c4ncccc4-c4ccccc4)c3)cc2)cc1 ; "A530"]

### Synthesis of Compound A530-3

By referring to the synthesis and purification method of compound A17, only the corresponding raw materials need to be changed to obtain the target compound A530-3 (11.35 g, purity: 99.62%, yield: 76.74%), with a mass spectrometry of 198.08 (M+H).

### Synthesis of Compound A530-4

By referring to the synthesis and purification method of compound A10-3, only the corresponding raw materials need to be changed to obtain the target compound A530-4 (16.82 g, purity: 99.35%, yield: 61.38%), with a mass spectrometry of 540.10 (M+H).

### Synthesis of Compound A530-5

By referring to the synthesis and purification method of compound A17-7, only the corresponding raw materials need to be changed to obtain the target compound A530-5 (13.44 g, purity: 99.28%, yield: 74.93%), with a mass spectrometry of 588.27 (M+H).

### Synthesis of Compound A530

By referring to the synthesis and purification method of compound A17, only the corresponding raw materials need to be changed to obtain crude product of the target compound A530 (10.74 g, purity: 99.96%, yield: 65.79%). 10.74 g of crude compound A530 were sublimated and purified to obtain 7.05 g of sublimed pure compound A530 (purity: 99.97%, yield: 65.64%), with a mass spectrometry of 738.26 (M H).

¹H NMR (400 MHz, CDCl₃) δ 9.11 (s, 2H), 8.50 (dd, J=15.0, 3.1 Hz, 2H), 8.01-7.94 (m, 6H), 7.82-7.74 (m, 4H), 7.55-7.47 (m, 6H), 7.46-7.37 (m, 2H), 7.29 (t, J=14.9 Hz, 2H), 7.25 (s, 4H), 7.19 (d, J=9.0 Hz, 8H).

### Synthesis of Compound A531

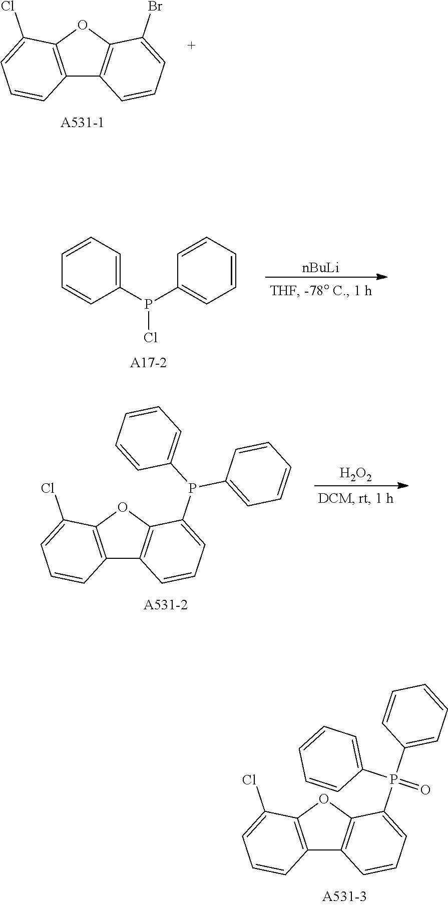

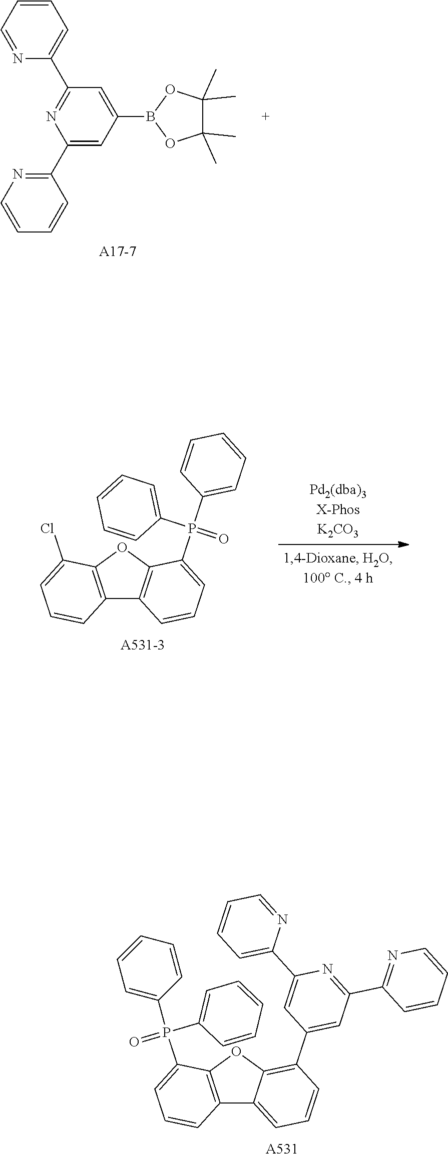

### Synthesis of Compound A531-2

By referring to the synthesis and purification method of compound A17-3, only the corresponding raw materials need to be changed to obtain the target compound A531-2 (12.17 g, yield: 88.58%), with a mass spectrometry of 387.06 (M+H).

### Synthesis of Compound A531-3

By referring to the synthesis and purification method of compound A10, only the corresponding raw materials need to be changed to obtain the target compound A531-3 (6.50 g, purity: 99.47%, yield: 52.03%), with a mass spectrometry of 403.06 (M+H).

### Synthesis of Compound A531

By referring to the synthesis and purification method of compound A17, only the corresponding raw materials need to be changed to obtain the crude product of the target compound A531 (5.62 g, purity: 99.93%, yield: 61.22%). After sublimation purification of 5.62 g of crude compound A531, 3.75 g of sublimed pure compound A531 (purity: 99.97%, yield: 66.72%) were obtained, with a mass spectrometry of 600.18 (M+H).

¹H NMR (400 MHz, CDCl₃) δ 9.18 (dd, J=14.9, 3.0 Hz, 2H), 9.14 (s, 2H), 8.55 (dd, J=15.0, 2.9 Hz, 2H), 8.23 (dd, J=14.9, 3.0 Hz, 1H), 8.15-7.99 (m, 3H), 7.83-7.70 (m, 6H), 7.55-7.47 (m, 6H), 7.46-7.37 (m, 2H), 7.27-7.19 (m, 2H).

### Application Example: Fabrication of Organic Electroluminescent Devices

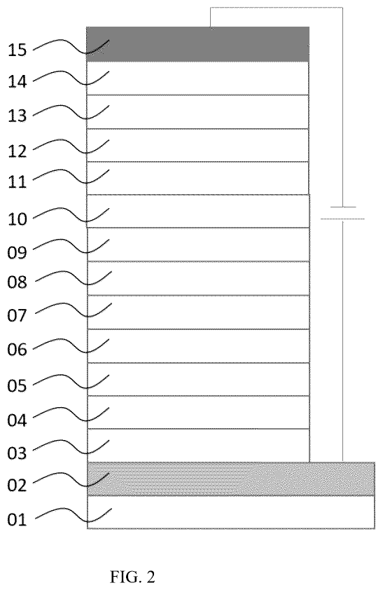

FIG. 2 shows a schematic diagram of an organic electroluminescent device, which includes a glass substrate 01, an anode 02, a hole injection layer 03, a first hole transport layer 04, a first electron blocking layer 05, a first light-emitting layer 06, a first electron transport layer 07, an N-type charge generation layer 08, a P-type charge generation layer 09, a second hole transport layer 10, a second electron blocking layer 11, a second light-emitting layer 12, a second electron transport layer 13, an electron injection layer 14, and a cathode 15, which were stacked sequentially.

### Device Fabrication Method:

A glass substrate 01 with an ITO transparent electrode (anode) on its surface was provided, wherein the anode had a thickness of 1,000 nm;
the glass substrate 01 was washed sequentially with deionized water, ethanol, acetone and deionized water, then dried at 80° C. and then treated with oxygen plasma for 30 minutes;
the compound HATCN was vacuum-deposited on the surface of the anode 02 to form a hole injection layer 03 with a thickness of 20 nm;
HTL was vacuum-deposited on one side of the hole injection layer 03 to form a first hole transport layer 04 with a thickness of 10 nm;
EBL was vacuum-deposited on one side of the first hole transport layer 04 to form a first electron blocking layer 05 with a thickness of 5 nm;
a host material (BH) and a guest material (BD) were co-vacuum-deposited on one side of the first electron blocking layer 05 to form a first light-emitting layer 06, where a weight ratio of BH to BD was 97:3 and the first light-emitting layer 06 had a thickness of 20 nm;
ET and LiQ were co-vacuum-deposited on one side of the first light-emitting layer to form a first electron transport layer 07, where the weight ratio of ET to LiQ was 1:1 and the first electron transport layer 07 had a thickness of 35 nm;
a heterocyclic compound and a doped material (metal Yb) were co-vacuum-deposited on one side of the first electron transport layer 07 to form an N-type charge generation layer 08 (N-CGL). The types of heterocyclic compound in the N-CGL layers of each example and comparative example were shown in Table 1. The weight ratio of the heterocyclic compound to Yb was uniformly 95:5, and the N-type charge generation layer has a thickness of 100 nm;
HATCN was vacuum-deposited on one side of the N-type charge generation layer 08 to form a P-type charge generation layer 09 with a thickness of 10 nm;
HTL was vacuum-deposited on one side of the P-type charge generation layer 09 to form a second hole transport layer 10 with a thickness of 10 nm;
EBL was vacuum-deposited on one side of the second hole transport layer 10 to form a second electron blocking layer 11 with a thickness of 5 nm;
a host material (BH) and a guest material (BD) were co-vacuum-deposited on one side of the second electron blocking layer 11 to form a second light-emitting layer 12, where the weight ratio of BH to BD was 97:3 and the second light-emitting layer 12 had a thickness of 20 nm;
ET and LiQ were co-vacuum-deposited on one side of the second light-emitting layer 12 to form a second electron transport layer 13, where the weight ratio of ET to LiQ was 1:1 and the second electron transport layer 13 had a thickness of 35 nm;
Yb was vacuum-deposited on one side of the second electron transport layer 13 to form an electron injection layer 14 with a thickness of 1 nm;
Ag was vacuum-deposited on one side of the electron injection layer 14 to form a cathode 15 with a thickness of 1,000 nm, thus obtaining an organic electroluminescent device.

The structural formulas of HAT-CN, HTL, EBL, BH, BD, ET, LiQ, and comparative compounds 1-6 are as follows:

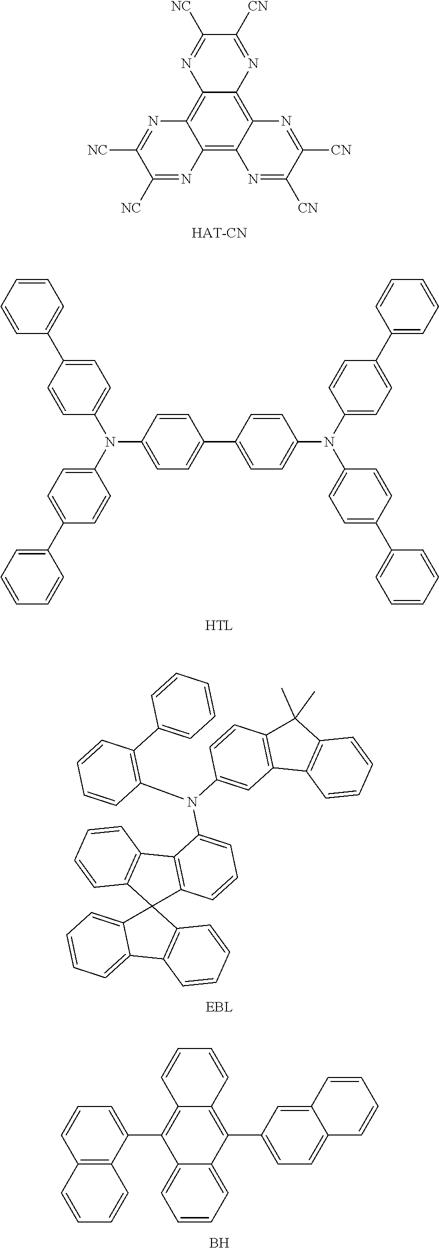

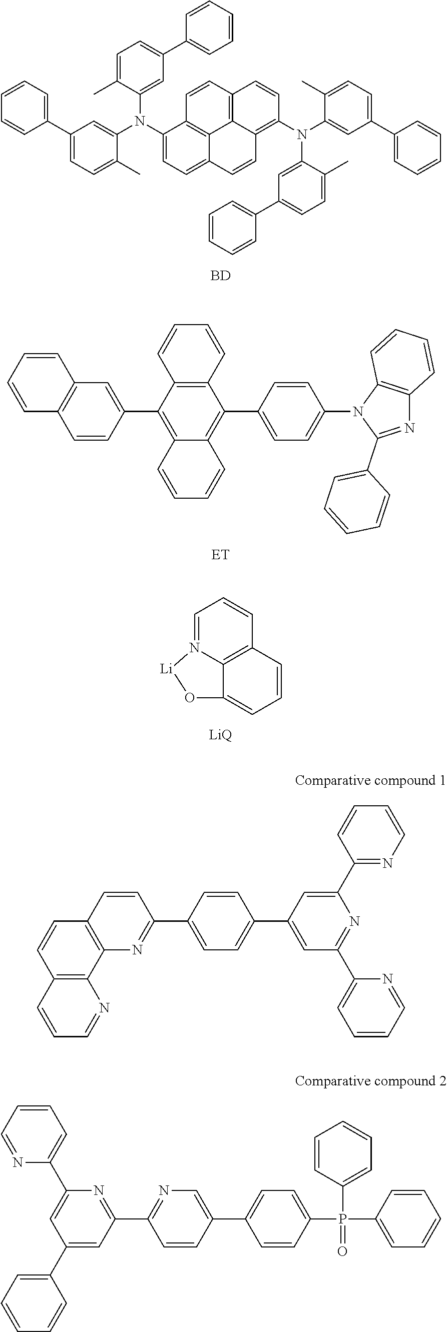

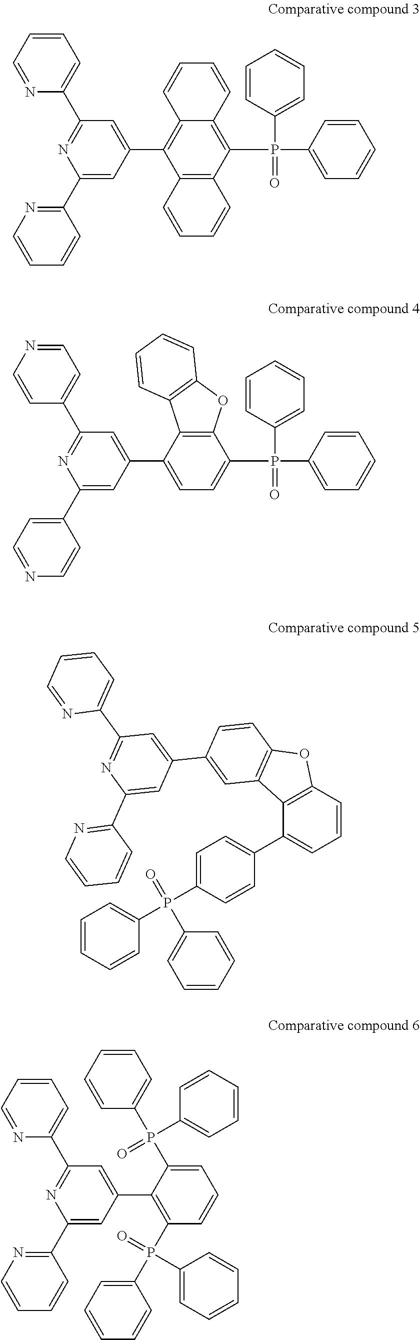 [SMILES: O=P(c1ccccc1)(c1ccccc1)c1c2ccccc2c(-c2cc(-c3ccccn3)nc(-c3ccccn3)c2)c2ccccc12 ; O=P(c1ccccc1)(c1ccccc1)c1ccc(-c2cc(-c3ccncc3)nc(-c3ccncc3)c2)c2c1oc1ccccc12 ; O=P(c1ccccc1)(c1ccccc1)c1ccc(-c2cccc3oc4ccc(-c5cc(-c6ccccn6)nc(-c6ccccn6)c5)cc4c23)cc1 ; O=P(c1ccccc1)(c1ccccc1)c1cccc(P(=O)(c2ccccc2)c2ccccc2)c1-c1cc(-c2ccccn2)nc(-c2ccccn2)c1]

### Evaluation:

The fabricated organic electroluminescent device was subjected to device performance testing. The emission spectrum was measured using a constant current power supply (Keithley 2400) with a fixed current density flowing through the light-emitting element and a spectroradiometer (CS 2000). Simultaneously, the IVL (current-voltage-luminance) performance of the device was measured at 10 mA/cm², and the lifetime of the LT95 device was tested at 50 mA/cm².

The test results were shown in Table 1. All data are based on the index values of Comparative Example 1 (set to 100). For example, a drive voltage of 91 means that under the same test conditions, the drive voltage is 91% of that in Comparative Example 1.

TABLE 1

| | Heterocyclic | | | |
|---|---|---|---|---|
| | Compound in | Driving | Current | LT95 |
| Number | N-CGL layer | Voltage | Efficiency | lifetime |
| Example 1 | A10 | 98% | 101% | 110% |
| Example 2 | A17 | 95% | 104% | 116% |
| Example 3 | A30 | 97% | 103% | 118% |
| Example 4 | A32 | 95% | 104% | 122% |
| Example 5 | A33 | 98% | 102% | 110% |
| Example 6 | A38 | 94% | 102% | 134% |
| Example 7 | A59 | 95% | 103% | 126% |
| Example 8 | A68 | 93% | 104% | 132% |
| Example 9 | A78 | 94% | 103% | 128% |
| Example 10 | A99 | 93% | 102% | 125% |
| Example 11 | A106 | 94% | 102% | 122% |
| Example 12 | A116 | 94% | 104% | 138% |
| Example 13 | A131 | 92% | 102% | 122% |
| Example 14 | A155 | 95% | 103% | 142% |
| Example 15 | A184 | 97% | 101% | 119% |
| Example 16 | A240 | 94% | 102% | 133% |
| Example 17 | A273 | 95% | 103% | 125% |
| Example 18 | A358 | 91% | 103% | 132% |
| Example 19 | A431 | 93% | 101% | 127% |
| Example 20 | A480 | 95% | 104% | 148% |
| Example 21 | A483 | 93% | 102% | 136% |
| Example 22 | A487 | 94% | 103% | 138% |
| Example 23 | A521 | 95% | 102% | 108% |
| Example 24 | A530 | 91% | 103% | 119% |
| Example 25 | A531 | 97% | 103% | 114% |
| Comparative | Comparative | 100% | 100% | 100% |
| Example 1 | compound 1 | | | |
| Comparative | Comparative | 112% | 89% | 84% |
| Example 2 | compound 2 | | | |
| Comparative | Comparative | 108% | 93% | 87% |
| Example 3 | compound 3 | | | |
| Comparative | Comparative | 116% | 92% | 83% |
| Example 4 | compound 4 | | | |
| Comparative | Comparative | 109% | 94% | 95% |
| Example 5 | compound 5 | | | |
| Comparative | Comparative | 114% | 85% | 74% |
| Example 6 | compound 6 | | | |

As can be seen from Table 1, when the N-CGL layer prepared using the heterocyclic compound of the present disclosure is applied to tandem organic electroluminescent device, the operating voltage of the device is significantly reduced compared with the comparative compounds 1-6, effectively reducing the device power consumption. Meanwhile, both the current efficiency and the device life are significantly improved. The heterocyclic compound, as an N-type charge generation layer material, is suitable for OLED light-emitting devices and has the potential to be applied in the AMOLED industry.

1. A heterocyclic compound, having a structure of formula (1): 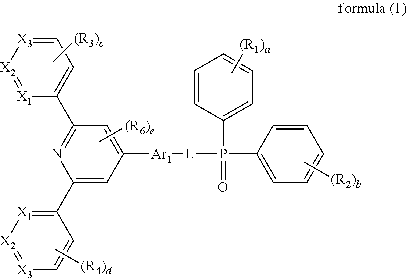
wherein X₁, X₂, and X₃ are each independently selected from N or CR₅; and at least one of X₁ to X₃ is N;
R₁ to R₅, each time appearing, are each independently selected from the group consisting of hydrogen, deuterium, halogen, cyano, nitro, C1-C40 alkyl, C1-C40 heteroalkyl, C2-C40 alkenyl, C2-C40 alkynyl, C3-C40 cycloalkyl, C3-C40 heterocycloalkyl, C6-C60 aryl, C5-C60 heteroaryl, C1-C40 alkoxy, C6-C60 aryloxy, C3-C40 alkylsilyl, C6-C60 arylsilyl, C1-C40 alkylboryl, C6-C60 arylboryl, C6-C60 arylphosphino, and C6-C60 arylamino;
R₆ is hydrogen, deuterium, or halogen;
Ar₁ is substituted or unsubstituted C6-C30 arylene, or substituted or unsubstituted C3-C60 heteroarylene;
a and b are each independently selected from an integer of 0 to 5; and c, d, and e are each independently selected from an integer of 0 to 2;
L is single bond, substituted or unsubstituted C6-C30 arylene, or substituted or unsubstituted C2-C30 heteroarylene;
a heteroatom in the heteroaryl, heteroarylene, heteroalkyl, or heterocycloalkyl is at least one selected from the group consisting of O, S, N, Se, Si, and Ge;
each of substitutions in L and Ar₁ refers to being independently substituted with at least one selected from the group consisting of deuterium, halogen, cyano, isocyano, nitro, C1-C20 alkyl, C1-C20 heteroalkyl, C2-C20 alkenyl, C2-C20 alkynyl, C3-C20 cycloalkyl, C3-C20 heterocycloalkyl, C1-C6 alkyl-substituted amino, C1-C8 hydrocarbyl-substituted or unsubstituted C6-C30 aryl, C1-C8 hydrocarbyl-substituted or unsubstituted C4-C30 heteroaryl, C1-C20 alkoxy, C6-C30 aryloxy, C3-C20 alkylsilyl, C6-C30 arylsilyl, C1-C20 alkylboryl, C6-C30 arylboryl, C6-C30 arylphosphino, and C6-C30 arylamino, wherein the number of substitutions ranges from monosubstitution to the maximum number of substitutions; and
the heterocyclic compound satisfies the following conditions:
(1) Ar₁ is not C1-C20 alkyl-substituted or unsubstituted anthrylene;
(2) Ar₁ is not 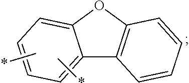
(3) when —Ar₁-L- is one of the structures of formula (C-1) to formula (C-3), L is not phenylene or six-membered heteroarylene; 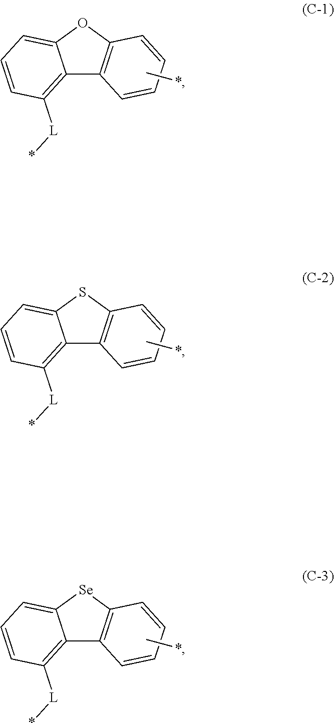
and
(4) neither L nor Ar₁ contains a benzonaphthofuran ring.

2. The heterocyclic compound according to claim 1, wherein only one of X₁ to X₃ is N.

3. The heterocyclic compound according to claim 1, wherein the heterocyclic compound is one of the structures of formula (A-1) to formula (A-3): 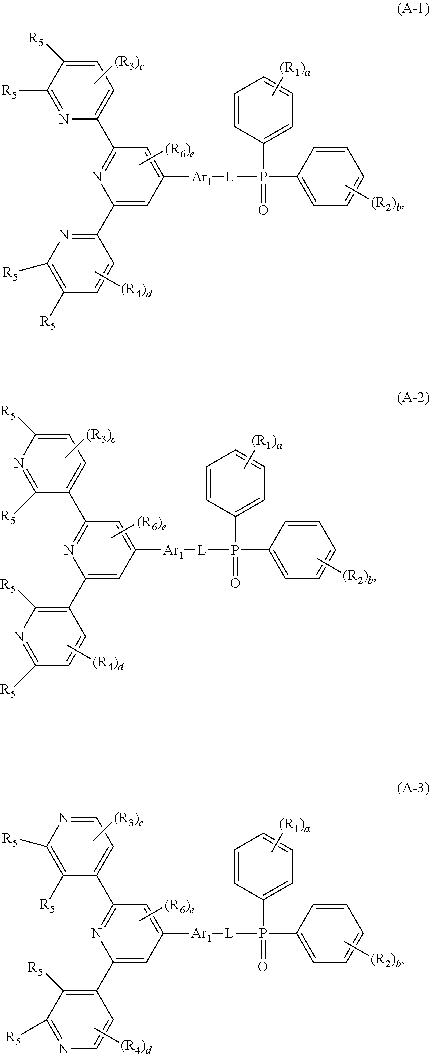
wherein R₅ is independently selected from the group consisting of hydrogen, deuterium, halogen, cyano, C1-C6 alkyl, C1-C6 heteroalkyl, C3-C6 cycloalkyl, C3-C6 heterocycloalkyl, C6-C12 aryl, and C5-C12 heteroaryl.

4. The heterocyclic compound according to claim 1, wherein Ar₁ is one of the structures of formula (B-1) to formula (B-22), or a combination of at least two thereof: 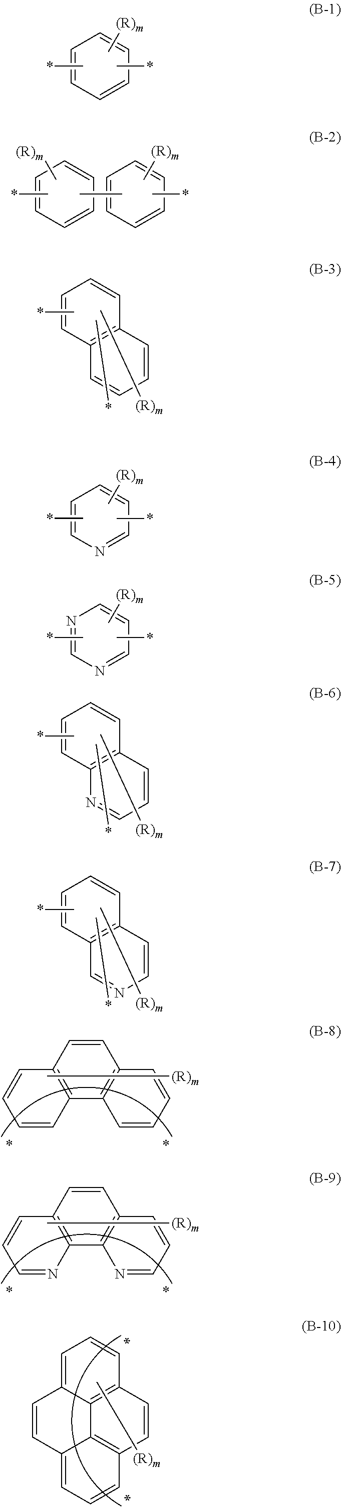 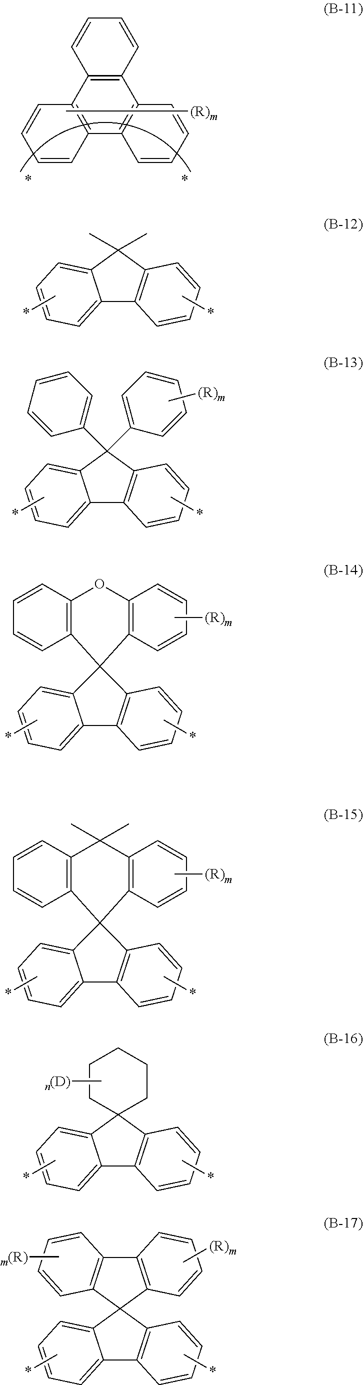 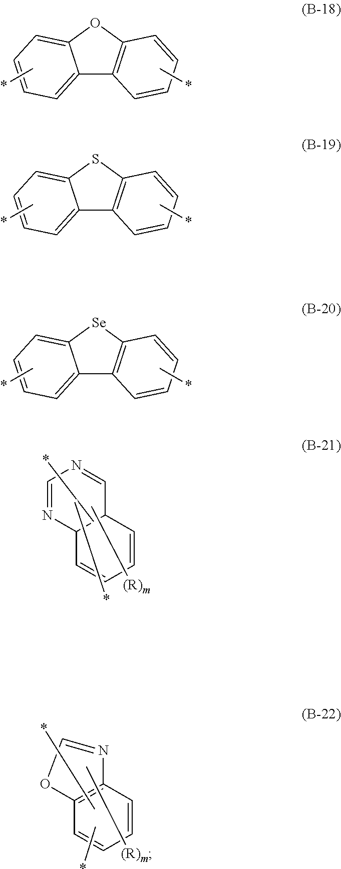
wherein R is independently selected from the group consisting of hydrogen, deuterium, halogen, cyano, isocyano, nitro, C1-C20 alkyl, C1-C20 heteroalkyl, C2-C20 alkenyl, C2-C20 alkynyl, C3-C20 cycloalkyl, C3-C20 heterocycloalkyl, C1-C6 alkyl-substituted amino, C1-C8 hydrocarbyl-substituted or unsubstituted C6-C30 aryl, C1-C8 hydrocarbyl-substituted or unsubstituted C4-C30 heteroaryl, C1-C20 alkoxy, C6-C30 aryloxy, C3-C20 alkylsilyl, C6-C30 arylsilyl, C1-C20 alkylboryl, C6-C30 arylboryl, C6-C30 arylphosphino, and C6-C30 arylamino;
m is selected from an integer of 0 to 8; and n is selected from an integer of 0 to 10; and
when —Ar₁-L- is one of the structures of formula (C-1) to formula (C-3), L is not phenylene or six-membered heteroarylene.

5. The heterocyclic compound according to claim 4, wherein L is selected from one of the structures of formula (B-1) to formula (B-20) or a combination of at least two thereof, or a single bond; and when —Ar₁-L- is selected from one of the structures of formula (C-1) to formula (C-3), L is not selected from formula (B-1), formula (B-4) or formula (B-5).

6. The heterocyclic compound according to claim 1, wherein X₁ or X₂ is N, and the rest of X₁ to X₃ are each selected from CR₅.

7. The heterocyclic compound according to claim 1, wherein R₁ to R₅, each time appearing, are each independently selected from the group consisting of hydrogen, deuterium, halogen, cyano, nitro, C1-C20 alkyl, C1-C20 heteroalkyl, C2-C20 alkenyl, C2-C20 alkynyl, C3-C20 cycloalkyl, C3-C20 heterocycloalkyl, C6-C30 aryl, C5-C30 heteroaryl, C1-C20 alkoxy, C6-C30 aryloxy, C3-C20 alkylsilyl, C6-C30 arylsilyl, C1-C20 alkylboryl, C6-C30 arylboryl, C6-C30 arylphosphino, and C6-C30 arylamino.

8. The heterocyclic compound according to claim 1, wherein R₁ to R₅, each time appearing, are each independently selected from the group consisting of hydrogen, deuterium, halogen, cyano, nitro, C1-C12 alkyl, C1-C12 heteroalkyl, C3-C12 cycloalkyl, C3-C12 heterocycloalkyl, C6-C20 aryl, and C5-C20 heteroaryl.

9. The heterocyclic compound according to claim 1, wherein each of substitutions in L and Ar₁ refers to being independently substituted with at least one selected from the group consisting of deuterium, halogen, cyano, isocyano, C1-C6 alkyl, C3-C6 cycloalkyl, C1-C6 alkyl-substituted amino, C1-C8 hydrocarbyl-substituted or unsubstituted C6-C16 aryl, C1-C8 hydrocarbyl-substituted or unsubstituted C4-C16 heteroaryl, and C6-C12 arylphosphino, wherein the number of substitutions ranges from monosubstitution to the maximum number of substitutions.

10. The heterocyclic compound according to claim 1, wherein each of substitutions in L and Ar₁ refers to being independently substituted with at least one selected from the group consisting of deuterium, halogen, cyano, isocyano, nitro, C1-C10 alkyl, C1-C10 heteroalkyl, C2-C10 alkenyl, C2-C10 alkynyl, C3-C10 cycloalkyl, C3-C10 heterocycloalkyl, C1-C6 alkyl-substituted amino, C1-C8 hydrocarbyl-substituted or unsubstituted C6-C20 aryl, C1-C8 hydrocarbyl-substituted or unsubstituted C4-C20 heteroaryl, C1-C10 alkoxy, C6-C20 aryloxy, C3-C10 alkylsilyl, C6-C20 arylsilyl, C1-C10 alkylboryl, C6-C20 arylboryl, C6-C20 arylphosphino, and C6-C20 arylamino, wherein the number of substitutions ranges from monosubstitution to the maximum number of substitutions.

11. The heterocyclic compound according to claim 1, wherein R₁ to R₅, each time appearing, are each independently selected from the group consisting of hydrogen, deuterium, halogen, cyano, C1-C6 alkyl, C1-C6 heteroalkyl, C3-C6 cycloalkyl, C3-C6 heterocycloalkyl, C6-C12 aryl, and C5-C12 heteroaryl.

12. The heterocyclic compound according to claim 1, wherein R₁ to R₅, each time appearing, are each independently selected from the group consisting of hydrogen, deuterium, F, Cl, Br, methyl, ethyl, propyl, butyl, phenyl and benzoxazolyl.

13. The heterocyclic compound according to claim 4, wherein the heterocyclic compound satisfies at least one of the following conditions:
(1) only one of X₁ to X₃ is N, and the rest of X₁ to X₃ are each selected from CR₅, and each of R₅ is independently selected from the group consisting of hydrogen, deuterium, methyl and phenyl;
(2) R₁ to R₄, each time appearing, are each independently selected from the group consisting of hydrogen, deuterium, methyl, phenyl and pyridyl;
(3) R₆ is hydrogen, deuterium, or fluorine; and
(4) Ar₁ is one of the structures of formula (B-1) to formula (B-22), or a combination of at least two thereof, L is one of the structures of formula (B-1) to formula (B-20) or a combination of at least two thereof, or single bond; and when —Ar1-L- is one of the structures of formula (C-1) to formula (C-3), L is not formula (B-1), formula (B-4), or formula (B-5);
wherein R is independently selected from the group consisting of hydrogen, deuterium, fluorine, cyano, methyl, isopropyl, tert-butyl, C1-C8 hydrocarbyl-substituted or unsubstituted phenyl, naphthyl, phenanthryl, pyridyl, pyrimidinyl, and benzoxazolyl.

14. An organic electroluminescent device, comprising an anode and a cathode, wherein a functional layer is disposed between the cathode and the anode; the functional layer comprises the heterocyclic compound according to claim 1.

15. The organic electroluminescent device according to claim 14, wherein the functional layer comprises a first light-emitting unit, a charge generation layer and a second light-emitting unit stacked sequentially from a side of the anode to a side of the cathode; and the charge generation layer comprises the heterocyclic compound.

16. The organic electroluminescent device according to claim 15, wherein the charge generation layer comprises an N-type charge generation layer and a P-type charge generation layer stacked sequentially from a side of the first light-emitting unit to a side of the second light-emitting unit; and the N-type charge generation layer comprises the heterocyclic compound.

17. The organic electroluminescent device according to claim 16, wherein the N-type charge generation layer further comprises a dopant material; the dopant material is at least one selected from the group consisting of an alkali metal, an alkaline earth metal, and a lanthanide metal.

18. The organic electroluminescent device according to claim 17, wherein the N-type charge generation layer comprises the dopant material with a mass percentage of 0.1% to 20%.

19. The organic electroluminescent device according to claim 16, wherein the mass percentage of the heterocyclic compound in the N-type charge generation layer is 80% to 99.9%.

20. An optoelectronic element, comprising the organic electroluminescent device according to claim 14.
